(19) United States
(12) Patent Application Publication
(10) Pub. No.: US 2024/0209006 A1
(43) Pub. Date: Jun. 27, 2024

(54) ORGANIC COMPOUND, LIGHT-EMITTING ELEMENT, AND DISPLAY PANEL

(71) Applicant: SHENZHEN CHINA STAR OPTOELECTRONICS SEMICONDUCTOR DISPLAY TECHNOLOGY CO., LTD., SHENZHEN (CN)

(72) Inventors: Ruifeng He, Shenzhen (CN); Canjie Wu, Shenzhen (CN); Yan Li, Shenzhen (CN); Jingyao Song, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 18/148,878

(22) Filed: Dec. 30, 2022

(30) Foreign Application Priority Data
Dec. 12, 2022 (CN) 202211598613.0

(51) Int. Cl. C07F 5/02; H10K 50/11; H10K 59/10; H10K 85/60

(52) U.S. Cl. CPC C07F 5/027; H10K 50/11; H10K 59/10; H10K 85/622; H10K 85/624; H10K 85/633; H10K 85/636; H10K 85/6572; H10K 85/6574; H10K 85/6576; H10K 85/658; C07B 2200/05

(57) ABSTRACT

The present disclosure discloses an organic compound, a light emitting element, and a display panel. The organic compound is represented by formula (1):

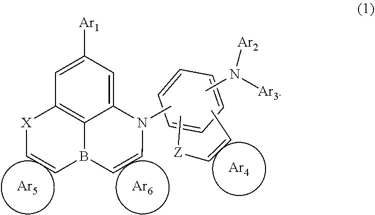

Z is selected from CR₁R₂, NR₃, O, and S; X is selected from O and NR₄; Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group; Ar₂ and Ar₃ are each independently selected from a methyl group, a substituted or unsubstituted C₇-C₁₈ aromatic group, and a substituted or unsubstituted C₁₂-C₁₆ heteroaromatic group; and Ar₄, Ar₅, and Ar₆ are each independently selected from a substituted or unsubstituted C₆-C₃₁ aromatic group and a substituted or unsubstituted C₆-C₂₆ heteroaromatic group.

### TECHNICAL FIELD

The present disclosure relates to the technical field of display, in particular to an organic compound, a light-emitting element, and a display panel.

### BACKGROUND

At present, organic electroluminescent elements generally include a positive electrode, a negative electrode, and an organic layer located between the positive electrode and the negative electrode. Organic substances in the organic layer are used to convert electric energy into light energy to achieve organic electroluminescence. The organic layer is generally configured to be multi-layers, so as to improve light-emitting efficiency and service life of organic electroluminescent elements. The organic substances in each of the multi-layers are different. In particular, each of the organic layers mainly includes a hole injection layer, a hole transport layer, a light-emitting layer, an electron transport layer, and an electron injection layer, etc. Voltages are applied on the positive electrodes and the negative electrodes of the organic electroluminescent element. Holes are injected into the organic layer from the positive electrodes. Electrons are injected into the organic layer from the negative electrodes. The injected holes meet the injected electrons in the organic layer to form excitons. The excitons emit light when transiting back to the ground state, thereby realizing light emission of the organic electroluminescent element. Because the organic electroluminescent elements have characteristics such as self-emission, high brightness, great efficiency, low driving voltages, wide viewing angles, high contrast ratios, good responsiveness, organic electroluminescent devices have broad application prospects.

Accordingly, development of organic light-emitting diode (OLED) materials has attracted extensive attention due to a series of advantages such as diversity in synthesis, simple composition and processes. At the same time, in order to improve luminous efficiency of the organic electroluminescent elements, people have tried various material systems with energy transmission and conversion mechanisms. However, performances such as luminous efficiency, stability, and life of light-emitting materials used for OLED elements are still poor, resulting in limited performance improvement of the OLED elements.

Therefore, an organic compound, a light-emitting element and a display panel are urgently needed to solve the above-mentioned technical problems.

### SUMMARY

The present disclosure provides an organic compound, a light-emitting element, and a display panel, which can alleviate technical problems that poor performances such as low luminous efficiency, poor stability, and low life of light-emitting materials currently used for OLED elements lead to difficulty in improving performances of the OLED elements.

The present disclosure provides an organic compound represented by formula (1):

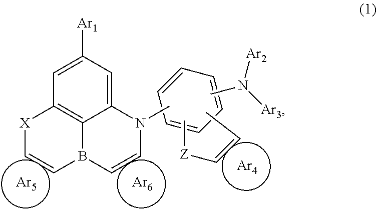

wherein Z is selected from CR₁R₂, NR₃, O, and S;

X is selected from O and NR₄;

R₁, R₂, R₃, and R₄ are each independently selected from a substituted or unsubstituted C₁-C₄ alkyl group, a substituted or unsubstituted C₆-C₂₉ aromatic group, and a substituted or unsubstituted C₂₆-C₃₆ heteroaromatic group;

a ring is formed or no ring is formed by an interconnection of R₁ and R₂;

Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group;

Ar₂ and Ar₃ are each independently selected from a methyl group, a substituted or unsubstituted C₇-C₁₈ aromatic group, and a substituted or unsubstituted C₁₂-C₁₆ heteroaromatic group; and

Ar₄, Ar₅, and Ar₆ are each independently selected from a substituted or unsubstituted C₆-C₃₁ aromatic group and a substituted or unsubstituted C₆-C₂₆ heteroaromatic group.

Preferably, the organic compound is represented by any one of formula (2) to formula (11):

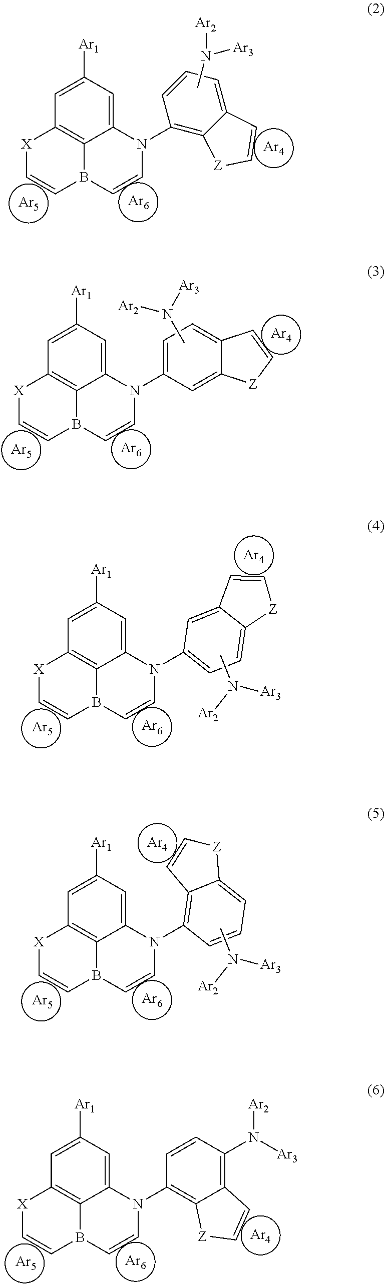

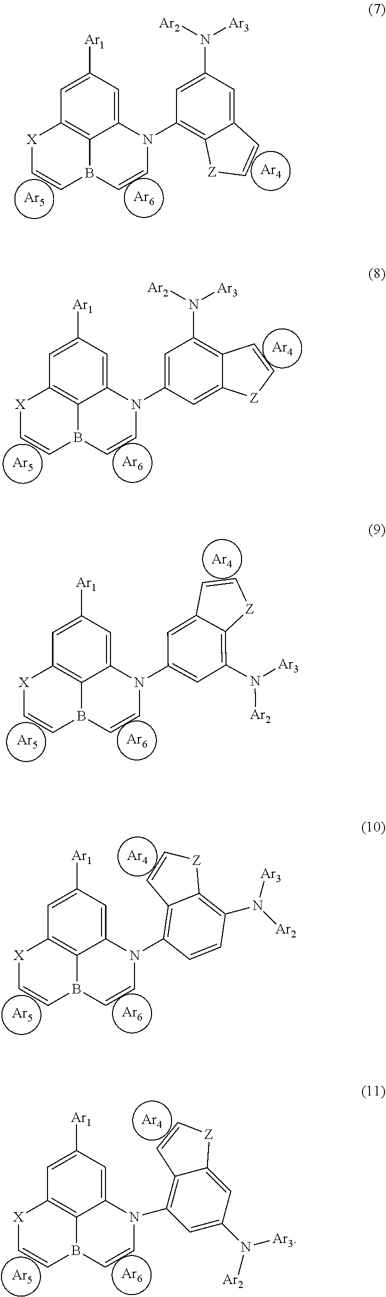

Preferably, the organic compound is represented by formula (12):

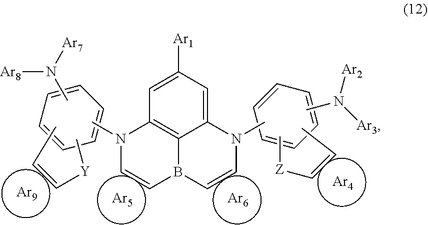

wherein Y is selected from CR₅R₆, NR₇, O, and S;

R₅, R₆, and R₇ are each independently selected from a substituted or unsubstituted methyl group and a substituted or unsubstituted C₆-C₁₀ aromatic group;

a ring is formed or no ring is formed by an interconnection of R₅ and R₆;

Ar₇ and Ar₈ are each independently selected from a substituted or unsubstituted C₆-C₁₀ aromatic group; and

Ar₉ is selected from a substituted or unsubstituted phenyl group.

Preferably, R₅, R₆, and R₇ are each independently selected from a methyl group and a substituted or unsubstituted phenyl group;

Ar₇ and Ar₈ are each independently selected from a methyl group, a substituted or unsubstituted phenyl group, and a substituted or unsubstituted naphthyl group.

Preferably, the organic compound is represented by formula (13):

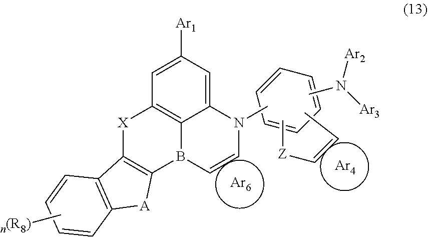

wherein A is represented by CR₉R₁₀, NR₁₁, O, or S;

n is an integer ranging from 0 to 4;

R₈, R₉, R₁₀, and R₁₁ are each independently selected from a substituted or unsubstituted C₁-C₄ alkyl group and a substituted or unsubstituted C₆-C₁₀ aromatic group; and

when n is equal to 0, a ring is formed or no ring is formed by an interconnection of R₉ and R₁₀; when n is greater than or equal to 1, a ring is formed or no ring is formed by an interconnection of R₈ and R₉ and/or R₁₀.

Preferably, the organic compound is represented by formula (14):

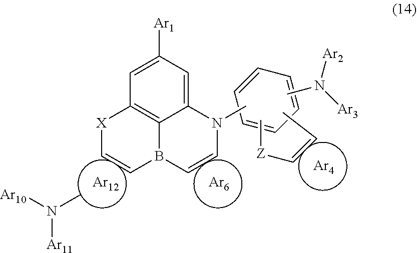

wherein Ar₁₀ and Ar₁₁ are each independently selected from a methyl group, a substituted or unsubstituted C₆-C₁₈ aromatic group, and a substituted or unsubstituted C₅-C₁₃ heteroaromatic group; and

Ar₁₂ is selected from a substituted or unsubstituted phenyl group.

Preferably, Ar₁₀ and Ar₁₁ are each independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

Preferably, Ar₁ is selected from —H, —D, a methyl group, an isopropyl group, a tertbutyl group, a tertamyl group, a substituted or unsubstituted phenyl group, a substituted or unsubstituted naphthyl group, a substituted or unsubstituted dibenzofuran, a substituted or unsubstituted dibenzothiophene, a substituted or unsubstituted fluorenyl group, a substituted or unsubstituted carbazolyl group, and a substituted or unsubstituted amino group;

Ar₂, Ar₃, Ar₄, Ar₅, and Ar₆ are each independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazolyl group; and

R₁, R₂, R₃, and R₄ are each independently selected from a methyl group and a substituted or unsubstituted phenyl group.

Preferably, the organic compound is selected from following compounds:

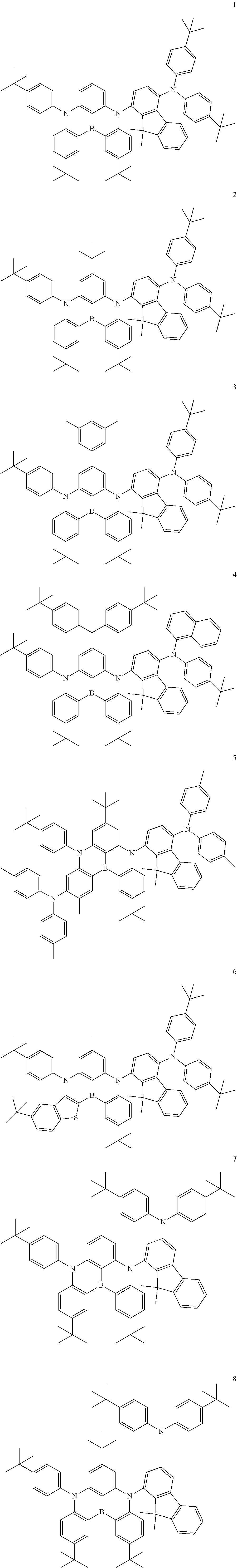

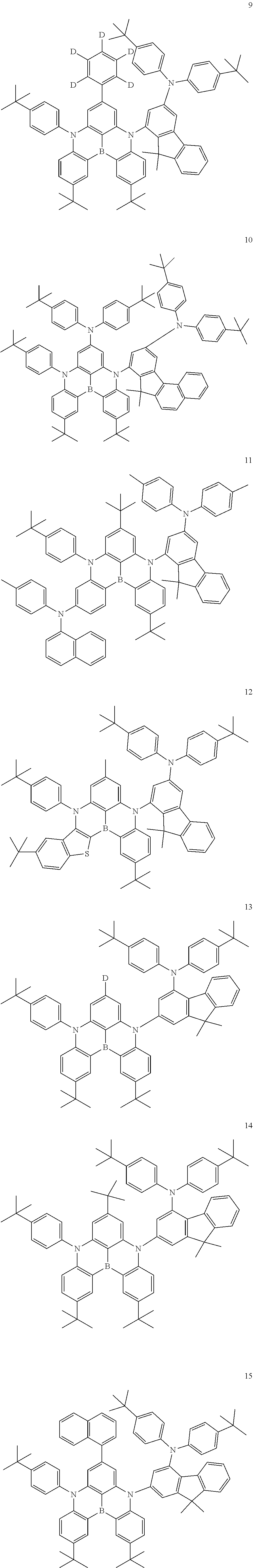

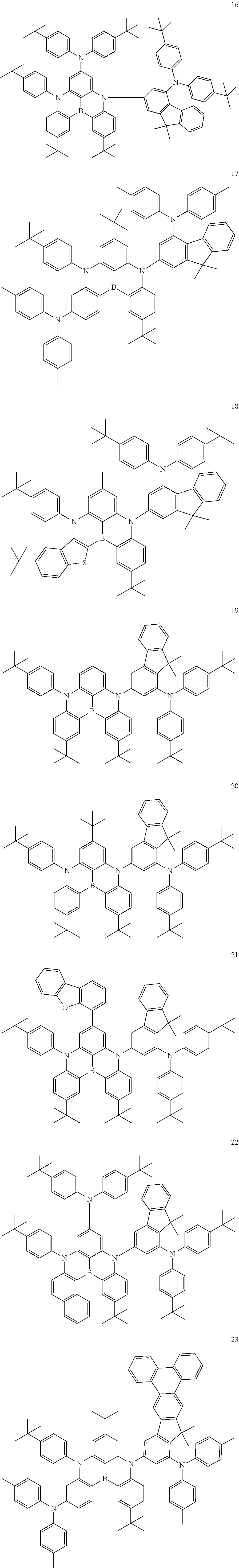

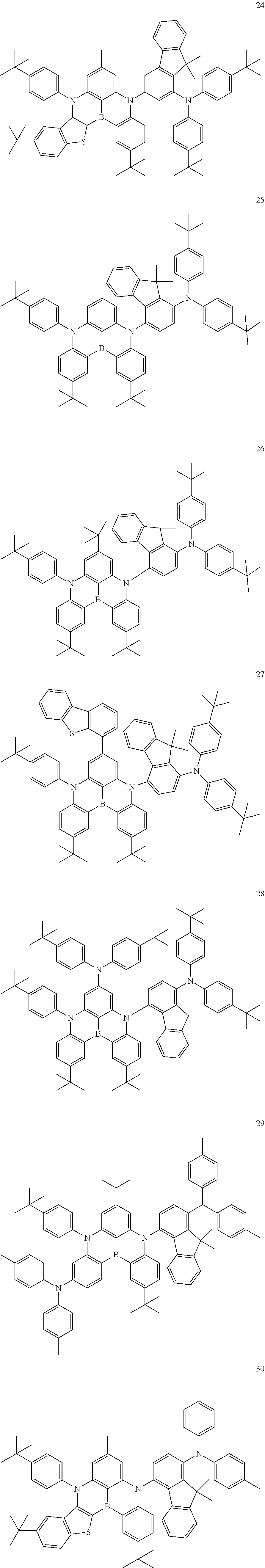

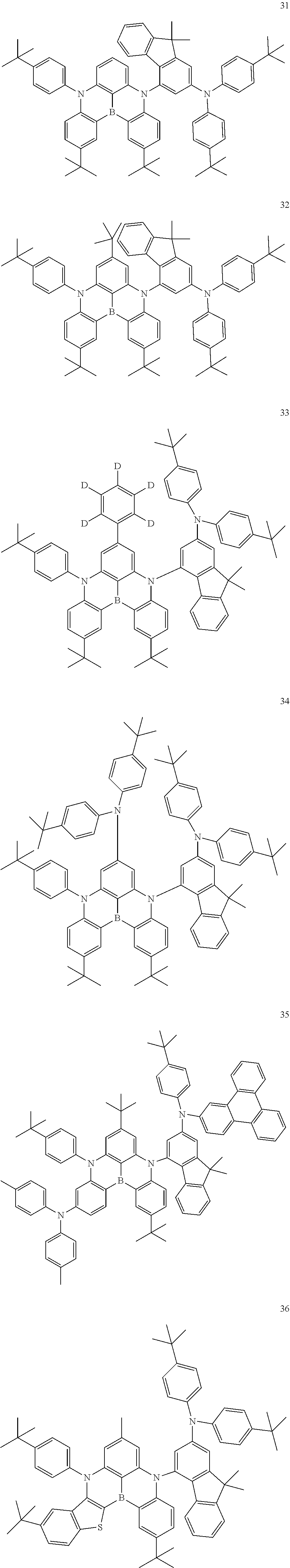

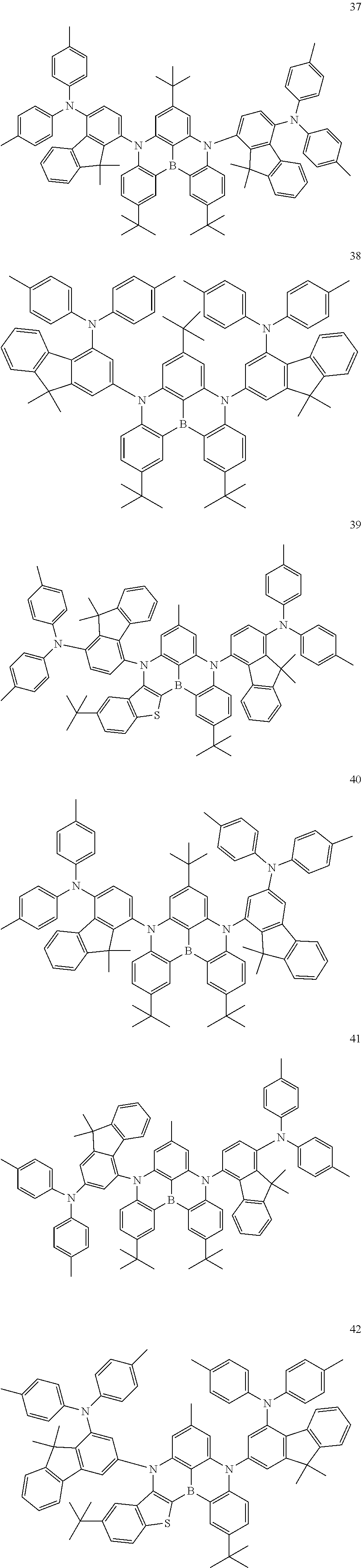

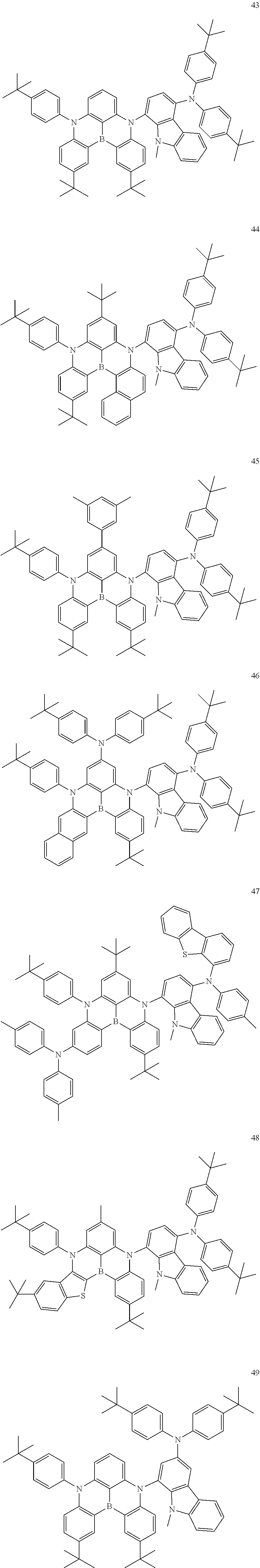

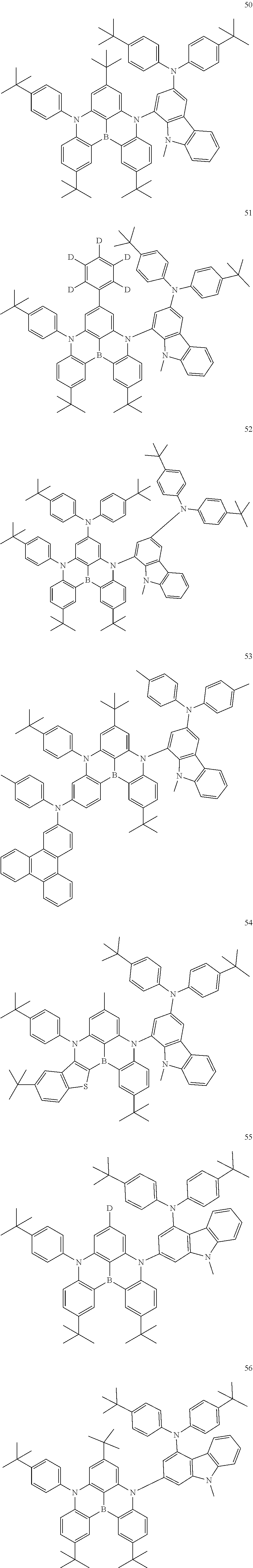

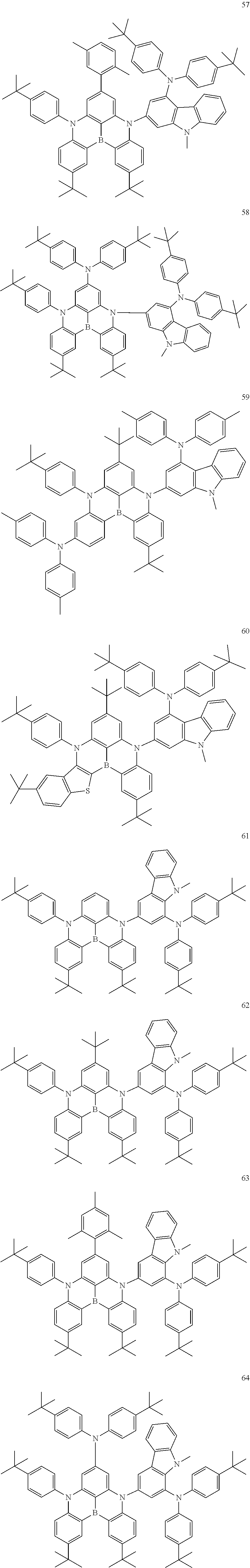

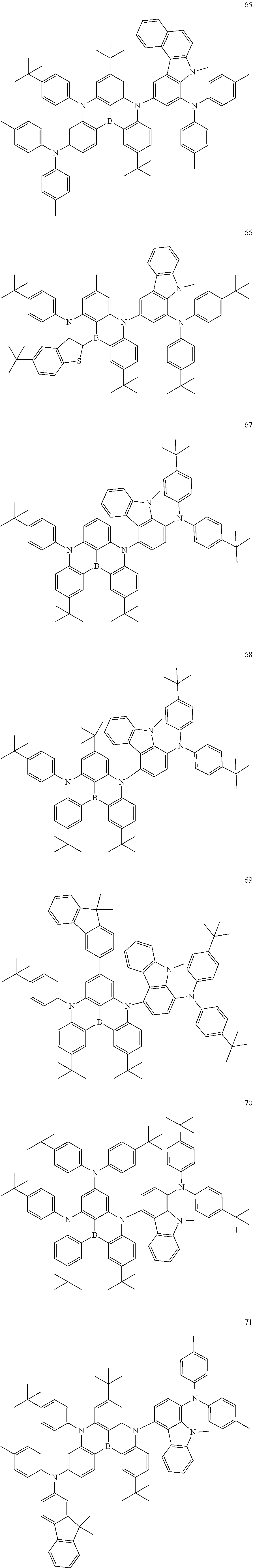

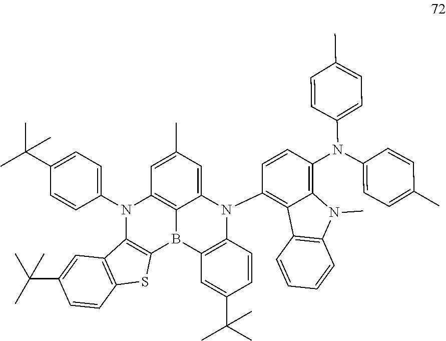 [SMILES: Cc1ccc(N(c2ccc(C)cc2)c2ccc(N3c4ccc(C(C)(C)C)cc4B4c5sc6ccc(C(C)(C)C)cc6c5N(c5ccc(C(C)(C)C)cc5)c5cc(C)cc3c54)c3c4ccccc4n(C)c23)cc1]

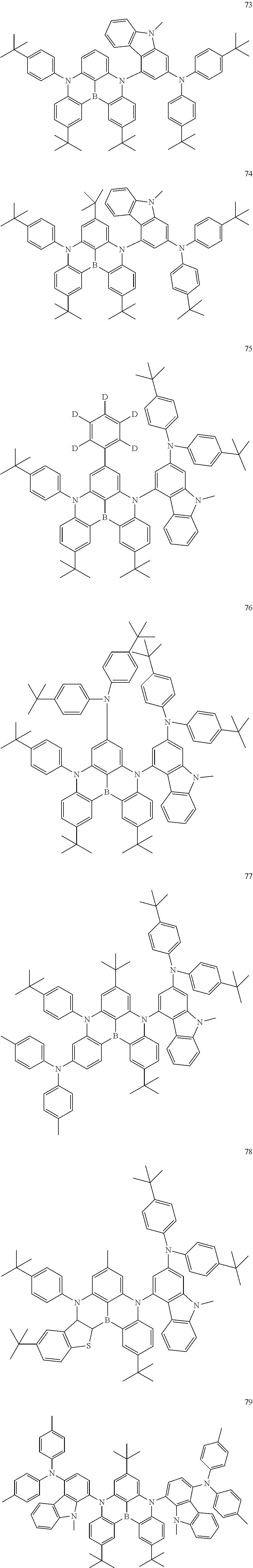

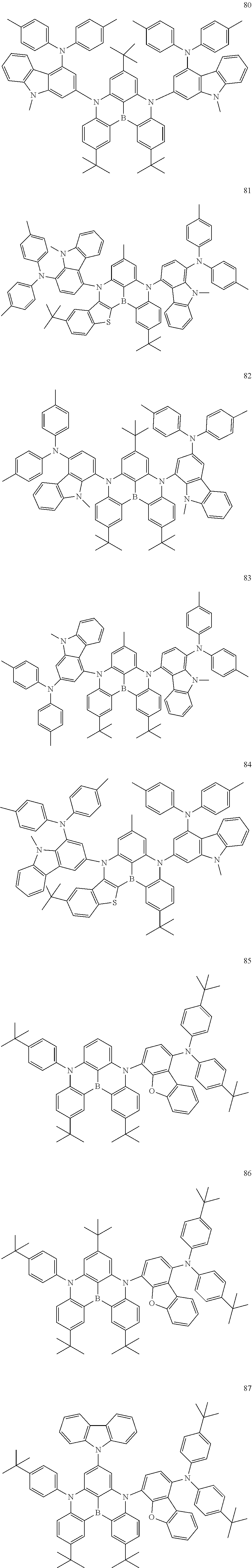

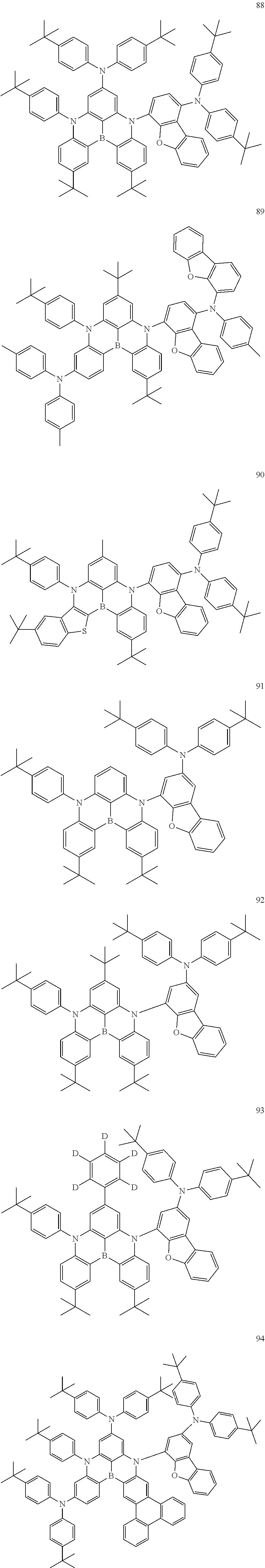

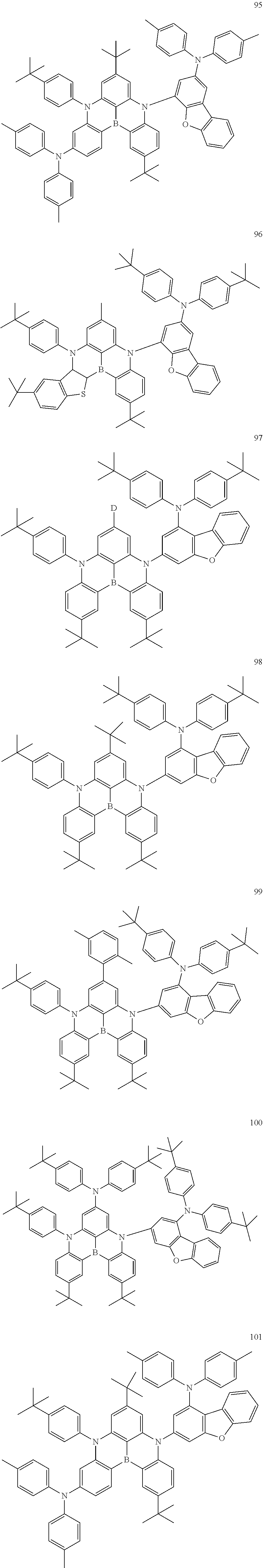

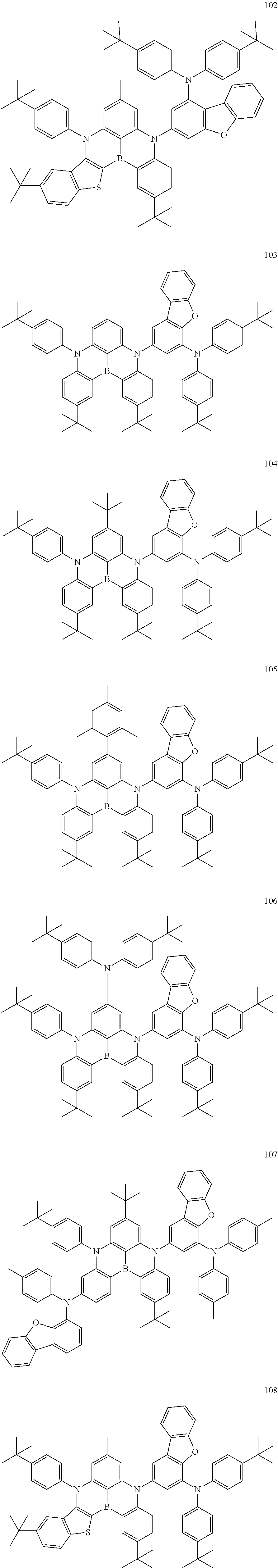

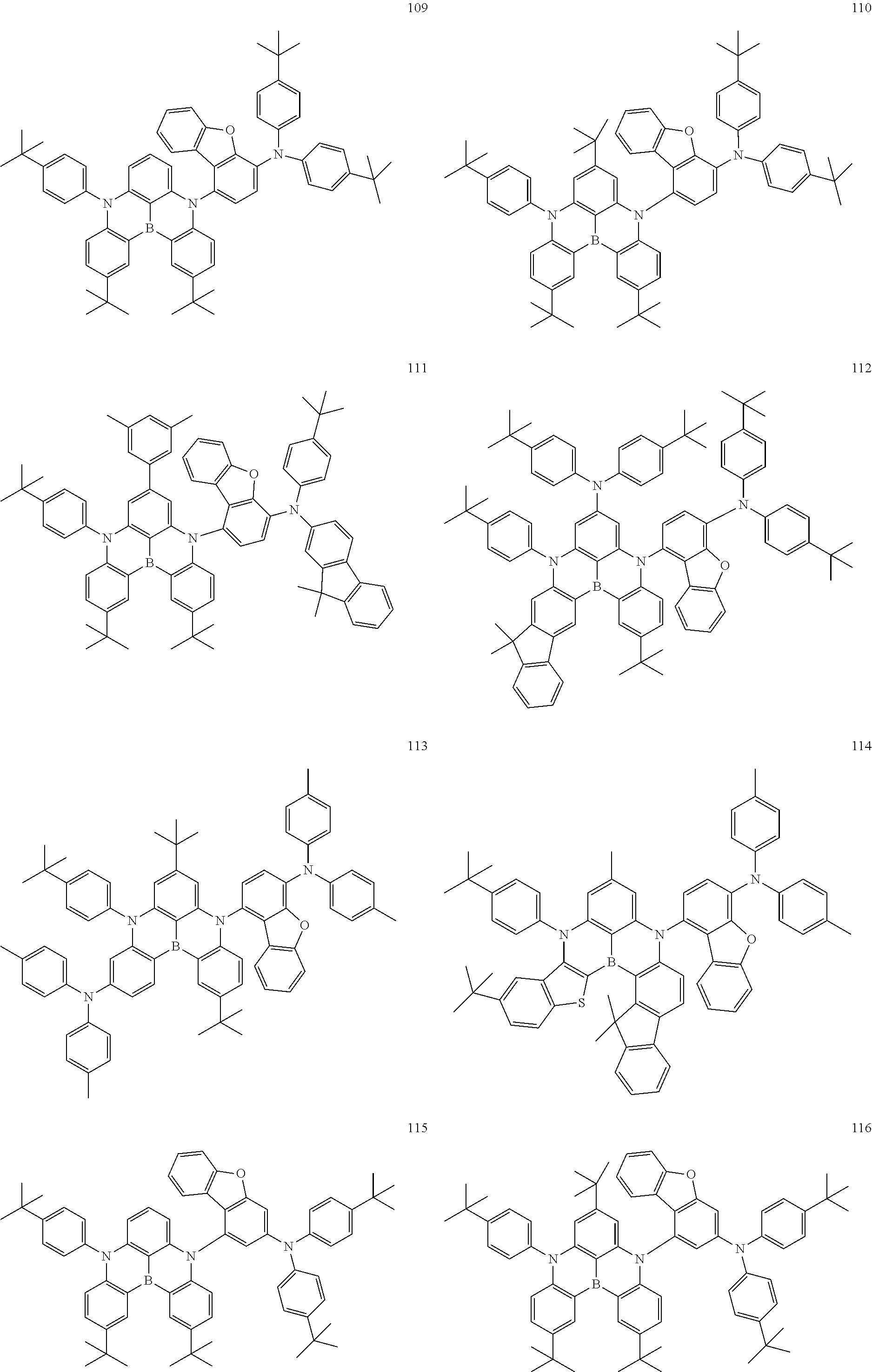

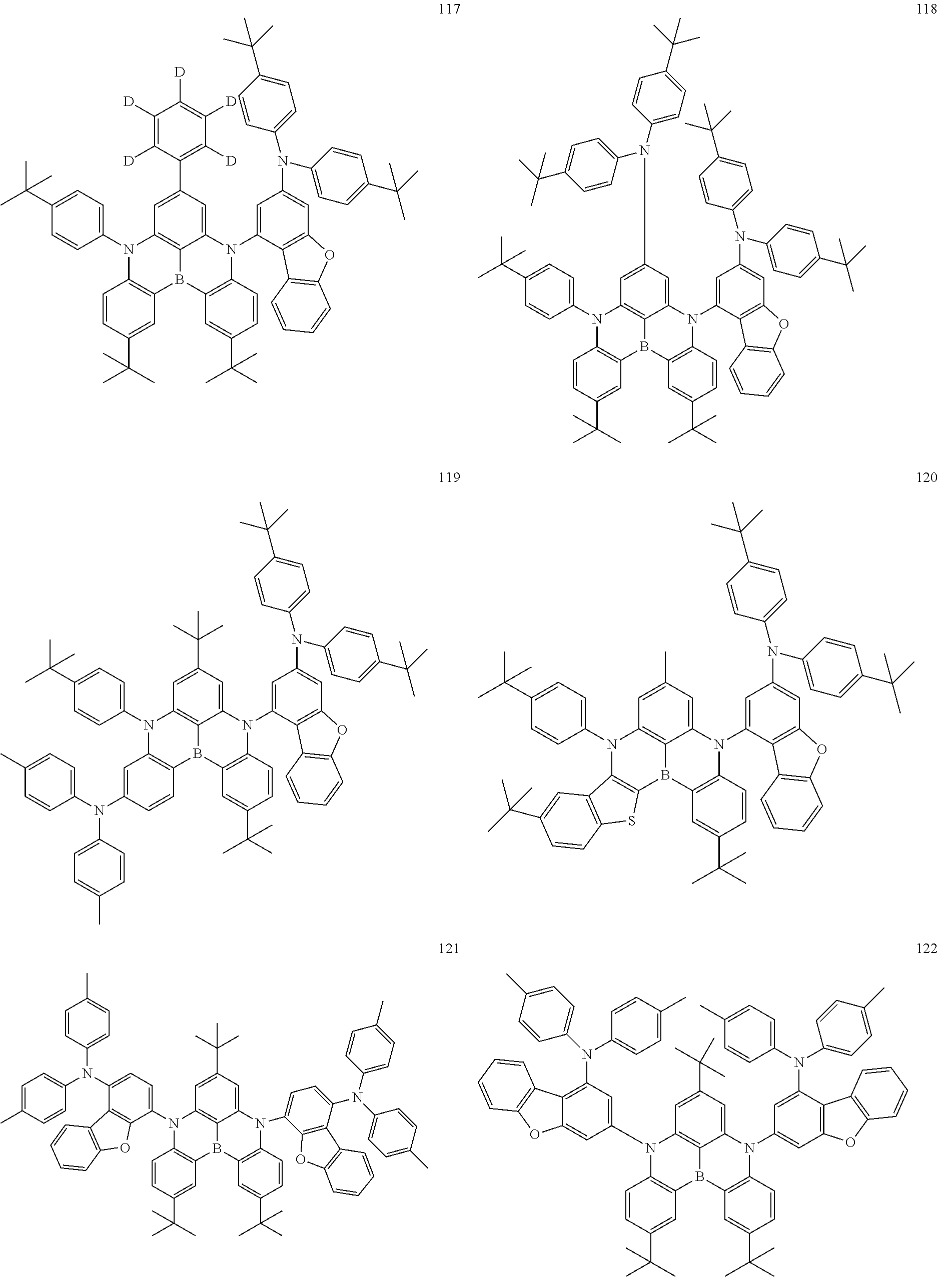

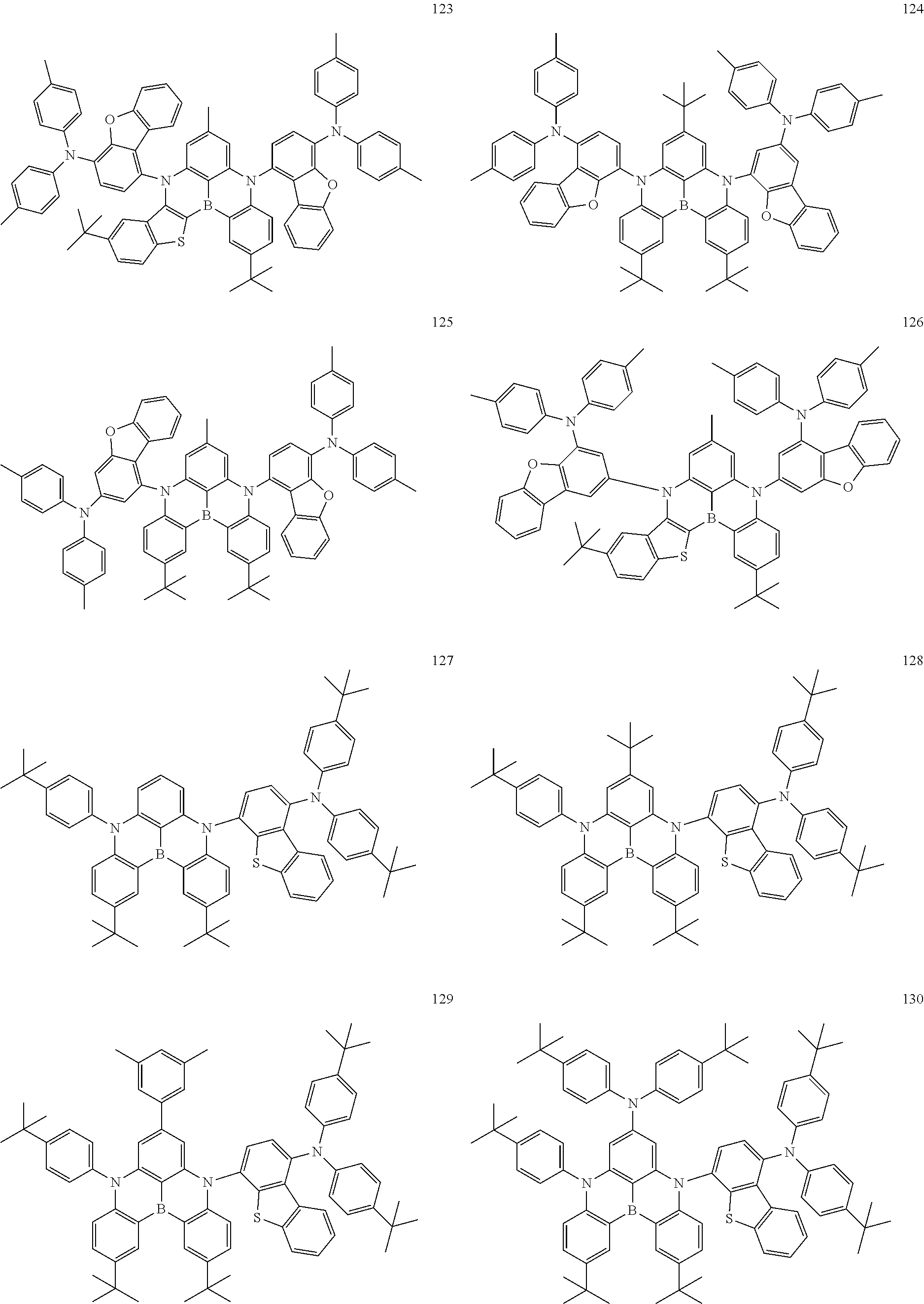

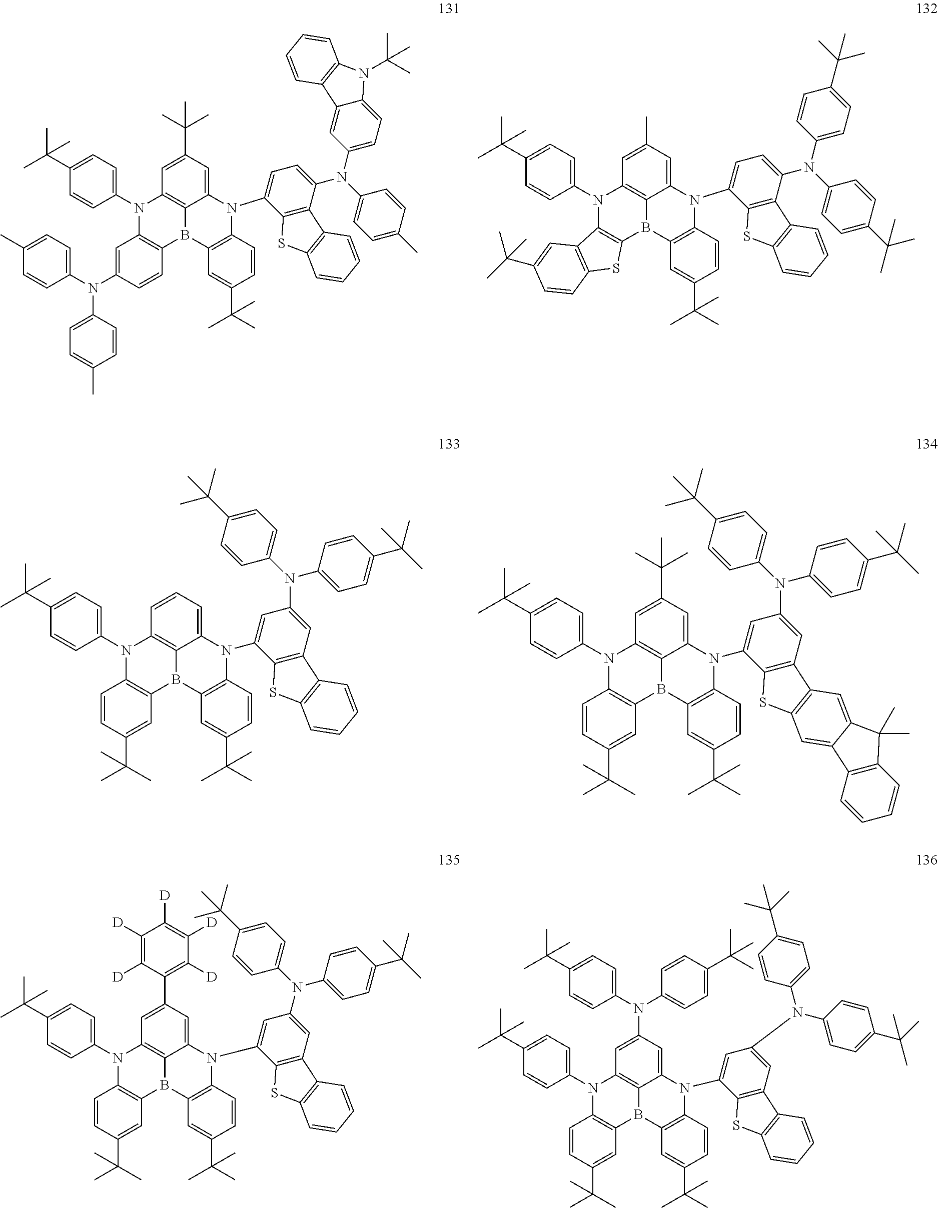

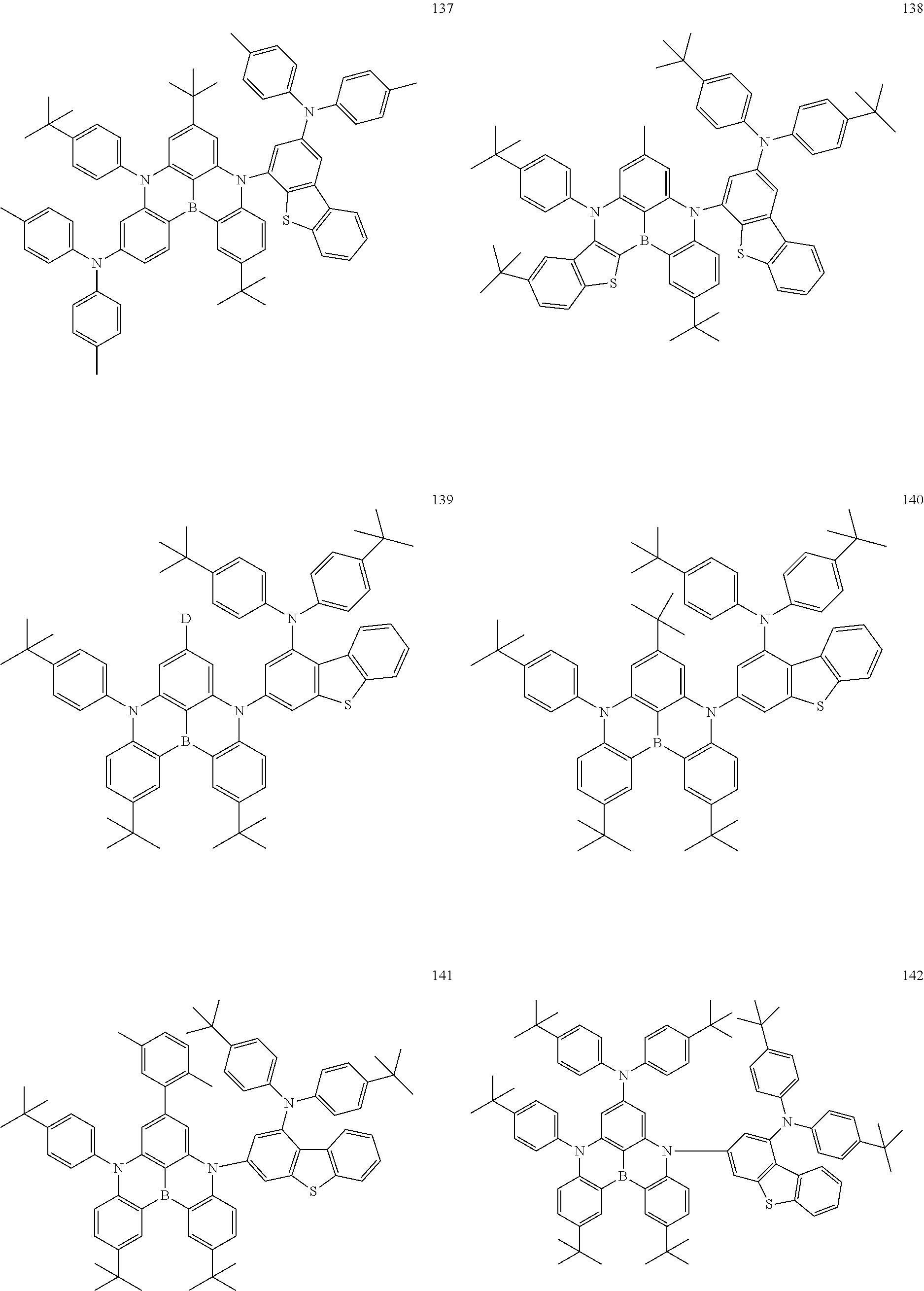

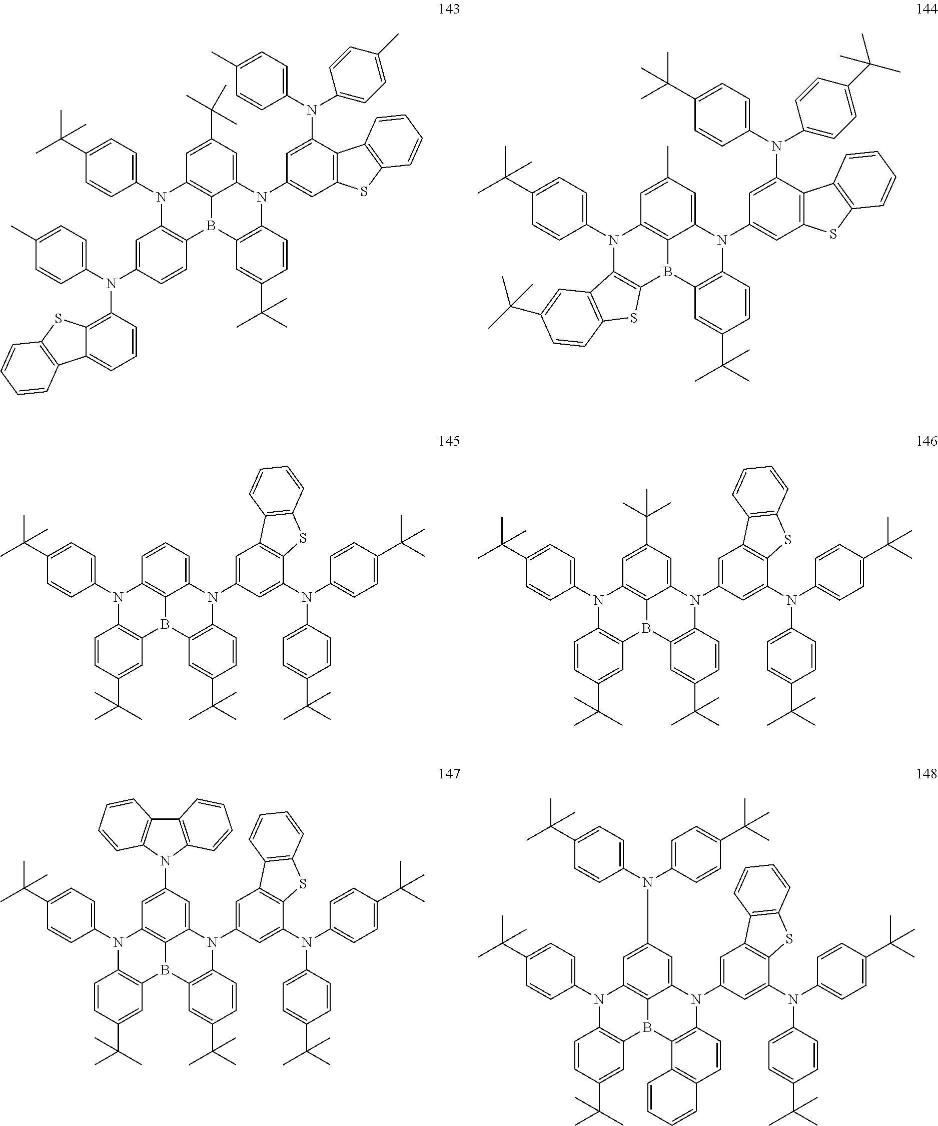

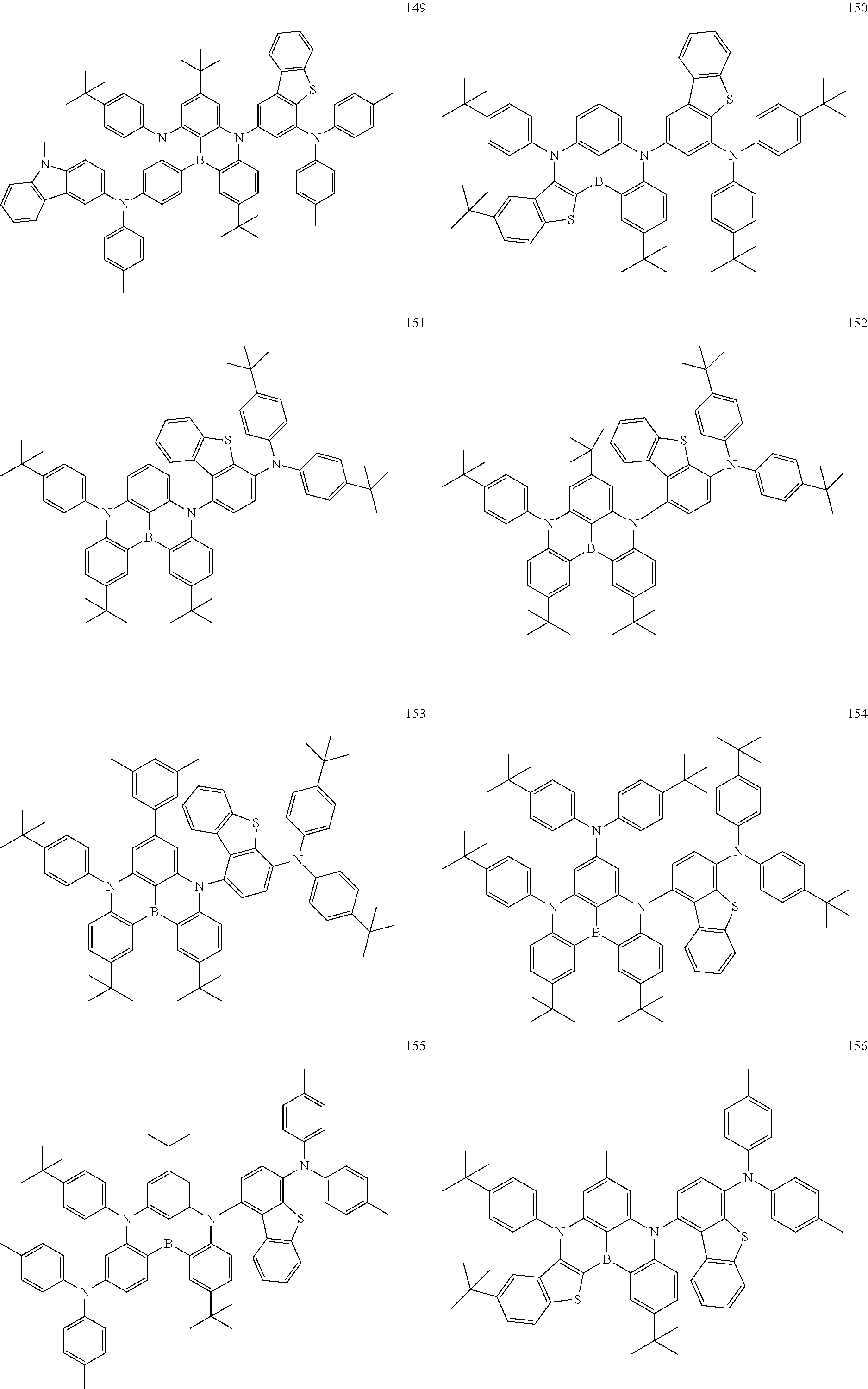

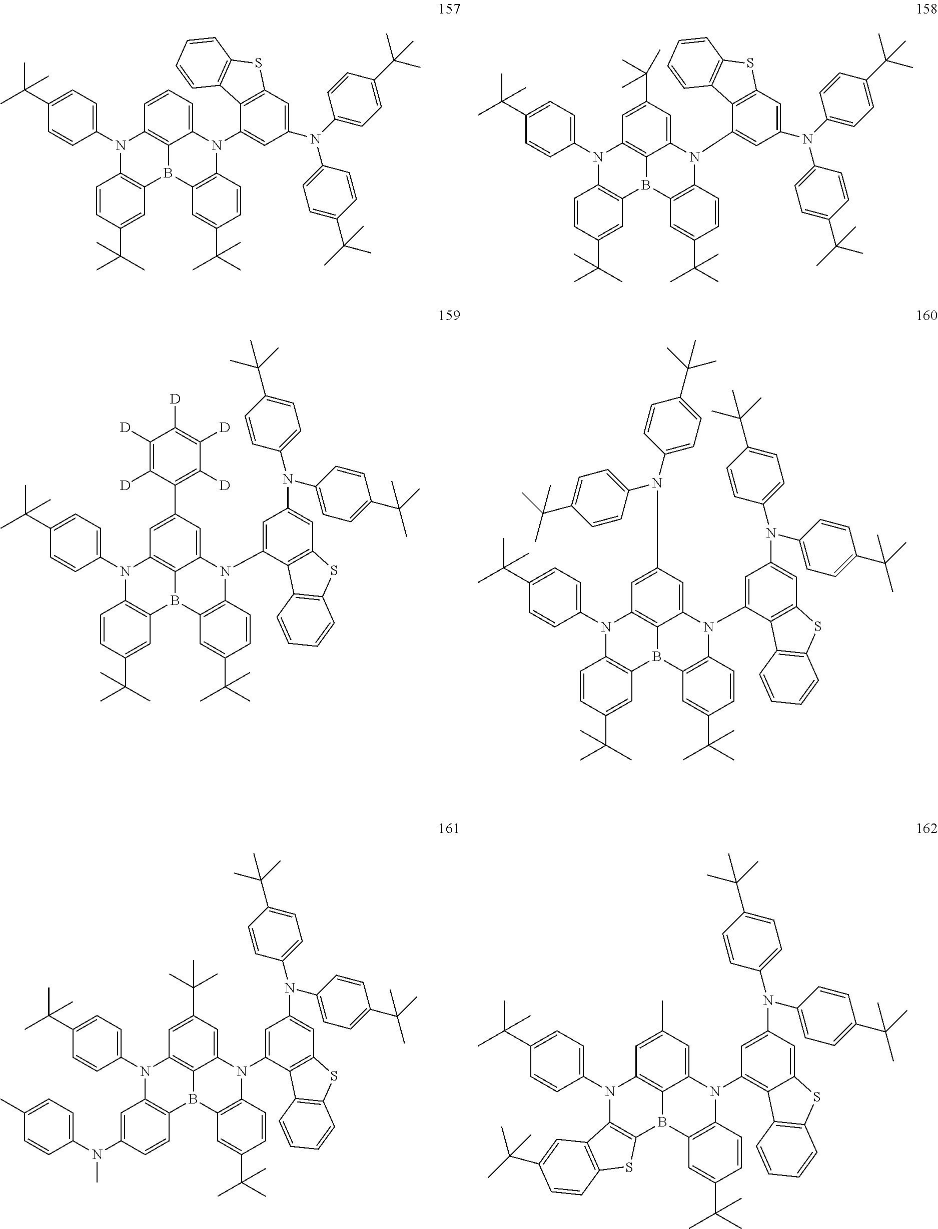

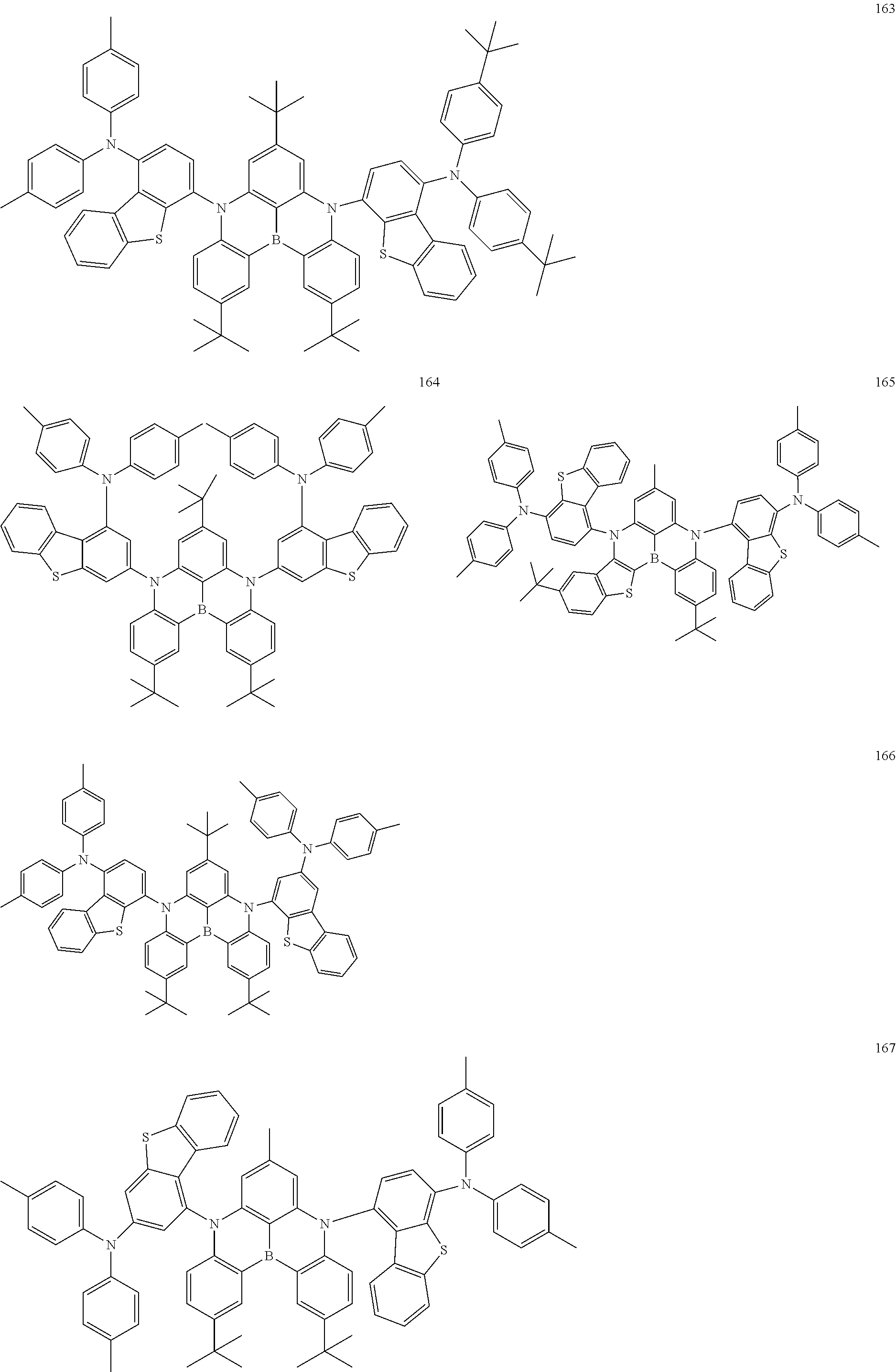

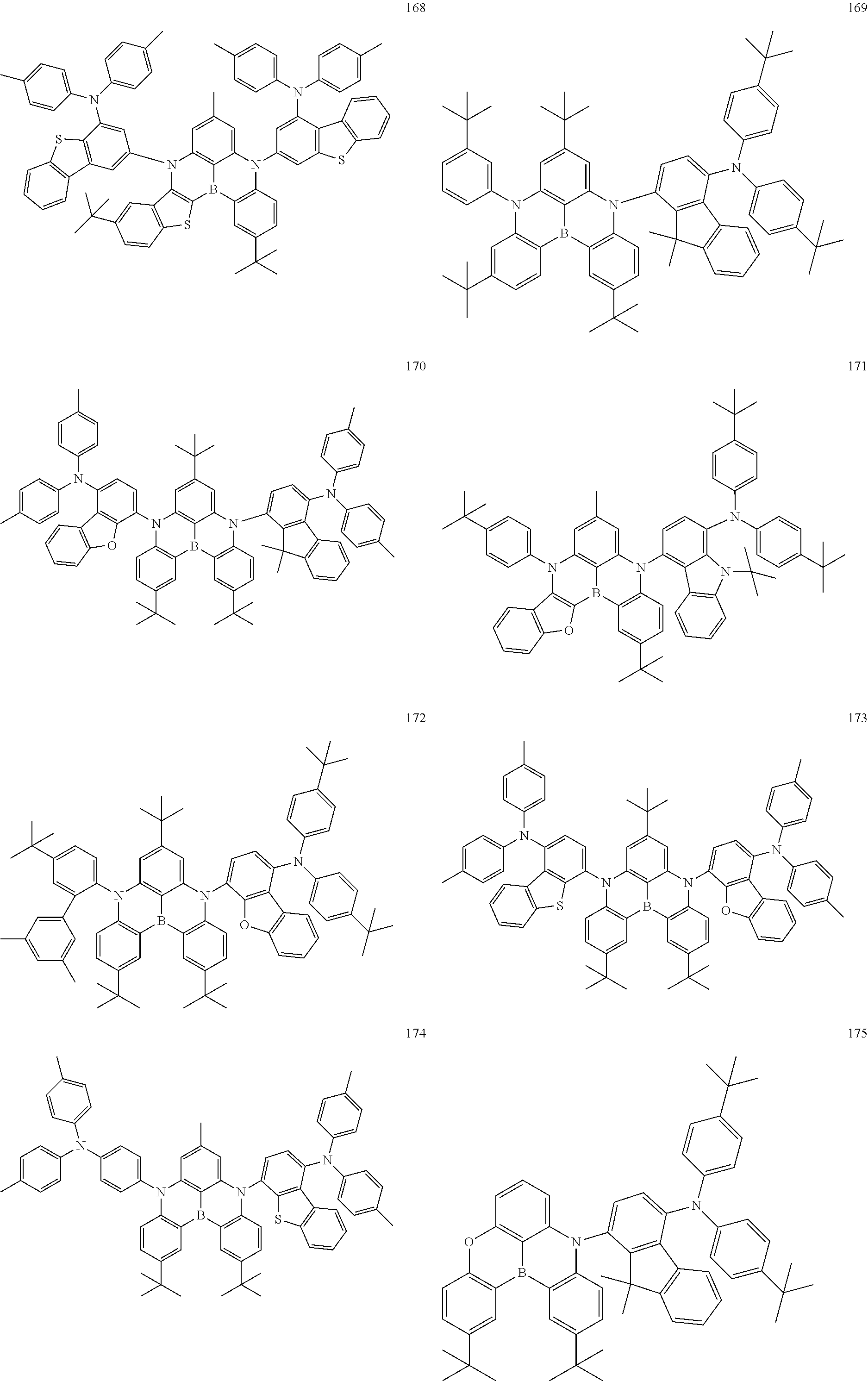

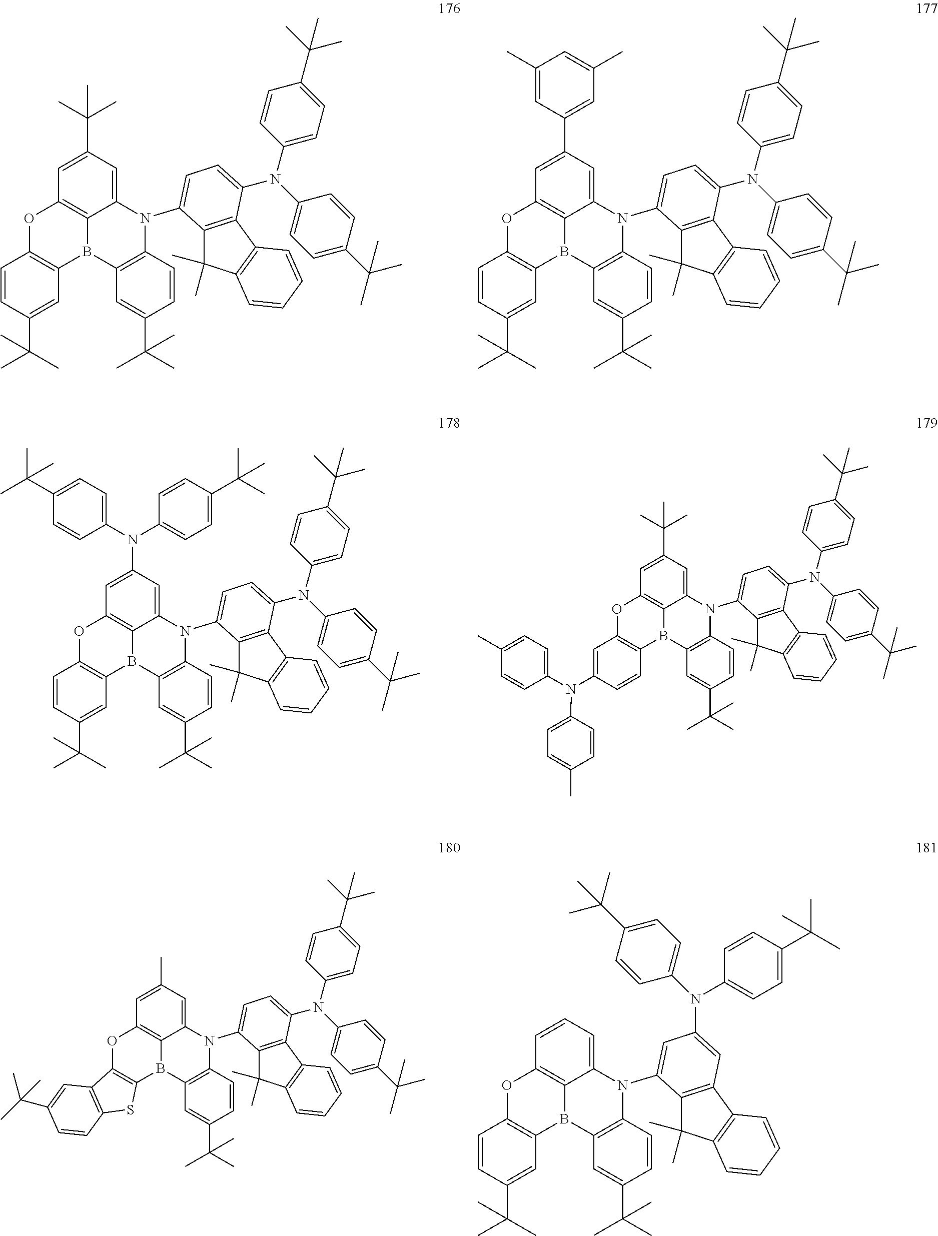

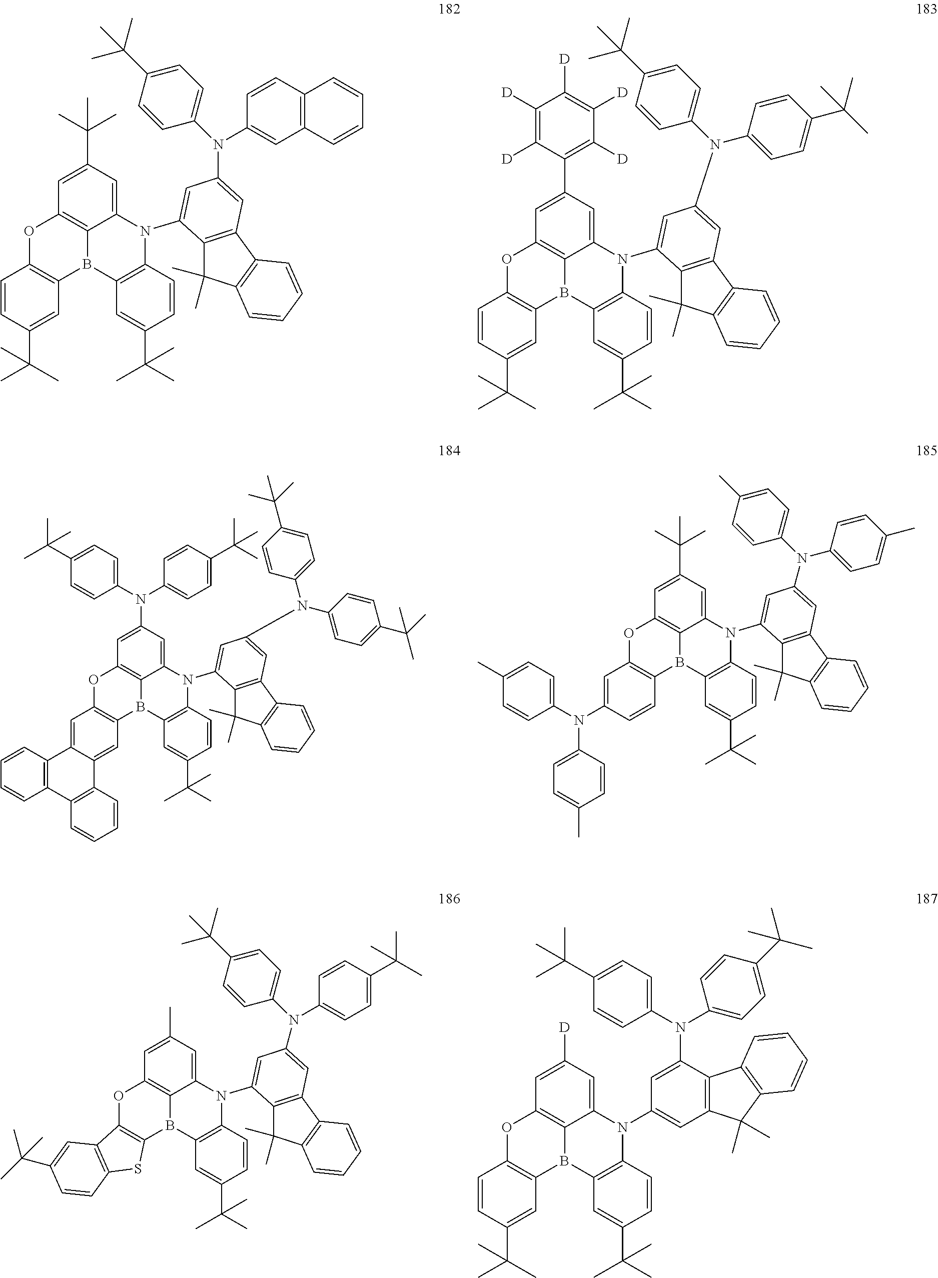

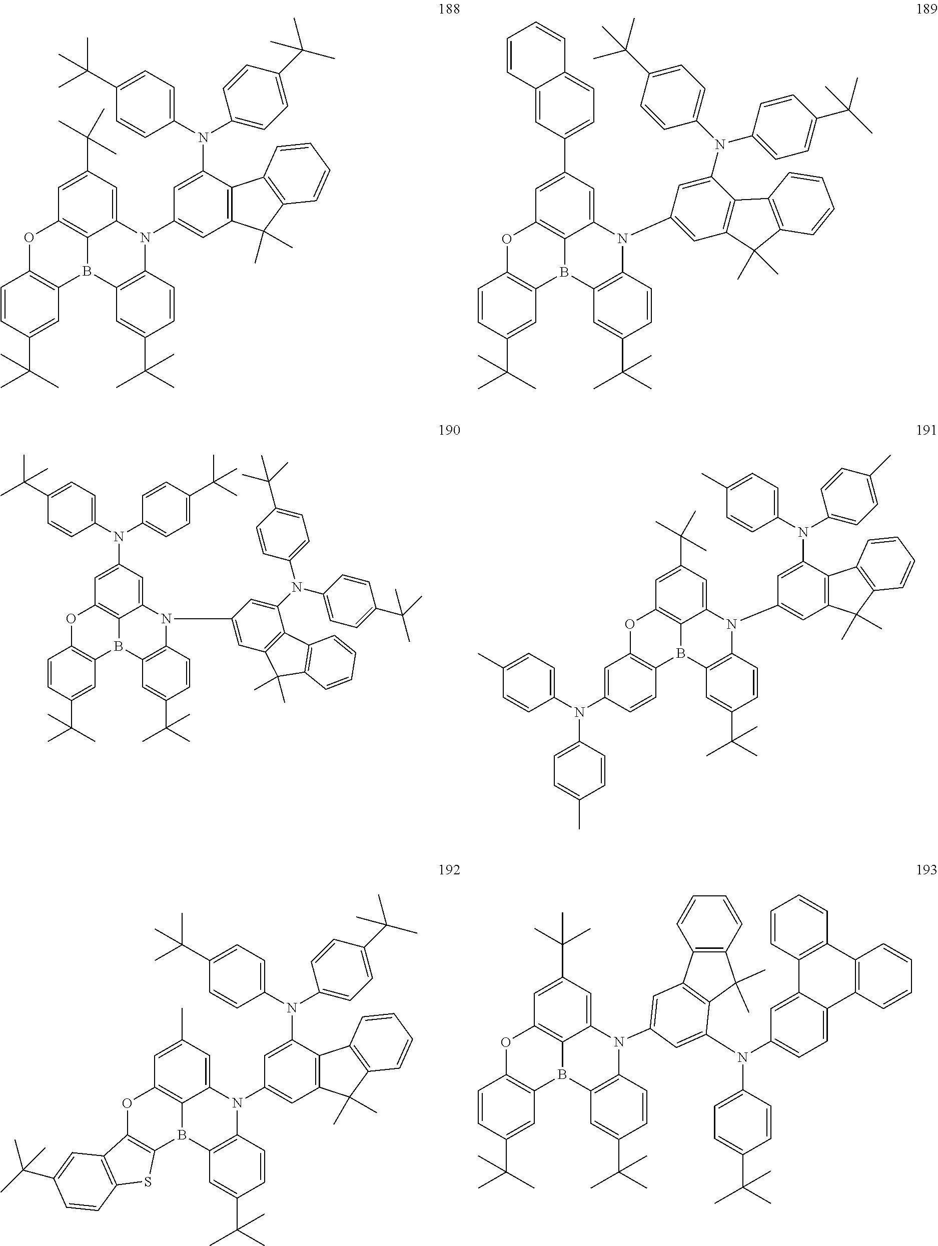

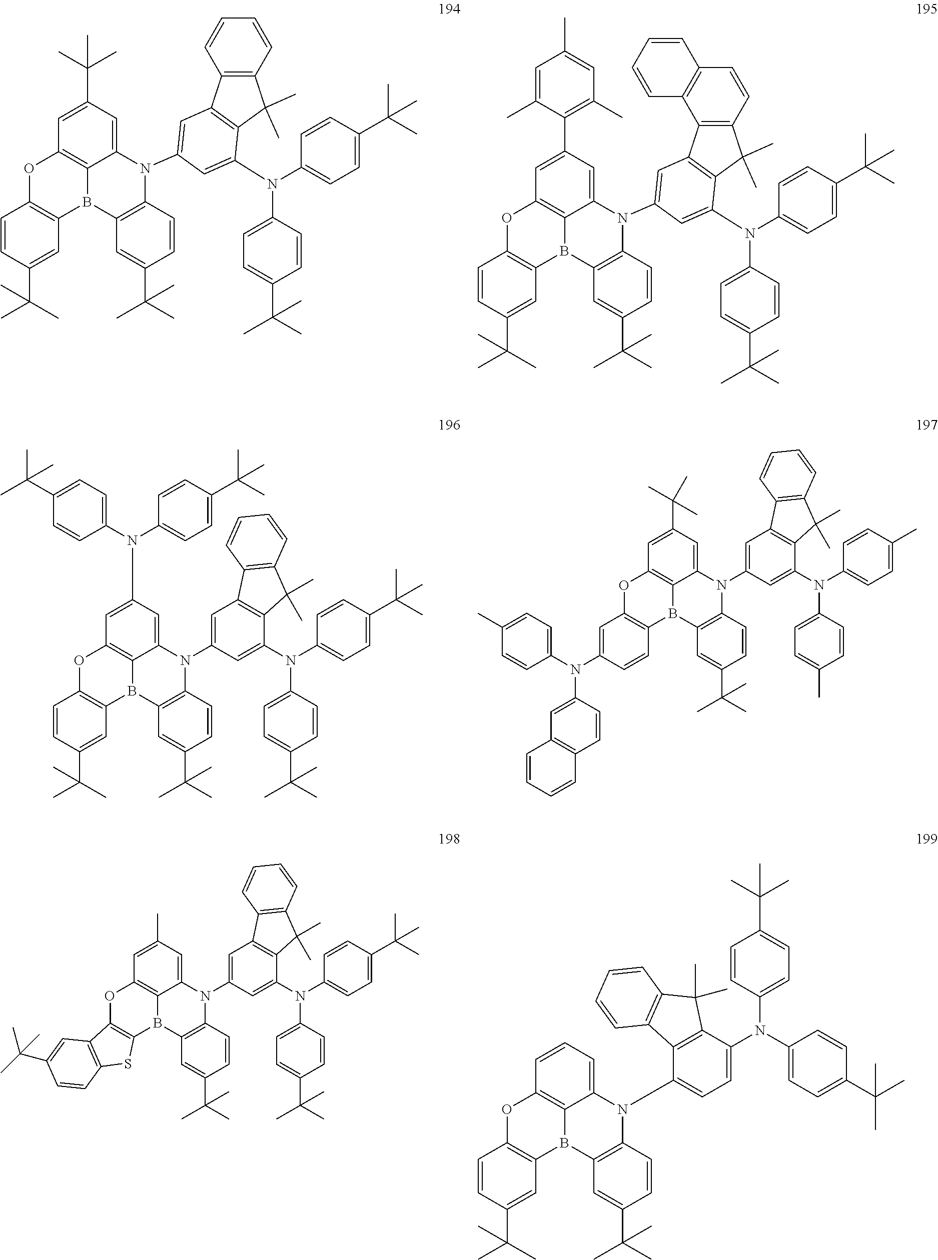

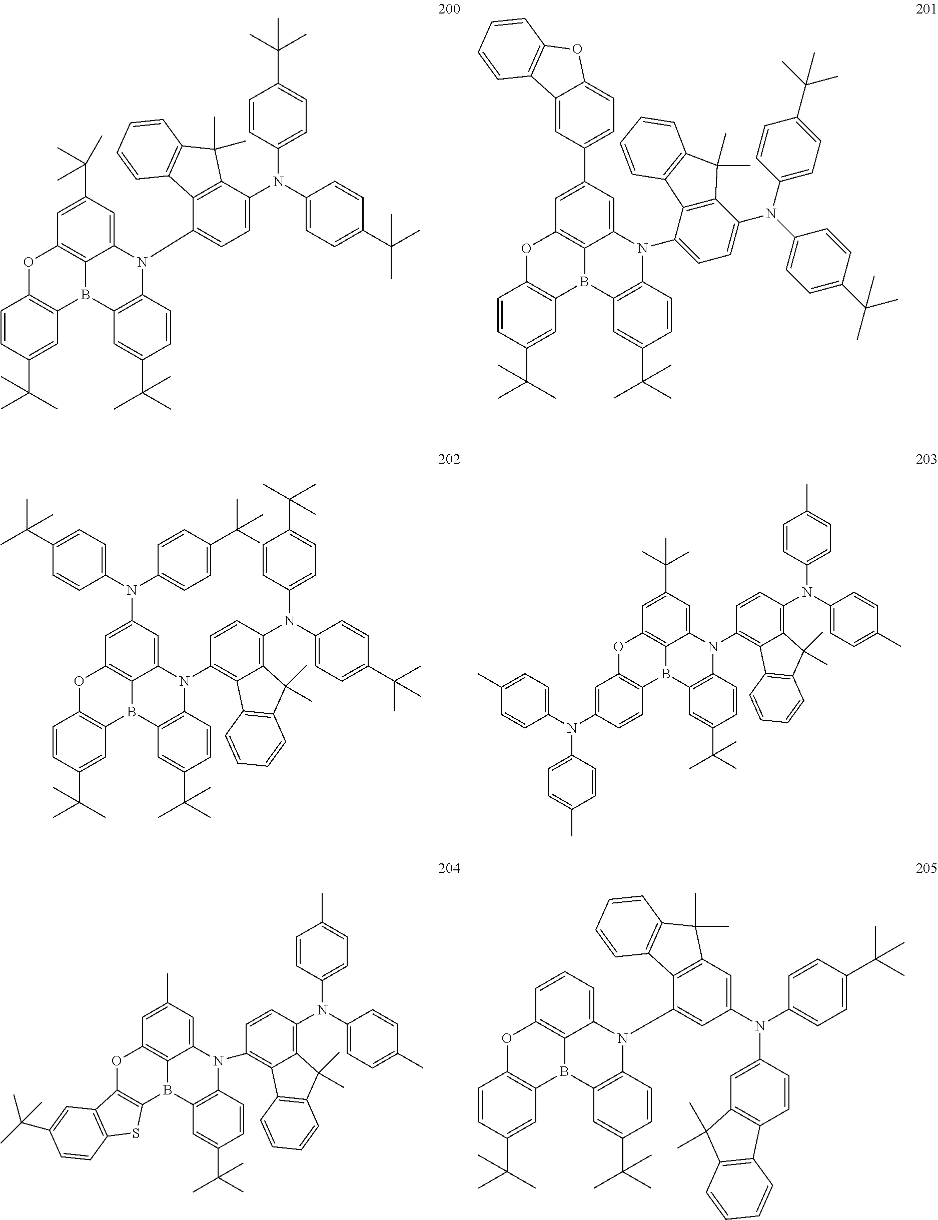

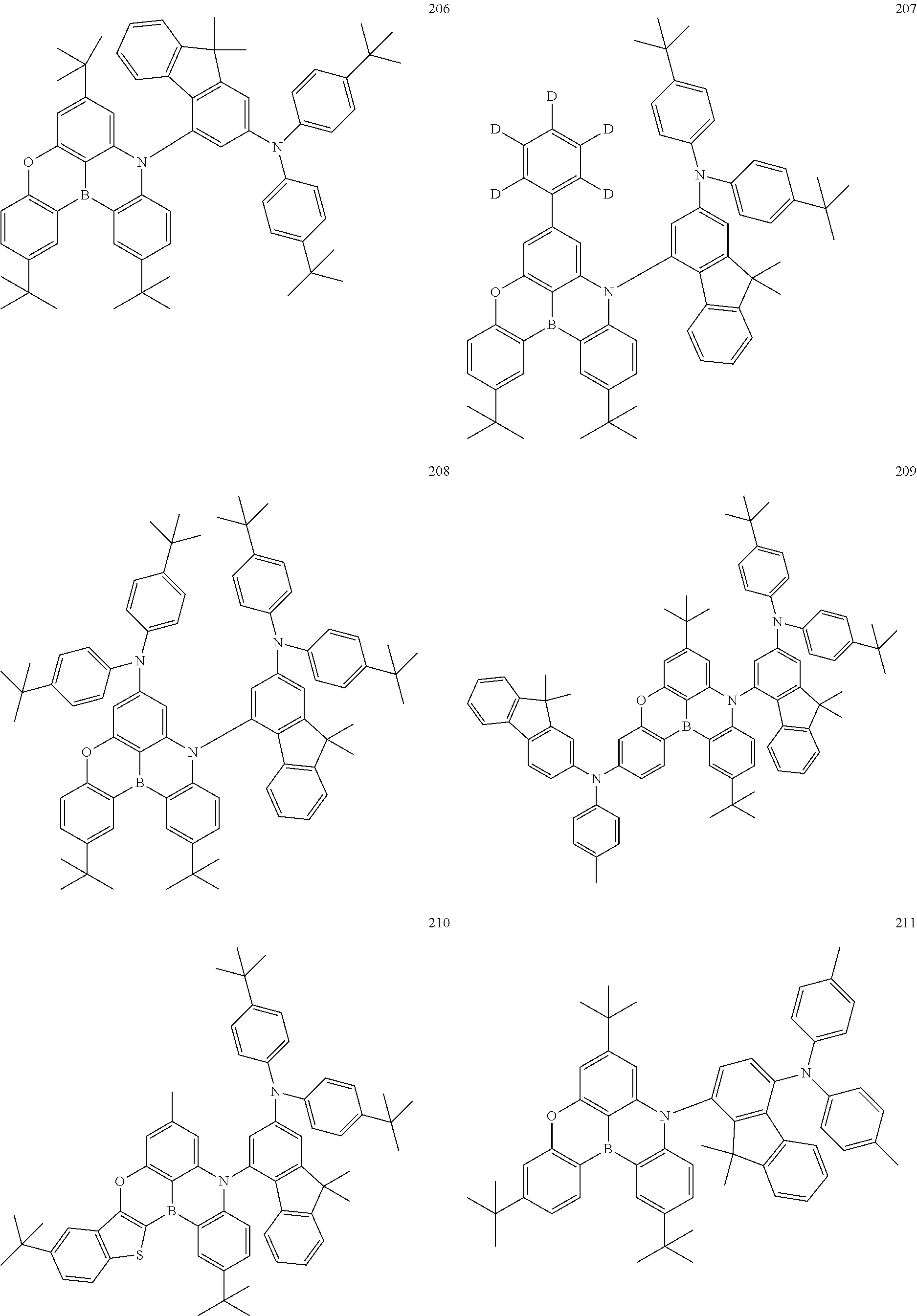

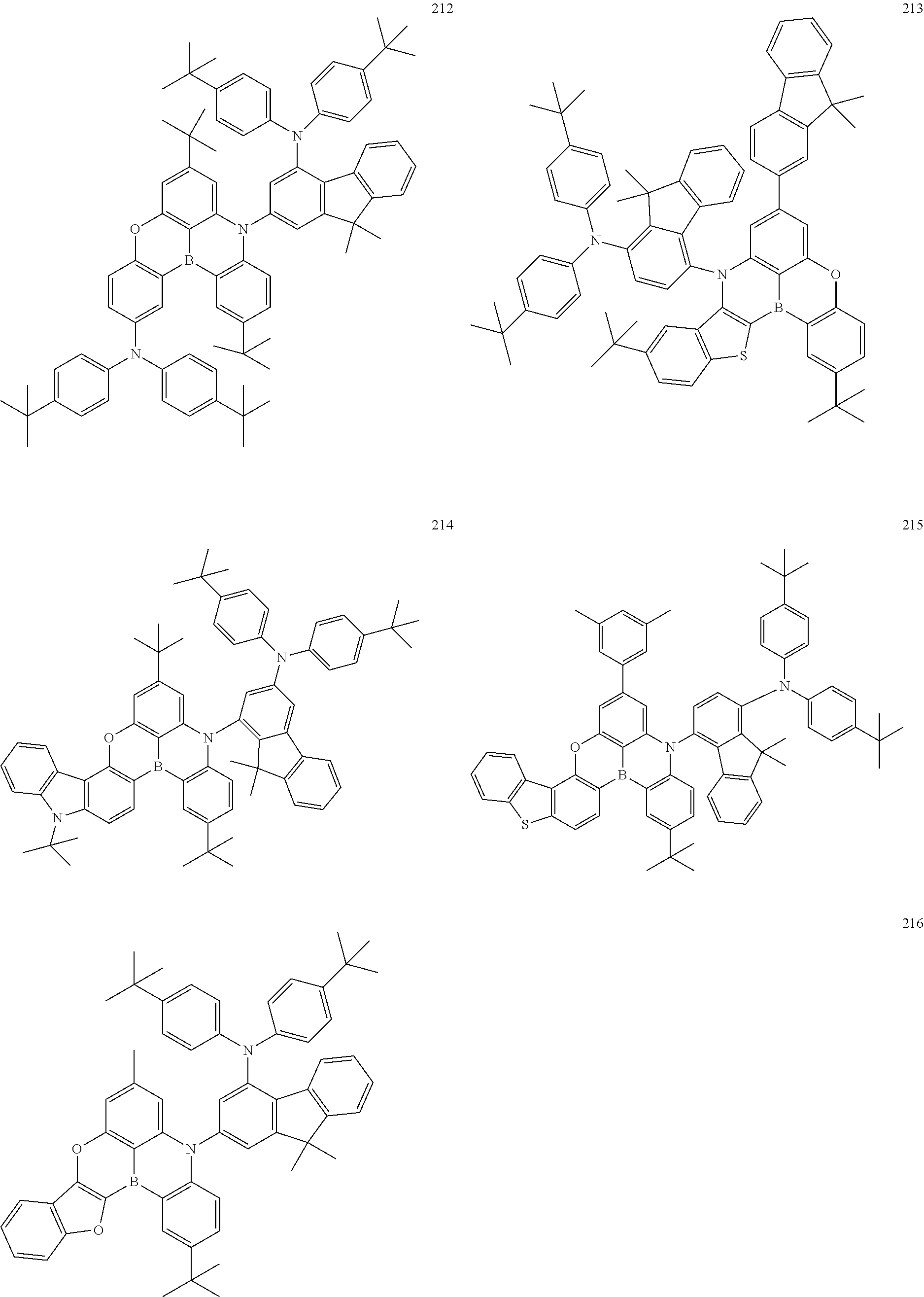

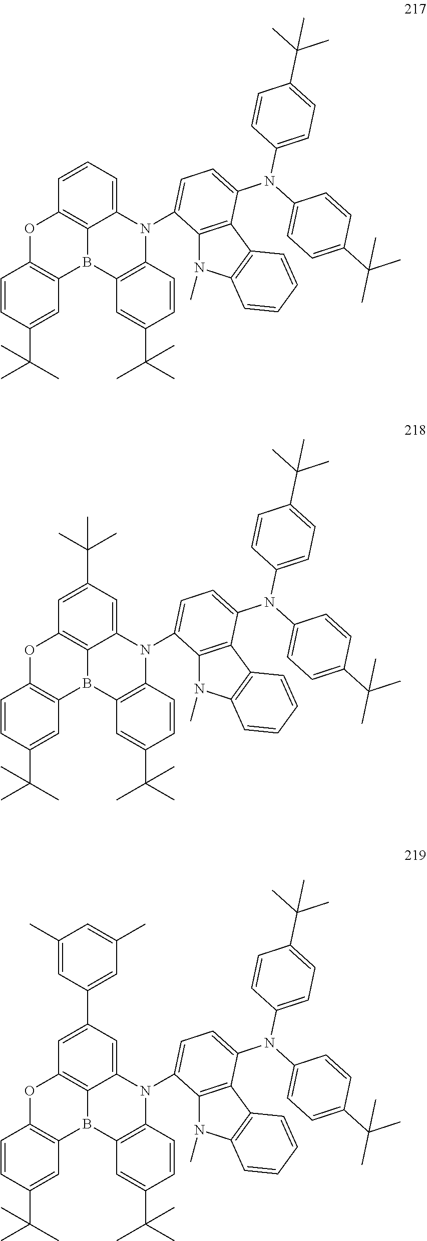 [SMILES: Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cccc3c54)c21 ; Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cc(C(C)(C)C)cc3c54)c21 ; Cc1cc(C)cc(-c2cc3c4c(c2)N(c2ccc(N(c5ccc(C(C)(C)C)cc5)c5ccc(C(C)(C)C)cc5)c5c6ccccc6n(C)c25)c2ccc(C(C)(C)C)cc2B4c2cc(C(C)(C)C)ccc2O3)c1]

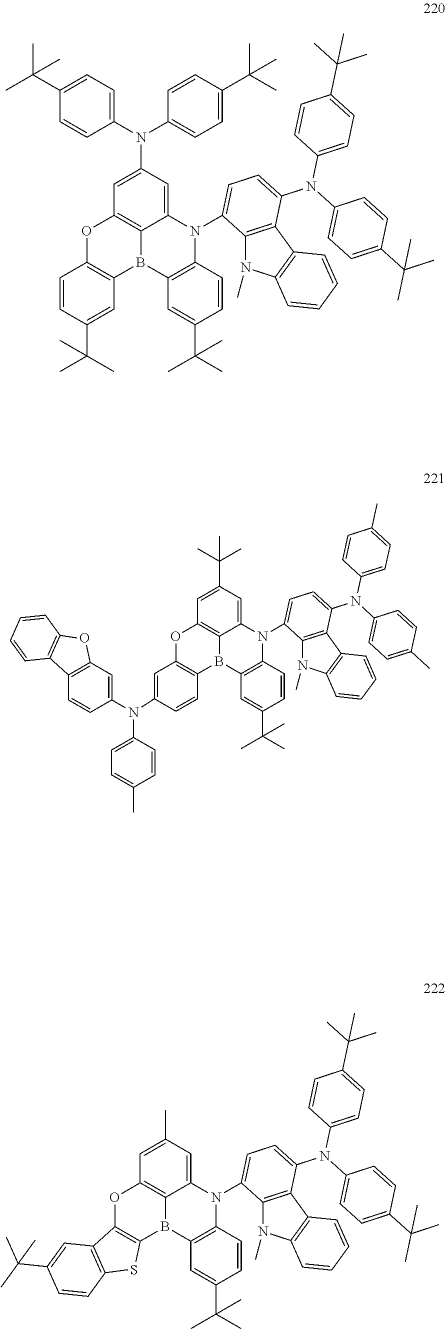

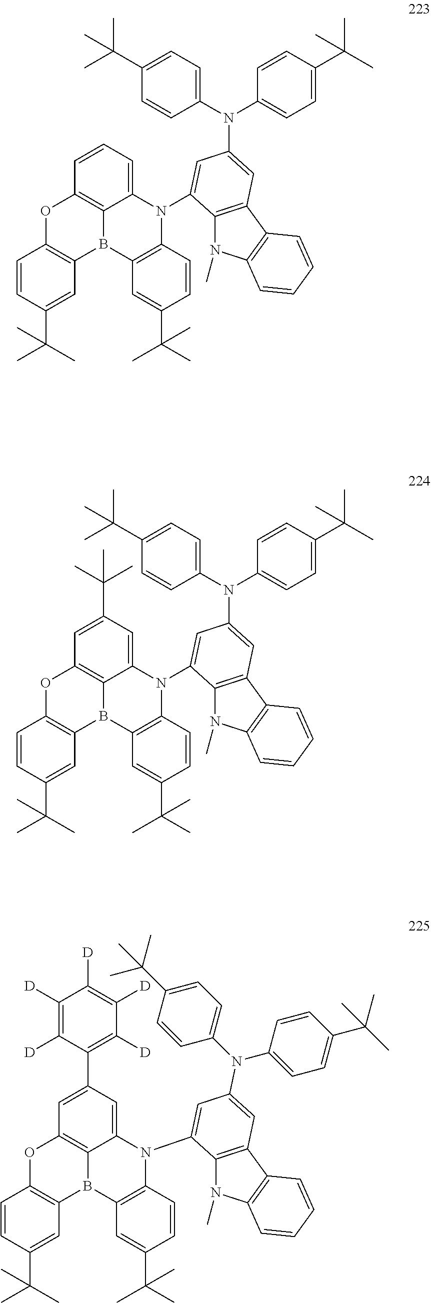 [SMILES: Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cccc3c54)c21 ; Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)c21 ; [2H]c1c([2H])c([2H])c(-c2cc3c4c(c2)N(c2cc(N(c5ccc(C(C)(C)C)cc5)c5ccc(C(C)(C)C)cc5)cc5c6ccccc6n(C)c25)c2ccc(C(C)(C)C)cc2B4c2cc(C(C)(C)C)ccc2O3)c([2H])c1[2H]]

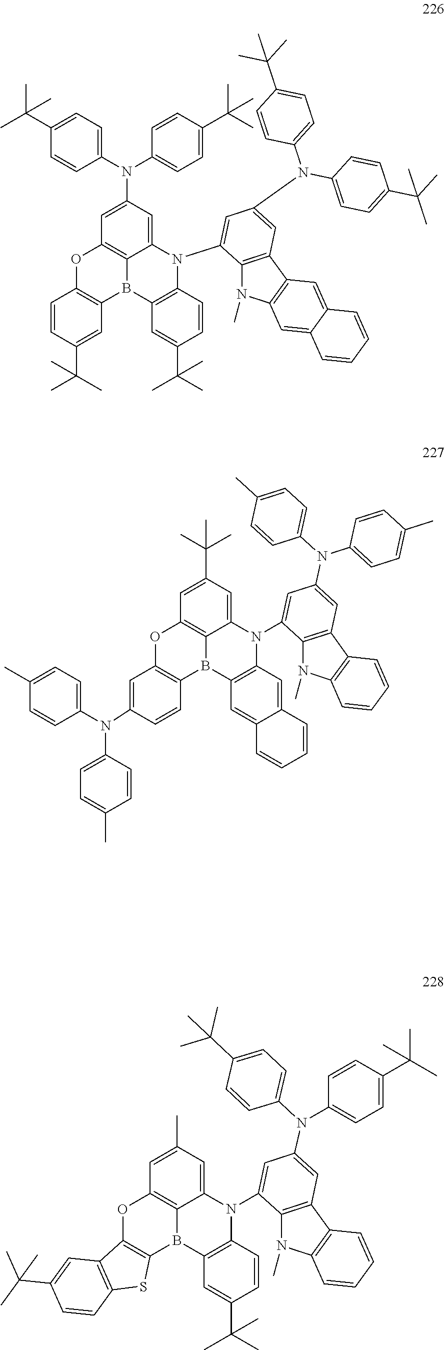

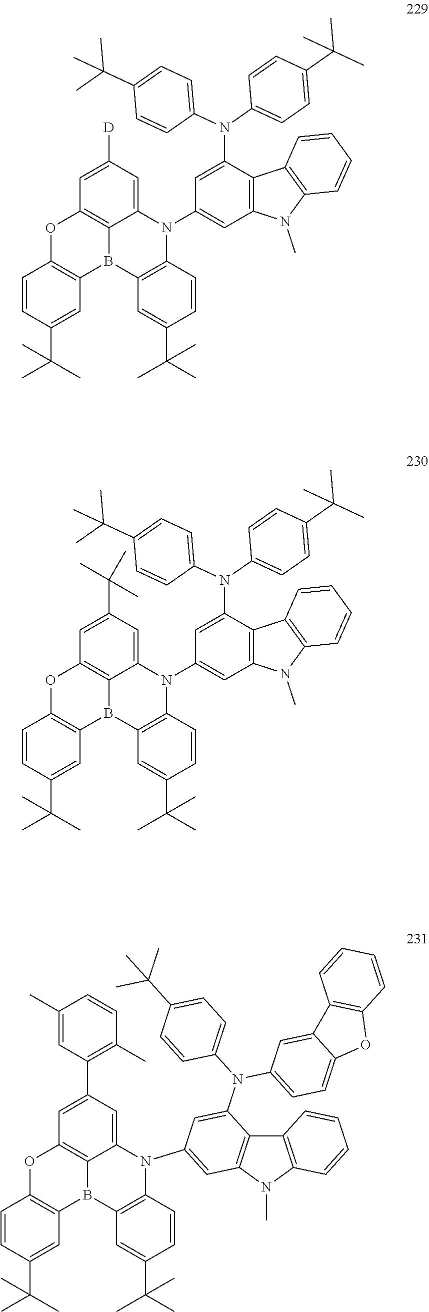 [SMILES: [2H]c1cc2c3c(c1)N(c1cc(N(c4ccc(C(C)(C)C)cc4)c4ccc(C(C)(C)C)cc4)c4c5ccccc5n(C)c4c1)c1ccc(C(C)(C)C)cc1B3c1cc(C(C)(C)C)ccc1O2 ; Cn1c2ccccc2c2c(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)cc21 ; Cc1ccc(C)c(-c2cc3c4c(c2)N(c2cc(N(c5ccc(C(C)(C)C)cc5)c5ccc6oc7ccccc7c6c5)c5c6ccccc6n(C)c5c2)c2ccc(C(C)(C)C)cc2B4c2cc(C(C)(C)C)ccc2O3)c1]

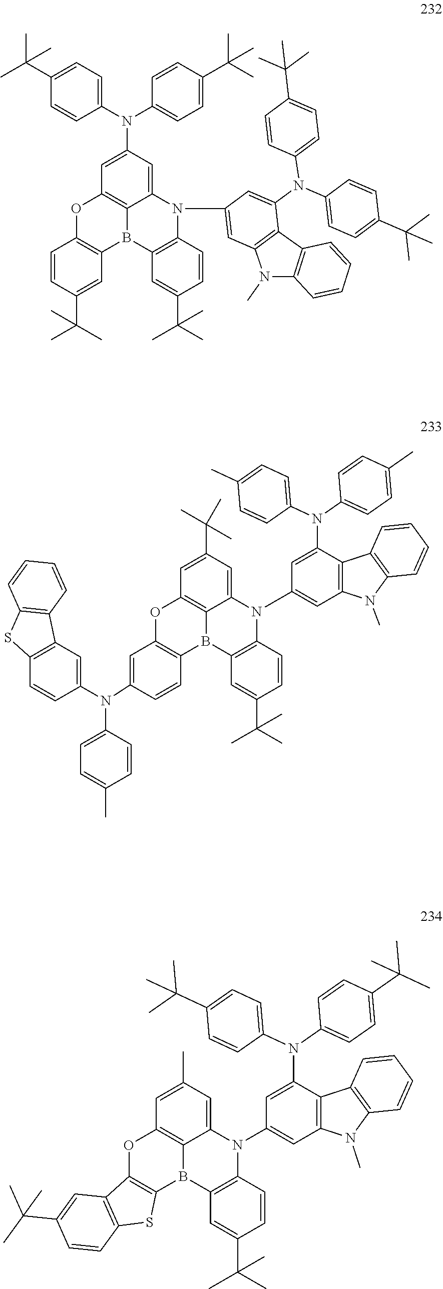

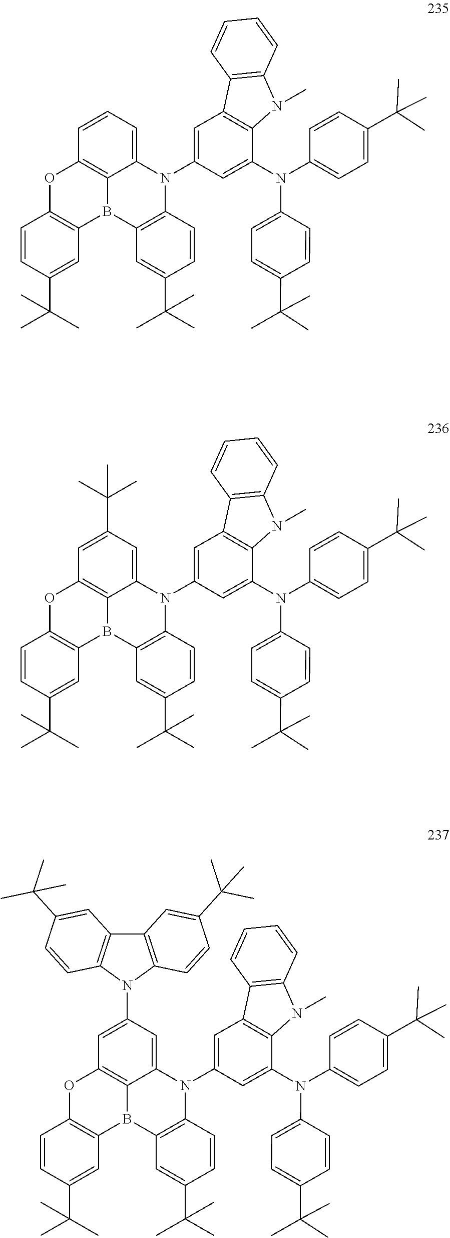

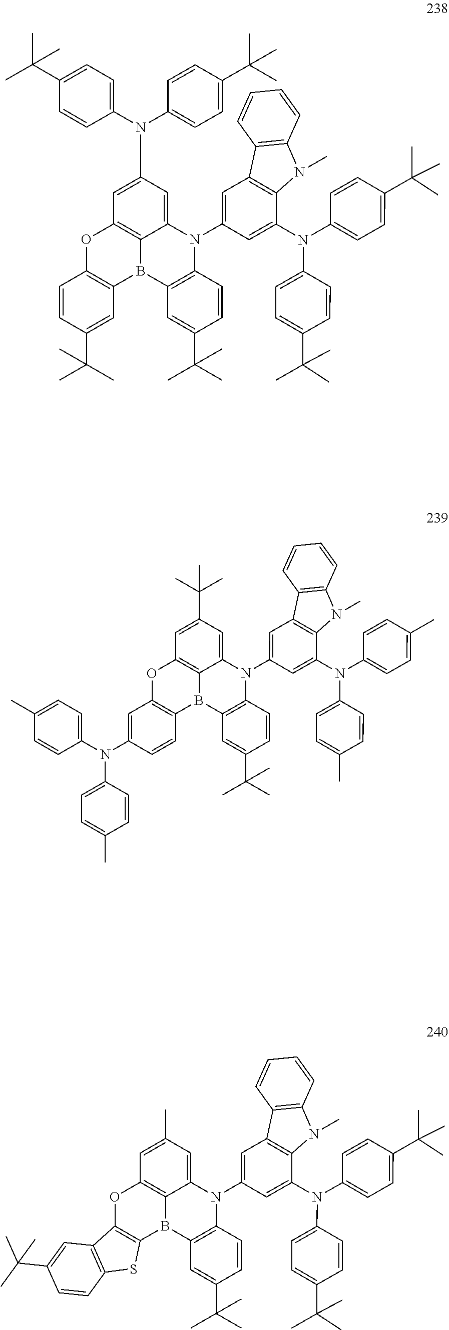

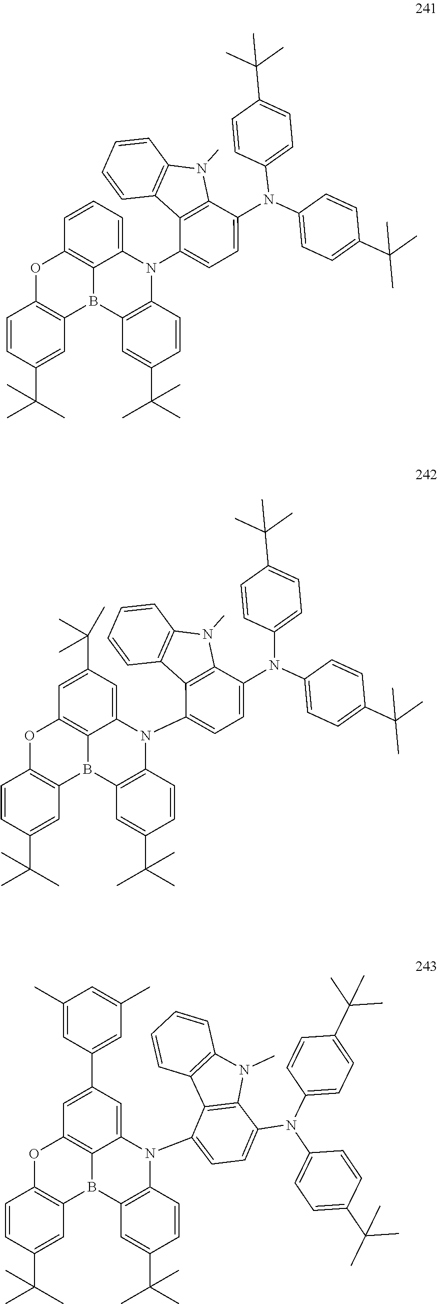 [SMILES: Cn1c2ccccc2c2c(N3c4ccc(C(C)(C)C)cc4B4c5cc(C(C)(C)C)ccc5Oc5cccc3c54)ccc(N(c3ccc(C(C)(C)C)cc3)c3ccc(C(C)(C)C)cc3)c21 ; Cn1c2ccccc2c2c(N3c4ccc(C(C)(C)C)cc4B4c5cc(C(C)(C)C)ccc5Oc5cc(C(C)(C)C)cc3c54)ccc(N(c3ccc(C(C)(C)C)cc3)c3ccc(C(C)(C)C)cc3)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2cc(C(C)(C)C)ccc2O3)c1]

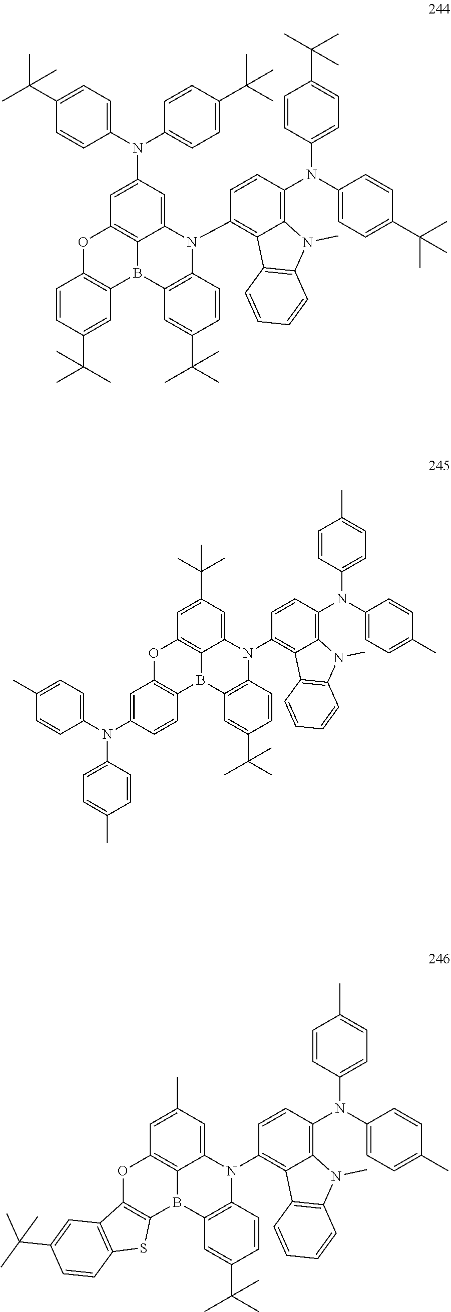

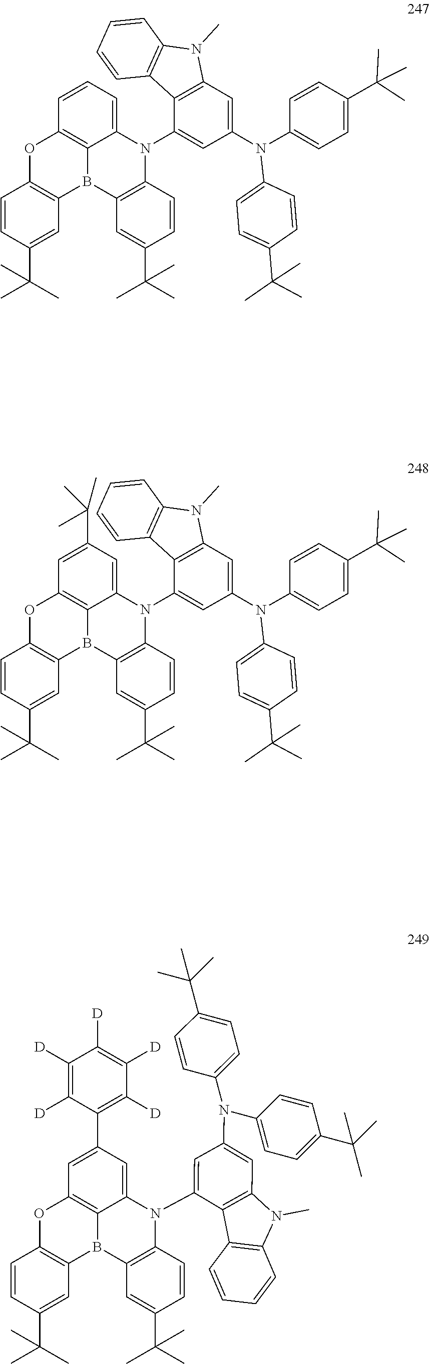 [SMILES: Cn1c2ccccc2c2c(N3c4ccc(C(C)(C)C)cc4B4c5cc(C(C)(C)C)ccc5Oc5cccc3c54)cc(N(c3ccc(C(C)(C)C)cc3)c3ccc(C(C)(C)C)cc3)cc21 ; Cn1c2ccccc2c2c(N3c4ccc(C(C)(C)C)cc4B4c5cc(C(C)(C)C)ccc5Oc5cc(C(C)(C)C)cc3c54)cc(N(c3ccc(C(C)(C)C)cc3)c3ccc(C(C)(C)C)cc3)cc21 ; [2H]c1c([2H])c([2H])c(-c2cc3c4c(c2)N(c2cc(N(c5ccc(C(C)(C)C)cc5)c5ccc(C(C)(C)C)cc5)cc5c2c2ccccc2n5C)c2ccc(C(C)(C)C)cc2B4c2cc(C(C)(C)C)ccc2O3)c([2H])c1[2H]]

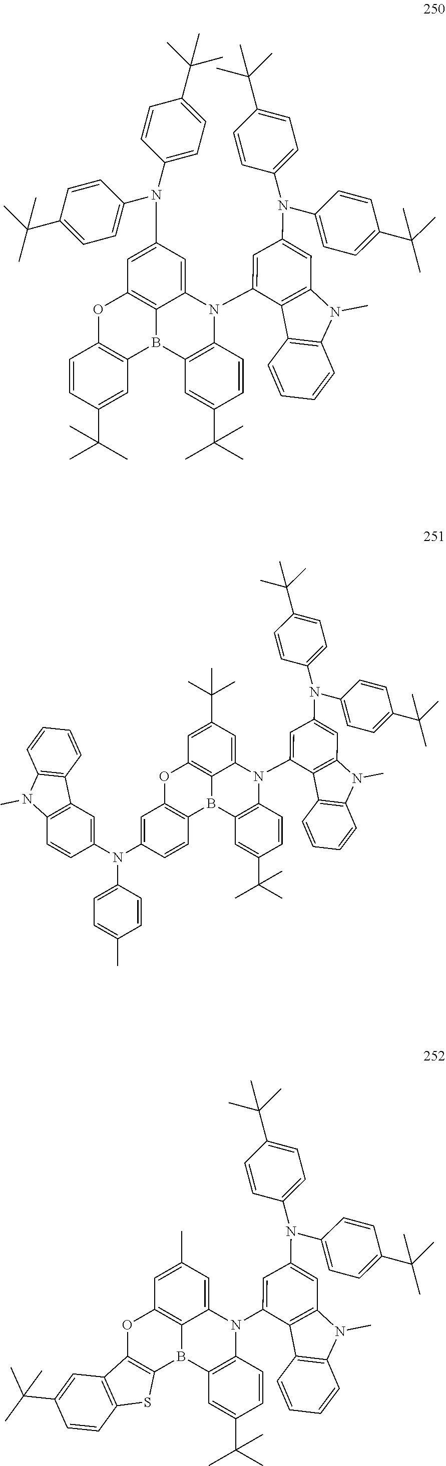

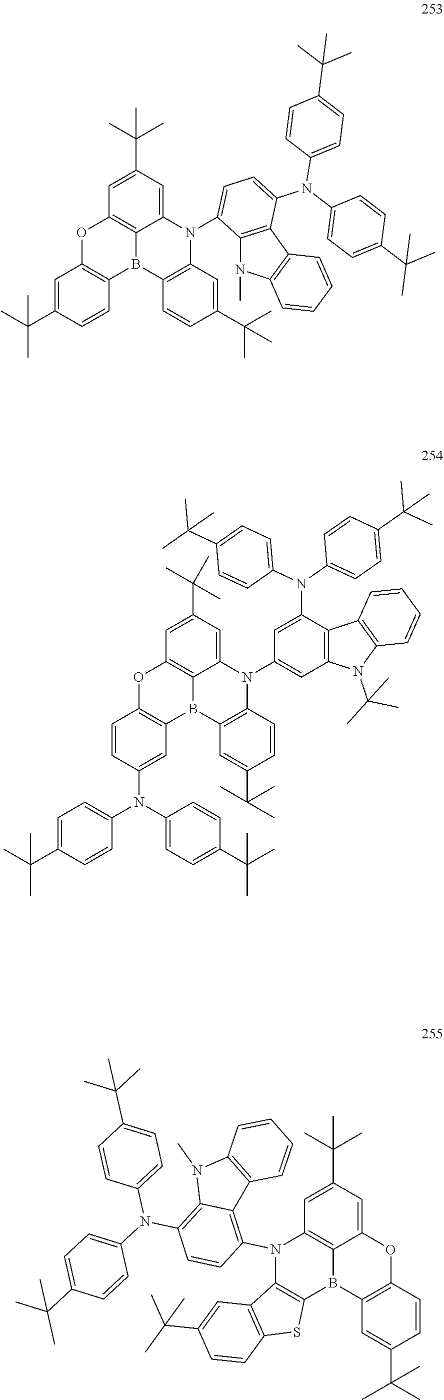

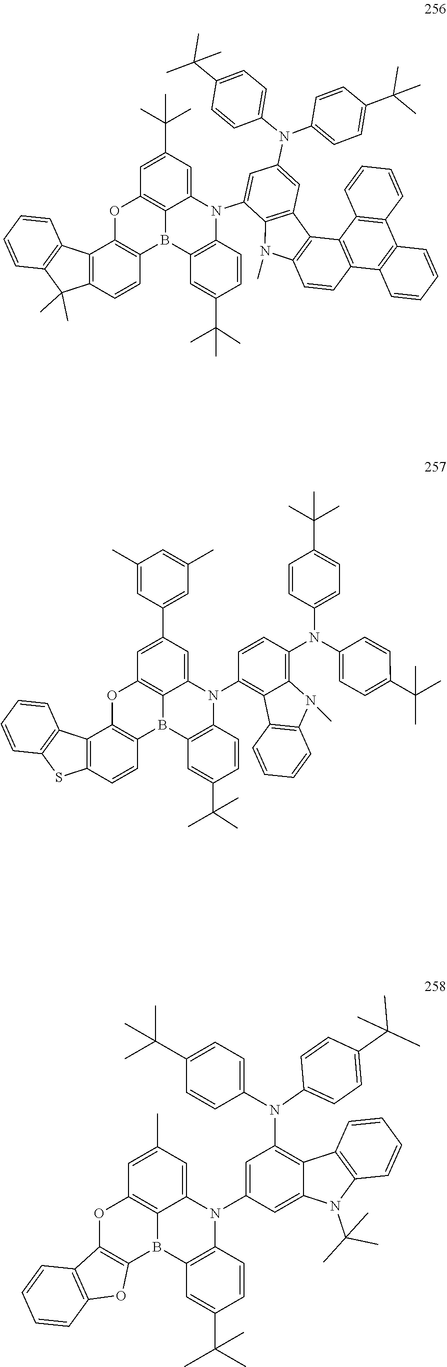 [SMILES: Cn1c2ccc3c4ccccc4c4ccccc4c3c2c2cc(N(c3ccc(C(C)(C)C)cc3)c3ccc(C(C)(C)C)cc3)cc(N3c4ccc(C(C)(C)C)cc4B4c5ccc6c(c5Oc5cc(C(C)(C)C)cc3c54)-c3ccccc3C6(C)C)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c5ccccc5n(C(C)(C)C)c4c1)c1ccc(C(C)(C)C)cc1B3c1oc3ccccc3c1O2]

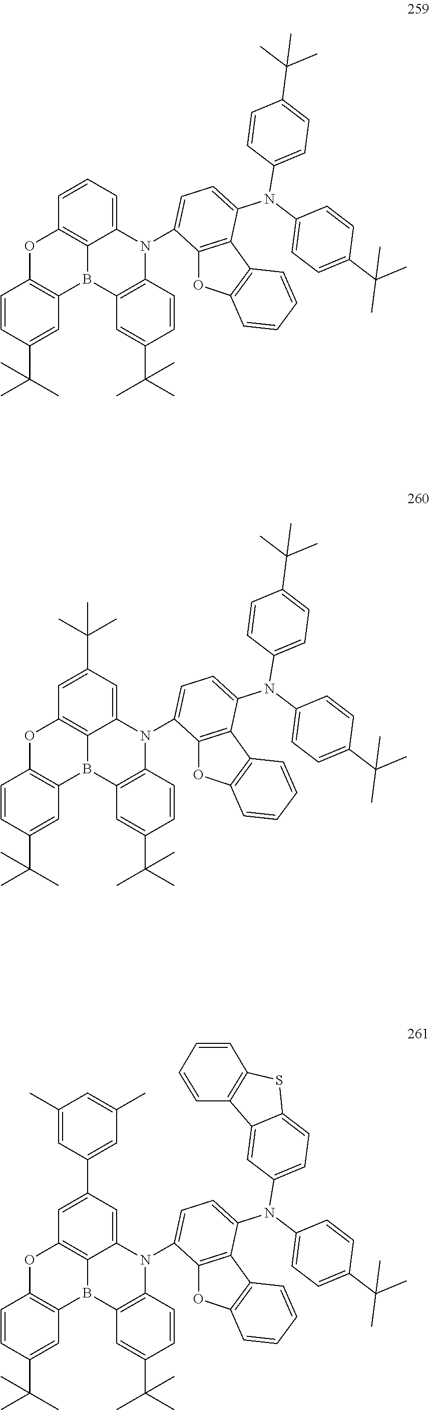 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3oc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3oc4ccccc4c23)cc1 ; Cc1cc(C)cc(-c2cc3c4c(c2)N(c2ccc(N(c5ccc(C(C)(C)C)cc5)c5ccc6sc7ccccc7c6c5)c5c2oc2ccccc25)c2ccc(C(C)(C)C)cc2B4c2cc(C(C)(C)C)ccc2O3)c1]

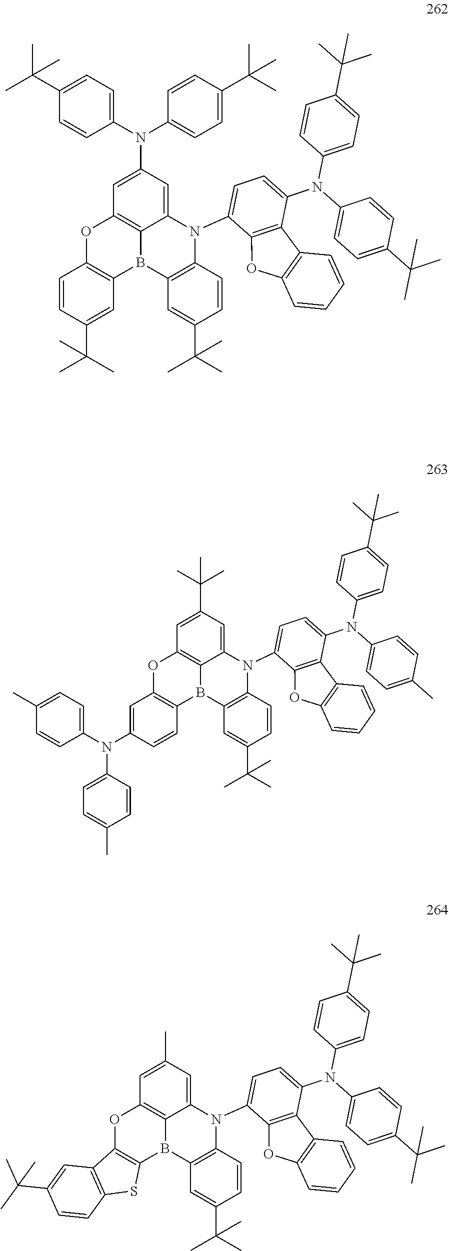

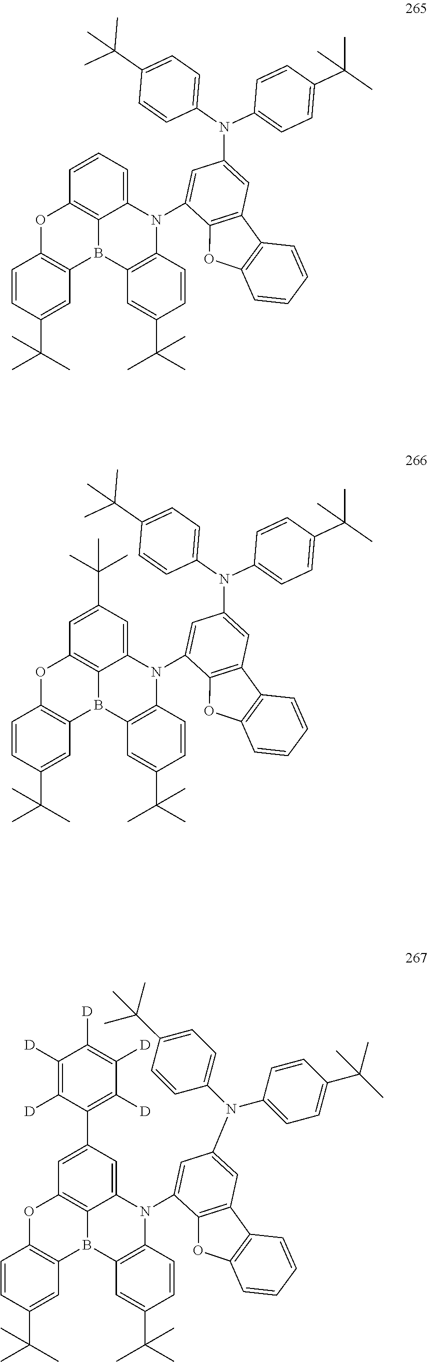 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3oc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3oc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2oc2ccccc25)c2ccc(C(C)(C)C)cc2B4c2cc(C(C)(C)C)ccc2O3)c([2H])c1[2H]]

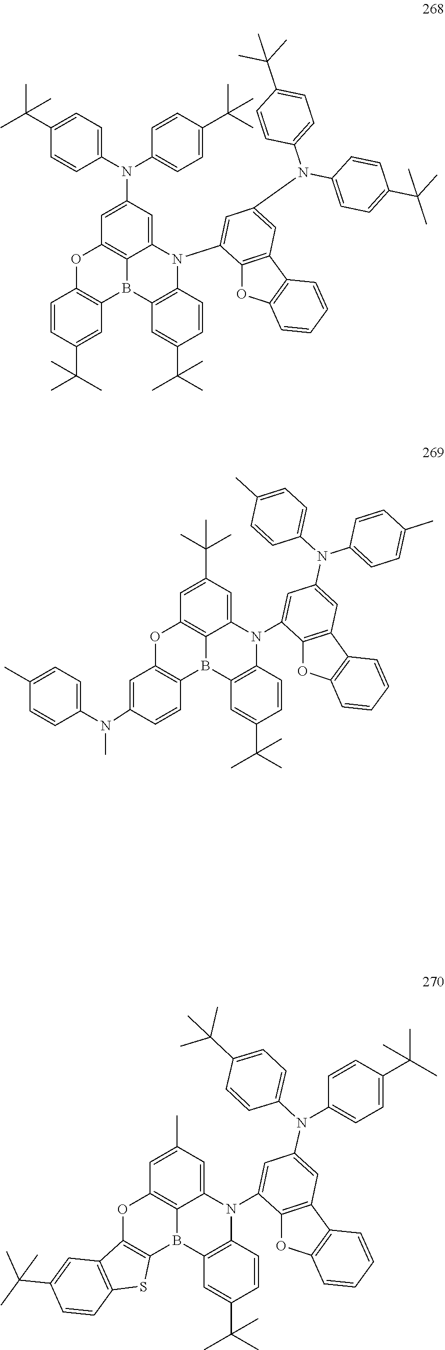

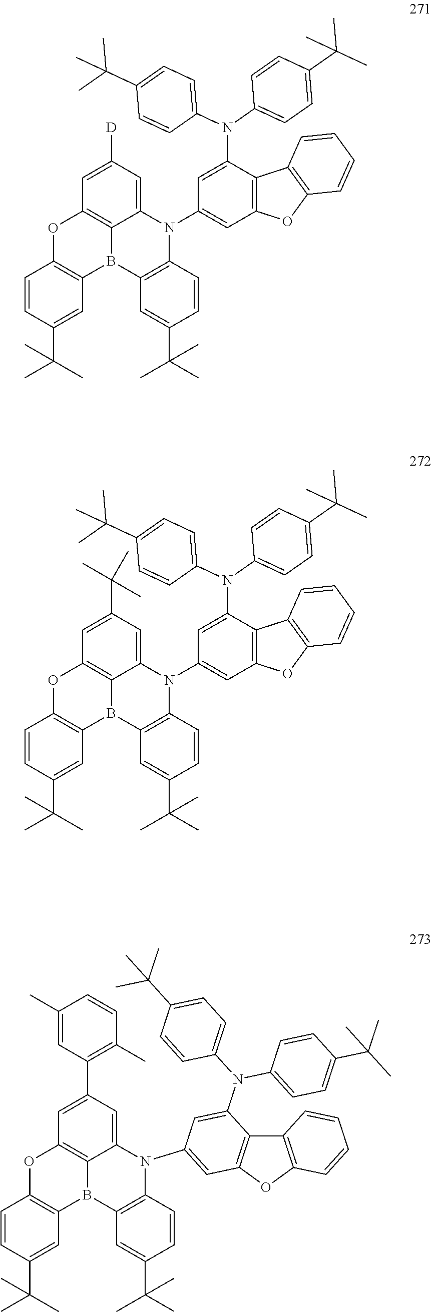 [SMILES: [2H]c1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3oc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)oc2ccccc25)c2ccc(C(C)(C)C)cc2B4c2cc(C(C)(C)C)ccc2O3)c1]

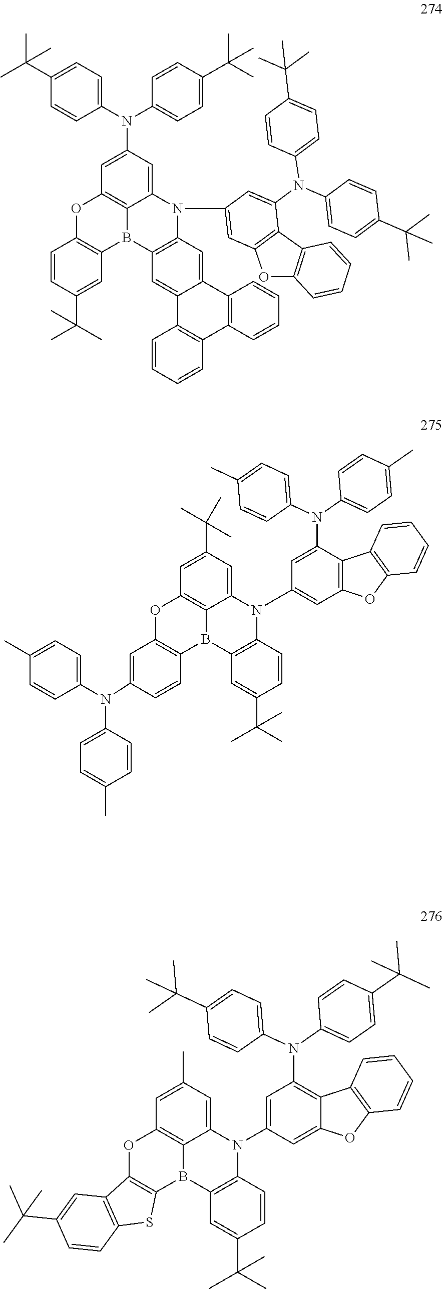

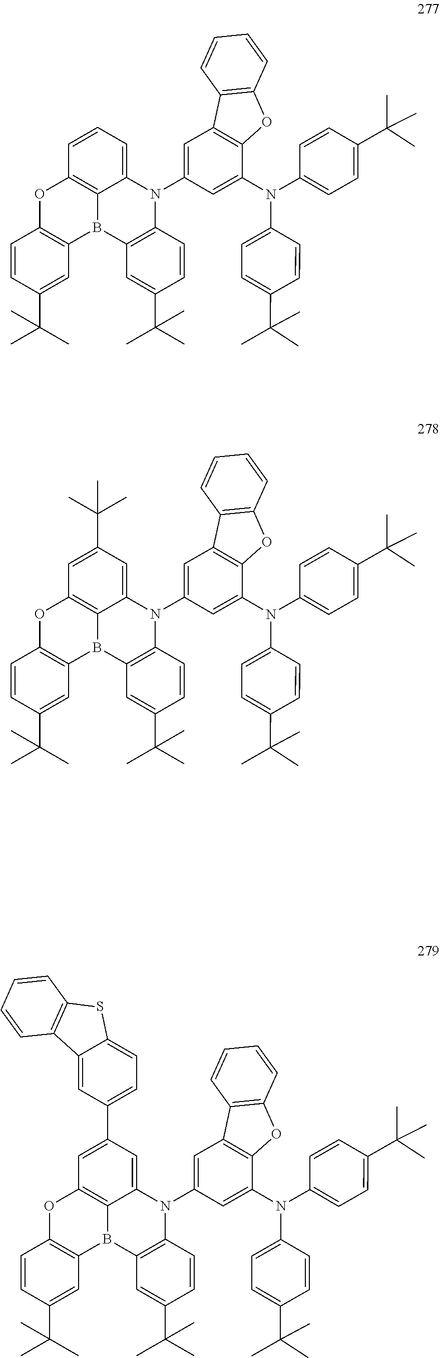 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(-c6ccc7sc8ccccc8c7c6)cc3c54)cc3c2oc2ccccc23)cc1]

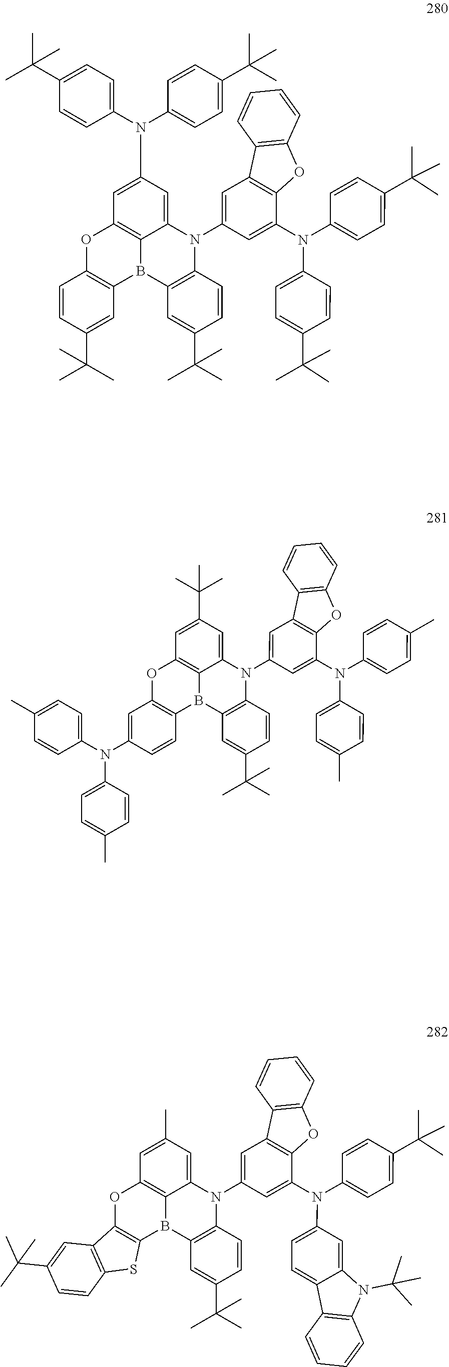

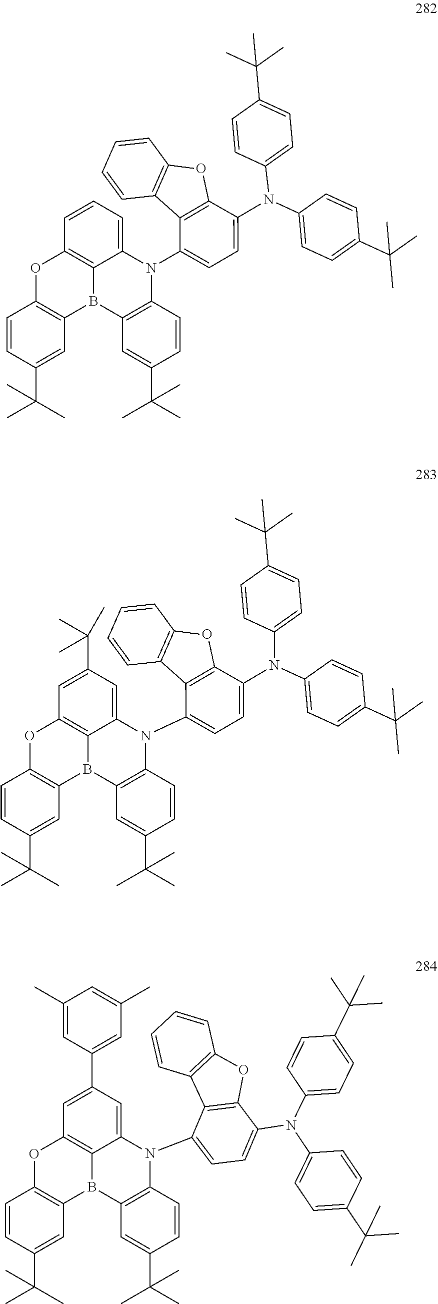 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2oc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2oc2ccccc23)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2cc(C(C)(C)C)ccc2O3)c1]

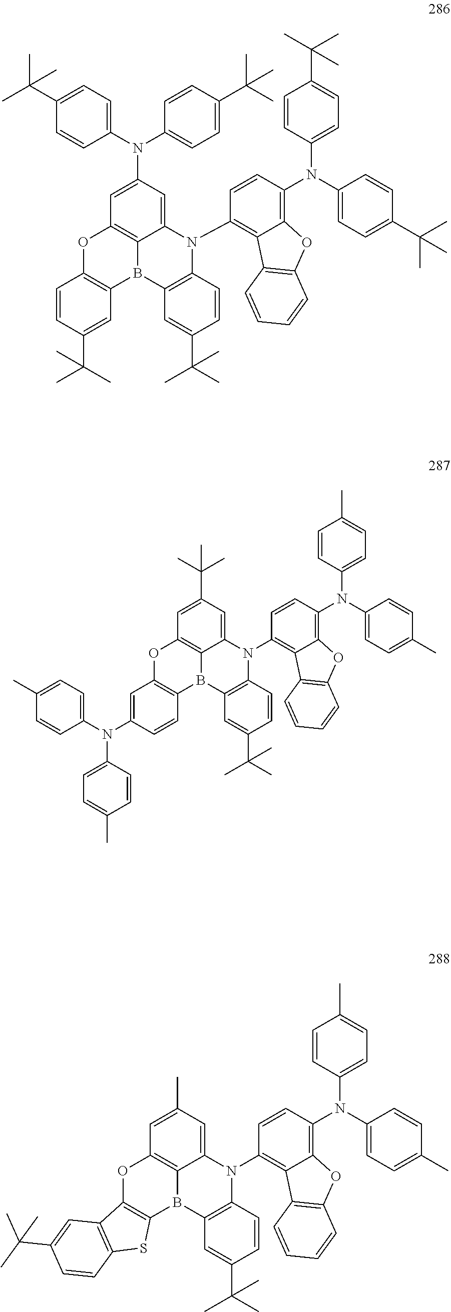

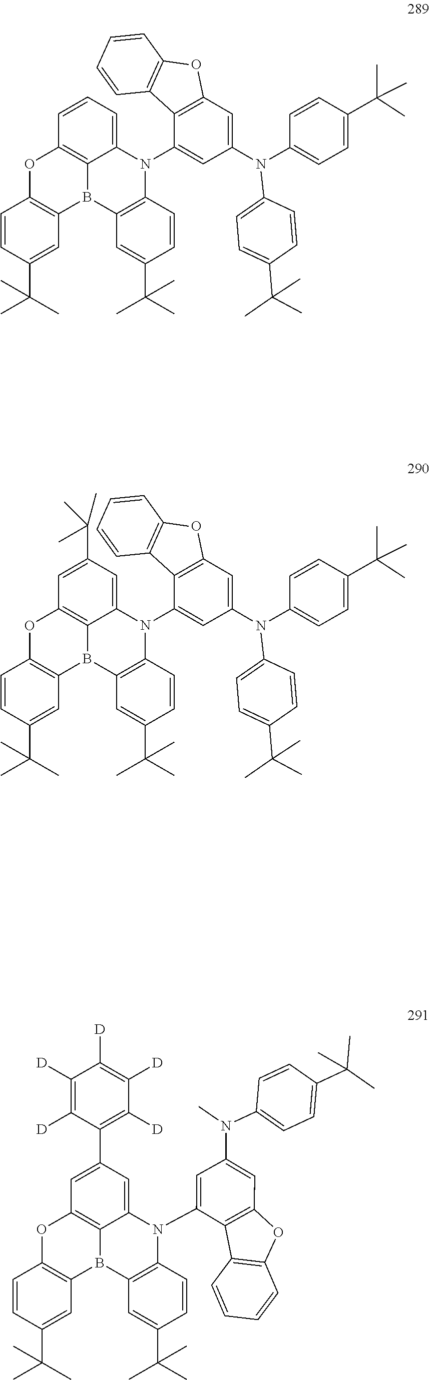 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)oc2ccccc23)cc1 ; [2H]c1c([2H])c([2H])c(-c2cc3c4c(c2)N(c2cc(N(C)c5ccc(C(C)(C)C)cc5)cc5oc6ccccc6c25)c2ccc(C(C)(C)C)cc2B4c2cc(C(C)(C)C)ccc2O3)c([2H])c1[2H]]

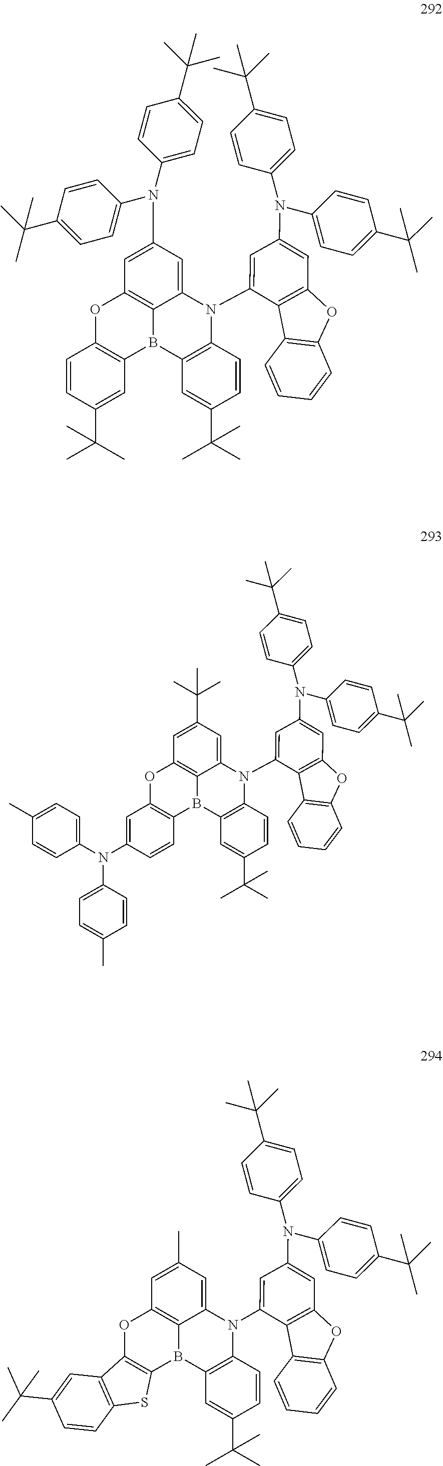

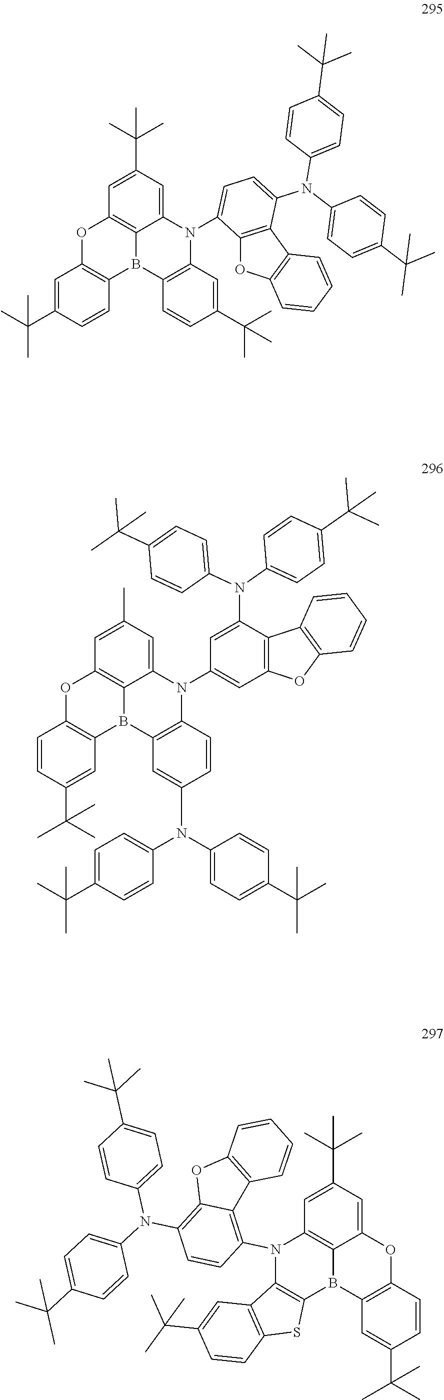

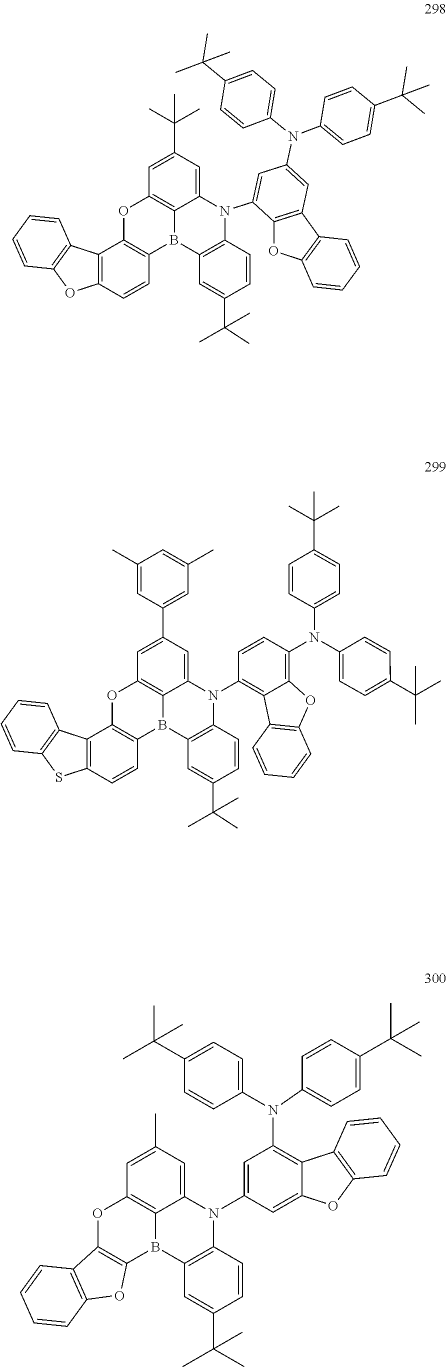 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3oc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1oc3ccccc3c1O2]

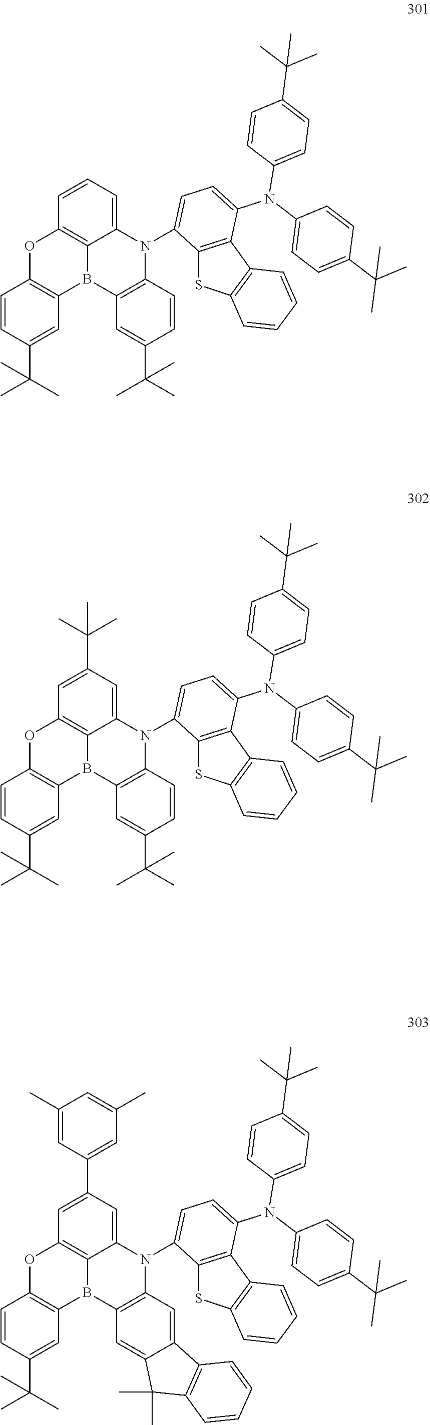 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3sc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3sc4ccccc4c23)cc1 ; Cc1cc(C)cc(-c2cc3c4c(c2)N(c2ccc(N(c5ccc(C(C)(C)C)cc5)c5ccc(C(C)(C)C)cc5)c5c2sc2ccccc25)c2cc5c(cc2B4c2cc(C(C)(C)C)ccc2O3)C(C)(C)c2ccccc2-5)c1]

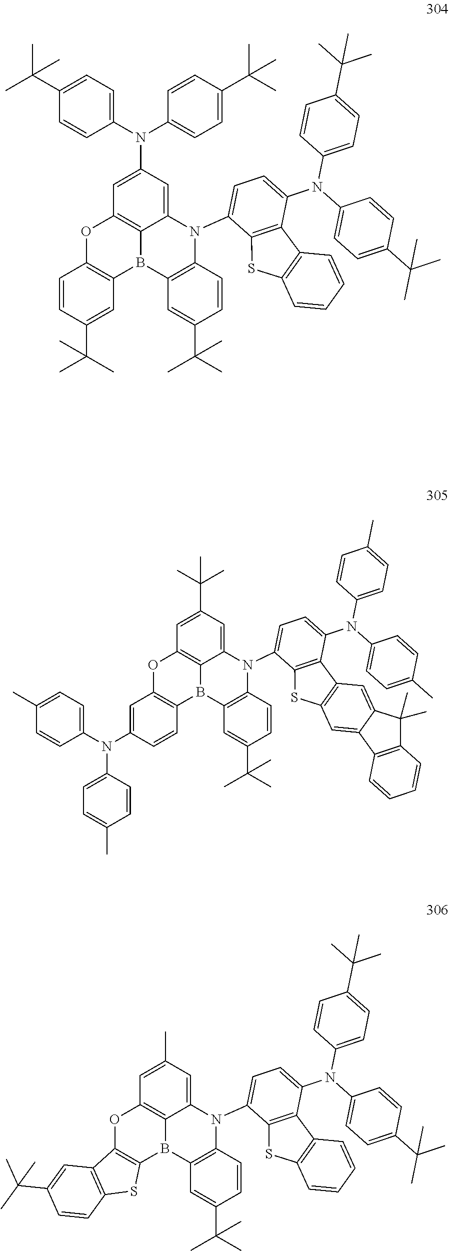

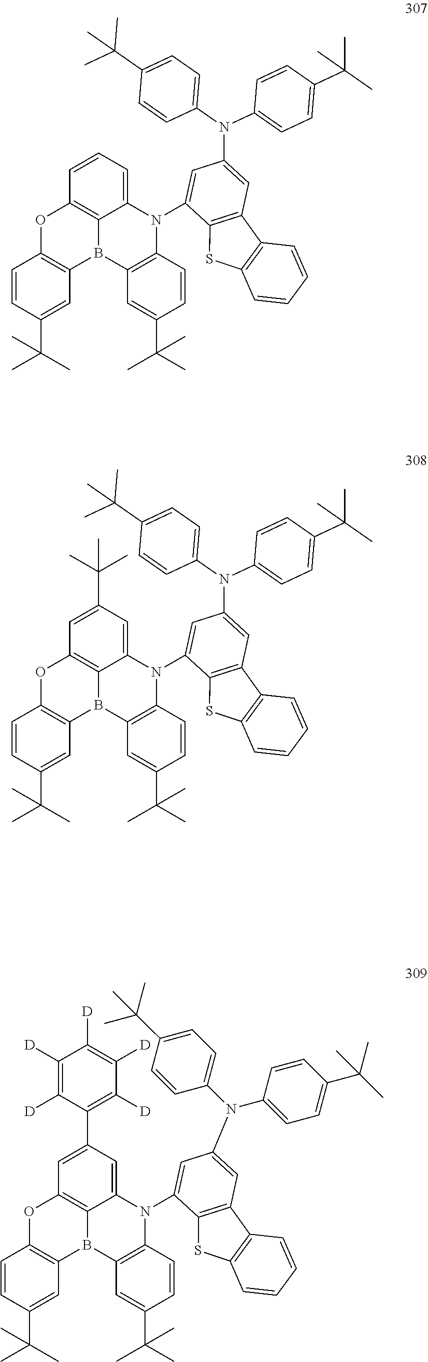 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3sc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3sc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2sc2ccccc25)c2ccc(C(C)(C)C)cc2B4c2cc(C(C)(C)C)ccc2O3)c([2H])c1[2H]]

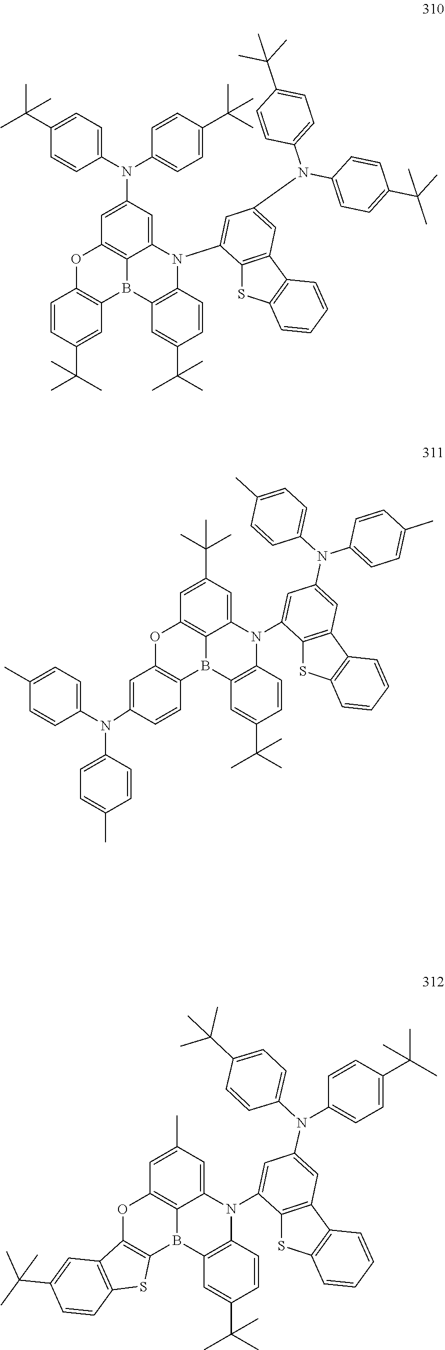

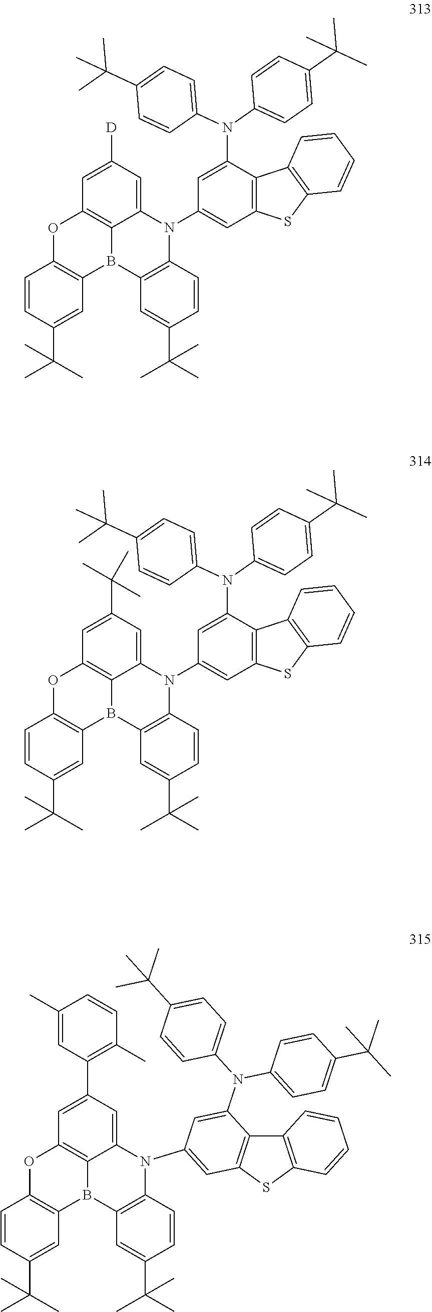 [SMILES: [2H]c1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3sc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)sc2ccccc25)c2ccc(C(C)(C)C)cc2B4c2cc(C(C)(C)C)ccc2O3)c1]

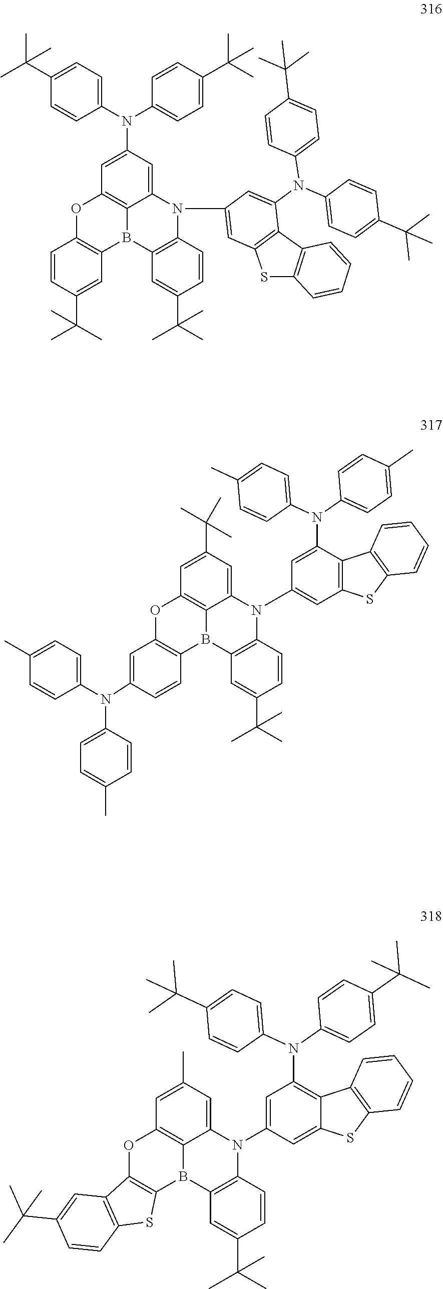

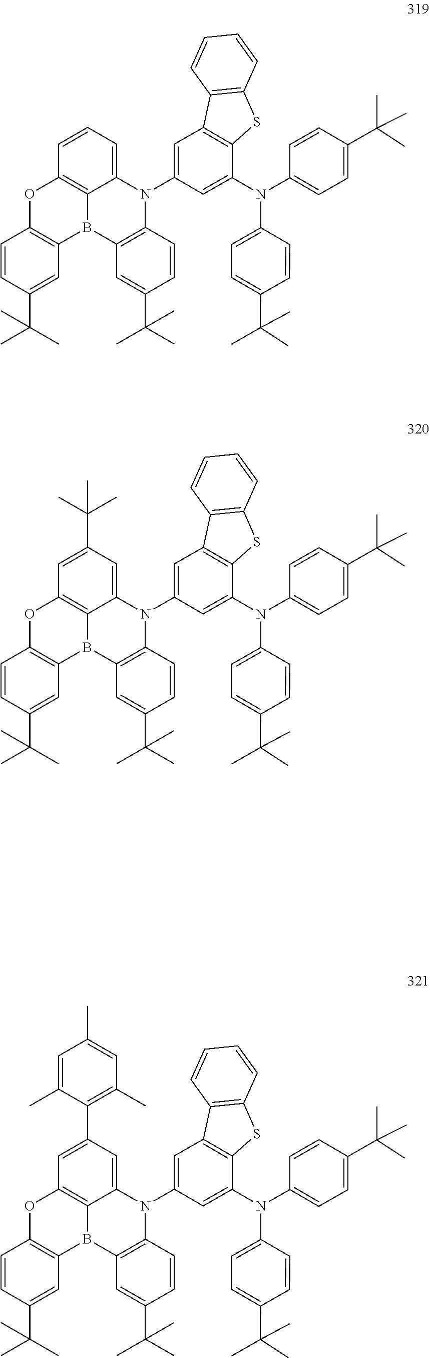 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2sc2ccccc23)cc1 ; Cc1cc(C)c(-c2cc3c4c(c2)N(c2cc(N(c5ccc(C(C)(C)C)cc5)c5ccc(C(C)(C)C)cc5)c5sc6ccccc6c5c2)c2ccc(C(C)(C)C)cc2B4c2cc(C(C)(C)C)ccc2O3)c(C)c1]

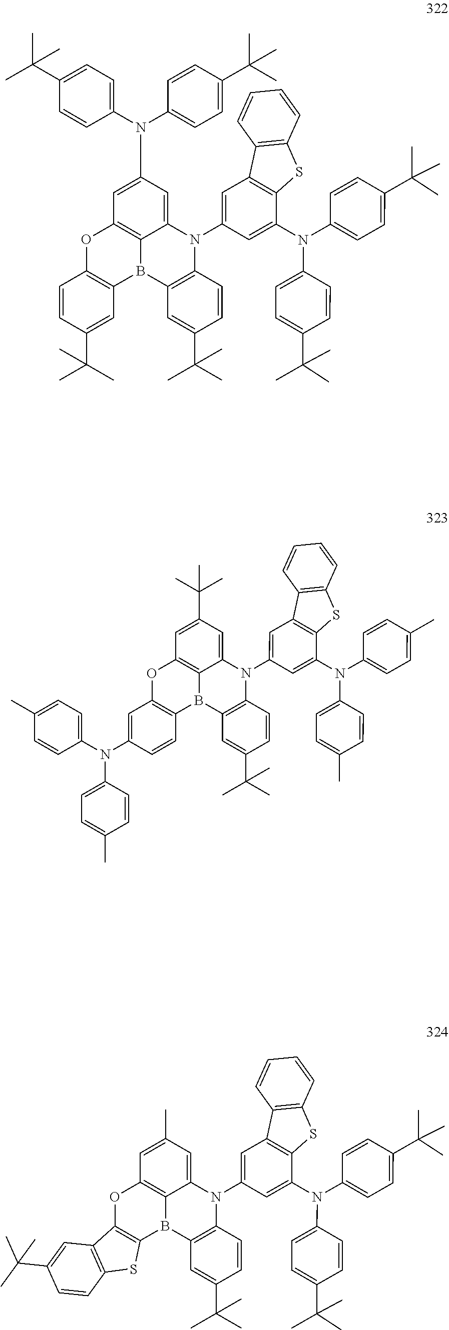

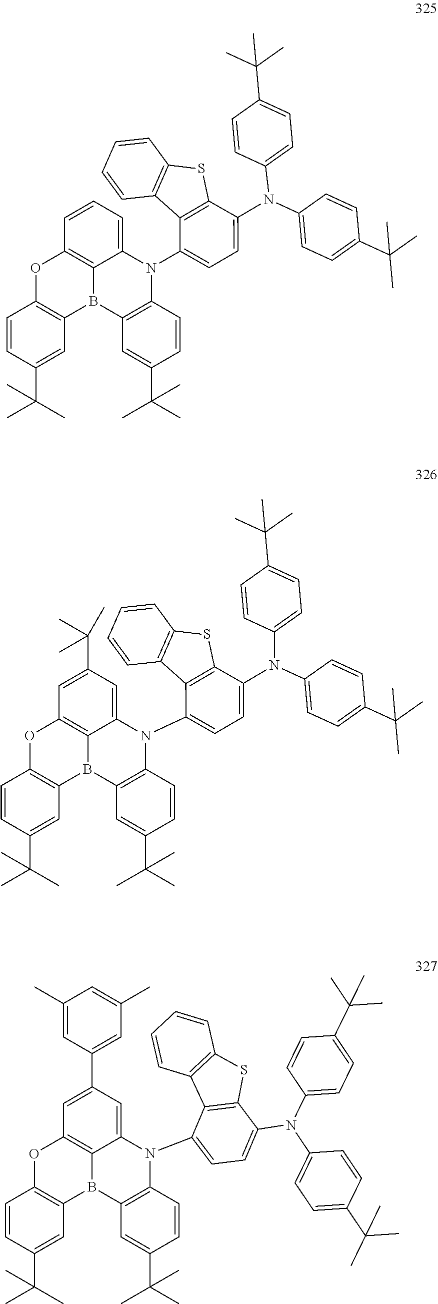 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2sc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2sc2ccccc23)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2cc(C(C)(C)C)ccc2O3)c1]

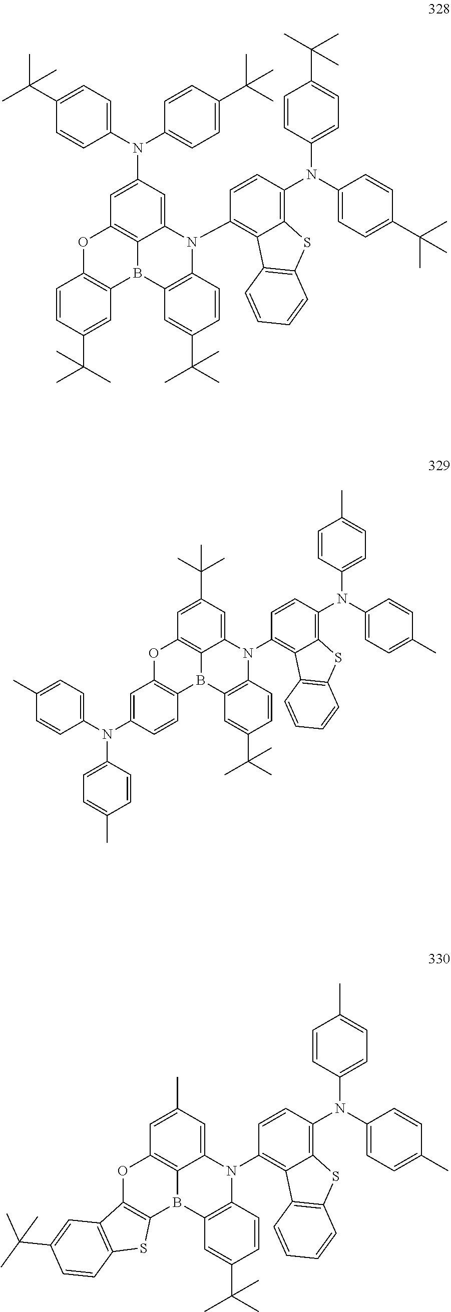

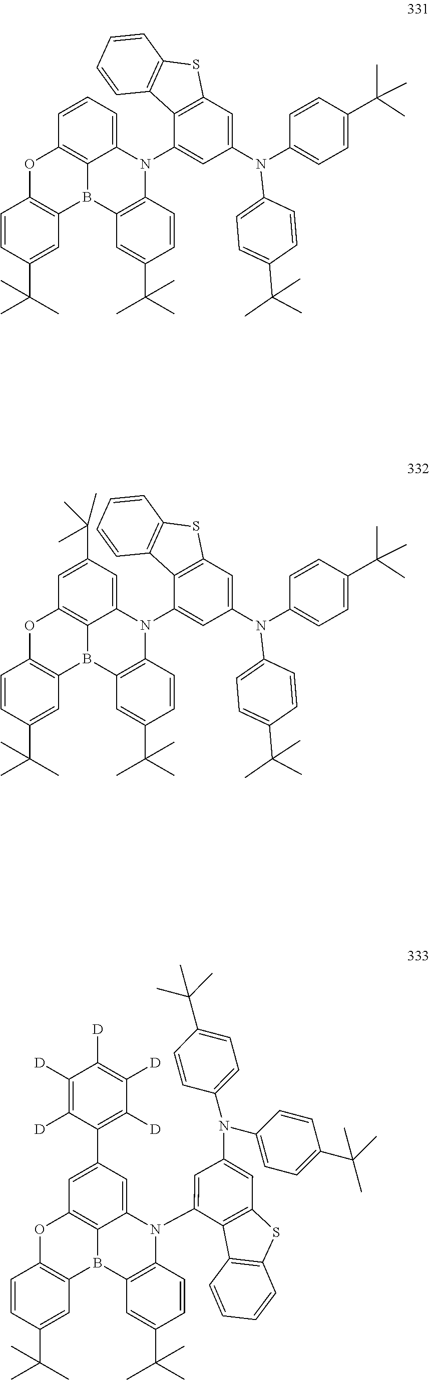 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)sc2ccccc23)cc1 ; [2H]c1c([2H])c([2H])c(-c2cc3c4c(c2)N(c2cc(N(c5ccc(C(C)(C)C)cc5)c5ccc(C(C)(C)C)cc5)cc5sc6ccccc6c25)c2ccc(C(C)(C)C)cc2B4c2cc(C(C)(C)C)ccc2O3)c([2H])c1[2H]]

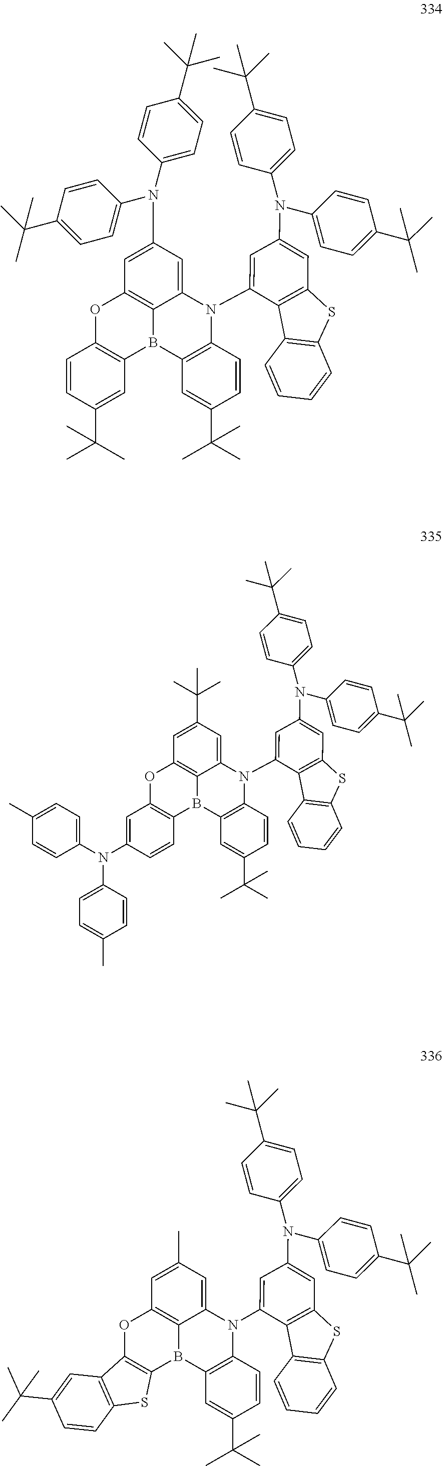

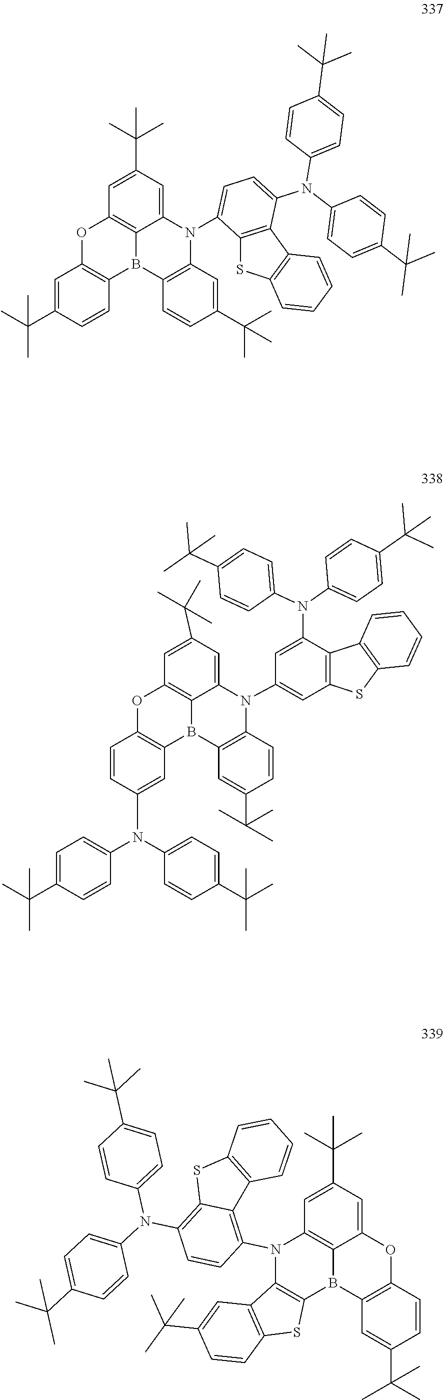

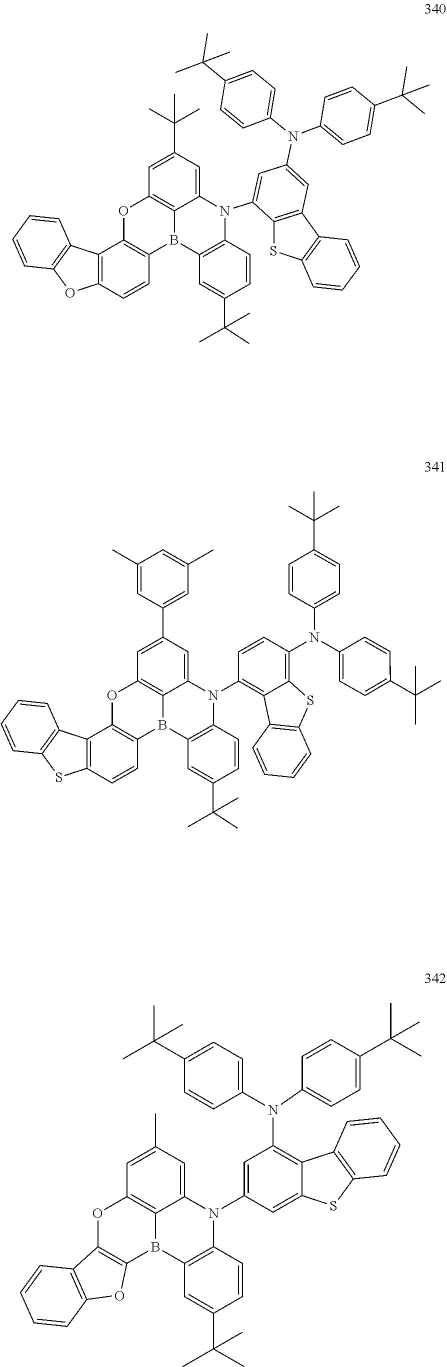 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3sc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1oc3ccccc3c1O2]

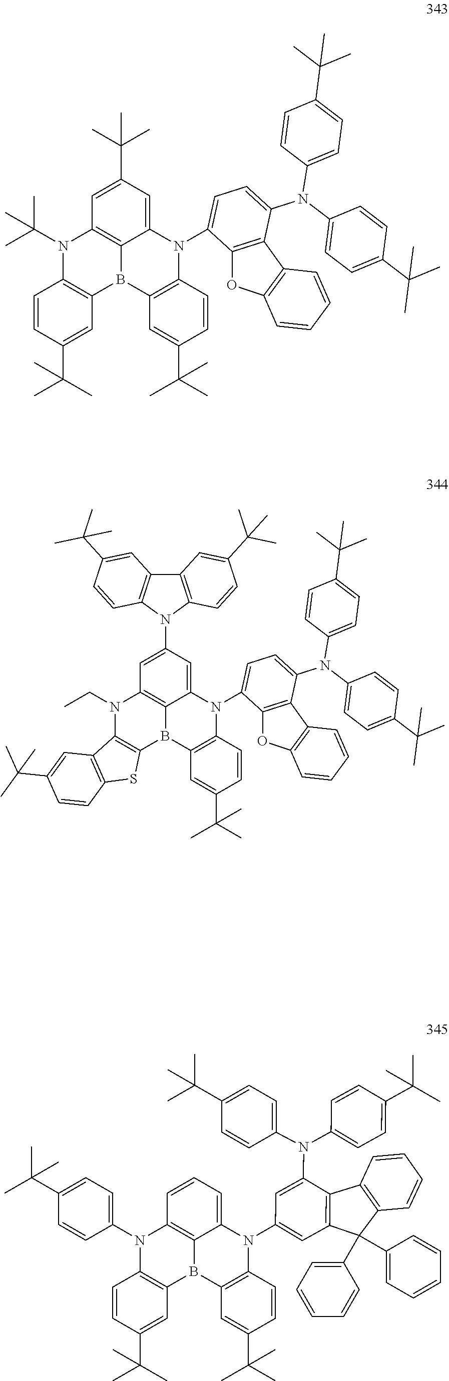

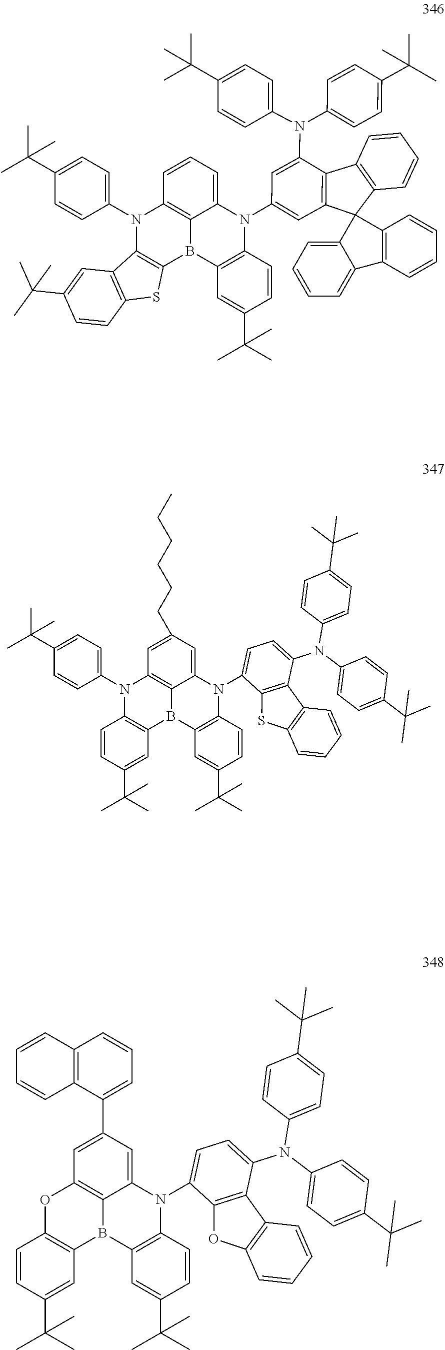 [SMILES: CC(C)(C)c1ccc(N(c2ccc(C(C)(C)C)cc2)c2cc(N3c4ccc(C(C)(C)C)cc4B4c5sc6ccc(C(C)(C)C)cc6c5N(c5ccc(C(C)(C)C)cc5)c5cccc3c54)cc3c2-c2ccccc2C32c3ccccc3-c3ccccc32)cc1 ; CCCCCCc1cc2c3c(c1)N(c1ccc(N(c4ccc(C(C)(C)C)cc4)c4ccc(C(C)(C)C)cc4)c4c1sc1ccccc14)c1ccc(C(C)(C)C)cc1B3c1cc(C(C)(C)C)ccc1N2c1ccc(C(C)(C)C)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(-c6cccc7ccccc67)cc3c54)c3oc4ccccc4c23)cc1]

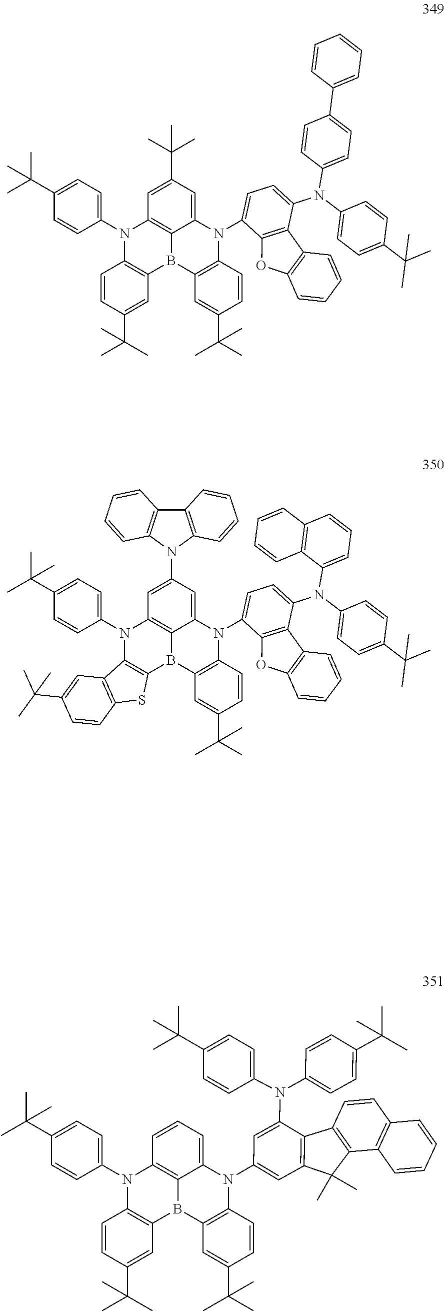

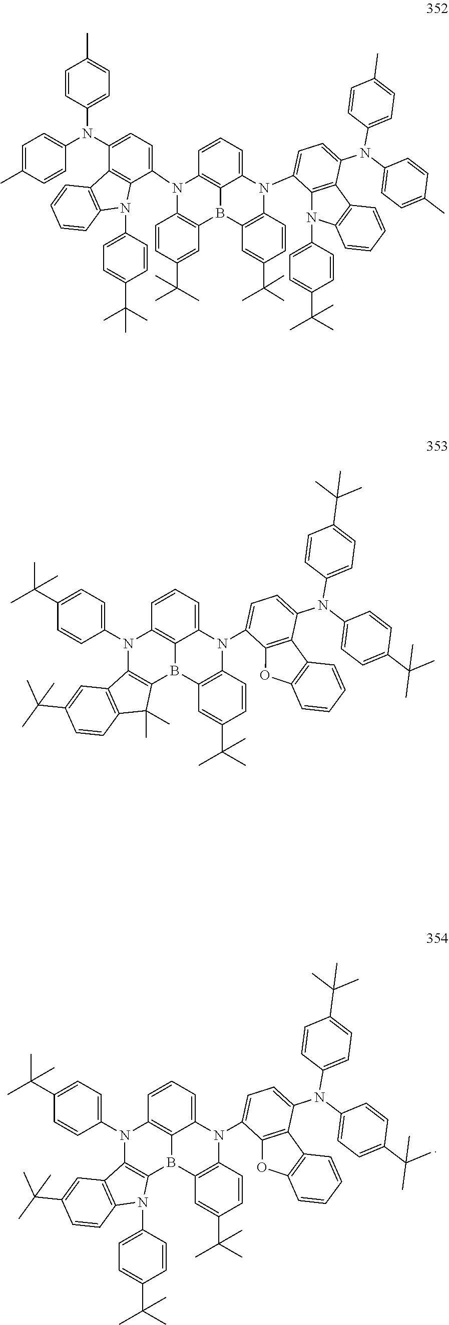

The present disclosure further provides a light-emitting element, which includes:

a pair of electrodes including a first electrode and a second electrode;

an organic functional layer located between the first electrode and the second electrode;

wherein a material of the organic functional layer includes at least one of organic compounds as described in any one of the above-mentioned embodiments.

Preferably, the organic functional layer includes at least a light-emitting layer, the light-emitting layer includes a host material and a guest material, and the guest material is at least one of organic compounds as described in any one of the above-mentioned embodiments.

The present disclosure further provides a display panel including a light-emitting element as described in any one of the above-mentioned embodiments.

By adopting the organic compound containing an amino group, the organic compound of the disclosure contains heterocyclic rings and the amino group at a same time. Therefore, a resonance effect of a material containing the organic compound used in the light-emitting element can be enhanced, thereby improving performances of the material, improving luminous efficiency of the light-emitting element, and prolonging luminous life of the light-emitting element.

### BRIEF DESCRIPTION OF THE DRAWINGS

In order to illustrate technical solutions in embodiments of the present disclosure more clearly, the following briefly introduces drawings needed to be used in description of the embodiments. Obviously, the drawings in the following description are only some embodiments of the present disclosure. For those skilled in the art, other drawings can be obtained from these drawings without paying creative effort.

FIG. 1 is a first schematic structural diagram of a light-emitting element provided by an embodiment of the present disclosure.

FIG. 2 is a second schematic structural diagram of the light-emitting element provided by the embodiment of the present disclosure.

### DETAILED DESCRIPTION OF THE EMBODIMENT

Technical solutions in the present disclosure will be illustrated clearly and completely below in combination drawings in the embodiments of the present disclosure. Obviously, the described embodiments are only a part of the embodiments of the present disclosure, not all of them. Based on the embodiments in the present disclosure, all other embodiments obtained by those skilled in the art without pay creative effort belong to a scope of the present disclosure. In addition, it should be understood that specific embodiments described herein are only used to explain the present disclosure, not to define the present disclosure. In the present disclosure, location terms described, such as “up” and “down”, generally refer to up and down in actual use or working state of devices, in particular drawing directions in the drawings, unless otherwise described. Terms “inside” and “outside” refer to outlines of the devices. In the present disclosure, “optional” and “optionally” refer to that either of two parallel schemes is “yes” or “no”. Each “optional” is independent, if there are multiple “optional” in a technical scheme, and there is no special description, contradiction, or mutual restriction. In the present disclosure, technical features described in open forms include both closed technical solutions composed of listed features and open technical solutions containing listed features.

In the present disclosure, an aromatic group, an aromatic ring and an aromatic ring system have a same meaning and may be interchanged.

In the present disclosure, a heteroaromatic group, a heteroaromatic ring and a heteroaromatic ring system have a same meaning and may be interchanged.

In the present disclosure, “substituted” means that one or more hydrogen atoms in one substituted group are substituted by a substituent group.

In the present disclosure, a same substituent group at different substituent site may be independently selected from different groups. If a formula includes a plurality of R, each R can be independently selected from different groups.

In the present disclosure, “substituted or unsubstituted” means that a defined group may be substituted or not be substituted. When the defined group is substituted, it should be understood that the defined group may be substituted by at least one substituent R. The substituent R is selected from, but not limited thereto: —D, a cyano group, an isocyano group, a nitro group, a halogen group, a C₁-C₂₀ alkyl group, a heterocyclic group containing 3-20 ring atoms, an aromatic group containing 6-20 ring atoms, a heteroaromatic group containing 5-20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group. The above-mentioned groups may further be substituted by acceptable substituent groups in the art. Understandably, R′ and R″ in the —NR′R″ are both independently selected from, but not limited thereto: —H, —D, a cyanogen group, an isocyano group, a nitro group, a halogen group, a C₁-C₁₀ alkyl group, a heterocyclic group containing 3-20 ring atoms, an aromatic group containing 6-20 ring atoms, and a heteroaromatic group containing 5-20 ring atoms. In some embodiments, the R is selected from, but not limited thereto: —D, a cyano group, an isocyano group, a nitro group, a halogen group, a C₁-C₁₀ alkyl group, a heterocyclic group containing 3-10 ring atoms, an aromatic group containing 6-20 ring atoms, a heteroaromatic group containing 5-20 ring atoms, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, and a trifluoromethyl group, and the above-mentioned groups may further be substituted by acceptable substituent groups in the art.

In the present disclosure, “a ring atom number” refers to a number of atoms constituting a ring of structural compounds (such as a monocyclic compound, a fused ring compound, a cross-linked compound, a carbon ring compound, and a heterocyclic compound) obtained by atomic bonding. In a ring substituted by a substituent group, atoms contained in the substituent group is not included in the atoms forming the ring. The same applies to the “number of ring atoms” described below unless otherwise specified. For example, a ring atom number of a benzene ring is 6, a ring atom number of a naphthalene ring is 10, and a ring atom number of a thiophene group is 5.

In the present disclosure, “an aryl group or an aromatic group” refers to an aromatic hydrocarbon group derived from a basis of an aromatic ring compound removing an H. The aromatic ring compound may be a single ring aromatic group, a fused ring aromatic group, or a polycyclic aromatic group. For a polycyclic ring type, at least one ring is an aromatic ring system. For example, in some embodiments, “a substituted or unsubstituted aryl group containing 6 to 40 ring atoms” refers to an aryl group containing 6 to 40 ring atoms. In some embodiments, “the substituted or unsubstituted aryl group containing 6 to 30 ring atoms” refers to a substituted or unsubstituted aryl group containing 6 to 30 ring atoms. In some embodiments, “the substituted or unsubstituted aryl group containing 6 to 18 ring atoms” refers to a substituted or unsubstituted aryl group containing 6 to 18 ring atoms. In some embodiments, “the substituted or unsubstituted aryl group containing 6 to 14 ring atoms” refers to a substituted or unsubstituted aryl group containing 6 to 14 ring atoms, and the aryl group is optionally further substituted. Suitable examples include, but are not limited thereto: a phenyl group, a biphenyl group, a triphenyl group, a naphthyl group, an anthracyl group, a phenanthryl group, a fluoranthenyl group, a triphenylene group, a pyrenyl group, a perylene group, a tetraphenyl group, a fluorenyl group, a diphenyl group, an acenaphthenyl group, and derivatives of these groups. Understandably, multiple aryl groups may further be disconnected by short non-aromatic units (for example, a non hydrogenium atoms contenting less than 10%, such as C, N, or O). In detail, an acenaphthene group, a fluorene group, a 9,9-diarylfluorene group, a triarylamine group, and a diaryl ether system should be further included in a definition of the aryl groups.

In the present disclosure, “a heteroaryl group or a heteroaromatic group” refers a basis of an aryl group with at least one carbon atom substituted by a non-carbon atom, and the non-carbon atom may be N, O, S, etc. For example, in some embodiments, “a substituted or unsubstituted heteroaryl group containing 5 to 40 ring atoms” refers to a heteroaryl group containing 5 to 40 ring atoms. In some embodiments, “the substituted or unsubstituted heteroaryl group containing 6 to 30 ring atoms” refers to a substituted or unsubstituted heteroaryl group containing 6 to 30 ring atoms. In some embodiments, “the substituted or unsubstituted heteroaryl group containing 6 to 18 ring atoms” refers to a substituted or unsubstituted heteroaryl group containing 6 to 18 ring atoms. In some embodiments, “the substituted or unsubstituted heteroaryl group containing 6 to 14 ring atoms” refers to a substituted or unsubstituted heteroaryl group containing 6 to 14 ring atoms, and the heteroaryl group are optionally further substituted. Suitable examples include but are not limited thereto: a thiophene group, a furan group, a pyrrolyl group, a diazo group, a triazole group, an imidazolyl group, a pyridinyl group, a bipyridyl group, a pyrimidinyl group, a triazinyl group, an acridine group, a pyridazinyl group, a pyrazinyl group, a quinolinyl group, an isoquinolinyl group, a quinazolinyl group, a quinoxalinyl group, a phthalazinyl group, a pyridino pyrimidinyl group, a pyridino pyrazinyl group, a benzo thienyl group, a benzofuranyl group, an indolyl group, a pyrrolo imidazolyl group, a pyrrolo pyrrolyl group, a thiophenopyrrolyl group, a thiophenothiophenyl group, a furanopyrrolyl group, a furanofuranyl group, a thiophenofuranyl group, a benzoisoxazolyl group, a benzoisothiazolyl group, a benzimidazolyl group, an o-diaznaphthyl group, a phenanthryl group, a pyridinyl group, a quinazolinketone group, a dibenzothiophenyl group, a dibenzofuranyl group, a carbazolyl group, and derivatives of these groups.

In the present disclosure, “an amino group” refers to a derivative of an amine, has a feature of a group represented by formula —NR′R″. R′ and R′ have same meanings as above-mentioned.

In the present disclosure, the “*” connected to a single bond indicates a binding site or a fused site. When a binding site of a group is not specified, it means that any of connectable sites in the group may be selected as the binding site. When a same group contains a plurality of substituent groups having a same symbol, the substituent groups may be the same or be different, such as

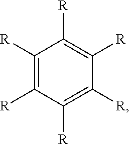

six R groups of a benzene ring may be the same or different. A single bond connected to a substituent group and penetrated a corresponding ring indicates that the substituent group may be connected to any site of the ring. For example,

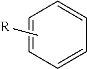

means that R is connected to any substituent site of the benzene ring.

At present, it is difficult to improve performances of OLED elements because of poor performances such as low luminous efficiency, poor stability and low life of light-emitting materials used in the OLED elements.

An embodiment of the present disclosure provides an organic compound represented by formula (1):

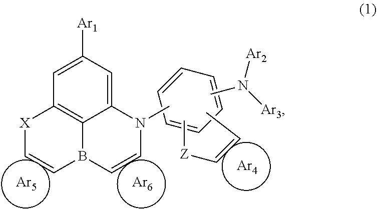

wherein Z is selected from CR₁R₂, NR₃, O, and S;

X is selected from O and NR₄;

R₁, R₂, R₃, and R₄ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group;

a ring is formed or no ring is formed by an interconnection of R₁ and R₂;

Ar₁ is selected from —H, —D, a substituted or unsubstituted C₁-C₂₀ alkyl group, a substituted or unsubstituted C₆-C₃₀ aromatic group, and a substituted or unsubstituted C₅-C₃₀ heteroaromatic group;

Ar₂ and Ar₃ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group; and

Ar₄, Ar₅, and Ar₆ are each independently selected from a substituted or unsubstituted C₆-C₃₁ aromatic group and a substituted or unsubstituted C₅-C₃₀ heteroaromatic group.

By adopting the organic compound containing an amino group, the organic compound contains heterocyclic rings and the amino group at a same time. Therefore a resonance effect of a material containing the organic compound used in the light-emitting element can be enhanced, thereby improving performances of the material, improving luminous efficiency of the light-emitting element, and prolonging luminous life of the light-emitting element.

In some embodiments, the organic compound is represented by any one of formula (2) to formula (11):

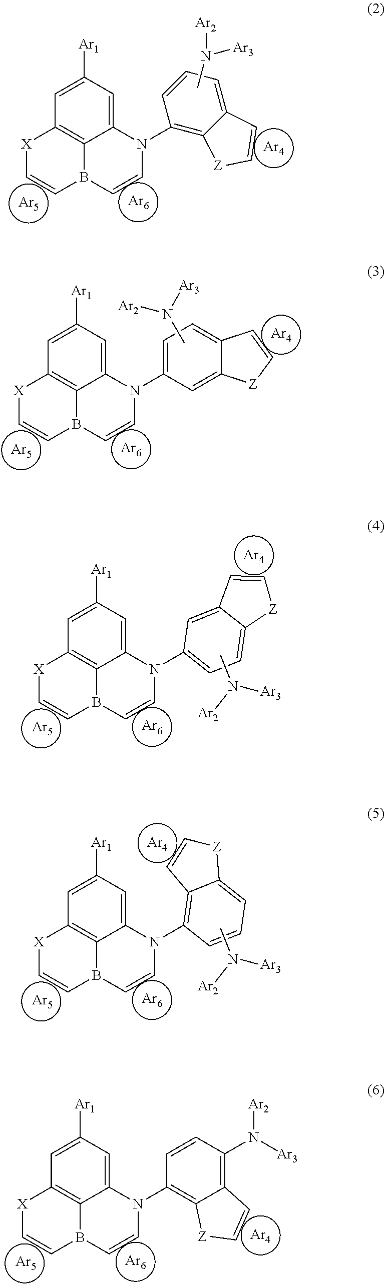

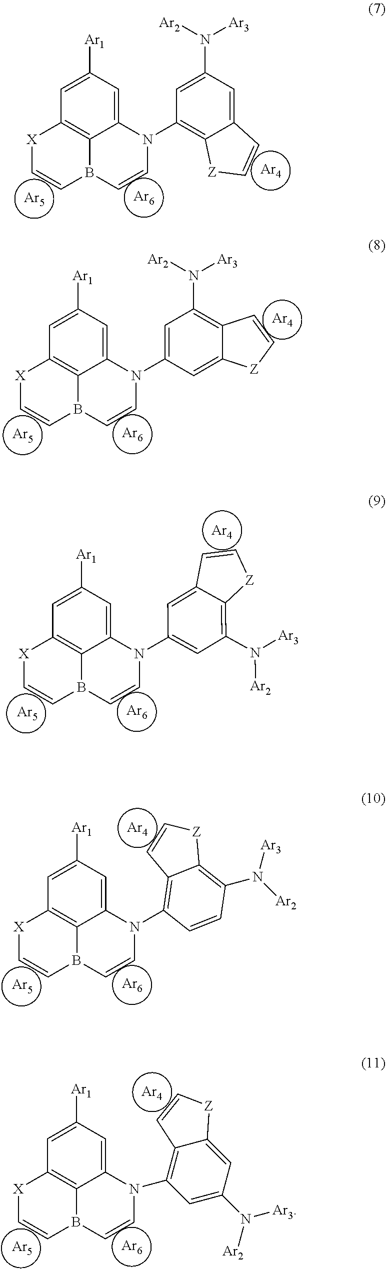

In some embodiments, Z is selected from CR₁R₂, O, and S, preferably O or S. In some embodiments, X is NR₄.

In some embodiments, the organic compound is represented by formula

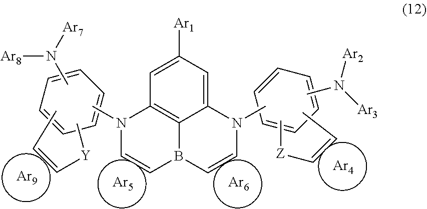

In some embodiments, Y is selected from CR₅R₆, NR₇, O, and S.

In some embodiments, R₅, R₆, and R₇ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group every time it presents. In some embodiments, R₅, R₆, and R₇ are each independently selected from a substituted or unsubstituted C₁-C₁₂ alkyl group, a substituted or unsubstituted C₆-C₂₀ aromatic group, and a substituted or unsubstituted C₅-C₂₀ heteroaromatic group every time it presents. In some embodiments, R₅, R₆, and R₇ are each independently selected from a substituted or unsubstituted C₁-C₈ alkyl group, a substituted or unsubstituted C₆-C₁₅ aromatic group, and a substituted or unsubstituted C₅-C₁₅ heteroaromatic group every time it presents. In some embodiments, R₅, R₆, and R₇ are each independently selected from a substituted or unsubstituted methyl group and a substituted or unsubstituted C₆-C₁₀ aromatic group every time it presents. In some embodiments, R₅, R₆, and R₇ are each independently selected from a methyl group and a phenyl group every time it presents.

In some embodiments, a ring is formed or no ring is formed by an interconnection of R₅ and R₆.

In some embodiments, Ar₇ and Ar₈, are each independently selected from a substituted or unsubstituted C₁-C₁₂ alkyl group, a substituted or unsubstituted C₆-C₂₀ aromatic group, and a substituted or unsubstituted C₅-C₂₀ heteroaromatic group. In some embodiments, Ar₇ and Ar₈, are each independently selected from a substituted or unsubstituted C₁-C₈ alkyl group, a substituted or unsubstituted C₆-C₁₅ aromatic group, and a substituted or unsubstituted C₅-C₁₅ heteroaromatic group. In some embodiments, Ar₇ and Ar₈, are each independently selected from a substituted or unsubstituted C₆-C₁₀ aromatic group and a substituted or unsubstituted C₅-C₁₀ heteroaromatic group. In some embodiments, Ar₇ and Ar₈, are each independently selected from a methyl group, a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

In some embodiments, Ar₉ is selected from a substituted or unsubstituted C₆-C₂₀ aromatic group and a substituted or unsubstituted C₅-C₂₀ heteroaromatic group. In some embodiments, Ar is selected from a substituted or unsubstituted C₆-C₁₅ aromatic group and a substituted or unsubstituted C₅-C₁₅ heteroaromatic group. In some embodiments, Aro is selected from a substituted or unsubstituted C₆-C₁₀ aromatic group and a substituted or unsubstituted C₅-C₁₀ heteroaromatic group. In some embodiments, Ar₉ is independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

In some embodiments, the organic compound is represented by formula

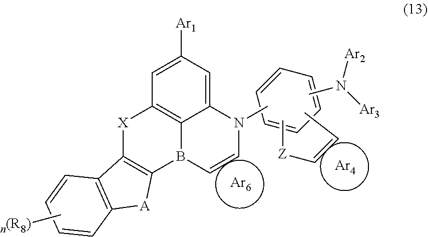

In some embodiments, A is represented by CR₉R₁₀, NR₁₁, O, or S.

In some embodiments, n is an integer ranging from 0 to 4, such as 0, 1, 2, 3, or 4.

In some embodiments, R₈, R₉, R₁₀, and R₁₁ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group every time it presents. In some embodiments, R₈, R₉, R₁₀, and R₁₁ are each independently selected from a substituted or unsubstituted C₁-C₄ alkyl group, a substituted or unsubstituted C₆-C₃₀ aromatic group, and a substituted or unsubstituted C₅-C₃₀ heteroaromatic group every time it presents. In some embodiments, R₈, R₉, R₁₀, and R₁₁ are each independently selected from a substituted or unsubstituted C₁-C₄ alkyl group, a substituted or unsubstituted C₆-C₁₀ aromatic group every time it presents. In some embodiments, R₈, R₉, R₁₀, and R₁₁ are each independently selected from a methyl group, a tertbutyl group, a substituted or unsubstituted phenyl group. In some embodiments, the substituted phenyl group is a phenyl group substituted by a tertbutyl group.

When n is equal to 0, a ring is formed or no ring is formed by an interconnection of R₉ and R₁₀. When n is greater than or equal to 1, a ring is formed or no ring is formed by an interconnection of R₈ and R₉ and/or R₁₀, that is, when n is greater than or equal to 1, a ring is formed by any two of R₈, R₉, and R₁₀, a ring is formed by all of R₈, R₉, and R₁₀, or no ring is formed among R₈, R₉, and R₁₀.

In some embodiments, the organic compound is represented by formula (14):

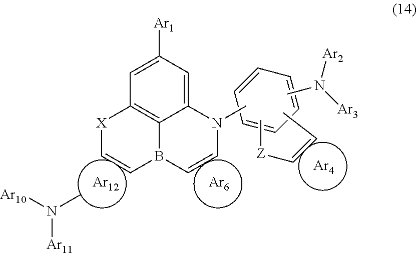

In some embodiments, Ar₁₀ and Ar₁₁ are each independently selected from a substituted or unsubstituted C₁-C₁₂ alkyl group, a substituted or unsubstituted C₆-C₂₄ aromatic group, and a substituted or unsubstituted C₅-C₂₄ heteroaromatic group. In some embodiments, Ario and Arn are each independently selected from a substituted or unsubstituted C₁-C₁₂ alkyl group, a substituted or unsubstituted C₆-C₂₀ aromatic group, and a substituted or unsubstituted C₅-C₂₀ heteroaromatic group. In some embodiments, Ar₁₀ and Ar₁ are each independently selected from a substituted or unsubstituted C₁-C₈ alkyl group, a substituted or unsubstituted C₆-C₁₅ aromatic group, and a substituted or unsubstituted C₅-C₁₅ heteroaromatic group. In some embodiments, Ar₁₀ and Ar₁₁ are each independently selected from a methyl group, a substituted or unsubstituted C₆-C₁₈ aromatic group, and a substituted or unsubstituted C₅-C₁₃ heteroaromatic group. In some embodiments, Ar₁₀ and Ar₁₁ are each independently selected from a methyl group, a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

In some embodiments, Ar₁₂ is selected from a substituted or unsubstituted phenyl group.

In the above-mentioned embodiments, R₁, R₂, R₃, and R₄ are each independently selected from a substituted or unsubstituted C₁-C₄ alkyl group, a substituted or unsubstituted C₆-C₃₀ aromatic group, and a substituted or unsubstituted C₅-C₃₀ heteroaromatic group every time it presents. In some embodiments, R₁, R₂, R₃, and R₄ are each independently selected from a substituted or unsubstituted C₁-C₄ alkyl group, a substituted or unsubstituted C₆-C₂₉ aromatic group, and a substituted or unsubstituted C₂₆-C₃₆ heteroaromatic group every time it presents. In some embodiments, R₁, R₂, R₃, and R₄ are each independently selected from a substituted or unsubstituted C₁-C₁₂ alkyl group, a substituted or unsubstituted C₆-C₁₅ aromatic group, and a substituted or unsubstituted C₅-C₁₅ heteroaromatic group every time it presents. In some embodiments, R₄ is independently selected from a methyl group, a substituted or unsubstituted phenyl group, a substituted or unsubstituted naphthyl group, a substituted or unsubstituted dibenzofuran, a substituted or unsubstituted dibenzothiophene, a substituted or unsubstituted fluorenyl group, and a substituted or unsubstituted carbazole group every time it presents. In some embodiments, R₁, R₂, R₃, and R₄ are each independently selected from a methyl group, a substituted or unsubstituted phenyl group every time it presents.

In the above-mentioned embodiments, Ar₁ is selected from —H, —D, a substituted or unsubstituted C₁-C₅ alkyl group, a substituted or unsubstituted C₆-C₃₀ aromatic group, and a substituted or unsubstituted C₅-C₃₀ heteroaromatic group. In some embodiments, Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group. In some embodiments, Ar₁ is selected from —H, —D, a substituted or unsubstituted C₁-C₁₂ alkyl group, a substituted or unsubstituted C₆-C₂₀ aromatic group, and a substituted or unsubstituted C₅-C₂₀ heteroaromatic group. In some embodiments, Ar₁ is selected from —H, —D, a substituted or unsubstituted C₁-C₈ alkyl group, a substituted or unsubstituted C₆-C₁₅ aromatic group, and a substituted or unsubstituted C₅-C₁₅ heteroaromatic group. In some embodiments, Ar₁ is selected from —H, —D, a methyl group, an isopropyl group, a tertbutyl group, a tertamyl group, a substituted or unsubstituted phenyl group, a substituted or unsubstituted naphthyl group, a substituted or unsubstituted dibenzofuran, a substituted or unsubstituted dibenzothiophene, a substituted or unsubstituted fluorenyl group, a substituted or unsubstituted carbazolyl group, and a substituted or unsubstituted amino group.

In the above-mentioned embodiments, Ar₂ and Ar₃ are each independently selected from a substituted or unsubstituted methyl group, a substituted or unsubstituted C₆-C₃₀ aromatic group, and a substituted or unsubstituted C₅-C₃₀ heteroaromatic group. In some embodiments, Ar₂ and Ar₃ are each independently selected from a methyl group, a substituted or unsubstituted C₇-C₁₈ aromatic group, and a substituted or unsubstituted C₁₂-C₁₆ heteroaromatic group. In some embodiments, Ar₂ and Ar₃ are each independently selected from a substituted or unsubstituted C₁-C₁₂ alkyl group, a substituted or unsubstituted C₆-C₂₀ aromatic group, and a substituted or unsubstituted C₅-C₂₀ heteroaromatic group. In some embodiments, Ar₂ and Ar₃ are each independently selected from a substituted or unsubstituted C₁-C₈ alkyl group, a substituted or unsubstituted C₆-C₁₅ aromatic group, and a substituted or unsubstituted C₅-C₁₅ heteroaromatic group. In some embodiments, Ar₂ and Ar₃ are each independently selected from a methyl group, a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

In the above-mentioned embodiments, Ar₄, Ar₅, and Ar₆ are each independently selected from a substituted or unsubstituted C₆-C₃₁ aromatic group and a substituted or unsubstituted C₆-C₂₆ heteroaromatic group. In some embodiments, Ar₄, Ar₅, and Ar₆ are each independently selected from a substituted or unsubstituted C₆-C₂₀ aromatic group and a substituted or unsubstituted C₅-C₂₀ heteroaromatic group. In some embodiments, Ar₄, Ar₅, and Ar₆ are each independently selected from a substituted or unsubstituted C₆-C₁₅ aromatic group and a substituted or unsubstituted C₅-C₁₅ heteroaromatic group. In some embodiments, Ar₄, Ar₅, and Ar₆ are each independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

In some embodiments, the organic compound is selected from following compounds:

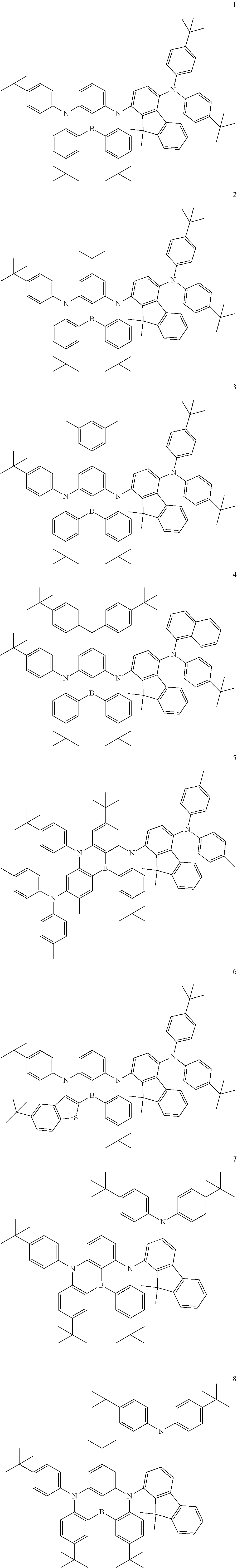

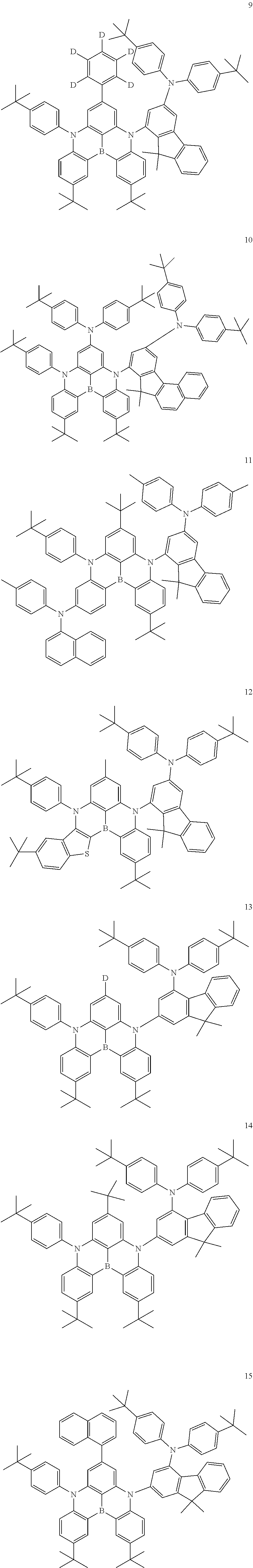

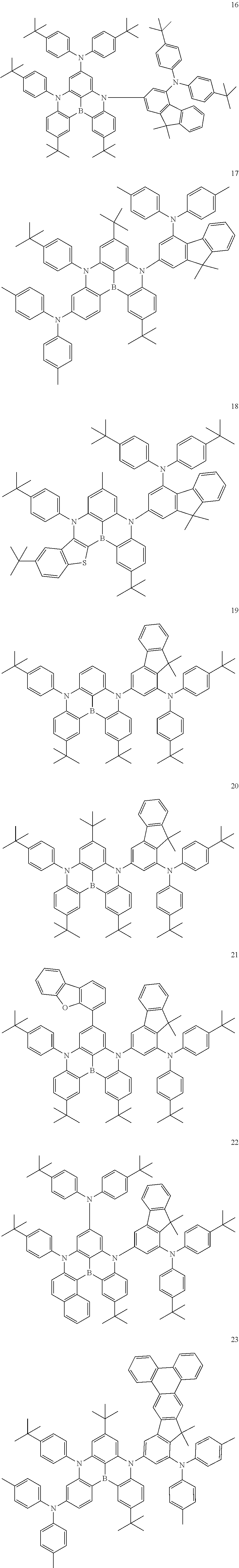

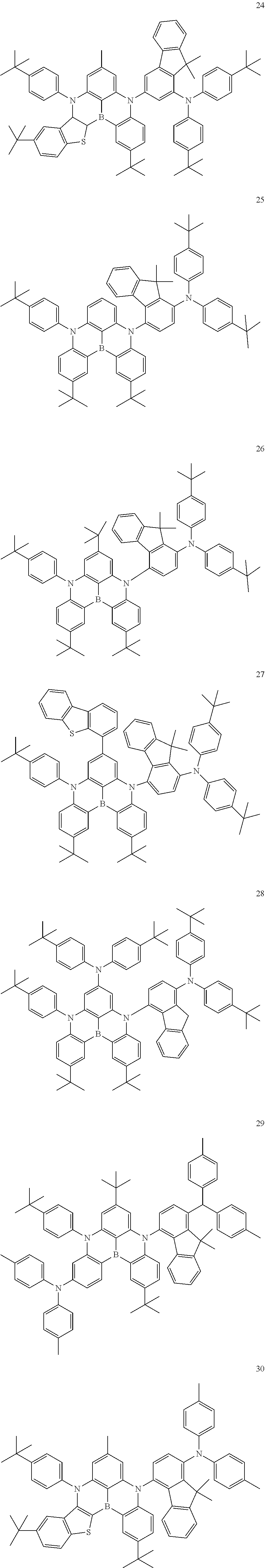

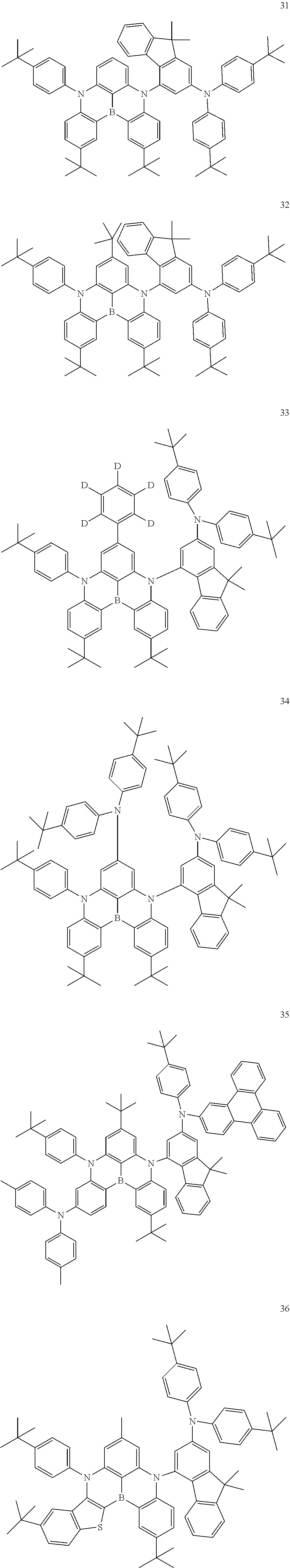

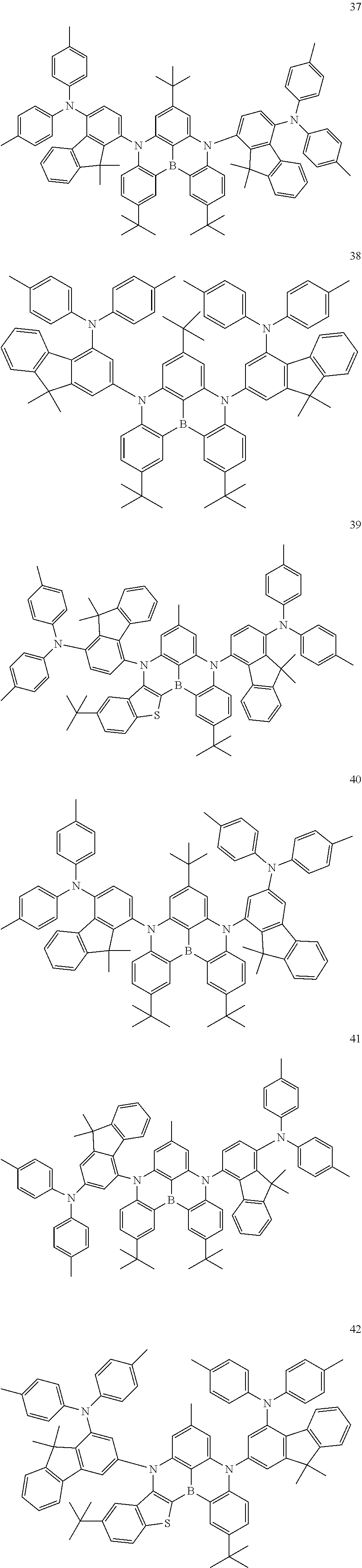

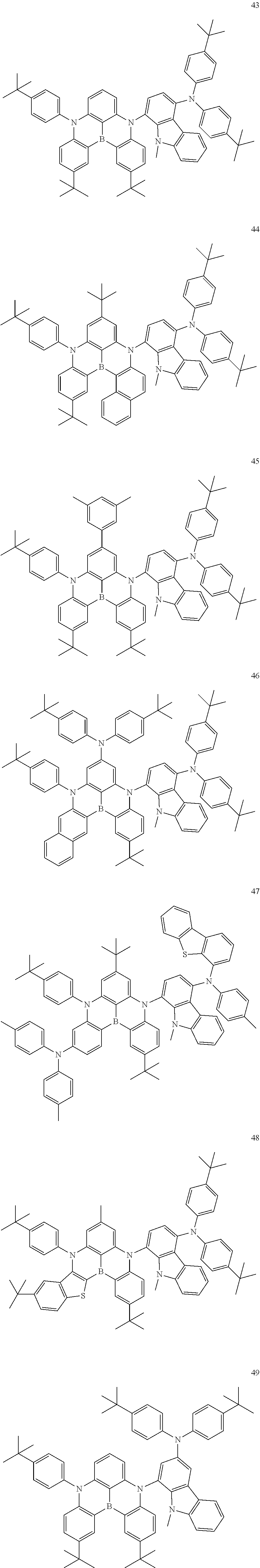

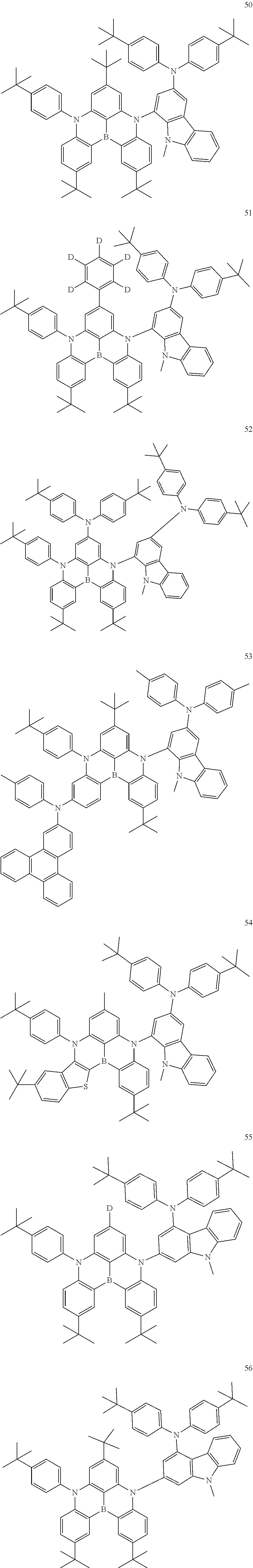

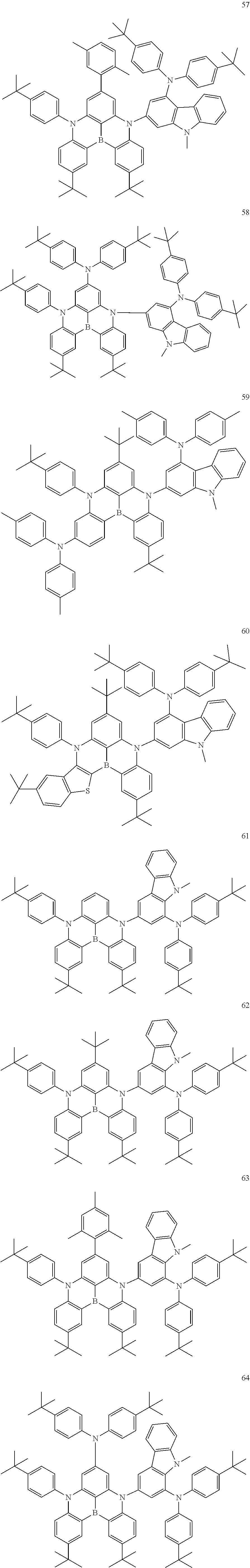

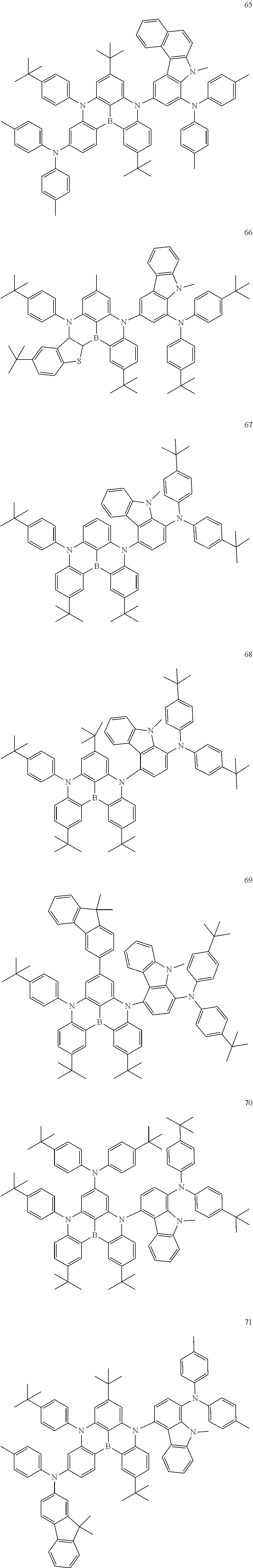

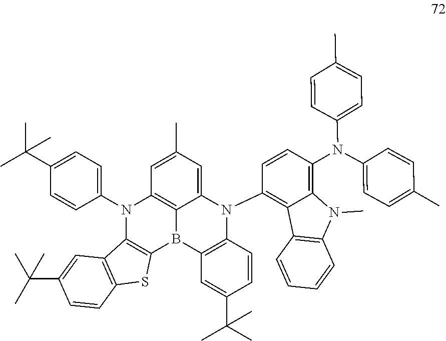 [SMILES: Cc1ccc(N(c2ccc(C)cc2)c2ccc(N3c4ccc(C(C)(C)C)cc4B4c5sc6ccc(C(C)(C)C)cc6c5N(c5ccc(C(C)(C)C)cc5)c5cc(C)cc3c54)c3c4ccccc4n(C)c23)cc1]

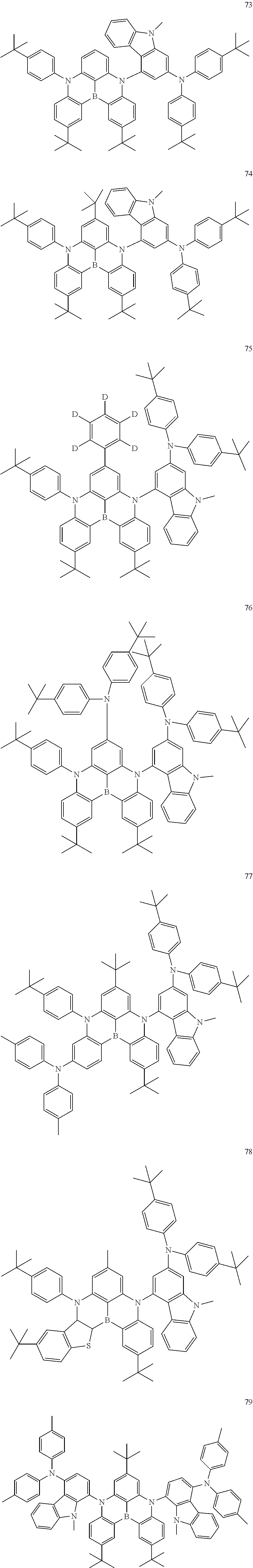

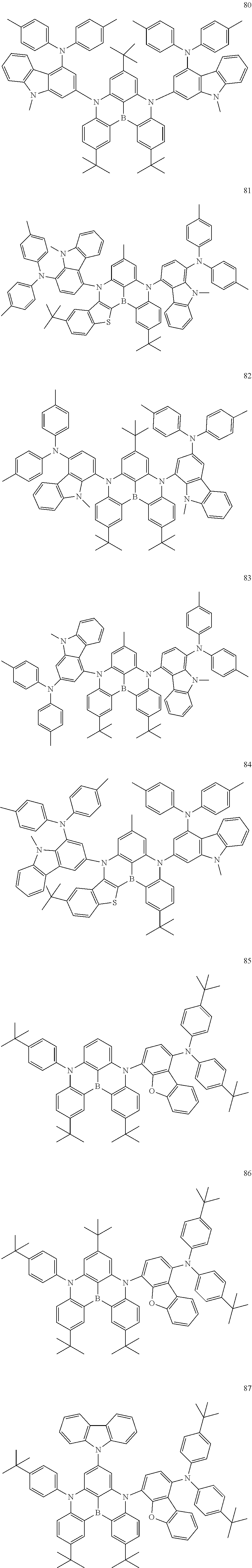

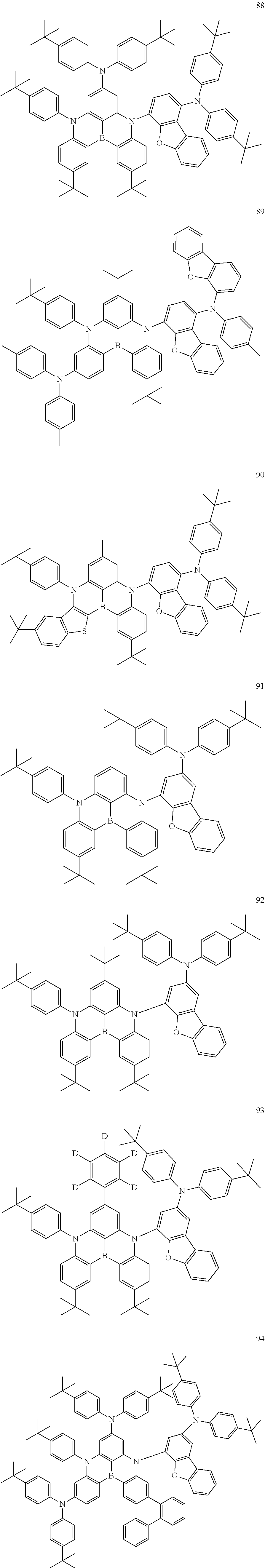

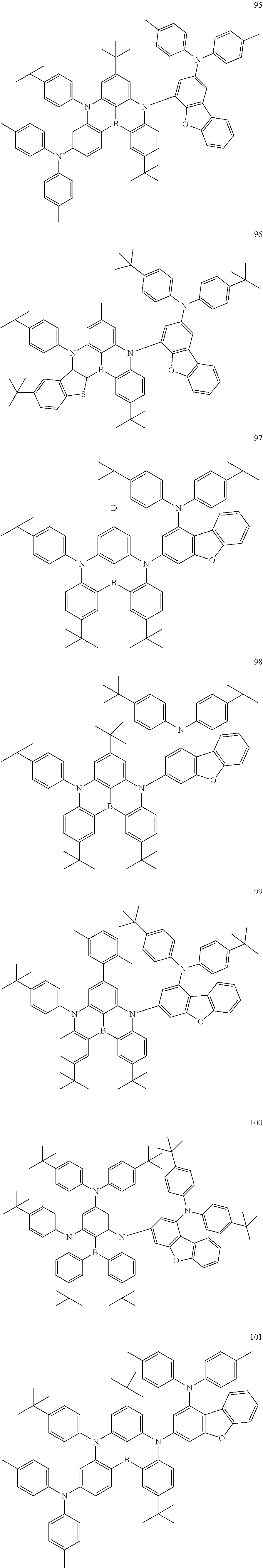

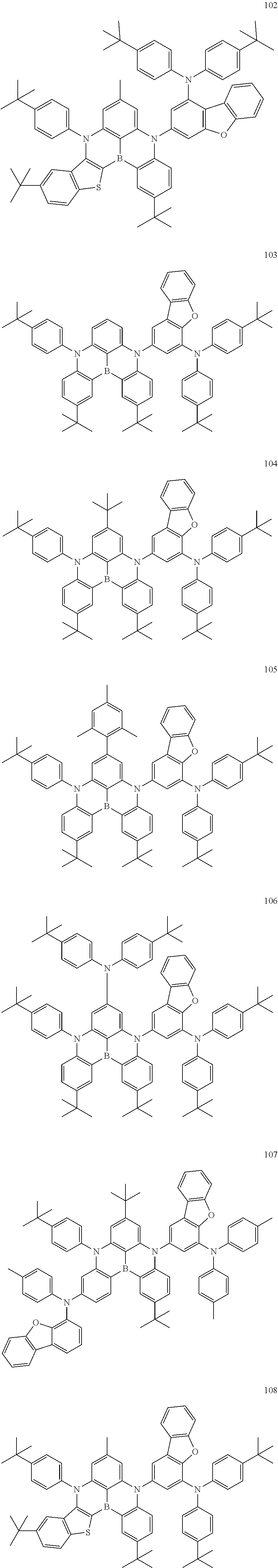

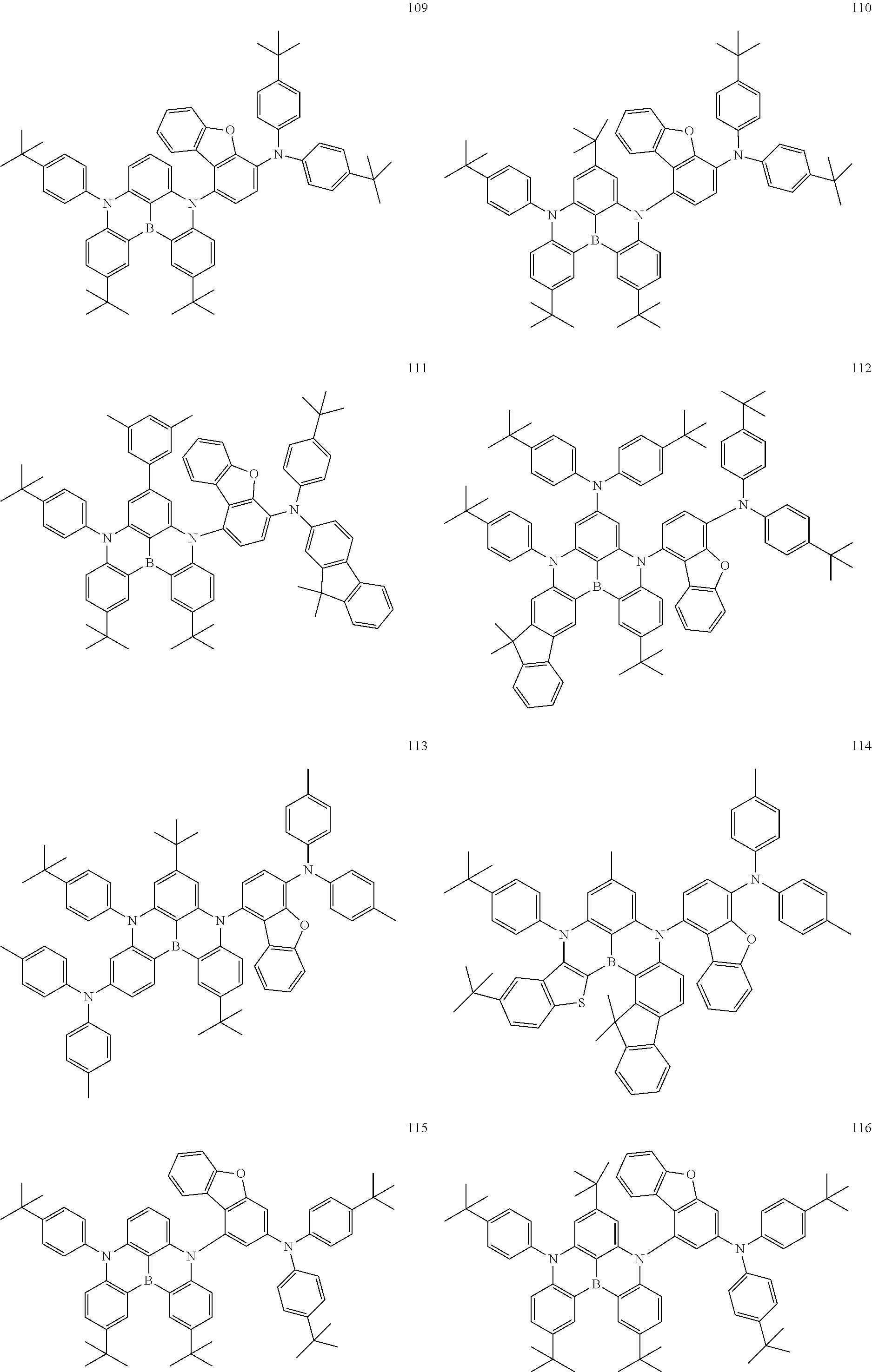

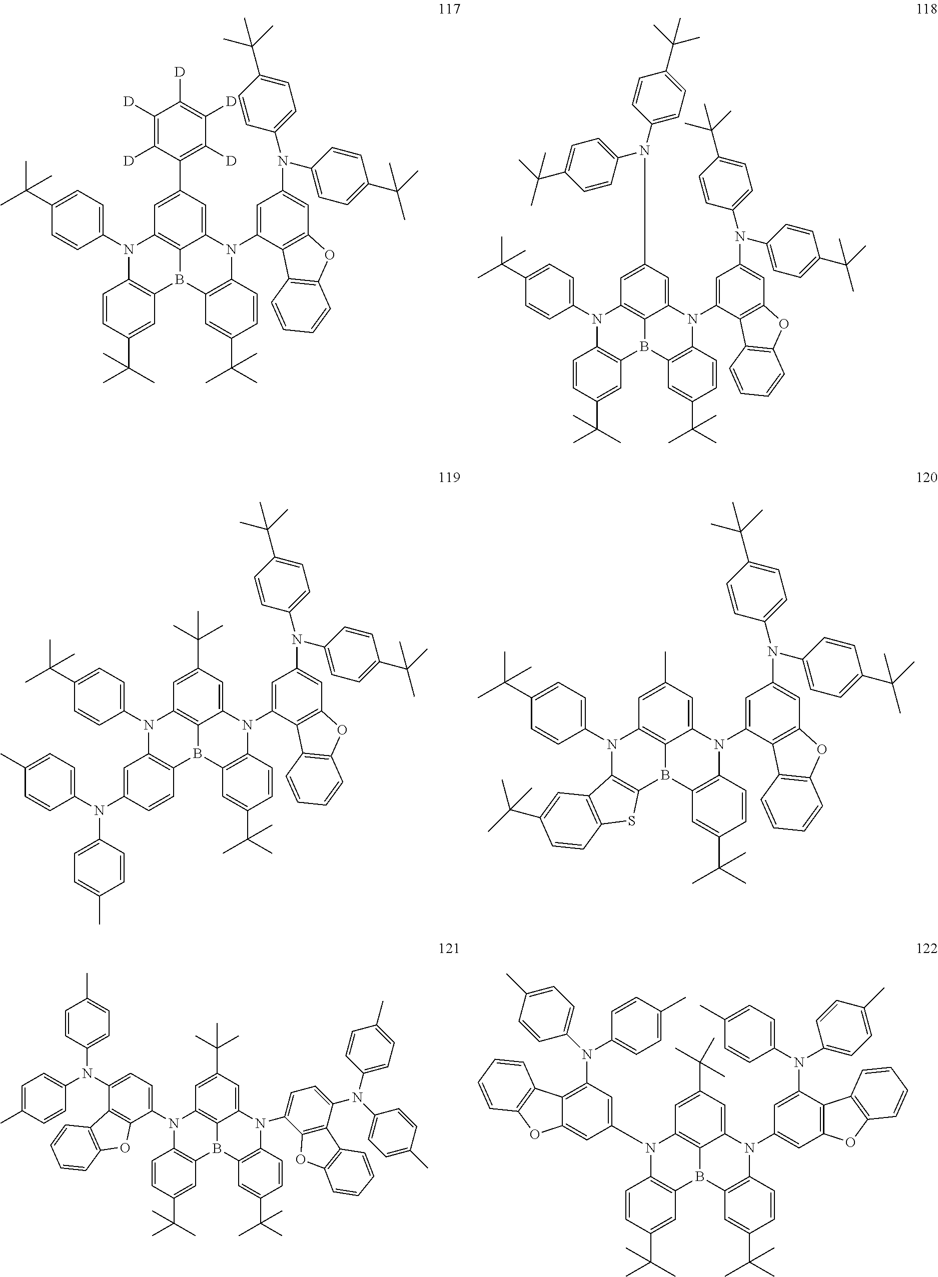

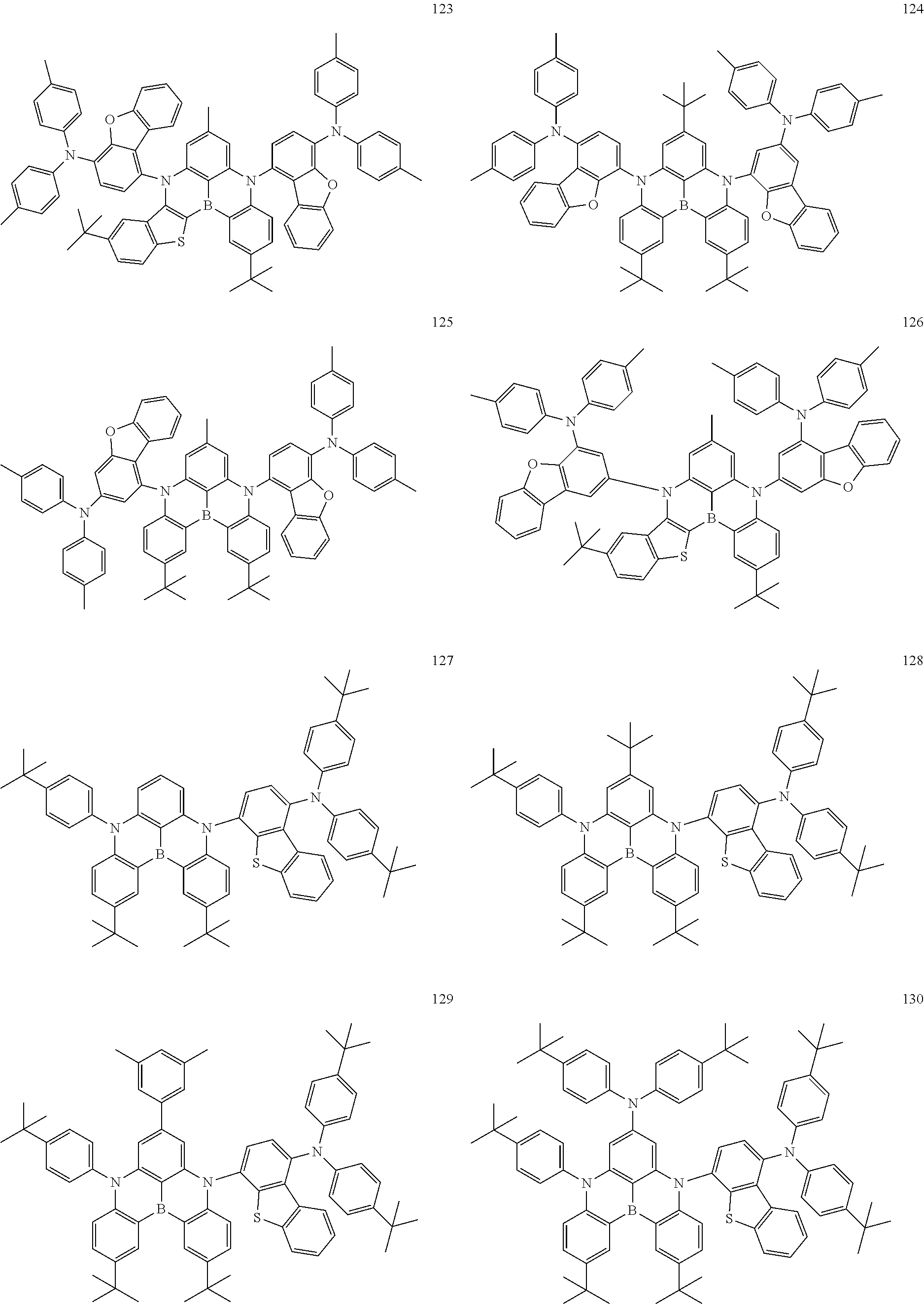

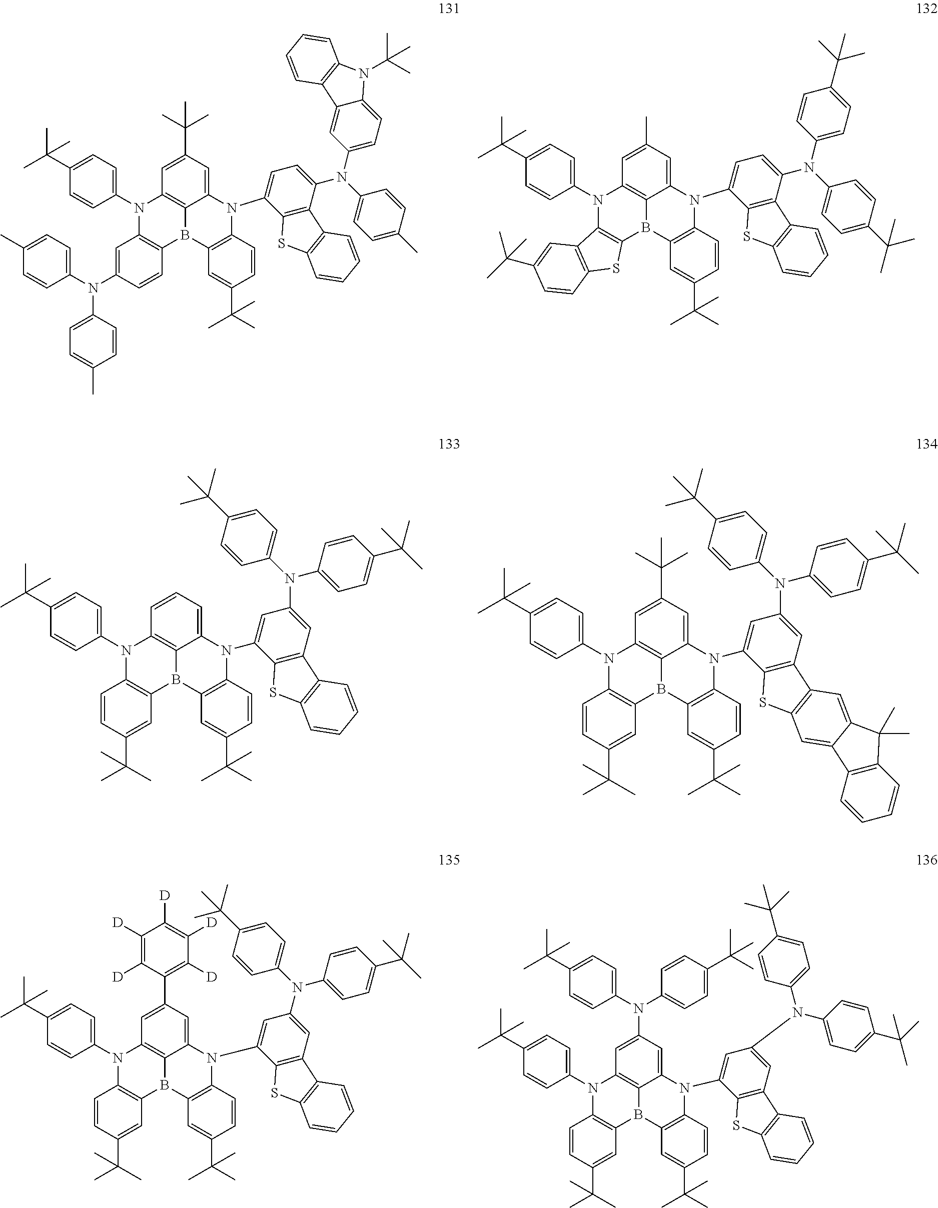

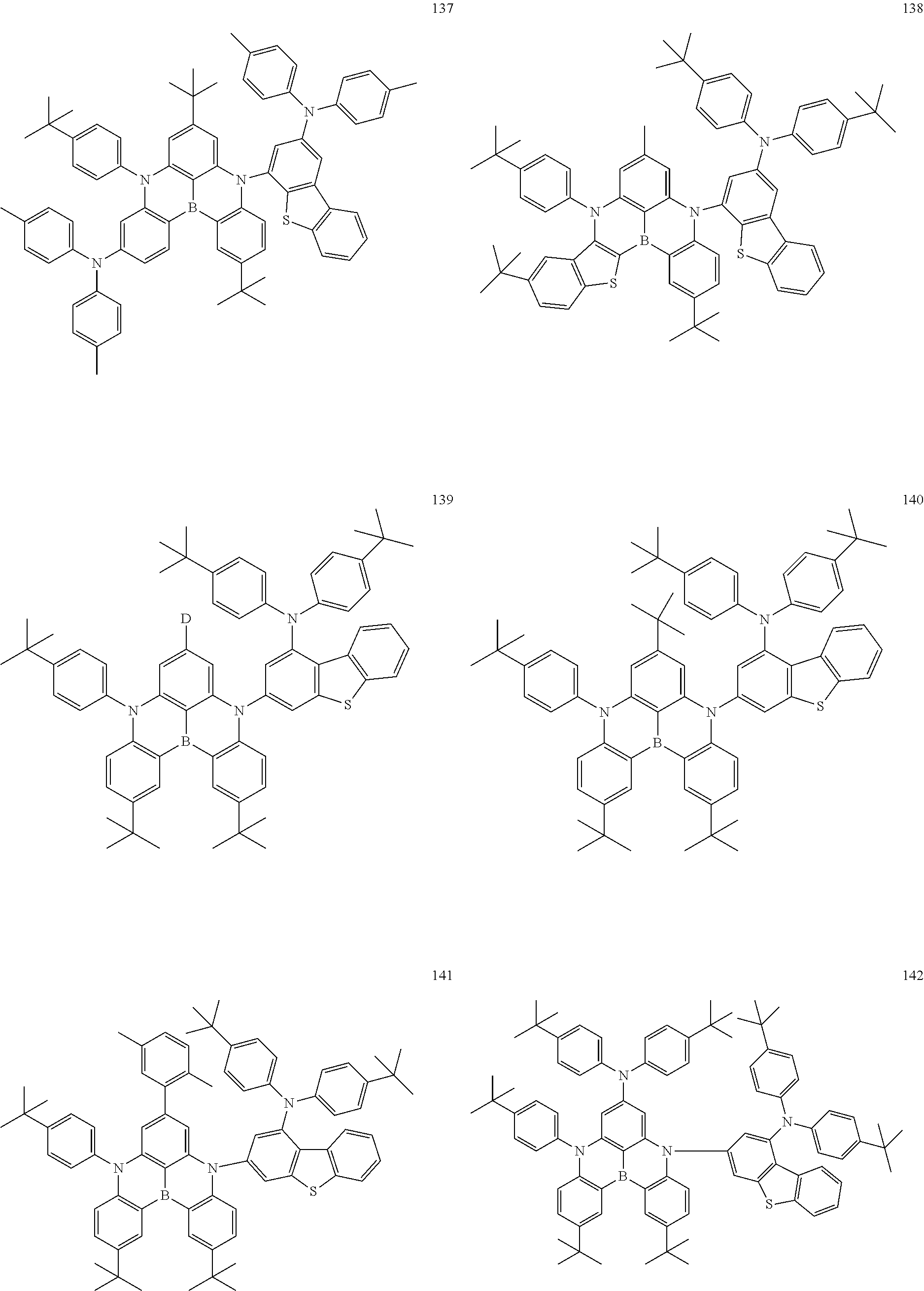

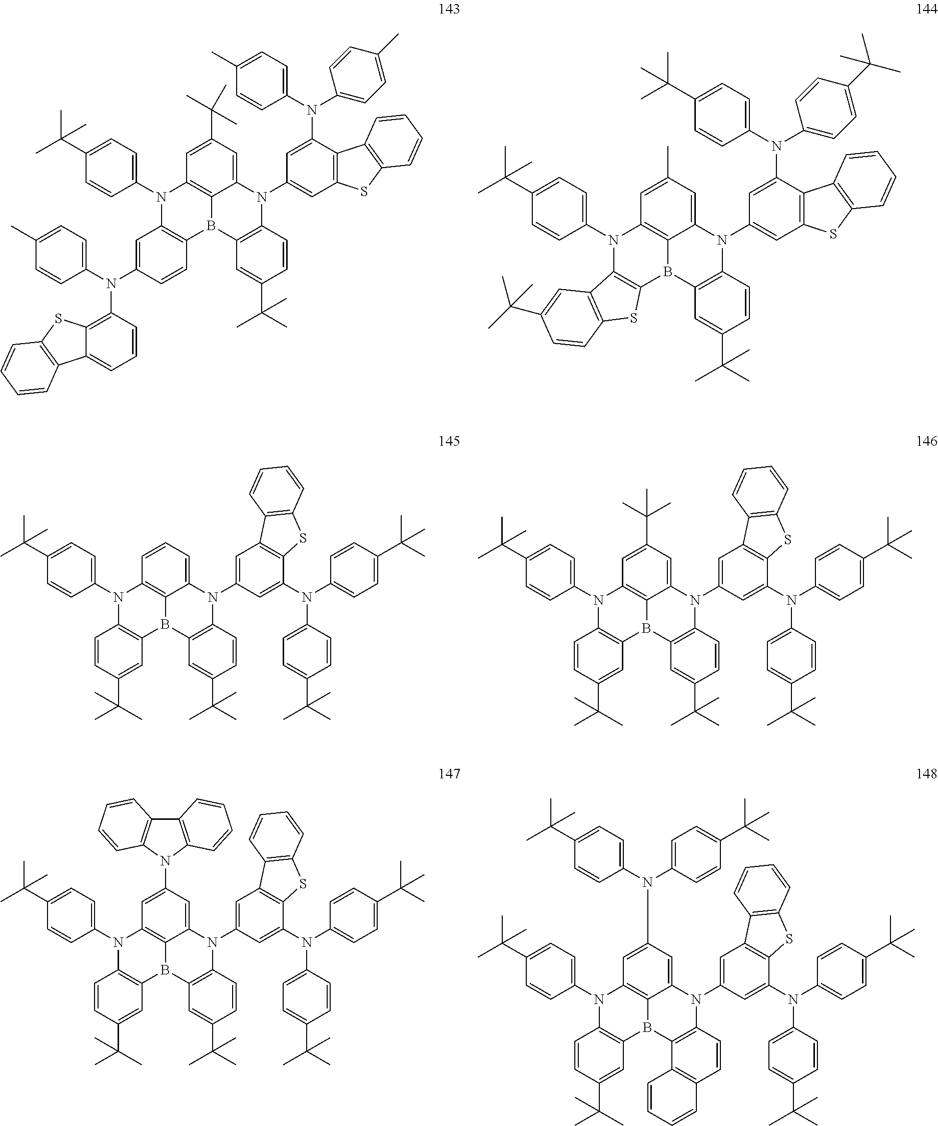

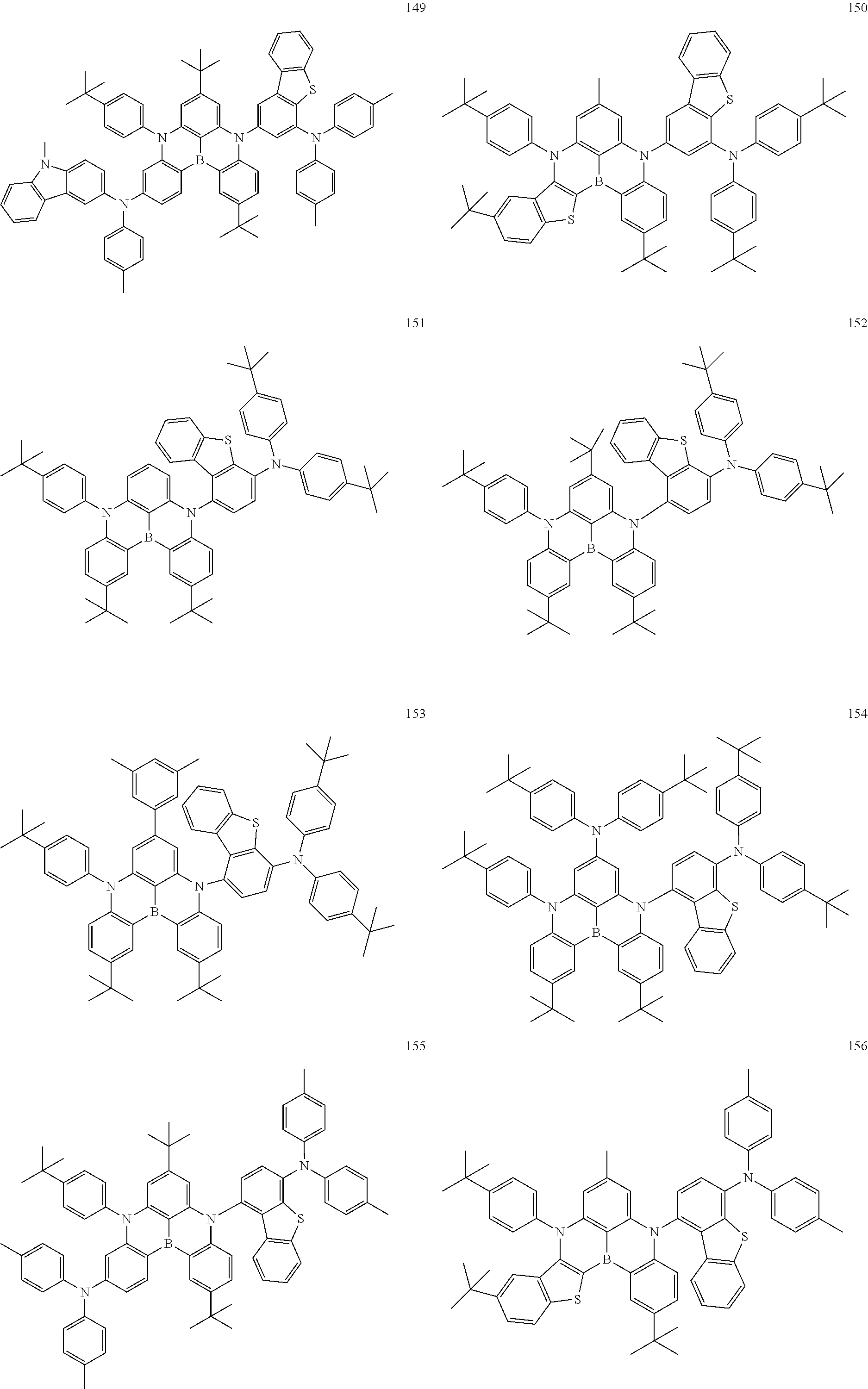

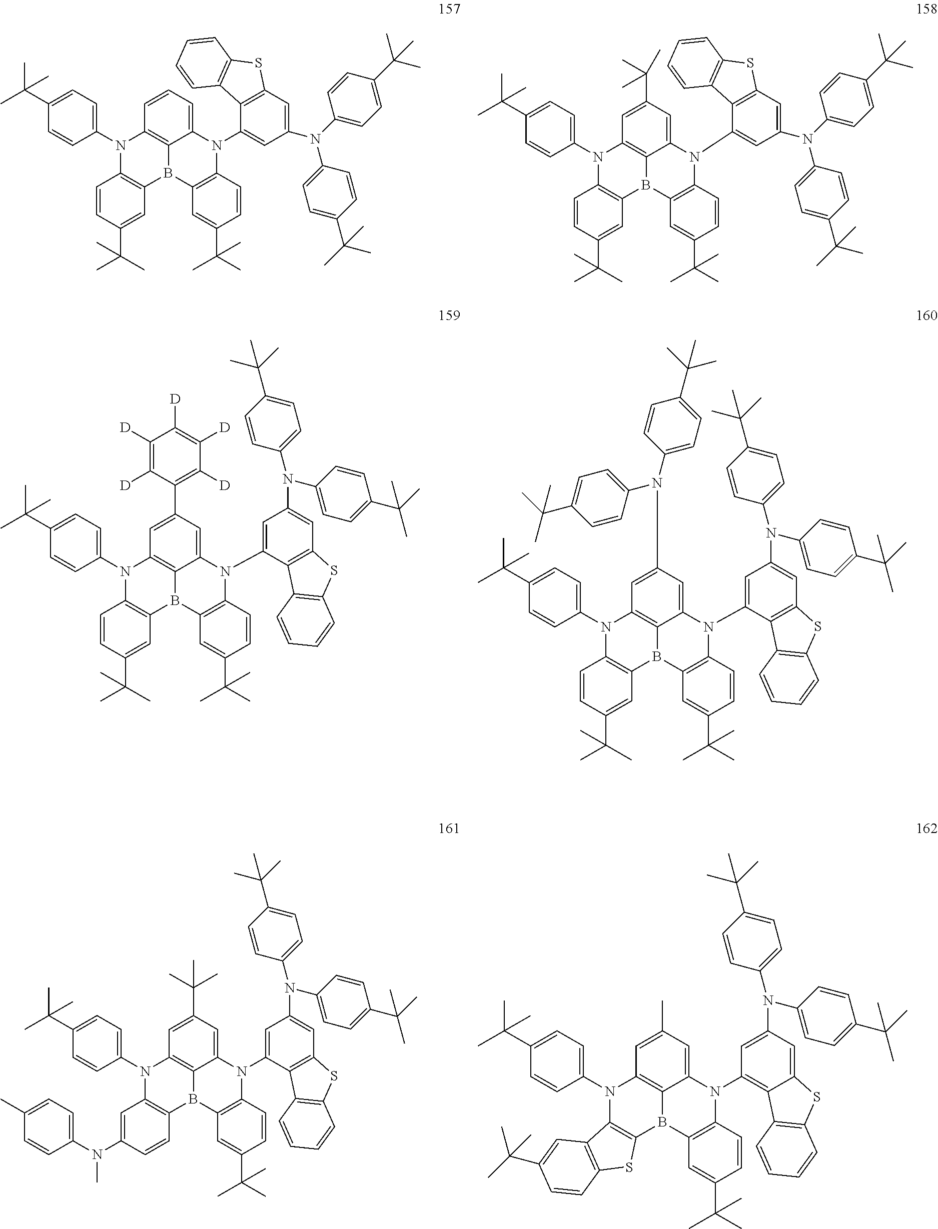

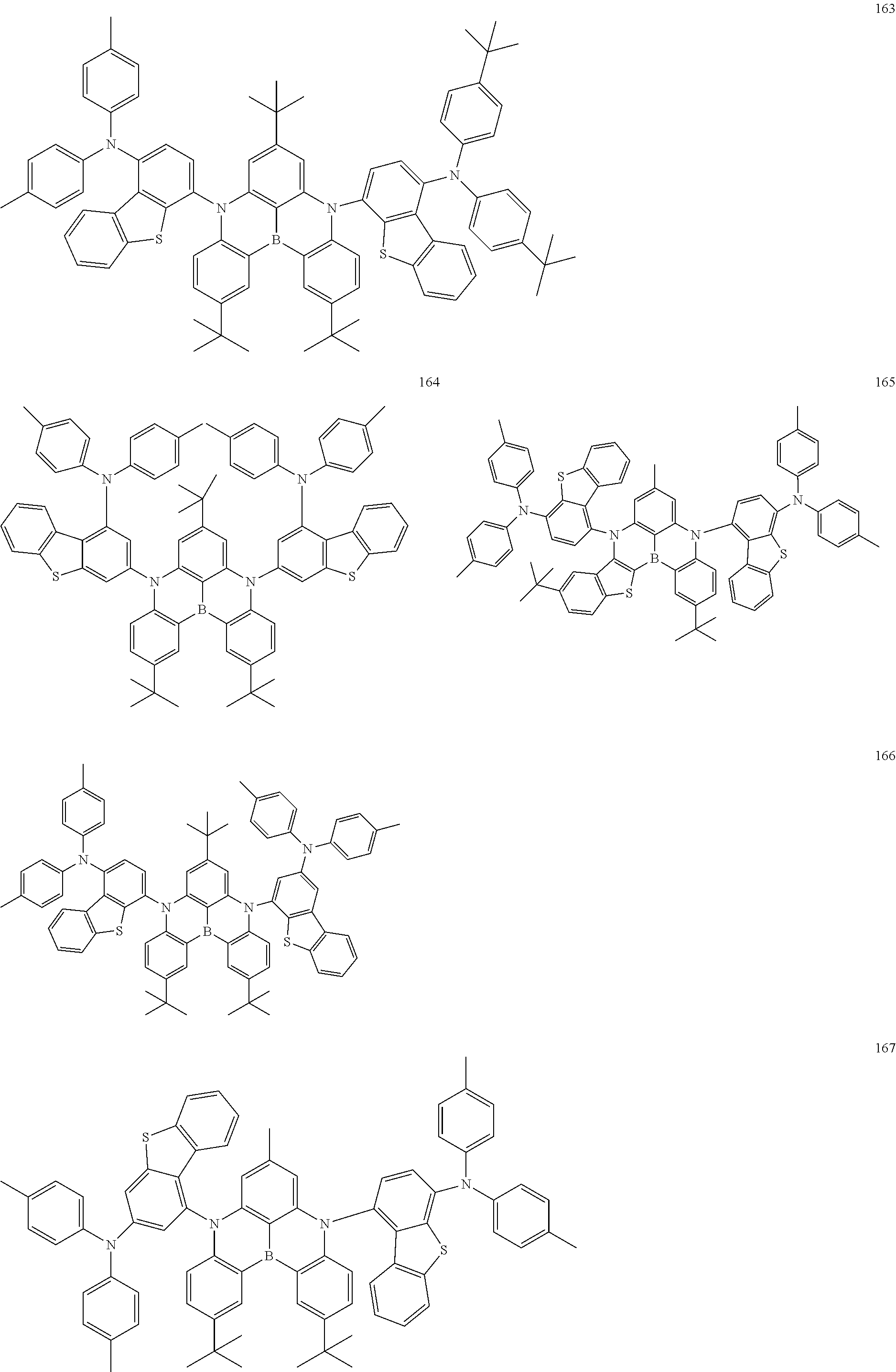

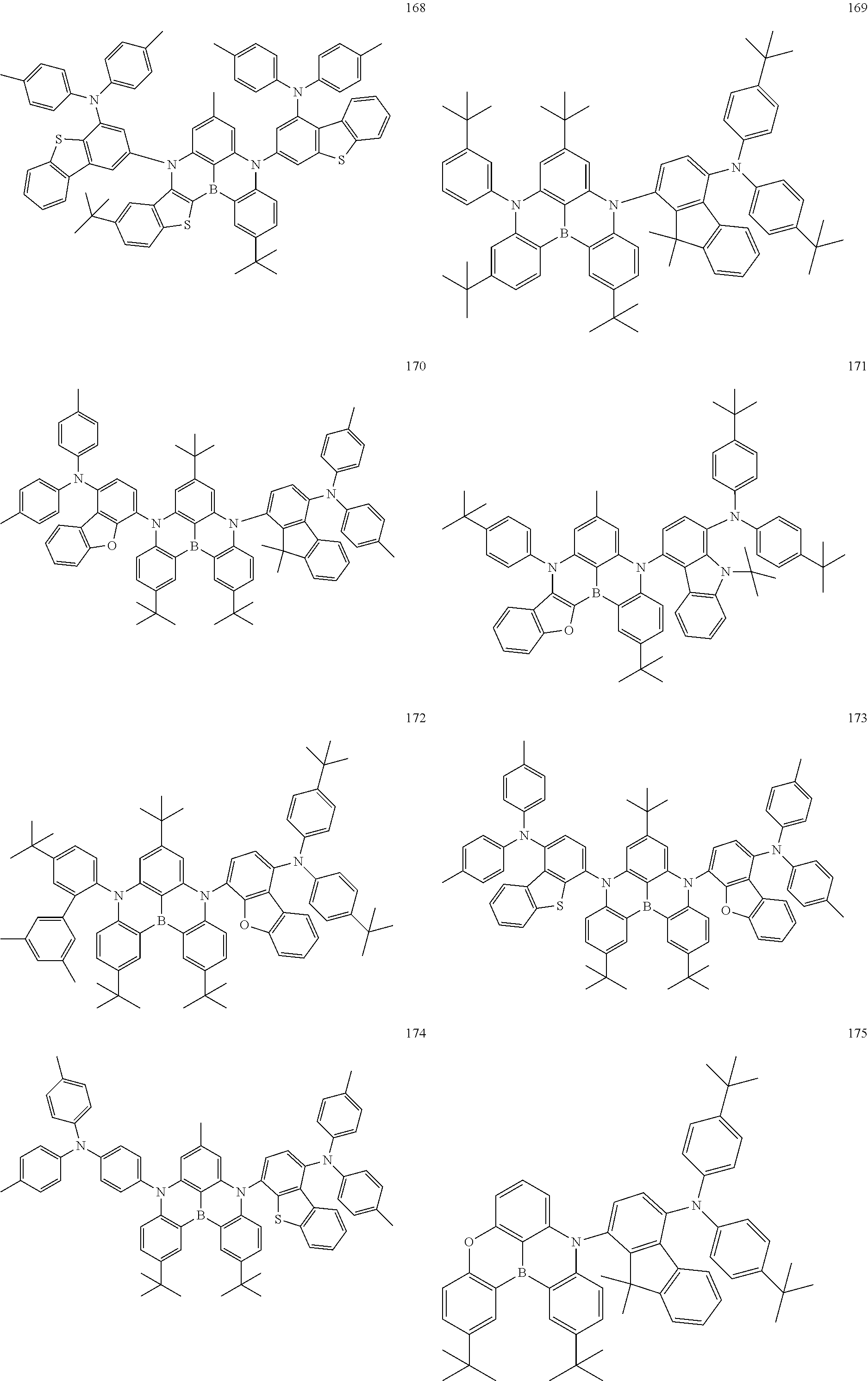

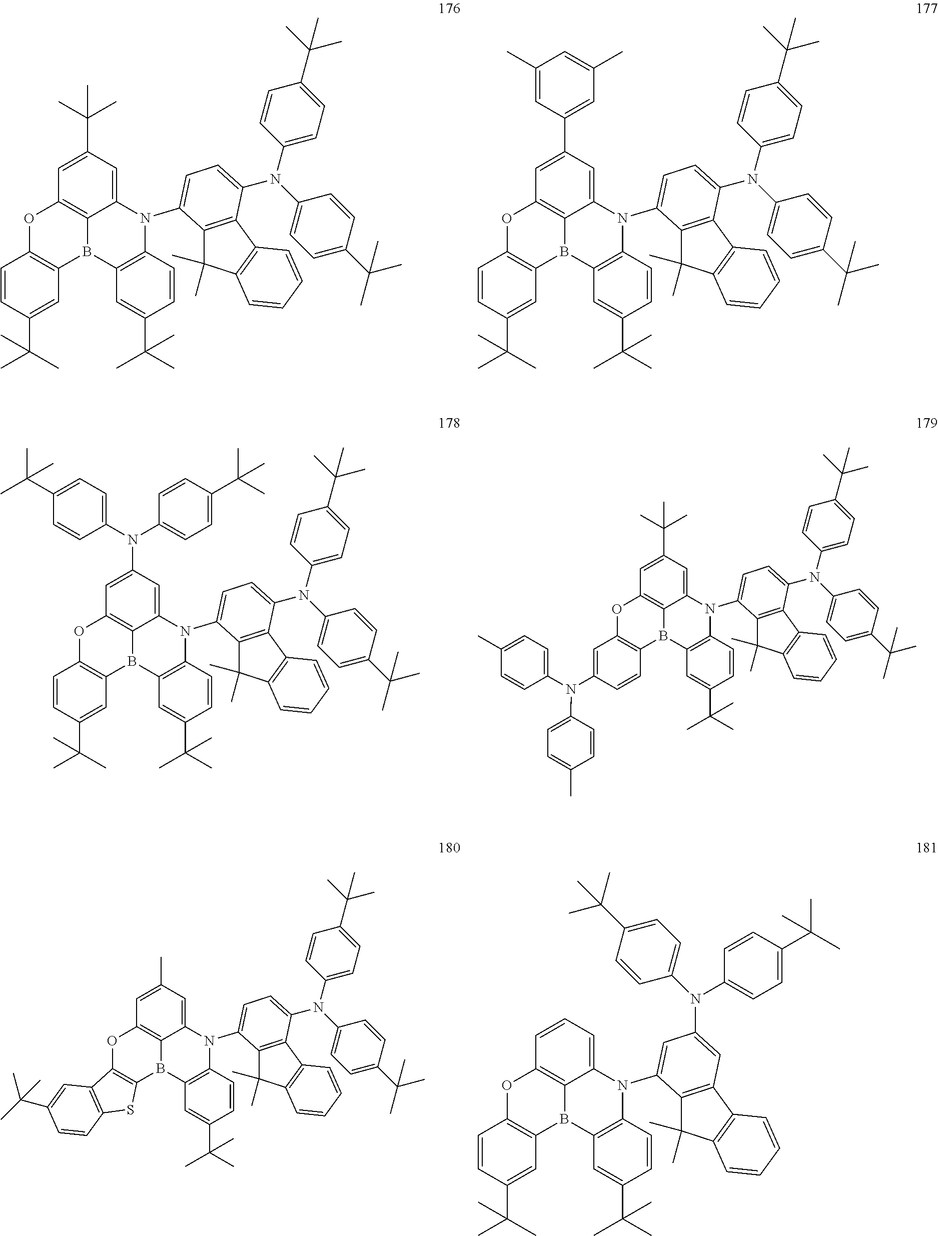

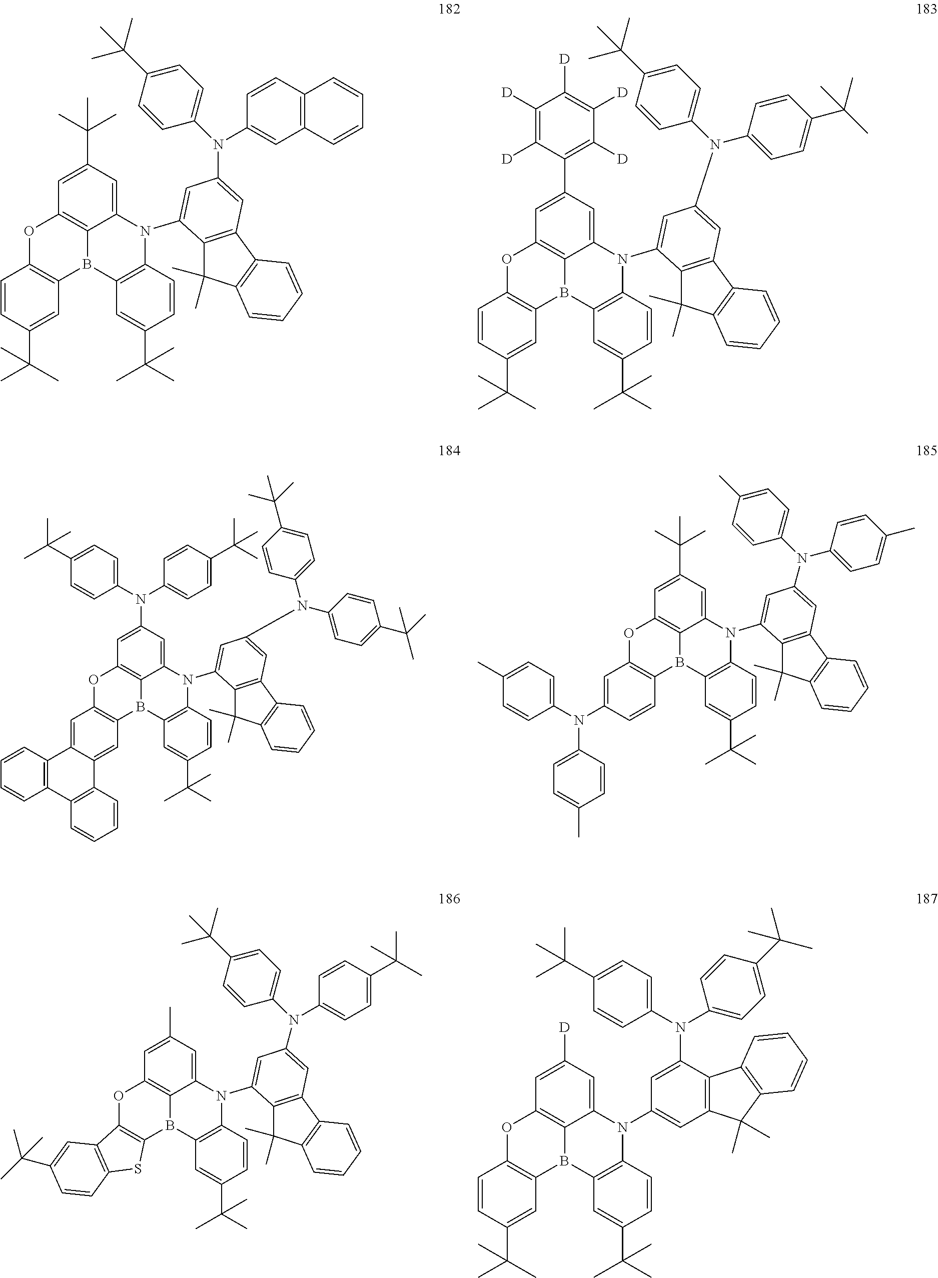

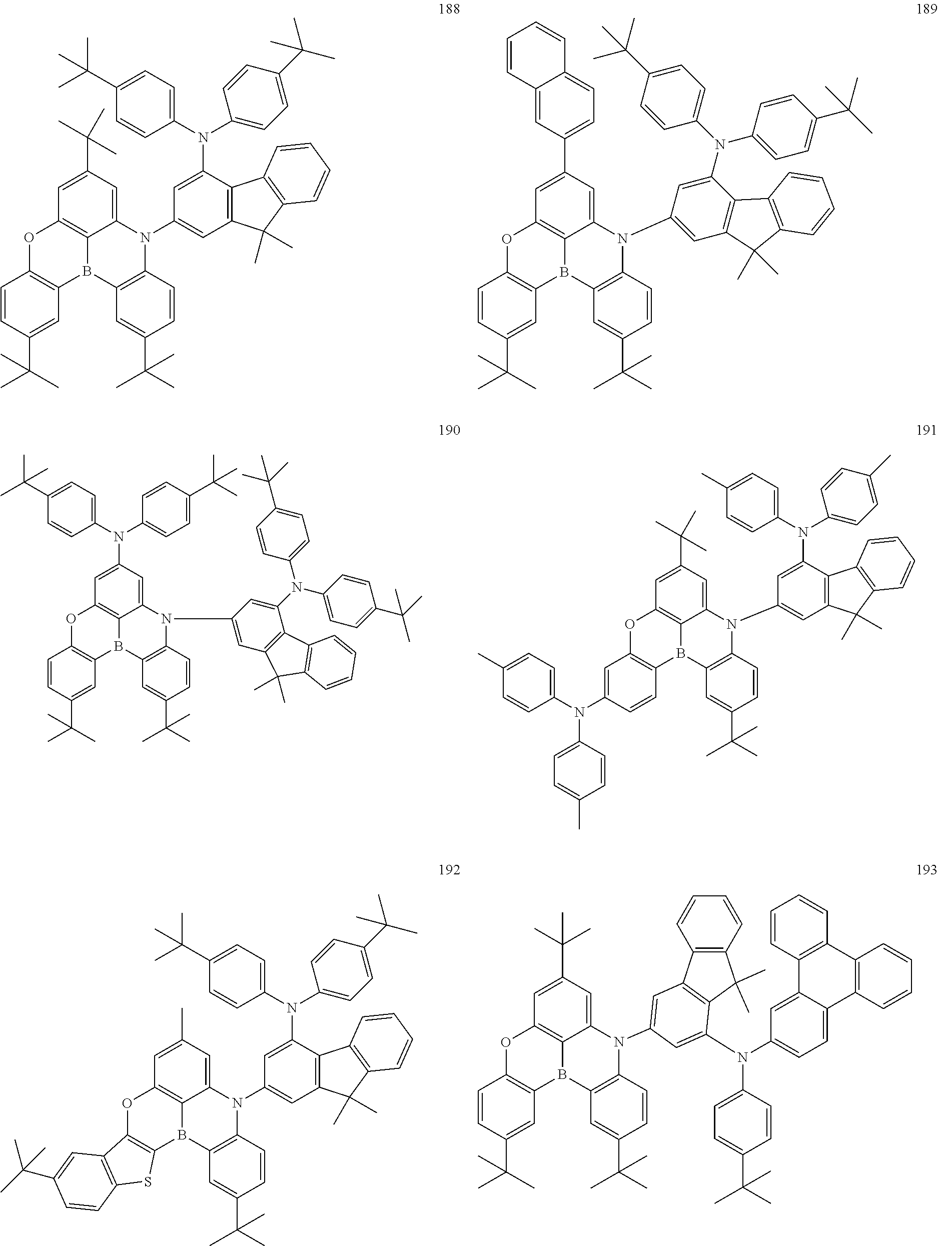

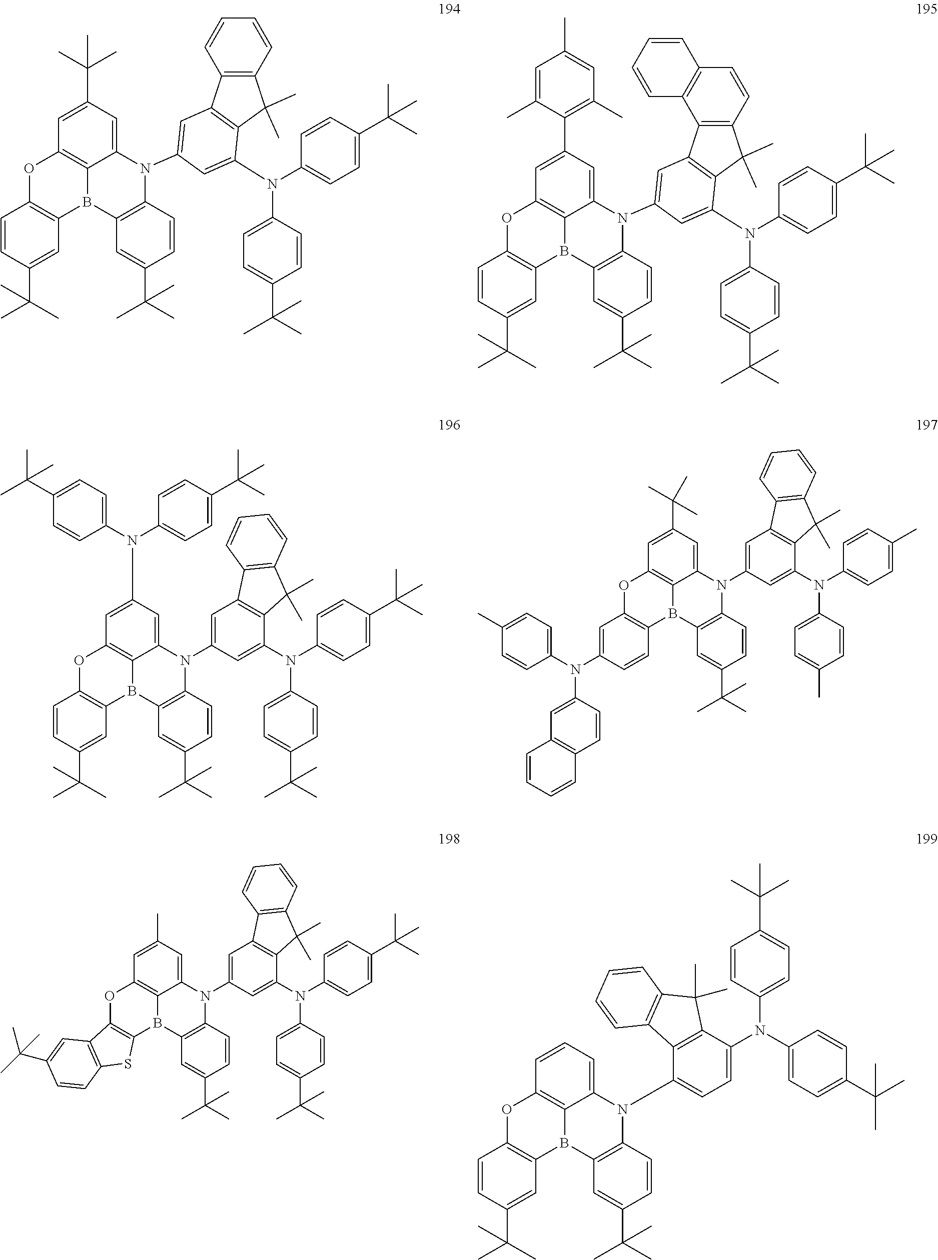

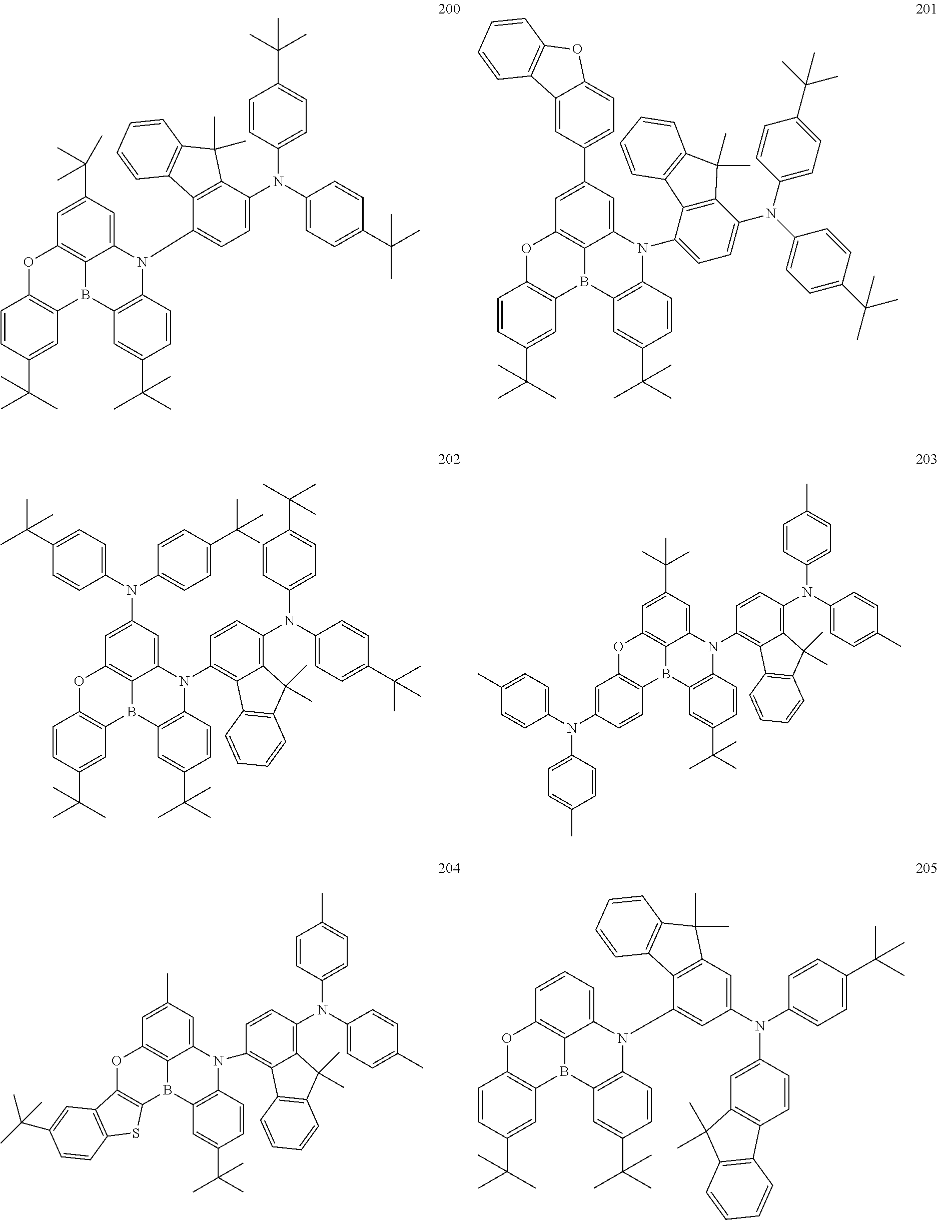

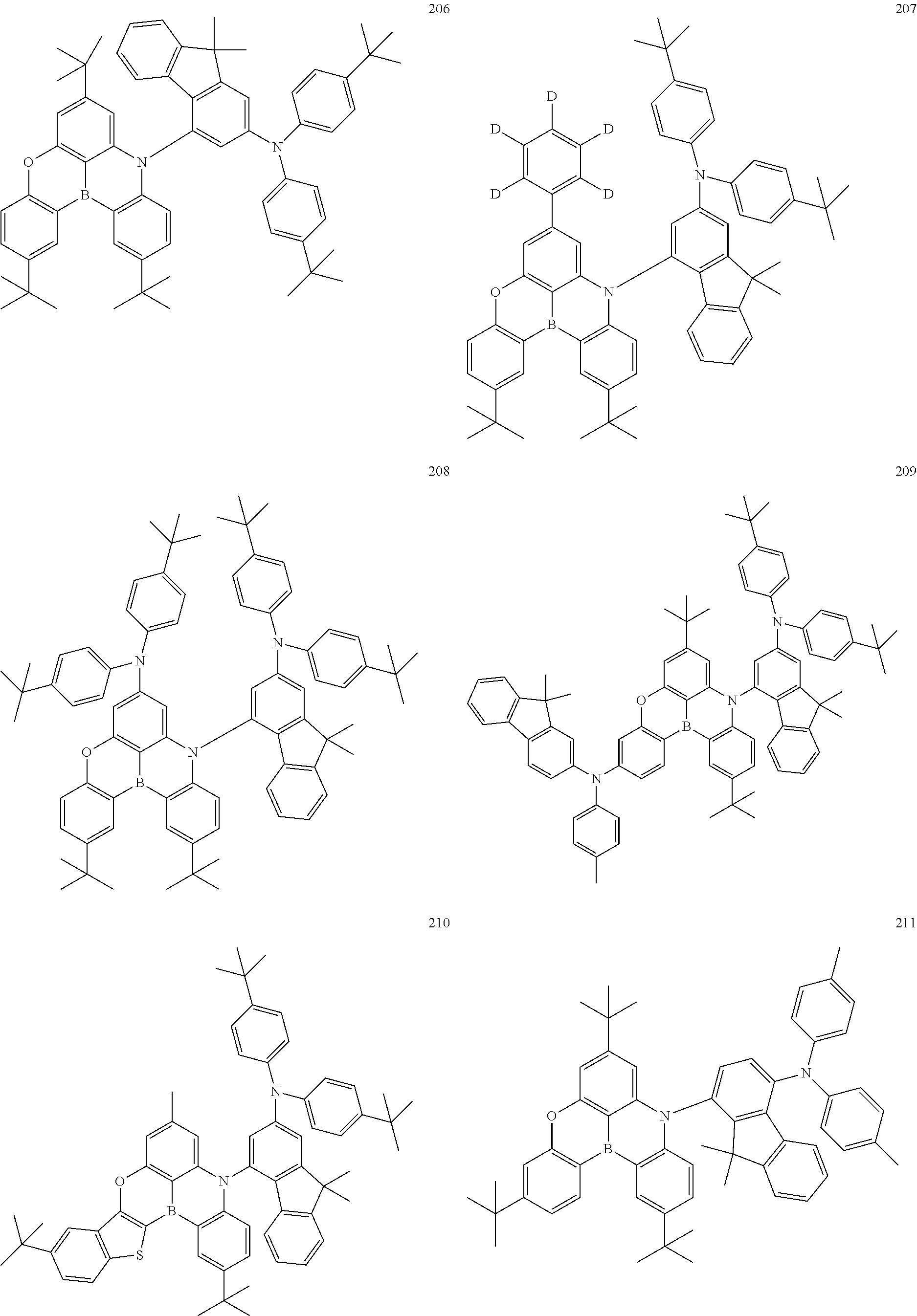

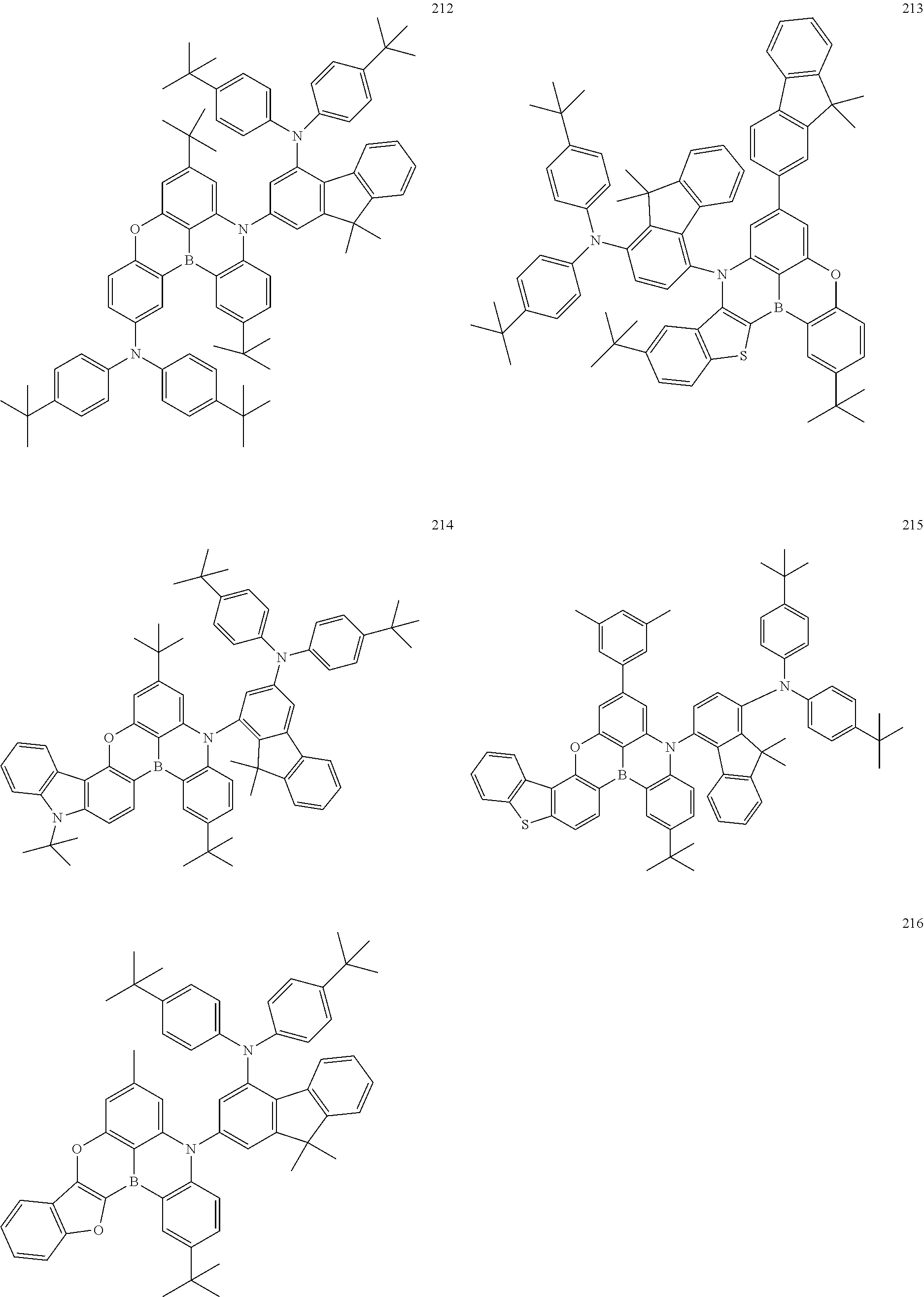

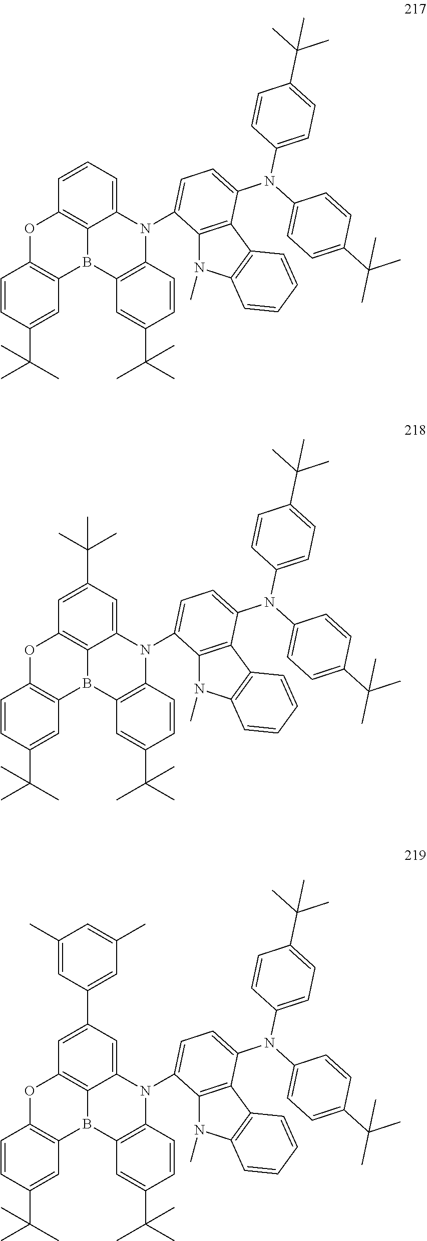 [SMILES: Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cccc3c54)c21 ; Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cc(C(C)(C)C)cc3c54)c21 ; Cc1cc(C)cc(-c2cc3c4c(c2)N(c2ccc(N(c5ccc(C(C)(C)C)cc5)c5ccc(C(C)(C)C)cc5)c5c6ccccc6n(C)c25)c2ccc(C(C)(C)C)cc2B4c2cc(C(C)(C)C)ccc2O3)c1]

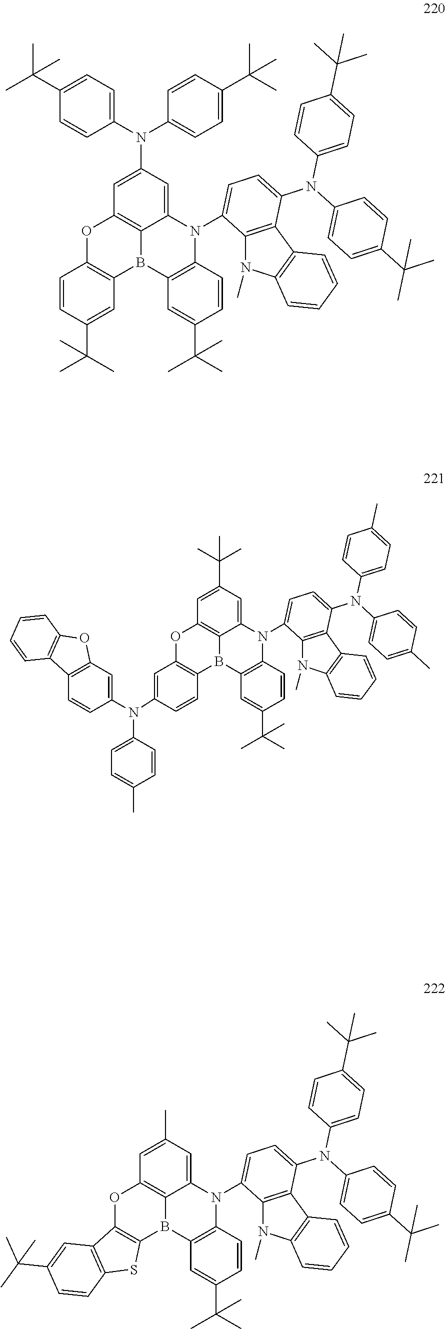

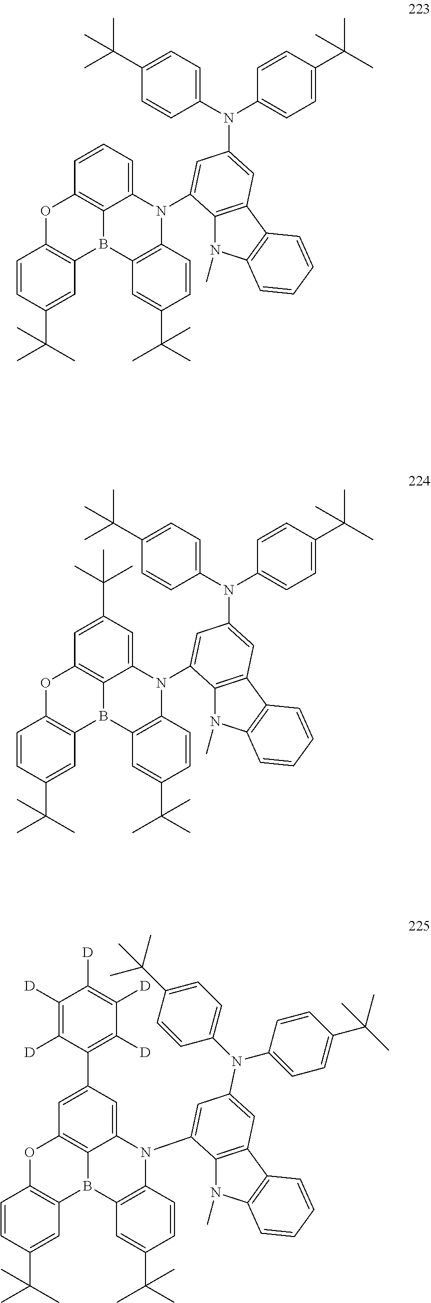 [SMILES: Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cccc3c54)c21 ; Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)c21 ; [2H]c1c([2H])c([2H])c(-c2cc3c4c(c2)N(c2cc(N(c5ccc(C(C)(C)C)cc5)c5ccc(C(C)(C)C)cc5)cc5c6ccccc6n(C)c25)c2ccc(C(C)(C)C)cc2B4c2cc(C(C)(C)C)ccc2O3)c([2H])c1[2H]]

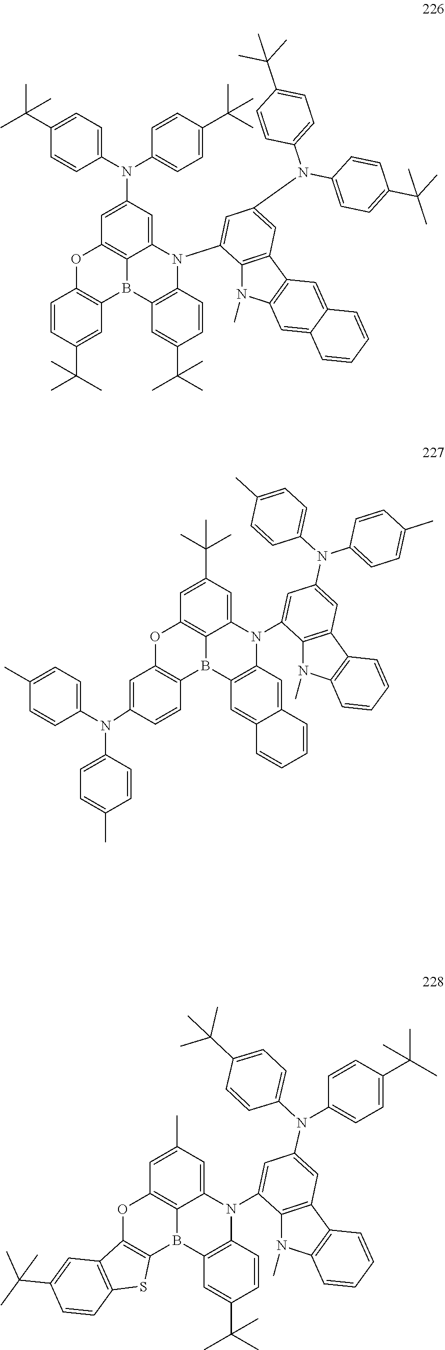

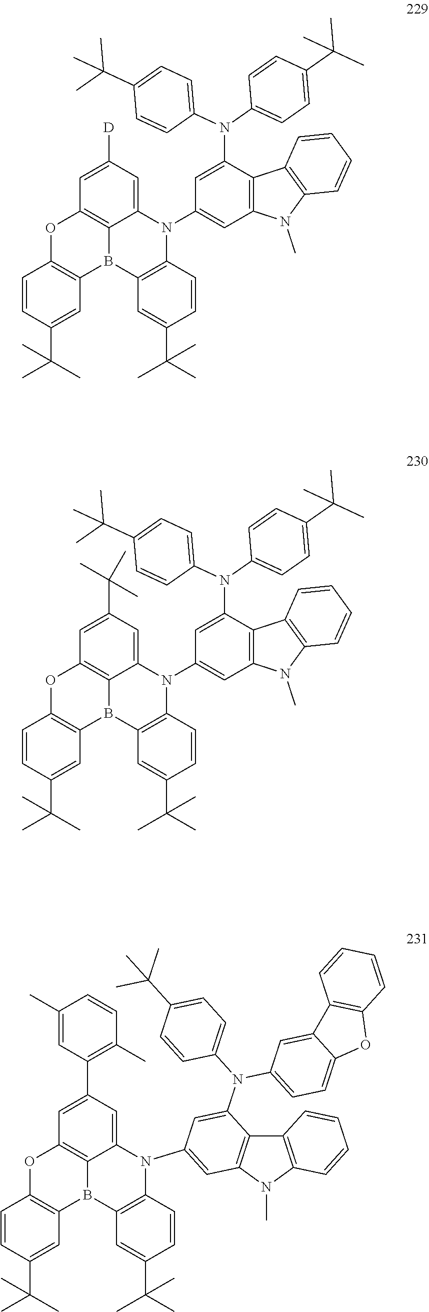 [SMILES: [2H]c1cc2c3c(c1)N(c1cc(N(c4ccc(C(C)(C)C)cc4)c4ccc(C(C)(C)C)cc4)c4c5ccccc5n(C)c4c1)c1ccc(C(C)(C)C)cc1B3c1cc(C(C)(C)C)ccc1O2 ; Cn1c2ccccc2c2c(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)cc21 ; Cc1ccc(C)c(-c2cc3c4c(c2)N(c2cc(N(c5ccc(C(C)(C)C)cc5)c5ccc6oc7ccccc7c6c5)c5c6ccccc6n(C)c5c2)c2ccc(C(C)(C)C)cc2B4c2cc(C(C)(C)C)ccc2O3)c1]

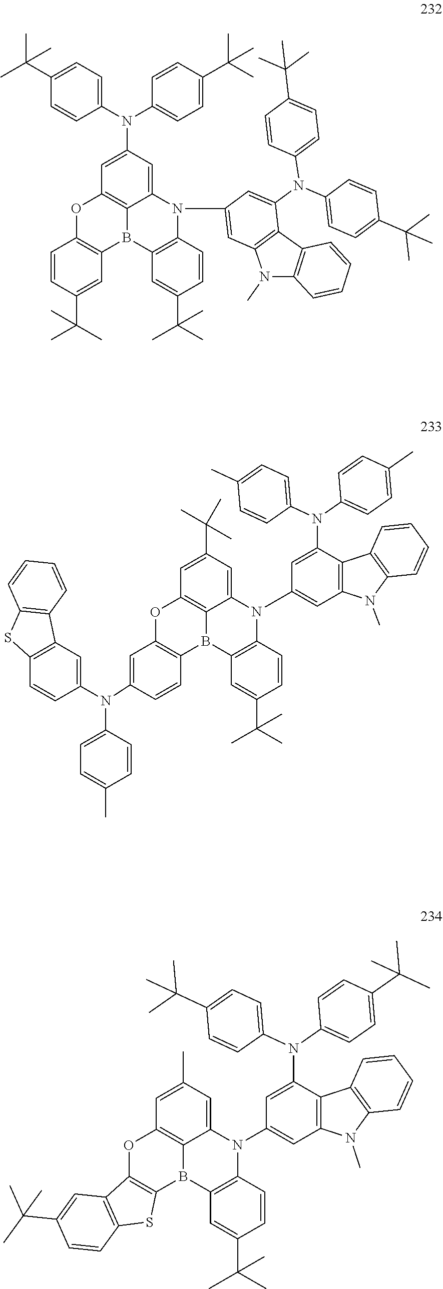

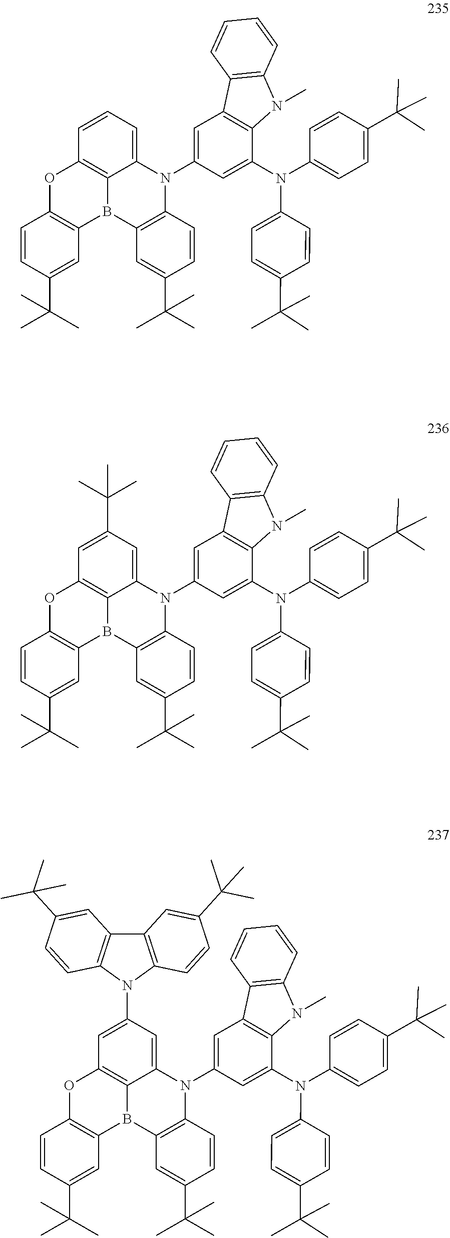

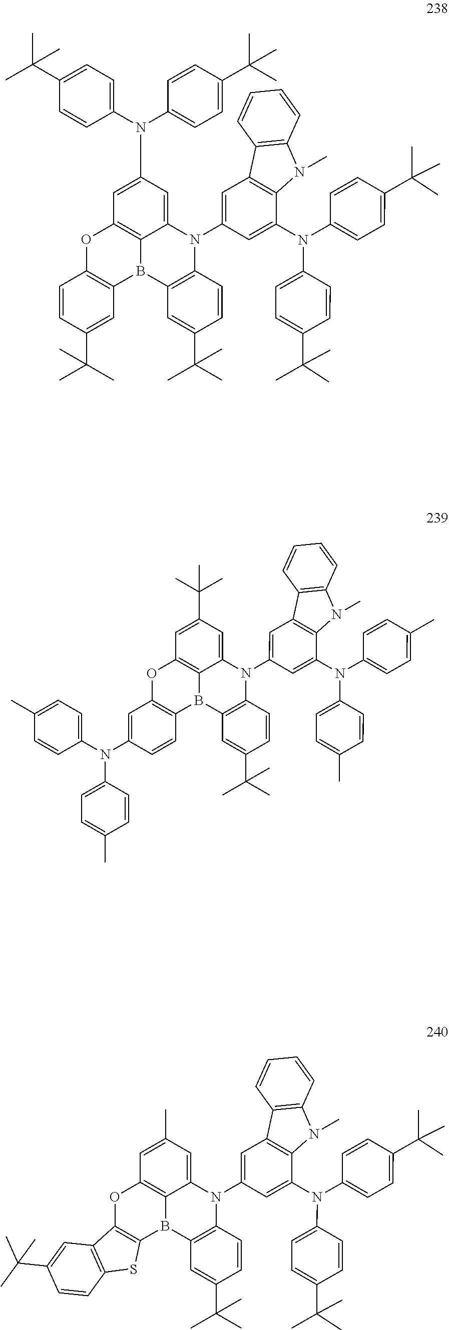

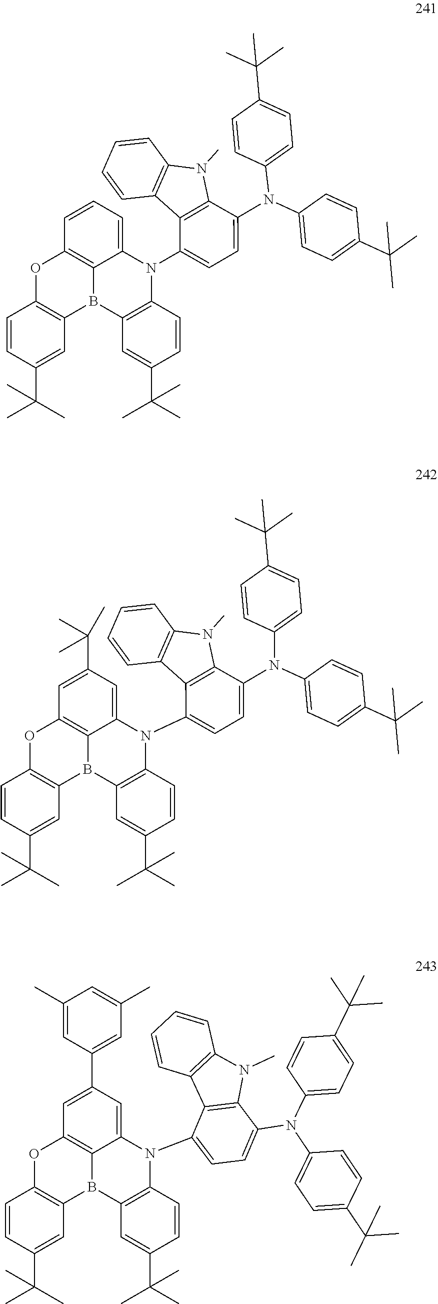 [SMILES: Cn1c2ccccc2c2c(N3c4ccc(C(C)(C)C)cc4B4c5cc(C(C)(C)C)ccc5Oc5cccc3c54)ccc(N(c3ccc(C(C)(C)C)cc3)c3ccc(C(C)(C)C)cc3)c21 ; Cn1c2ccccc2c2c(N3c4ccc(C(C)(C)C)cc4B4c5cc(C(C)(C)C)ccc5Oc5cc(C(C)(C)C)cc3c54)ccc(N(c3ccc(C(C)(C)C)cc3)c3ccc(C(C)(C)C)cc3)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2cc(C(C)(C)C)ccc2O3)c1]

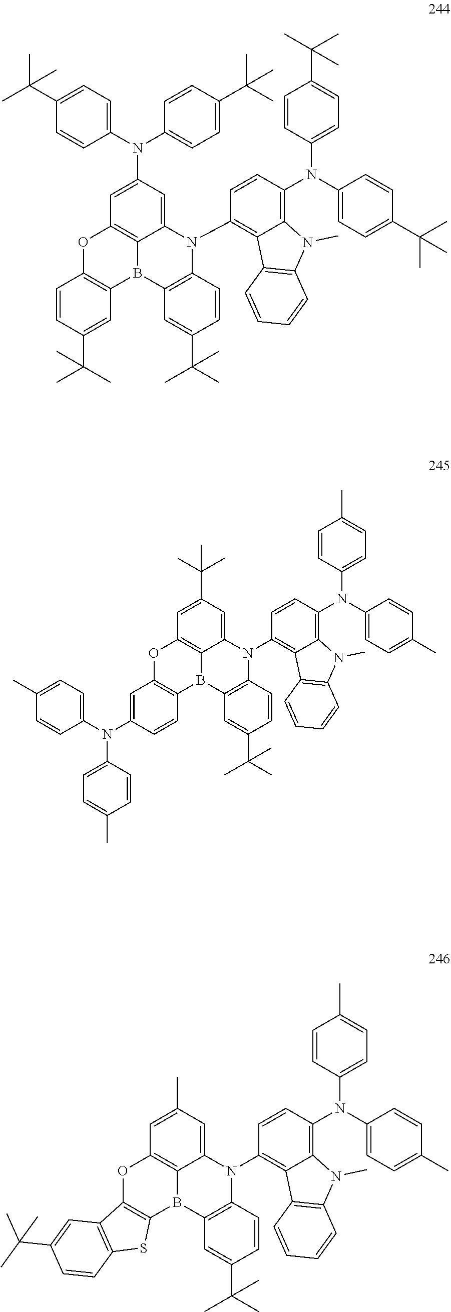

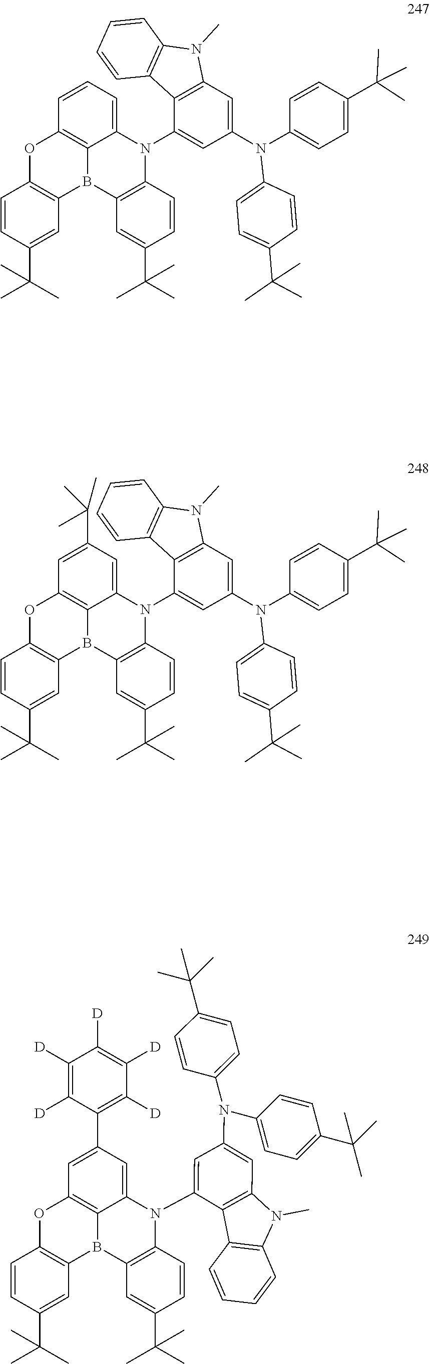 [SMILES: Cn1c2ccccc2c2c(N3c4ccc(C(C)(C)C)cc4B4c5cc(C(C)(C)C)ccc5Oc5cccc3c54)cc(N(c3ccc(C(C)(C)C)cc3)c3ccc(C(C)(C)C)cc3)cc21 ; Cn1c2ccccc2c2c(N3c4ccc(C(C)(C)C)cc4B4c5cc(C(C)(C)C)ccc5Oc5cc(C(C)(C)C)cc3c54)cc(N(c3ccc(C(C)(C)C)cc3)c3ccc(C(C)(C)C)cc3)cc21 ; [2H]c1c([2H])c([2H])c(-c2cc3c4c(c2)N(c2cc(N(c5ccc(C(C)(C)C)cc5)c5ccc(C(C)(C)C)cc5)cc5c2c2ccccc2n5C)c2ccc(C(C)(C)C)cc2B4c2cc(C(C)(C)C)ccc2O3)c([2H])c1[2H]]

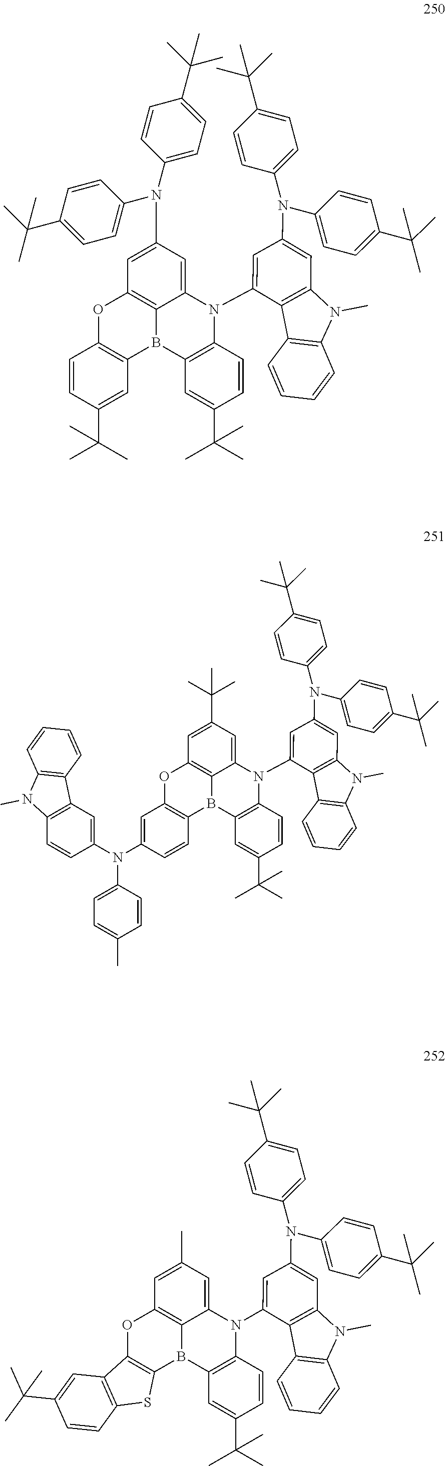

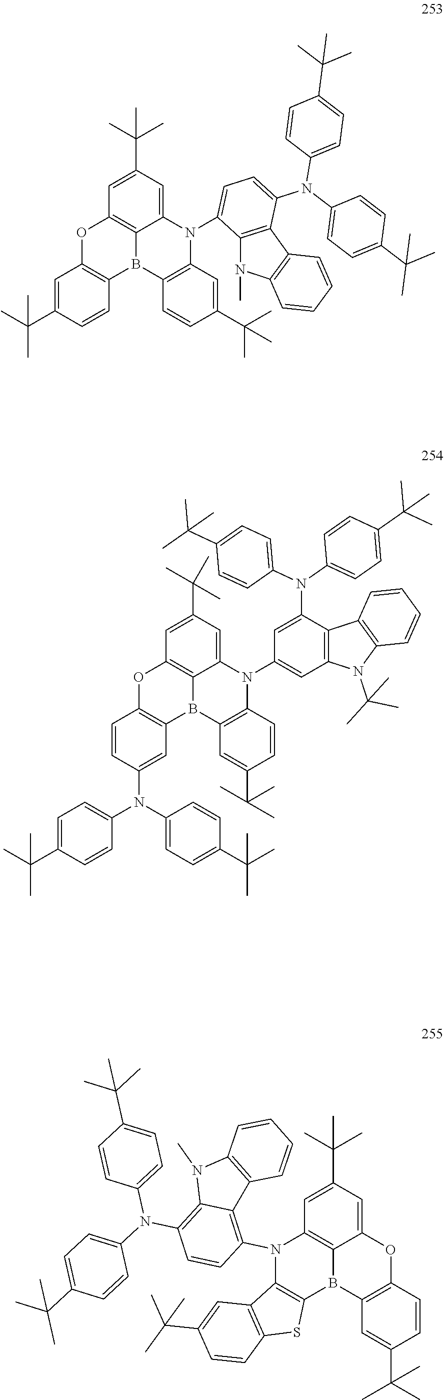

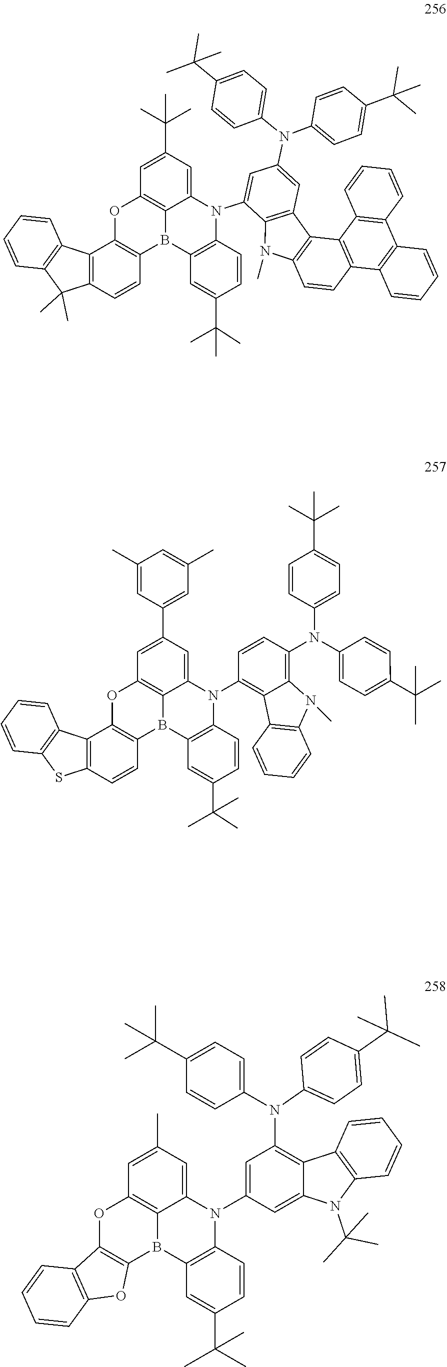 [SMILES: Cn1c2ccc3c4ccccc4c4ccccc4c3c2c2cc(N(c3ccc(C(C)(C)C)cc3)c3ccc(C(C)(C)C)cc3)cc(N3c4ccc(C(C)(C)C)cc4B4c5ccc6c(c5Oc5cc(C(C)(C)C)cc3c54)-c3ccccc3C6(C)C)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c5ccccc5n(C(C)(C)C)c4c1)c1ccc(C(C)(C)C)cc1B3c1oc3ccccc3c1O2]

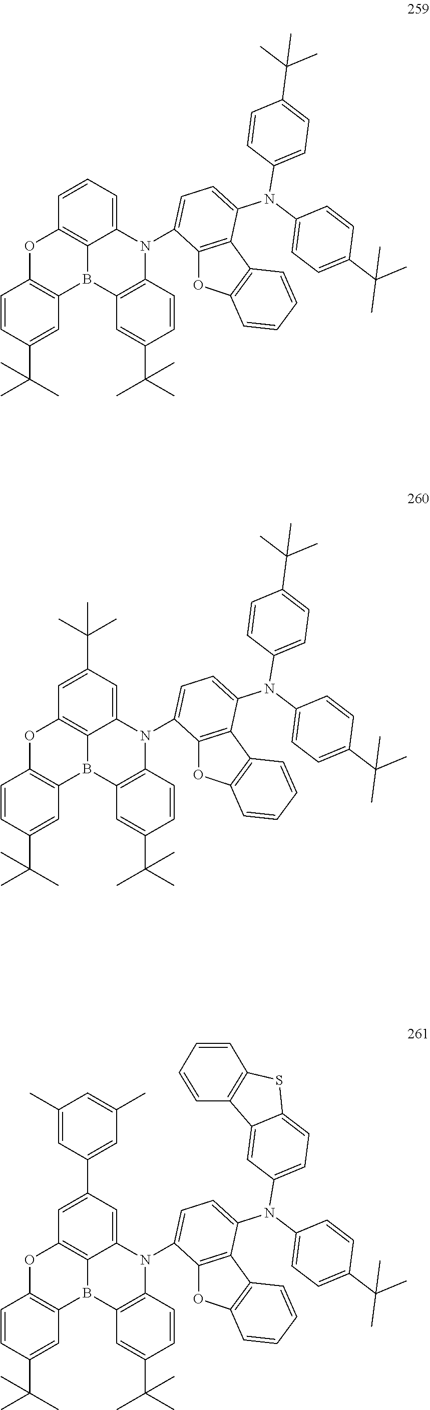 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3oc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3oc4ccccc4c23)cc1 ; Cc1cc(C)cc(-c2cc3c4c(c2)N(c2ccc(N(c5ccc(C(C)(C)C)cc5)c5ccc6sc7ccccc7c6c5)c5c2oc2ccccc25)c2ccc(C(C)(C)C)cc2B4c2cc(C(C)(C)C)ccc2O3)c1]

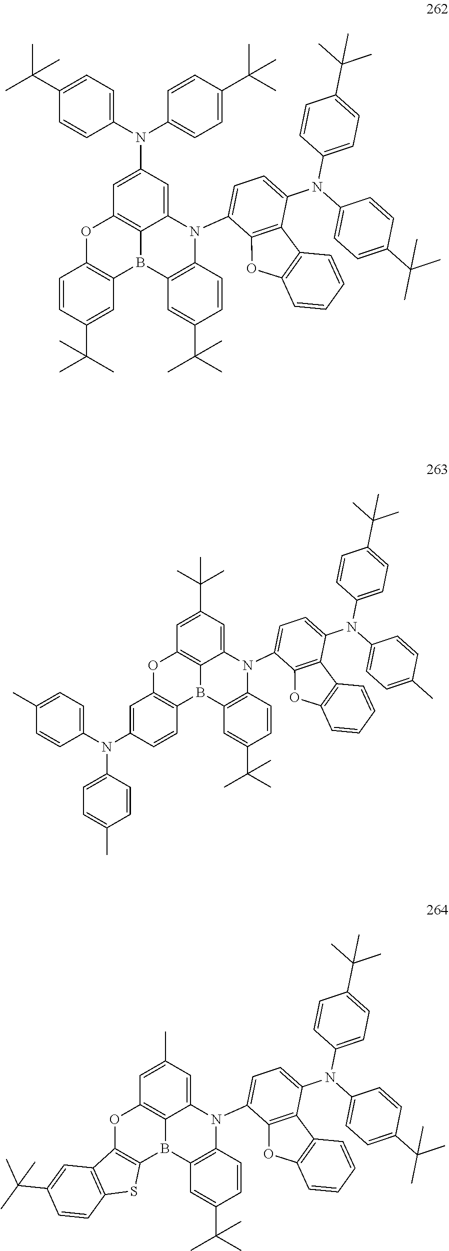

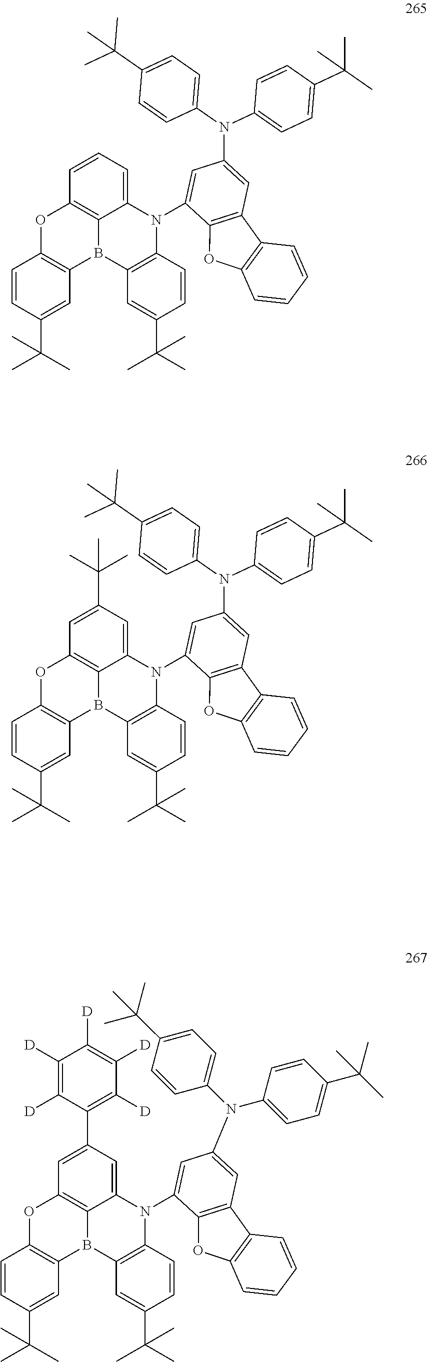 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3oc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3oc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2oc2ccccc25)c2ccc(C(C)(C)C)cc2B4c2cc(C(C)(C)C)ccc2O3)c([2H])c1[2H]]

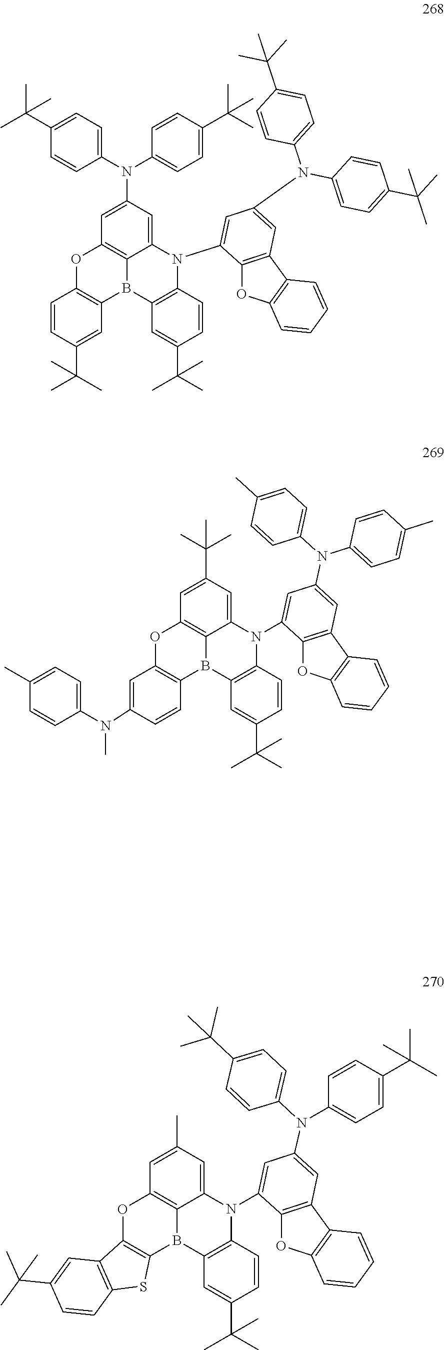

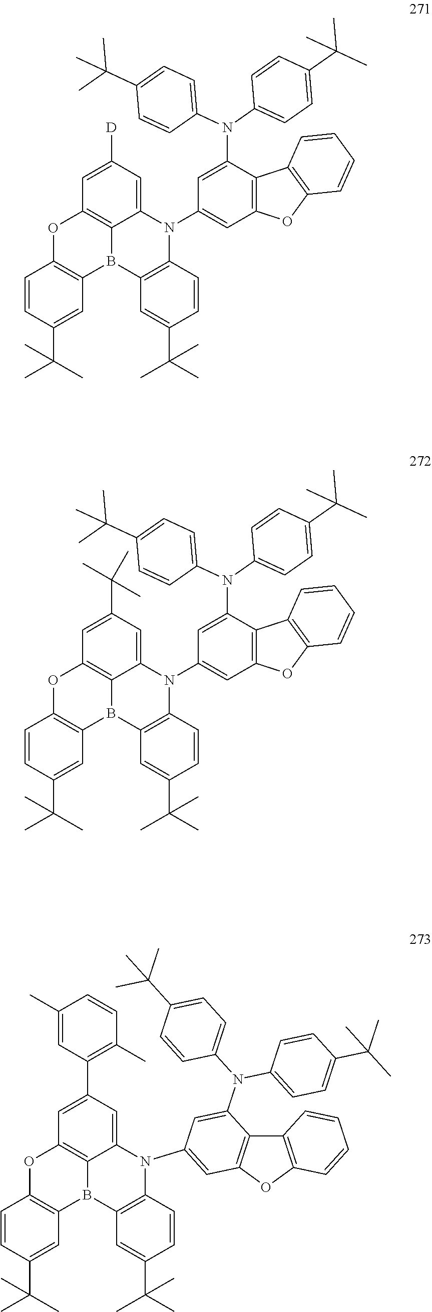 [SMILES: [2H]c1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3oc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)oc2ccccc25)c2ccc(C(C)(C)C)cc2B4c2cc(C(C)(C)C)ccc2O3)c1]

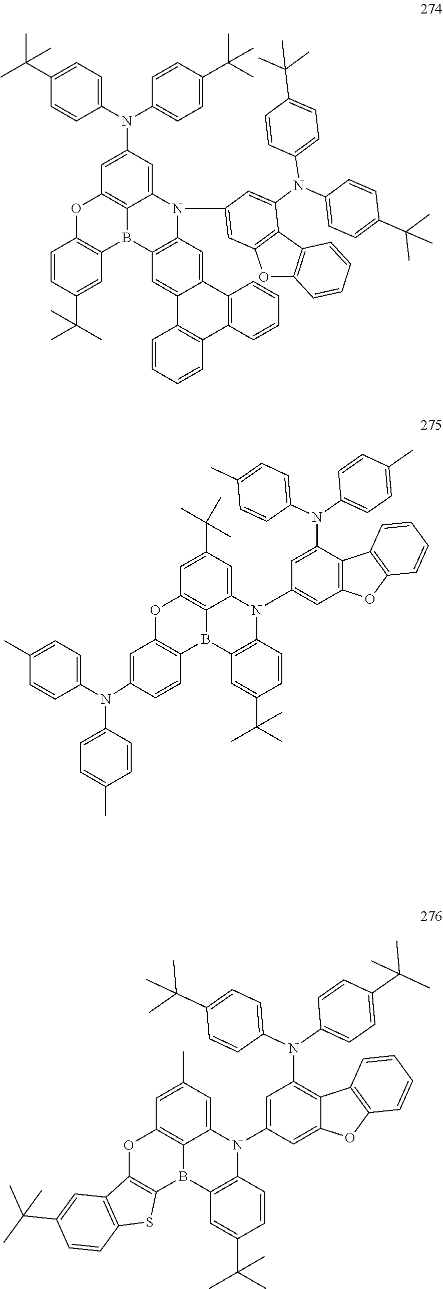

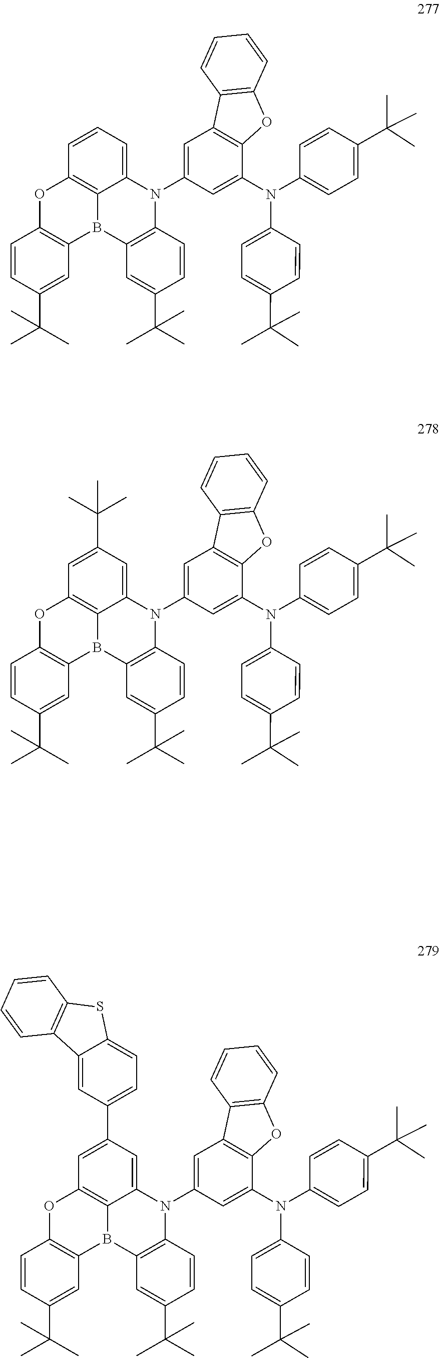 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(-c6ccc7sc8ccccc8c7c6)cc3c54)cc3c2oc2ccccc23)cc1]

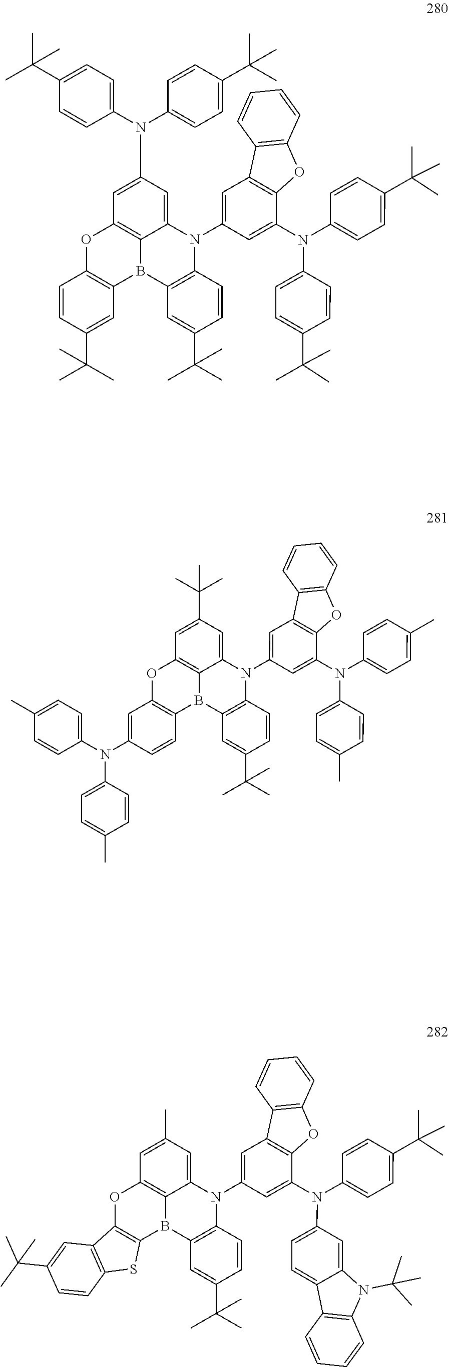

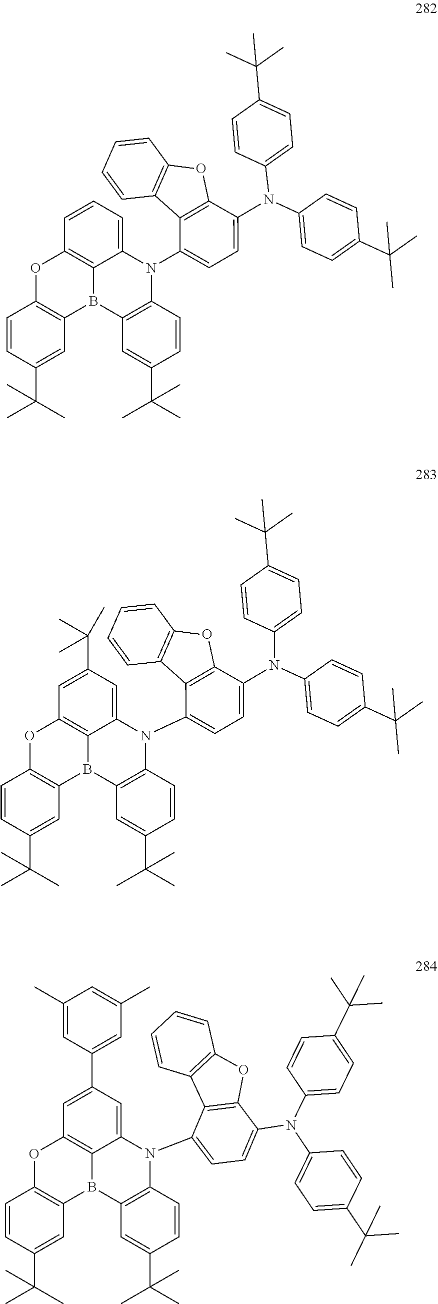 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2oc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2oc2ccccc23)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2cc(C(C)(C)C)ccc2O3)c1]

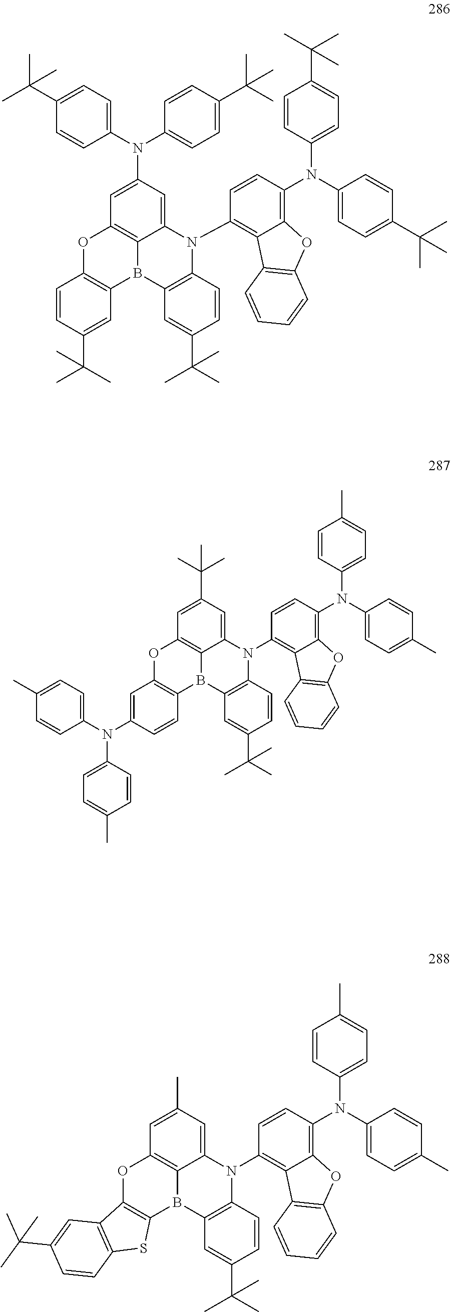

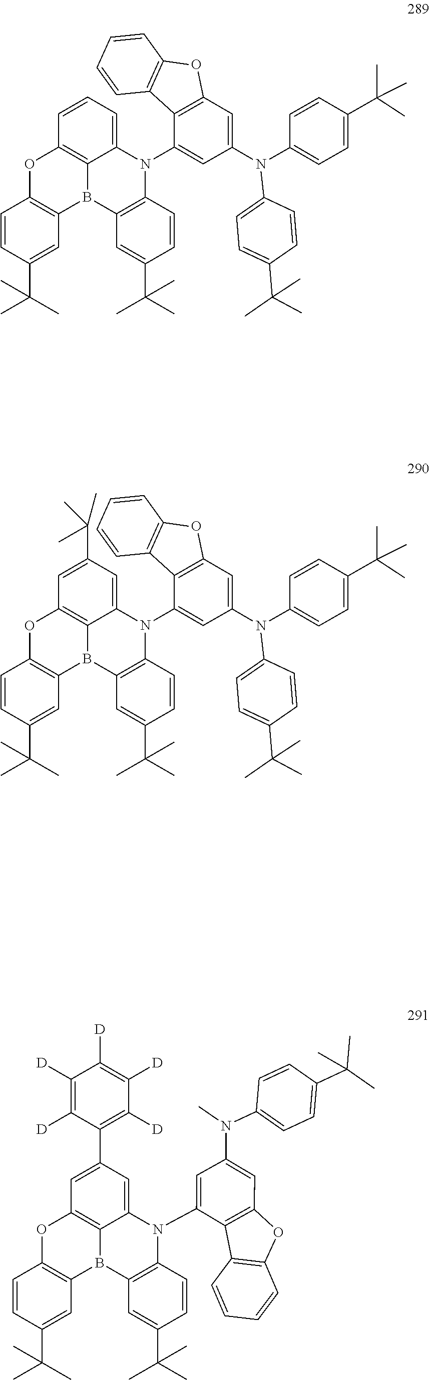 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)oc2ccccc23)cc1 ; [2H]c1c([2H])c([2H])c(-c2cc3c4c(c2)N(c2cc(N(C)c5ccc(C(C)(C)C)cc5)cc5oc6ccccc6c25)c2ccc(C(C)(C)C)cc2B4c2cc(C(C)(C)C)ccc2O3)c([2H])c1[2H]]

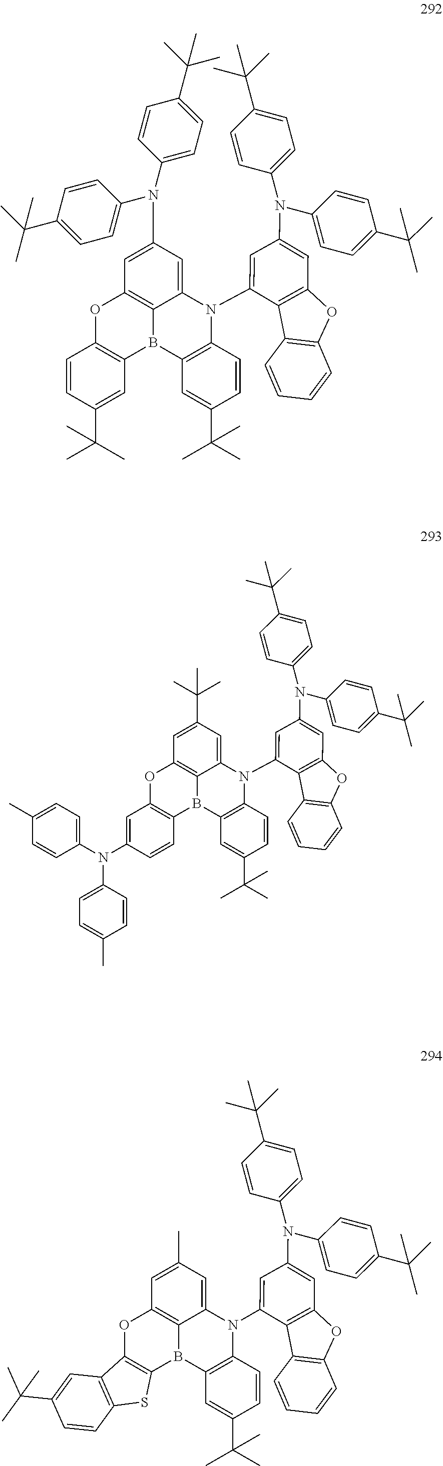

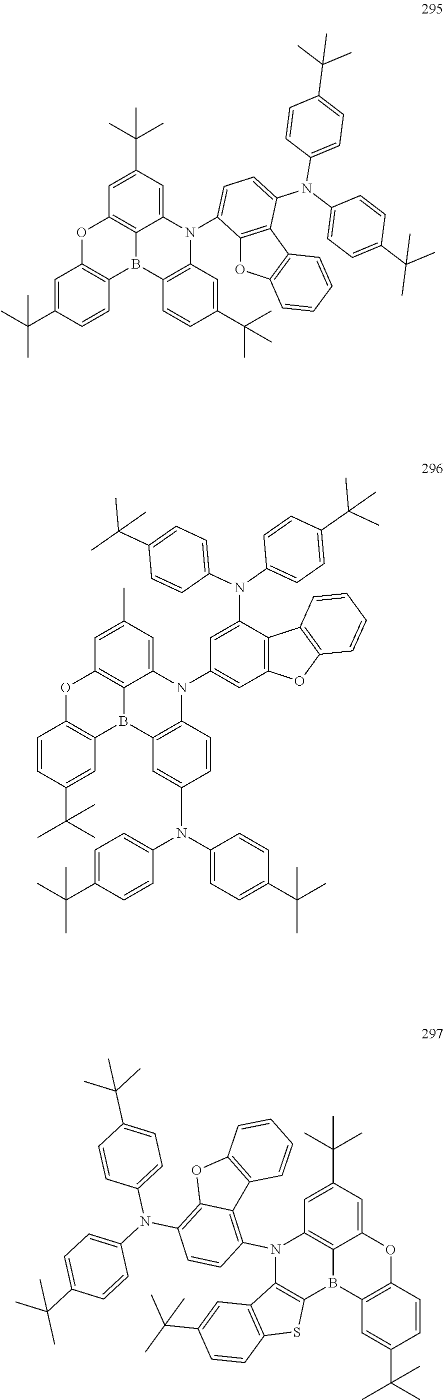

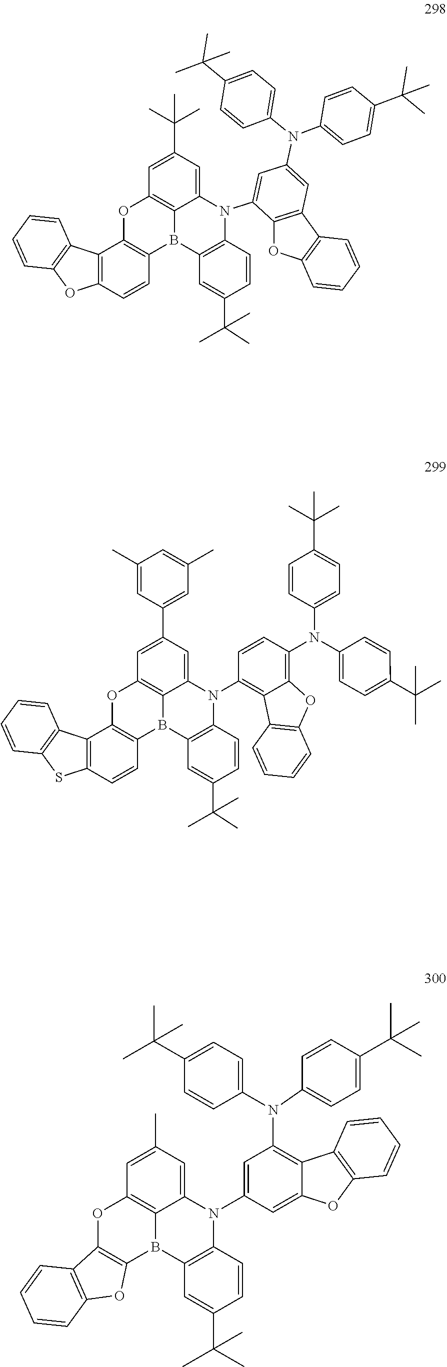 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3oc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1oc3ccccc3c1O2]

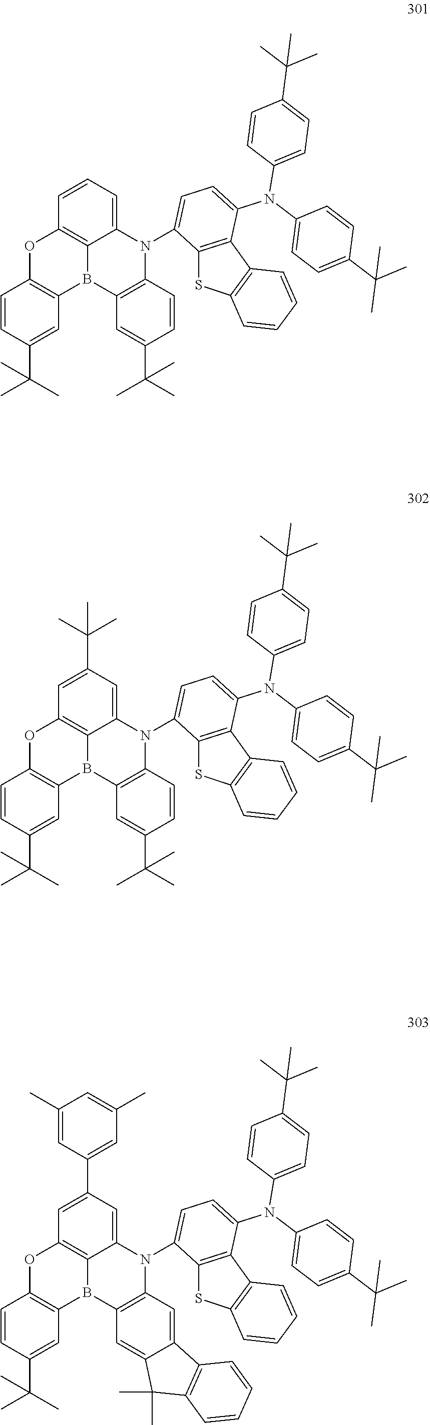 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3sc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3sc4ccccc4c23)cc1 ; Cc1cc(C)cc(-c2cc3c4c(c2)N(c2ccc(N(c5ccc(C(C)(C)C)cc5)c5ccc(C(C)(C)C)cc5)c5c2sc2ccccc25)c2cc5c(cc2B4c2cc(C(C)(C)C)ccc2O3)C(C)(C)c2ccccc2-5)c1]

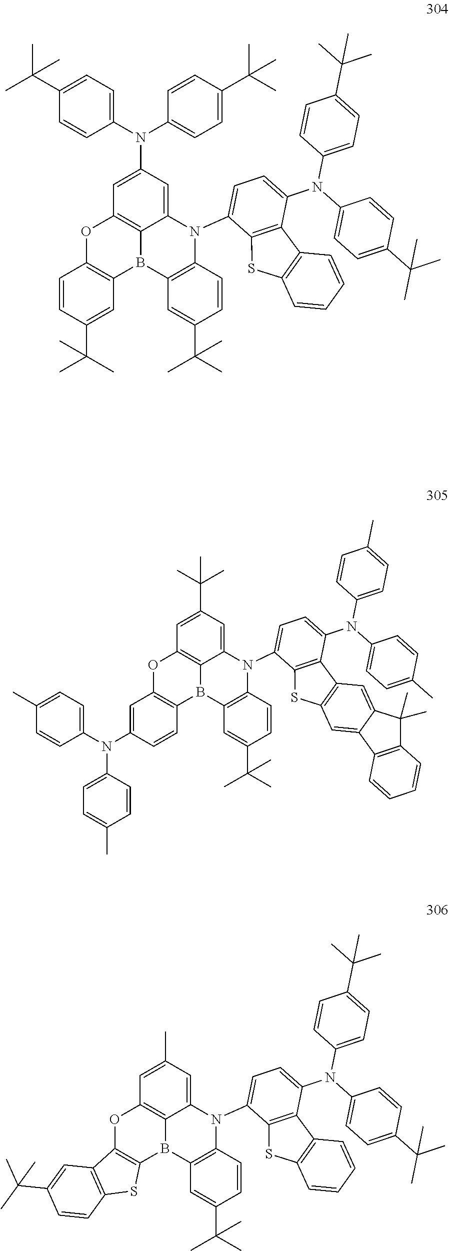

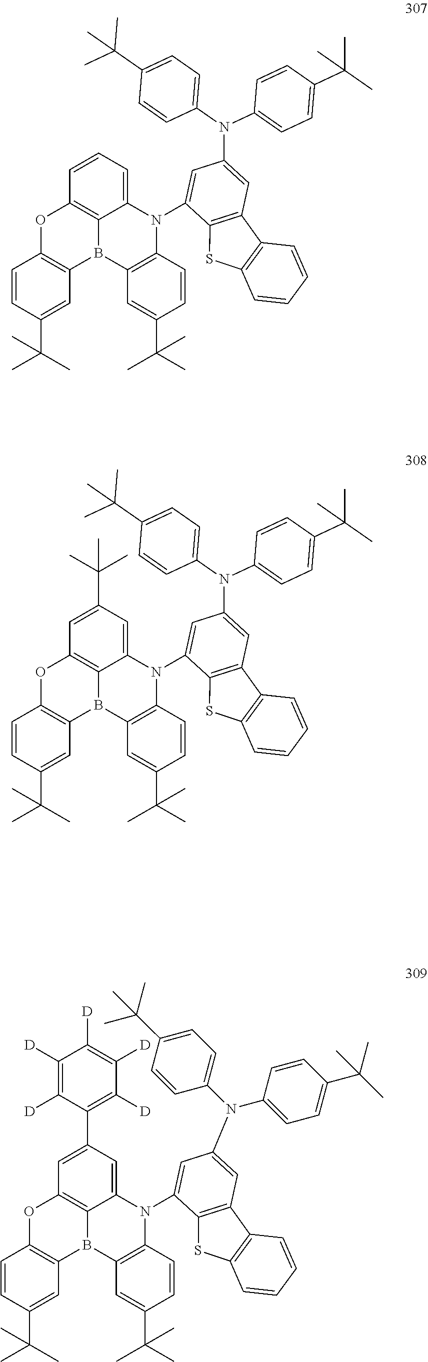 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3sc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3sc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2sc2ccccc25)c2ccc(C(C)(C)C)cc2B4c2cc(C(C)(C)C)ccc2O3)c([2H])c1[2H]]

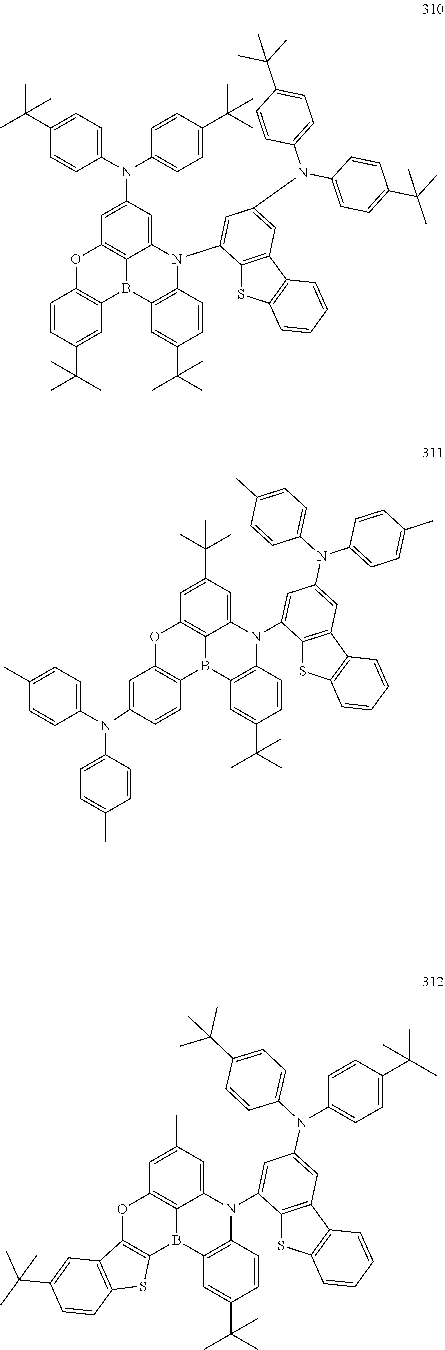

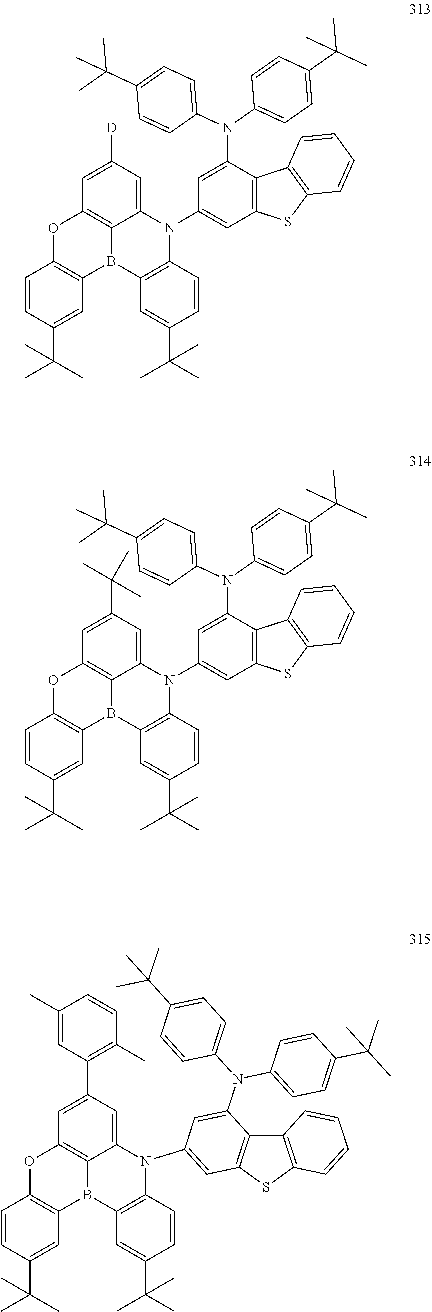 [SMILES: [2H]c1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3sc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)sc2ccccc25)c2ccc(C(C)(C)C)cc2B4c2cc(C(C)(C)C)ccc2O3)c1]

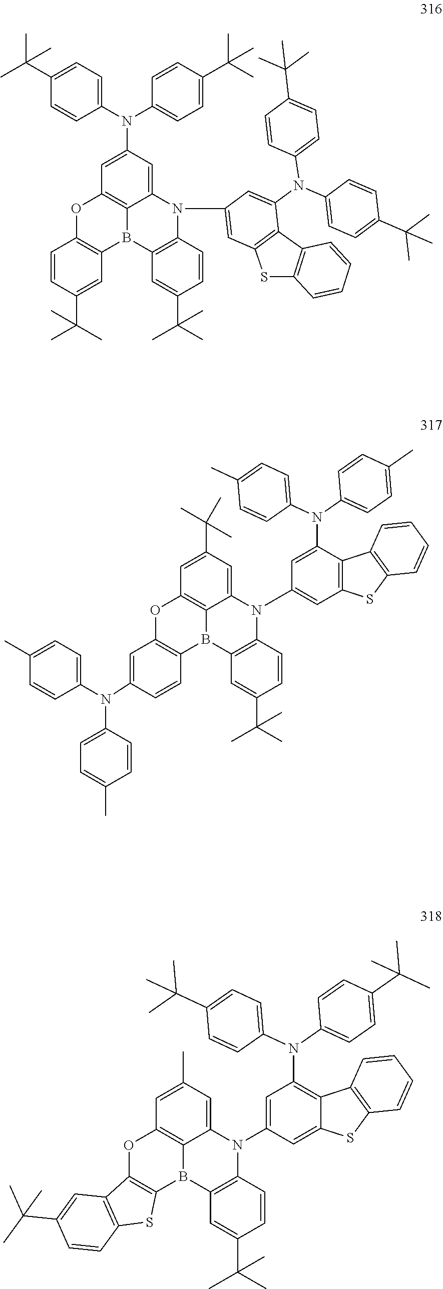

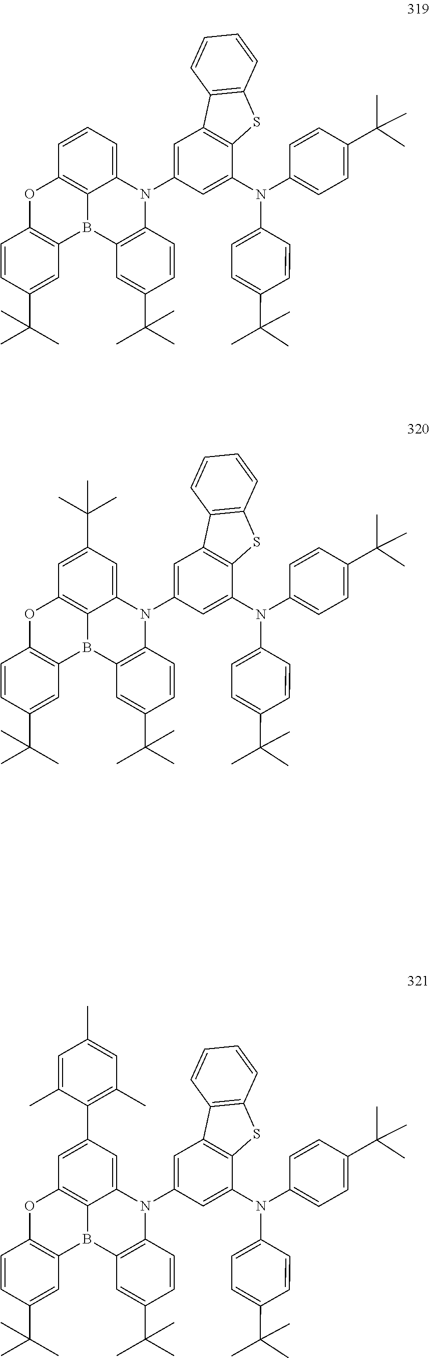 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2sc2ccccc23)cc1 ; Cc1cc(C)c(-c2cc3c4c(c2)N(c2cc(N(c5ccc(C(C)(C)C)cc5)c5ccc(C(C)(C)C)cc5)c5sc6ccccc6c5c2)c2ccc(C(C)(C)C)cc2B4c2cc(C(C)(C)C)ccc2O3)c(C)c1]

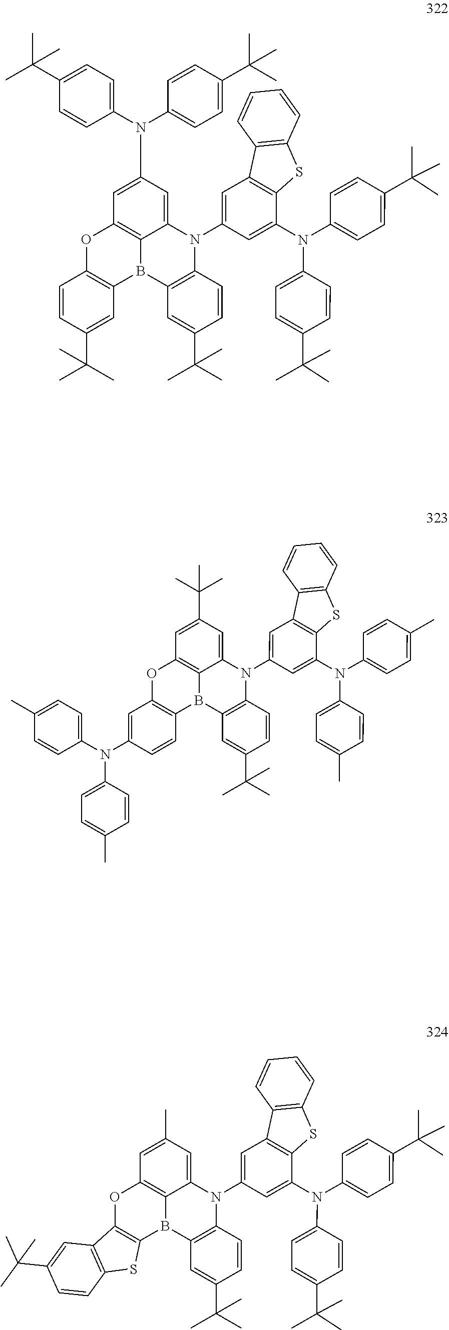

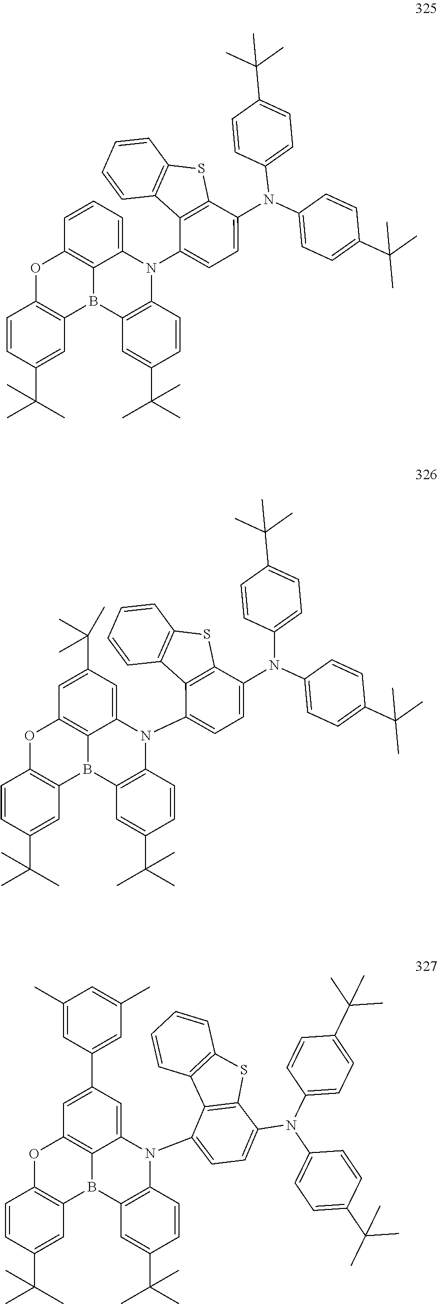 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2sc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2sc2ccccc23)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2cc(C(C)(C)C)ccc2O3)c1]

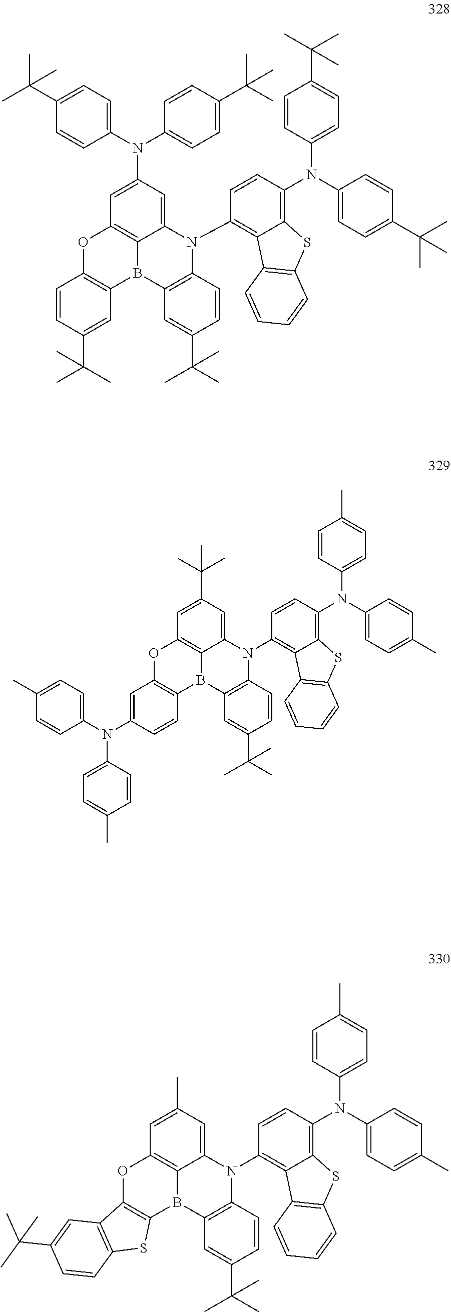

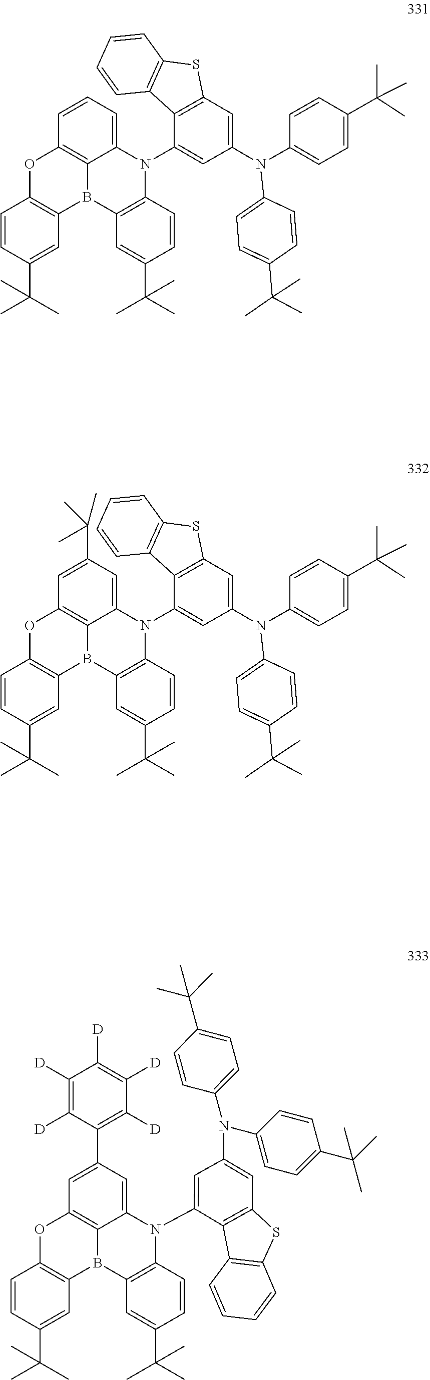 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)sc2ccccc23)cc1 ; [2H]c1c([2H])c([2H])c(-c2cc3c4c(c2)N(c2cc(N(c5ccc(C(C)(C)C)cc5)c5ccc(C(C)(C)C)cc5)cc5sc6ccccc6c25)c2ccc(C(C)(C)C)cc2B4c2cc(C(C)(C)C)ccc2O3)c([2H])c1[2H]]

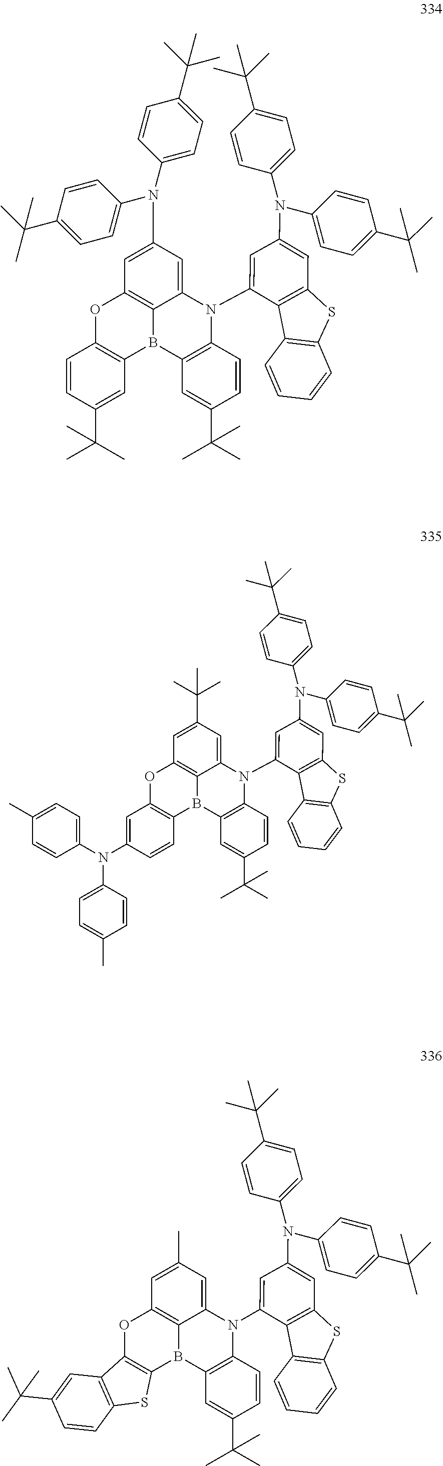

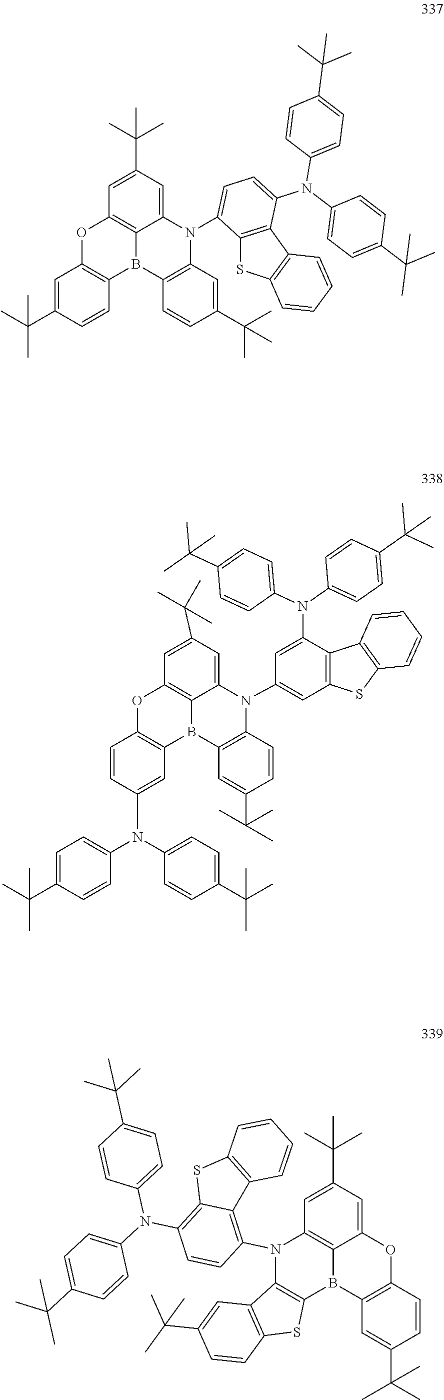

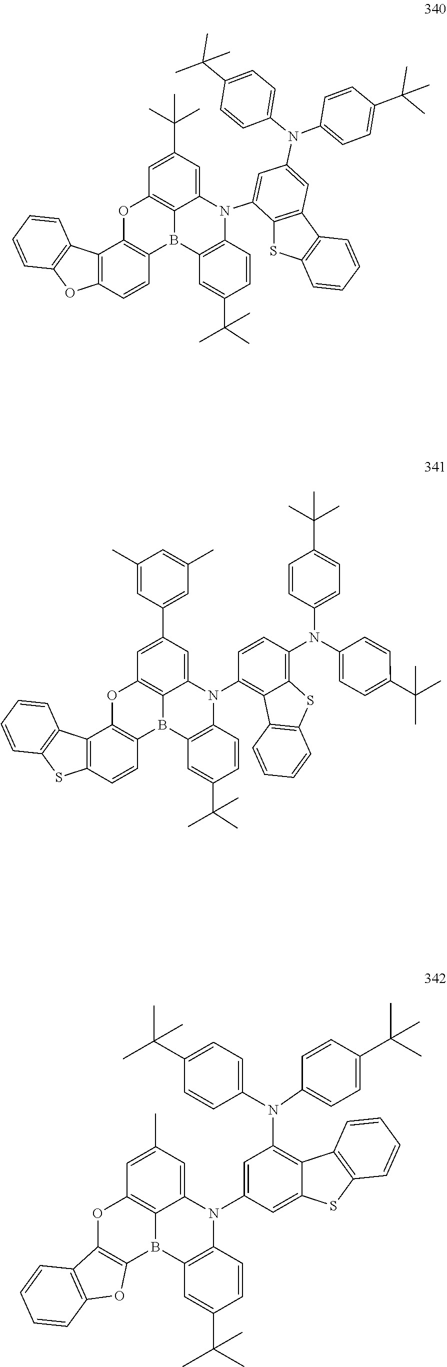 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3sc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1oc3ccccc3c1O2]

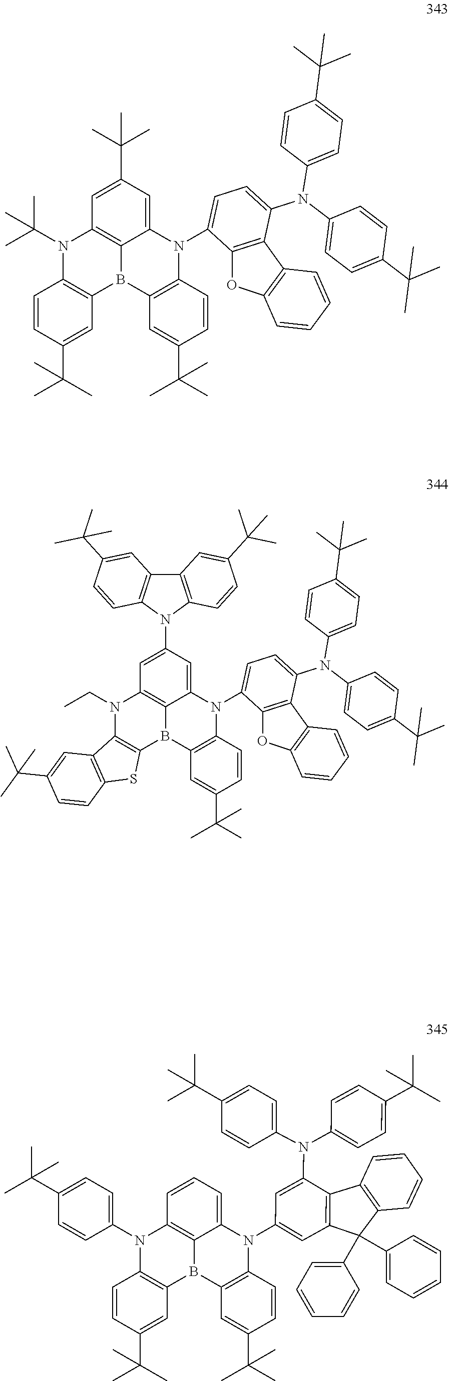

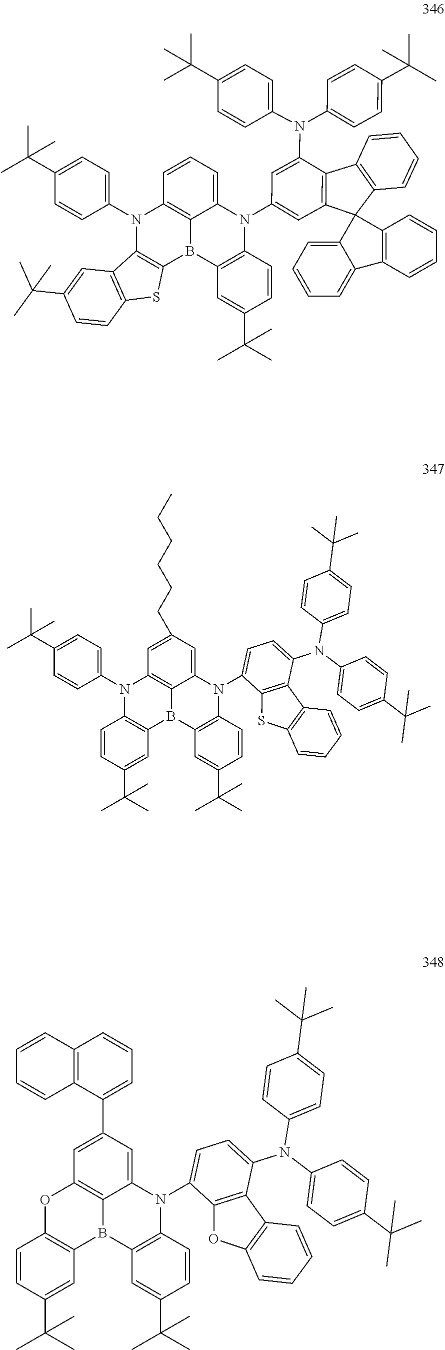 [SMILES: CC(C)(C)c1ccc(N(c2ccc(C(C)(C)C)cc2)c2cc(N3c4ccc(C(C)(C)C)cc4B4c5sc6ccc(C(C)(C)C)cc6c5N(c5ccc(C(C)(C)C)cc5)c5cccc3c54)cc3c2-c2ccccc2C32c3ccccc3-c3ccccc32)cc1 ; CCCCCCc1cc2c3c(c1)N(c1ccc(N(c4ccc(C(C)(C)C)cc4)c4ccc(C(C)(C)C)cc4)c4c1sc1ccccc14)c1ccc(C(C)(C)C)cc1B3c1cc(C(C)(C)C)ccc1N2c1ccc(C(C)(C)C)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(-c6cccc7ccccc67)cc3c54)c3oc4ccccc4c23)cc1]

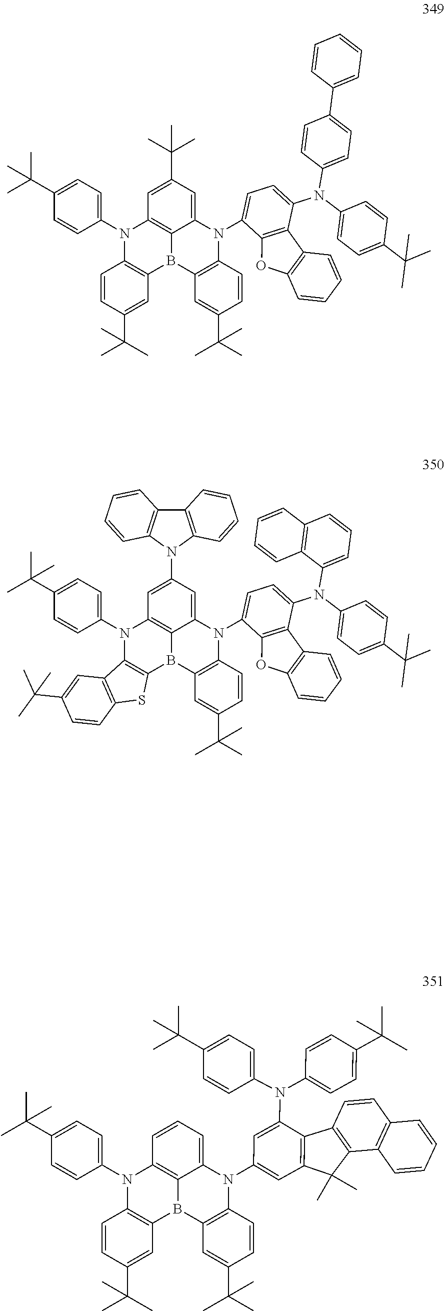

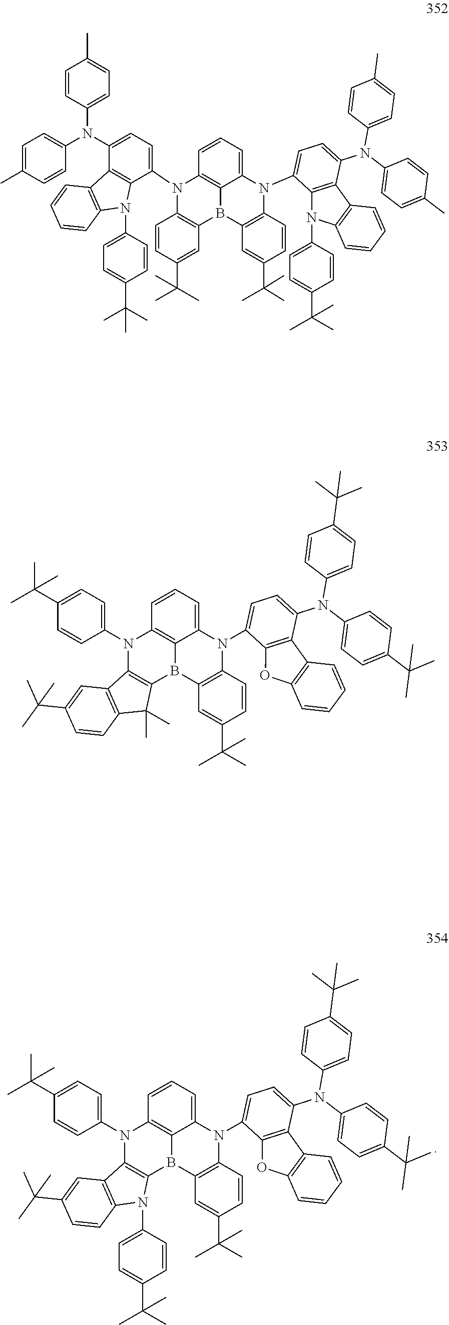

In the organic compound containing an amino group provided by the embodiment of the present disclosure, the organic compound contains heterocyclic rings and the amino group at a same time, and a resonance effect of a material containing the organic compound used in the light-emitting element can be enhanced, thereby improving performances of the material, improving luminous efficiency of the light-emitting element, and prolonging luminous life of the light-emitting element.

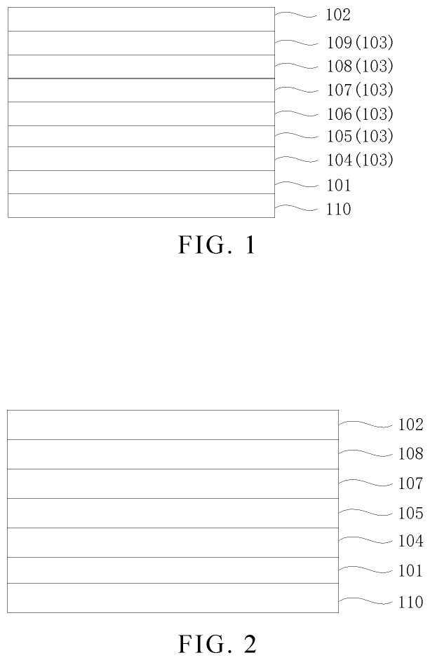

Referring to FIG. 1 and FIG. 2, the present disclosure further provides a light-emitting element. The light-emitting element includes a pair of electrodes including a first electrode 101 and a second electrode 102 and an organic functional layer 103 located between the first electrode 101 and the second electrode 102. A material of the organic functional layer 103 includes the organic compound described above. The first electrode 101 may be an anode, and the second electrode 102 may be a cathode.

In some embodiments, the light-emitting element may be applied to an organic light-emitting diode, an organic photovoltaic battery, an organic light-emitting battery, an organic field-effect tube, an organic light-emitting field-effect tube, an organic laser, an organic spin electron device, an organic sensor, or an organic plasmon emission diode, etc. In some embodiments, the light-emitting element may be applied to the organic light-emitting diode, the organic light-emitting battery, or the organic light-emitting field-effect tube.

In some embodiments, the light-emitting element may be applied to an electronic device such as a display panel, an illuminating device, or a lighting source, etc.

In some embodiments, the organic functional layer 103 may be a single layer, at this time, the organic functional layer 103 is a mixture layer. The mixture layer includes a first compound and a second compound. The first compound is selected from at least one organic compound described above. The second compound is selected from at least one of a hole injection material, a hole transport material, an electron transport material, a hole blocking material, a light-emitting guest material, a light-emitting host material, and an organic dye.

When the second compound is selected from at least one of the hole injection material, the hole transport material, the electron transport material, the hole blocking material, the light-emitting host material, and the organic dye, a mass ratio of the first compound to the second compound ranges from (1:99) to (30:70). In some embodiments, the mass ratio ranges from (1:99) to (10:90).

When the second compound is the light-emitting guest material, the mass ratio of the first compound to the second compound ranges from (99:1) to (70:30). In some embodiments, the mass ratio ranges from (99:1) to (90:10).

In some embodiments, the organic functional layer 103 may include multiple layers. When the organic functional layer 103 is multi-layers, the organic functional layer 103 includes at least the light-emitting layer 107. In some embodiments, the organic functional layer 103 includes a hole injection layer 104, a hole transport layer 105, a light-emitting layer 107, an electronic blocking layer 106, an electronic injection layer 109, an electronic transport layer 108, or a hole blocking layer.

In some embodiments, the light-emitting element may be a blue light-emitting element, a green light-emitting element, or a red light-emitting element. The light-emitting layer 107 may include at least one host material and at least one guest material. The guest material is at least one of the organic compounds described above. The host material includes a fused aromatic derivative or a heteroaromatic compound.

A wavelength of light emitted by the light-emitting element ranges from 300 nm to 1000 nm. In some embodiments, the wavelength ranges from 350 nm to 900 nm. In some embodiments, the wavelength ranges from 400 nm to 800 nm.

In some embodiments, the host material includes at least one of an anthracene derivative, a pyrene derivative, a naphthalene derivative, a pentacene derivative, a phenanthrene compound, a fluoranthene compound, a carbazole derivative, a dibenzofuran derivative, a ladder type furan compound, and a pyrimidine derivative.

In some embodiments, a mass ratio of the host material to the guest material ranges from (99:1) to (70:30), such as (90:10), (85:15), (80:20), (75:25), etc. In some embodiments, the mass ratio ranges from (99:1) to (90:10), such as (97:3), (96:4), (95:5), (93:7), (92:8), etc. The guest material is dispersed in the host material, and the mass ratio of the host material to the guest material ranging from (99:1) to (70:30) is conducive to inhibiting crystallization of the light-emitting layer 107 and concentration quenching caused by great concentration of the guest material, thereby improving the luminous efficiency of the light-emitting element.

In some embodiments, the anode is an electrode used for injecting holes, and the holes in the anode may be easily injected into the organic functional layer 103. For example, the holes in the anode may be injected into the hole injection layer, the hole transport layer, or the light-emitting layer. Materials of the anode may include at least one of conductive metal, conductive metal oxide, and conductive polymer. In some embodiments, absolute value of a difference between work function of the anode and highest occupied molecular orbital (HOMO) energy level or valence band energy level of a light-emitting material of the light-emitting layer, or a p-type semiconductor material of the hole injection layer, the hole transport layer, or the electron blocking layer is less than 0.5 eV. In some embodiments, the above-mentioned absolute value is less than 0.3 eV. In some embodiments, the above-mentioned absolute value is less than 0.2 eV. Examples of the materials of the anode include but are not limited thereto: aluminum (Al), copper (Cu), aurum (Au), argentum (Ag), magnesium (Mg), ferrum (Fe), cobalt (Co), nickel (Ni), manganese (Mn), palladium (Pd), platinum (Pt), indium tin oxide (ITO), and aluminum doped zinc oxide (AZO), etc. The materials of the anode may be applied to by any suitable technology, such as a suitable physical vapor deposition method including RF magnetron sputtering, vacuum thermal evaporation, electron beam (e-beam), etc. In some embodiments, the anode is patterned. A patterned ITO conductive substrate is commercially available and may be used to manufacture elements of the present disclosure.

In some embodiments, the cathode is an electrode used for injecting electrons, and the electrons in the cathode may be easily injected into the organic functional layer 103. For example, the electrons in the cathode may be injected into the electron injection layer, the electron transport layer, or the light-emitting layer. Materials of the cathode may include at least one of conductive metal and conductive metal oxide. In some embodiments, absolute value of a difference between work function of the cathode and lowest unoccupied molecular orbital (LUMO) energy level or valence band energy level of the light-emitting material of the light-emitting layer, or a n-type semiconductor material of the electron injection layer, the electron transport layer, or the hole blocking layer is less than 0.5 eV. In some embodiments, the above-mentioned absolute value is less than 0.3 eV. In some embodiments, the above-mentioned absolute value is less than 0.2 eV. All materials that may be used in the cathode of organic electronic devices may be used as materials of the cathode of devices applied for in the present disclosure. The materials of the cathode include, but are not limited thereto: Al, Au, Ag, calcium (Ca), barium (Ba), Mg, LiF/Al, MgAg alloy, BaF₂/Al, Cu, Fe, Co, Ni, Mn, Pd, Pt, ITO, etc. The materials of the cathode may be applied to by any suitable technology, such as a suitable physical vapor deposition method including RF magnetron sputtering, vacuum thermal evaporation, or electron beam (e-beam), etc.

In some embodiments, the hole injection layer 104 is used for promoting an injection of holes from the anode to the light-emitting layer 107. The hole injection layer 104 includes a hole injection material. The hole injection material may be configured to receive holes injected from a positive electrode at low voltages. In some embodiments, HOMO energy level of the hole injection material is between work function of the material of the anode and HOMO energy level of a functional material (such as a hole transport material of the hole transport layer) of a film layer located on a side away from the anode. The hole injection material includes, but are not limited thereto: at least one of metalloporphyrins, oligothiophenes, organic materials based on arylamines, organic materials based on hexacyano hexaazabenzophenanthrene, organic materials based on quinacridone, organic materials based on perylene, anthraquinone, conductive polymers based on polyaniline and polythiophene, etc.

In some embodiments, the hole transport layer 105 may be used for transmitting holes to the light-emitting layer 107. The hole transport layer 105 includes hole transport materials. The hole transport materials are configured to receive holes transmitted from the anode or the hole injection layer and transfer the holes to the light-emitting layer. The hole transport materials are materials with high hole mobility known in the art. The hole transport materials may include, but are not limited thereto: at least one of organic materials based on arylamine, conductive polymer, block copolymer containing both conjugated and non-conjugated portions, etc.

In some embodiments, the electron transport layer 108 is used for transmitting electrons. The electron transport layer 108 includes electron transport materials. The electron transport materials are configured to receive electrons injected from a negative electrode and transfer the electrons to the light-emitting layer 107. The electron transport materials are materials known in the art that have high electron mobility. The electron transport materials may include, but are not limited thereto: at least one of Al-based complexes of 8-hydroxyquinoline, complexes containing Alq₃, organic radical compounds, hydroxyflavone metal complexes, 8-hydroxyquinoline lithium (LiQ), and compounds based on benzimidazole.

In some embodiments, the electron injection layer 109 is used for injecting electrons. The electron injection layer 109 includes electron injection materials. In some embodiments, the electron injection materials are configured to have ability to transmit electrons, an effect of injecting electrons from a negative electrode, an excellent effect of injecting electrons into the light-emitting layer 107 or the light-emitting material, and a function of preventing excitons generated by the light-emitting layer 107 from transferring to the hole injection layer. The electron injection materials further have excellent ability to form thin films. The electron injection materials include, but are not limited thereto: at least one of 8-hydroxyquinoline lithium (LiQ), fluorenone, anthraquinone dimethyl, biphenylquinone, thian dioxide, azole, diazole, triazole, imidazole, perylene tetracarboxylic acid, fluorene methane, anthrone, derivatives of these compounds, metal complexes, nitrogen containing 5-membered ring derivatives, etc.

In some embodiments, the hole blocking layer is used for preventing holes from reaching the negative electrode, and may generally be formed under a same condition as the hole injection layer 104. The hole blocking layer includes hole barrier materials. The hole barrier materials include but are not limited thereto: at least one of a diazole derivative or triazole derivative, phenanthroline derivatives, BCP, aluminum complexes, etc.

Referring to FIG. 1, in some embodiments, the light-emitting element further includes a substrate 110. The first electrode 101, the hole injection layer 104, the hole transport layer 105, the electronic blocking layer 106, the light-emitting layer 107, the electronic transport layer 108, the electronic injection layer 109, and the second electrode 102 are stacked on the substrate 110 in sequence. Please refer to FIG. 2, in some embodiments, the first electrode 101, the hole injection layer 104, the hole transport layer 105, the light-emitting layer 107, the electronic transport layer 108, the electronic injection layer 109, and the second electrode 102 are stacked on the substrate 110 in sequence. The substrate 110 may be a transparent substrate or an opaque substrate. When the substrate 110 is the transparent substrate, a transparent light-emitting element may be provided. In some embodiments, the substrate 110 may be a rigid substrate or a flexible substrate having elasticity. In some embodiments, the substrate is made of plastic, polymer, metal, semiconductor chips, or glass. In some embodiments, the substrate 110 includes at least one smooth surface used for forming the anode on the surface. In some embodiments, the surface is free of surface defects. In some embodiments, the substrate 110 is a polymer film or the substrate 110 is made of plastic, the plastic includes but not limited to polyethylene terephthalate (PET) and polyethylene glycol (2,6-naphthalene) (PEN). A glass transition temperature of the substrate 110 is greater than or equal to 150° C. In some embodiments, the glass transition temperature is greater than or equal to 200° C. In some embodiments, the glass transition temperature is greater than or equal to 250° C. In some embodiments, the glass transition temperature is greater than or equal to 300° C.

In some embodiments, the light-emitting element may be a solution type light-emitting element, that is, at least one of organic functional layers is prepared by a printing process (such as an ink-jet printing process).

In some embodiments, the mixture layer or the light-emitting layer may be formed by a printing process or coating process of composition. The printing process or the coating process includes ink-jet printing, jet printing, letterpress printing, screen printing, dip coating, rotary coating, scraper coating, roller printing, rotary roller printing, lithographic printing, flexographic printing, rotary printing, spraying, brushing printing, pad printing, slot type extrusion coating, etc. In some embodiments, suitable printing process or the coating processes are intaglio printing, jet printing, and ink-jet printing.

The composition may be a solution or suspension. The composition may include dispersions and dispersants. The dispersions are at least one of the organic compounds described above, and the dispersants are used for dispersing the dispersions.

In the composition, a mass fraction of the above-mentioned organic compound may range from 0.01% to 10%. In some embodiments, the mass fraction ranges from 0.1% to 15%. In some embodiments, the mass fraction ranges from 0.2% to 5%. In some embodiments, the mass fraction ranges from 0.25% to 3%.

In some embodiments, a Hansen solubility parameter of the dispersants is within following ranges: δd (dispersion force) of the dispersants ranges from 17.0 MPa^{1/2} to 23.2 MPa^{1/2}, and further ranges from 18.5 MPa^{1/2} to 21.0 MPa^{1/2}; δp (polarity force) of the dispersants ranges from 0.2 MPa^{1/2} to 12.5 MPa^{1/2}, and further ranges from 2.0 MPa^{1/2} to 6.0 MPa^{1/2}; and δh (hydrogen bonding force) of the dispersants ranges from 0.9 MPa^{1/2} to 14.2 MPa^{1/2}, and further ranges from 2.0 MPa^{1/2} to 6.0 MPa^{1/2}.

Preferably, a boiling point of the dispersants is greater than or equal to 150° C. In some embodiments, the boiling point is greater than or equal to 180° C. In some embodiments, the boiling point is greater than or equal to 200° ° C. In some embodiments, the boiling point is greater than or equal to 250° C. In some embodiments, the boiling point is greater than or equal to 275° C. In some embodiments, the boiling point is greater than or equal to 300° C. The boiling point of the dispersants is at least greater than or equal to 150° C., which is conducive to preventing nozzles of the ink-jet printing heads from clogging during an ink-jet printing process, and a higher the boiling point, the more conducive to preventing clogging.

The dispersants may include at least one organic solvent. The organic solvent may evaporate from a solvent system to form a film containing functional materials. The organic solvent may include at least one first organic solvent, and the first organic solvent may be selected from an aromatic-based and a heteroaromatic-based solvent. In detail, the first organic solvent may be selected from p-diisopropylbenzene, pentyl benzene, tetrahydronaphthalene, cyclohexylbenzene, chloronaphthalene, 1,4-dimethylnaphthalene, 3-isopropylbiphenyl, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butadiene benzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylcumene, 1-methylnaphthalene, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbiphenyl, α, α-dichlorodiphenylmethane, 4-(3-phenylpropyl) pyridine, benzyl benzoate, 1,1-bis(3,4-dimethylphenyl) ethane, 2-isopropylnaphthalene, quinoline, isoquinoline, methyl 2-furanoate, ethyl 2-furanoate, etc.

The first organic solvent may be selected from aromatic ketone-based solvents. In detail, the first organic solvent may be selected from 1-tetrahydronaphthalenone, 2-tetrahydronaphthalenone, 2-(phenyl epoxy) tetrahydronaphthalenone, 6-(methoxy) tetrahydronaphthalenone, acetophenone, phenylacetone, benzophenone, and derivatives of these compounds, such as 4-methylacetophenone, 3-methylacetophenone, 2-methylacetophenone, 4-methylphenylacetone, 3-methylphenylacetone, and 2-methylphenylacetone.

The first organic solvent may be selected from aromatic ether-based solvent. In detail, the first organic solvent may be selected from 3-phenoxytoluene, butoxybenzene, p-anisaldehyde dimethyl acetal, tetrahydro-2-phenoxy-2H-pyran, 1,2-dimethoxy-4 - (1-propenyl) benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxynaphthalene, diphenyl ether, 2-phenoxymethyl ether, 2-phenoxytetrahydrofuran, and ethyl-2-naphthyl ether.

The first organic solvent may be selected from aliphatic ketones. In particular, the first organic solvent may be selected from 2-nonone, 3-nonone, 5-nonone, 2-decanone, 2,5-hexanedione, 2,6,8-trimethyl-4-nonone, fenone, phorone, isophorone, and di-n-pentyl ketone, and aliphatic ether, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, and tetraethylene glycol dimethyl ether.

The first organic solvent may be selected from organic ester-based solvent. In detail, the first solvent may be selected from octanoate, sebacate, stearate, benzoate, phenylacetate, cinnamate, oxalate, maleate, alkyl lactone, oleate, etc. In some embodiments, the ester-based solvents may be selected from octyl octanoate, diethyl sebacate, diallyl phthalate, and isononyl isononanoate.

The organic solvent may further include a second organic solvent. The second organic solvent may be selected from at least one of methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, naphthane, and indene.

In addition to the dispersions and the dispersants described above, the composition may further include one or more components such as surfactant, lubricant, wetting agent, dispersant, hydrophobic agent, adhesive, which may be used for adjusting viscosity, forming performance of films, and improving adhesion, and the like.

Exemplary manufacturing methods of the organic compound provided by the present disclosure are shown in following exemplary example 1 to example 16.

### EXAMPLE 1

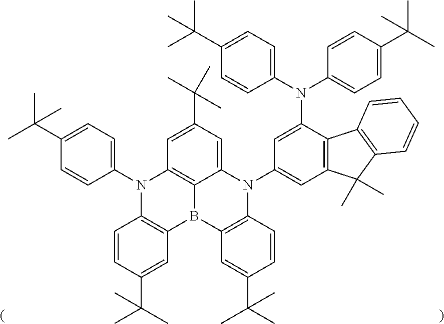 [SMILES: CC(C)(C)c1ccc(N(c2ccc(C(C)(C)C)cc2)c2cc(N3c4ccc(C(C)(C)C)cc4B4c5cc(C(C)(C)C)ccc5N(c5ccc(C(C)(C)C)cc5)c5cc(C(C)(C)C)cc3c54)cc3c2-c2ccccc2C3(C)C)cc1]

Synthesis of Organic Compound M1

Synthetic Route of the Organic Compound M1 is as following:

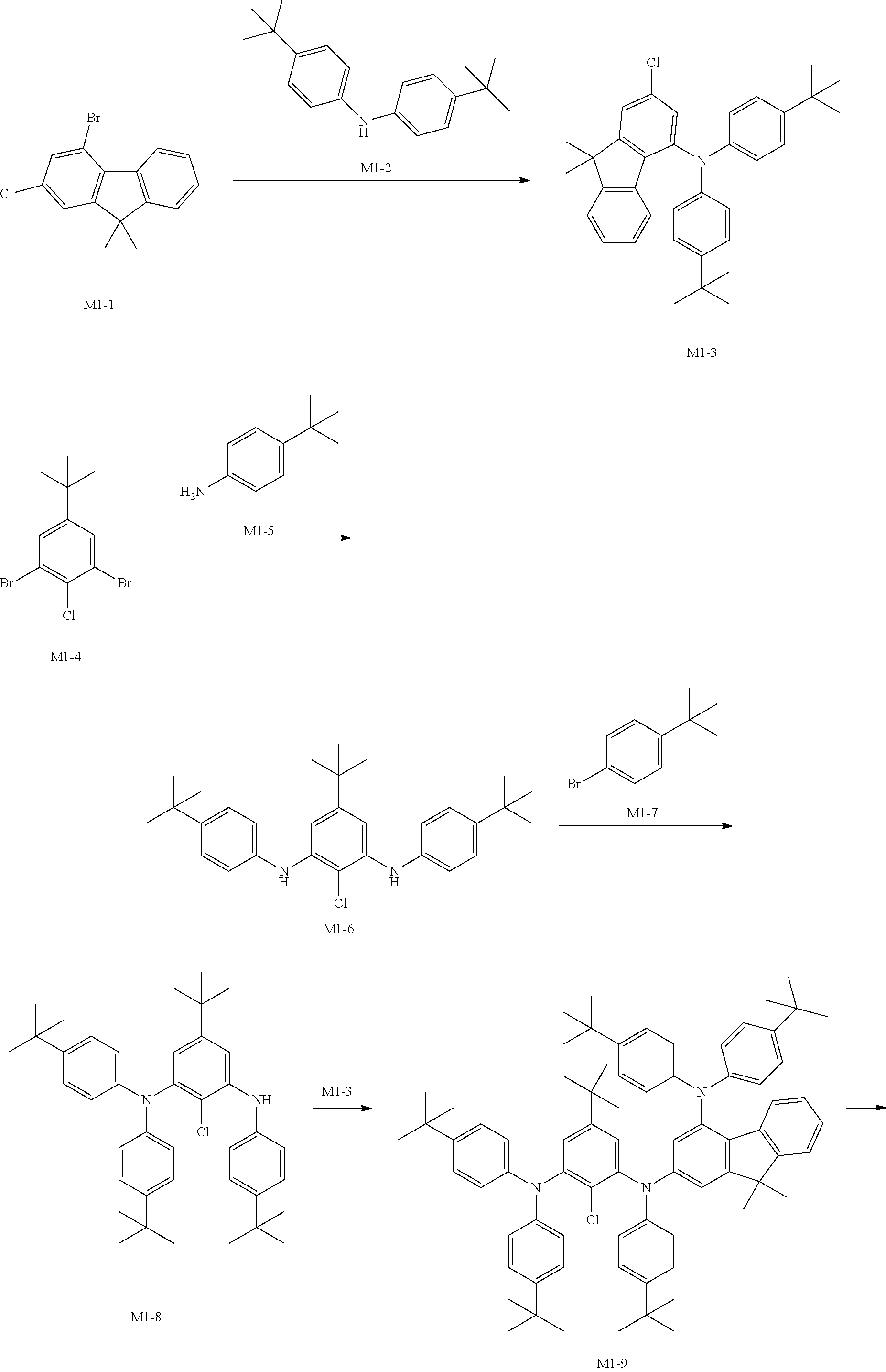

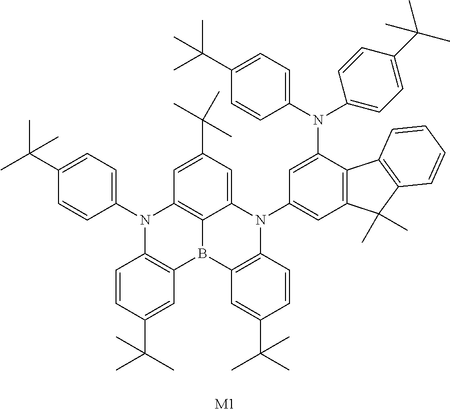

Specific synthesis steps of the organic compound M1 are as following:

1) Synthesis of intermediate M1-3: in a nitrogen atmosphere, 30.8 g (100 mmol) of compound M1-1, 28.1 g (100 mmol) of compound M1-2, 2.76 g (3 mmol) of Pd₂(dba)₃, 1.2 g (6 mmol) of tri tertbutyl phosphine, 18.2 g (200 mmol) of sodium tertbutyl alcohol, and 250 mL of anhydrous toluene were added into a two neck-flask (500 mL). The solution was heated to a temperature of 60° C., and was stirred for 6 hours. Then, the solution was cooled to room temperature, and water was added to quench the reaction. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M1-3 with yield of 74%.

2) Synthesis of intermediate M1-6: in a nitrogen atmosphere, 19.6 g (60 mmol) of compound M1-4, 17.9 g (120 mmol) of compound M1-5, 3.32 g (3.6 mmol) of Pd₂(dba)₃, 1.44 g (7.2 mmol) of tri tertbutyl phosphine, 11 g (120 mmol) of sodium tertbutyl alcohol, and 150 mL of anhydrous toluene were added into a two neck-flask (500 mL). The solution was heated to a temperature of 70° C., and was stirred for 6 hours. Then, the solution was cooled to room temperature, and water was added to quench the reaction. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M1-6 with yield of 62%.

3) Synthesis of intermediate M1-8: according to the synthesis method of the intermediate M1-3, compound M1-7 and compound M1-6 were substituted for the compound M1-1 and the compound M1-2 respectively to obtain the intermediate M1-8 with yield of 56%.

4) Synthesis of intermediate M1-9: in a nitrogen atmosphere, 11.9 g (20 mmol) of compound M1-8, 10.2 g (20 mmol) of compound M1-3, 0.92 g of Pd₂(dba)₃ (1 mmol), 0.4 g of tri tertbutyl phosphine (2 mmol), 3.64 g (40 mmol) of sodium tertbutyl alcohol, and 150 mL of anhydrous toluene were added into a two neck-flask (500 mL). The solution was heated to a temperature of 90° C., and stirred for 6 hours. Then, the solution was cooled to room temperature, and water was added to quench the reaction. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M1-9 with yield of 65%.

5) Synthesis of the organic compound M1: in a nitrogen atmosphere, 10.7 g (10 mmol) of the intermediate M1-9 and 80 mL of anhydrous tetrahydrofuran were added into a three neck-flask (250 mL). The solution was heated to a temperature of −30° C., and then 15 mmol of tertbutyl lithium solution was slowly added dropwise. After dropping, the temperature of the reaction was raised to a temperature of 60° C., and then was stirred for 2 hours. Then, the reaction was cooled to a temperature of −30° C., 20 mmol of boron tribromide was all added at once. Then, the temperature of the reaction solution was slowly raised to room temperature, and the reaction lasted for 1 hour. Then, 30 mmol of N, N-diisopropylethylamine was added into the reaction solution, the temperature of the reaction solution was slowly raised to 100° C., and the reaction lasted for 3 hours. After the reaction was completed, the reaction was cooled to room temperature, sodium acetate aqueous solution was added to quench the reaction. The reaction solution was rotationally evaporated to remove most of the solvent, and then the reaction solution was dissolved with dichloromethane. Then, the mixture was washed with water for 3 times. The organic solution was collected, and then was stirred with silica gel. The product was purified by column chromatography to obtain the organic compound M1 with yield of 28%. A result of atmospheric solids analysis probe-mass spectrometry (ASAP-MS) of the organic compound M1 was as following: MS (ASAP)=1041.

### EXAMPLE 2

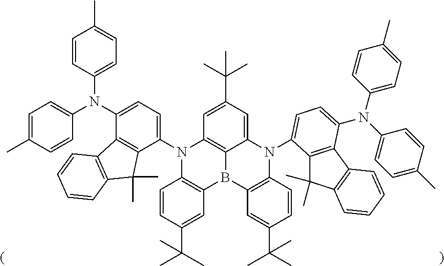

Synthesis of Organic Compound M2

Synthetic Route of the Organic Compound M2 is as following:

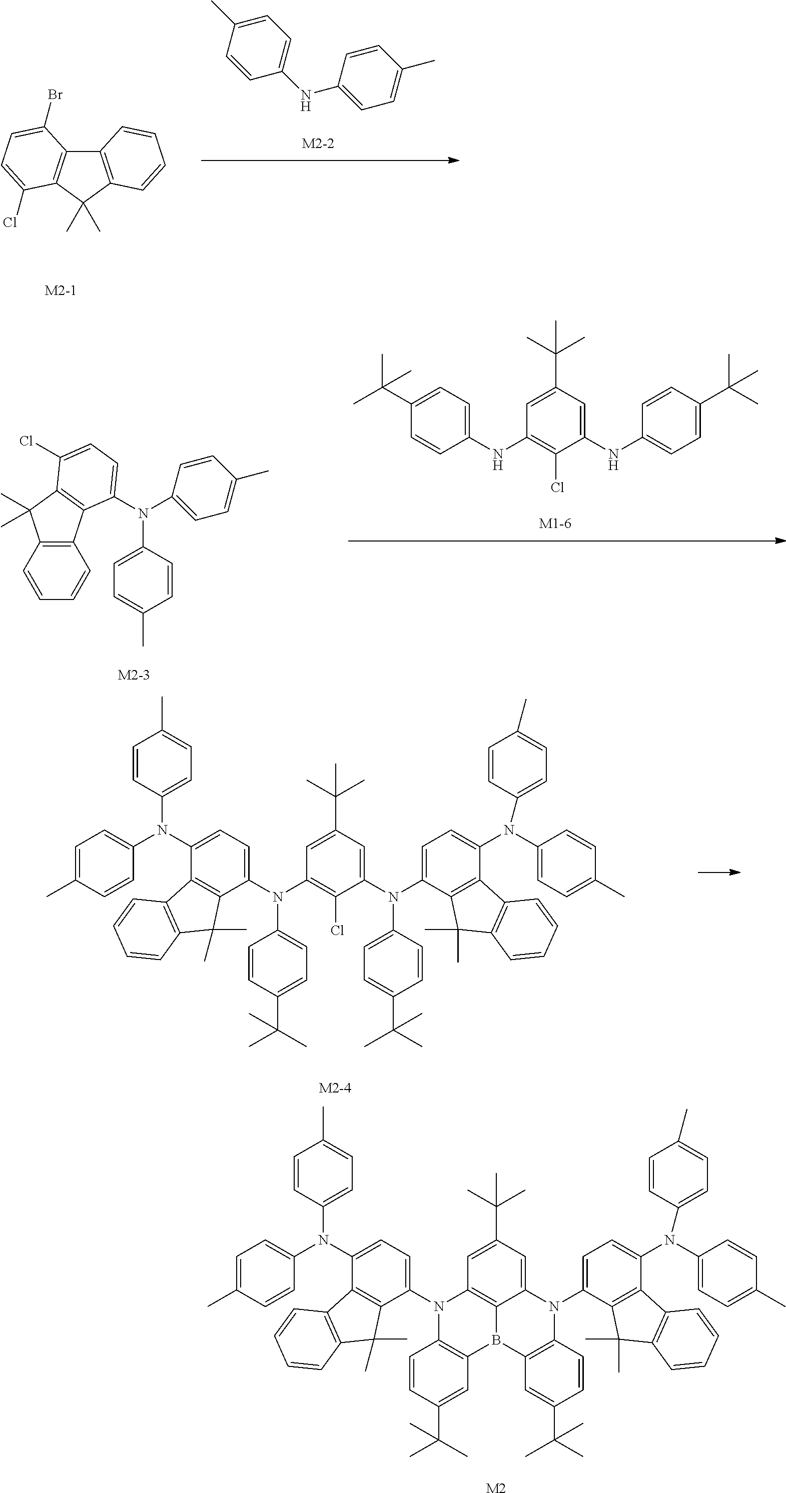

Specific synthesis steps of the organic compound M2 are as following:

1) Synthesis of intermediate M2-3: according to the synthesis method of the intermediate M1-3, compound M2-1 and compound M2-2 were substituted for the compound M1-1 and the compound M1-2 respectively to obtain the intermediate M2-3 with yield of 76%.

2) Synthesis of intermediate M2-4: in a nitrogen atmosphere, 27.8 g (60 mmol) of intermediate M1-6, 50.9 g (120 mmol) of compound M2-3, 3.32 g (3.6 mmol) of Pd₂(dba)₃, 1.44 g (7.2 mmol) of tri tertbutyl phosphine, 11 g (120 mmol) of sodium tertbutyl alcohol, and 150 mL of anhydrous toluene were added into a two neck-flask (500 mL). The solution was heated to a temperature of 90° C., and was stirred for 6 hours. Then, the solution was cooled to room temperature, and water was added to quench the reaction. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M2-4 with yield of 68%.

3) Synthesis of the organic compound M2: according to the synthesis method of the organic compound M1, the intermediate M2-4 was substituted for the intermediate M1-9 to obtain the organic compound M2 with yield of 25%. A result of ASAP-MS of the organic compound M2 was as following: MS (ASAP)=1212.

### EXAMPLE 3

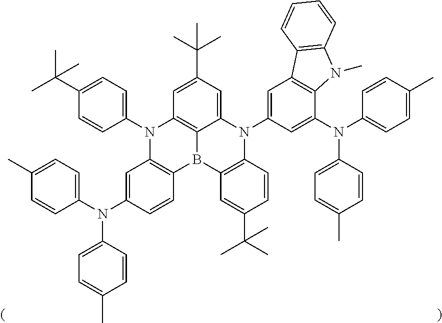

Synthesis of Organic Compound M3

Synthetic Route of the Organic Compound M3 is as following:

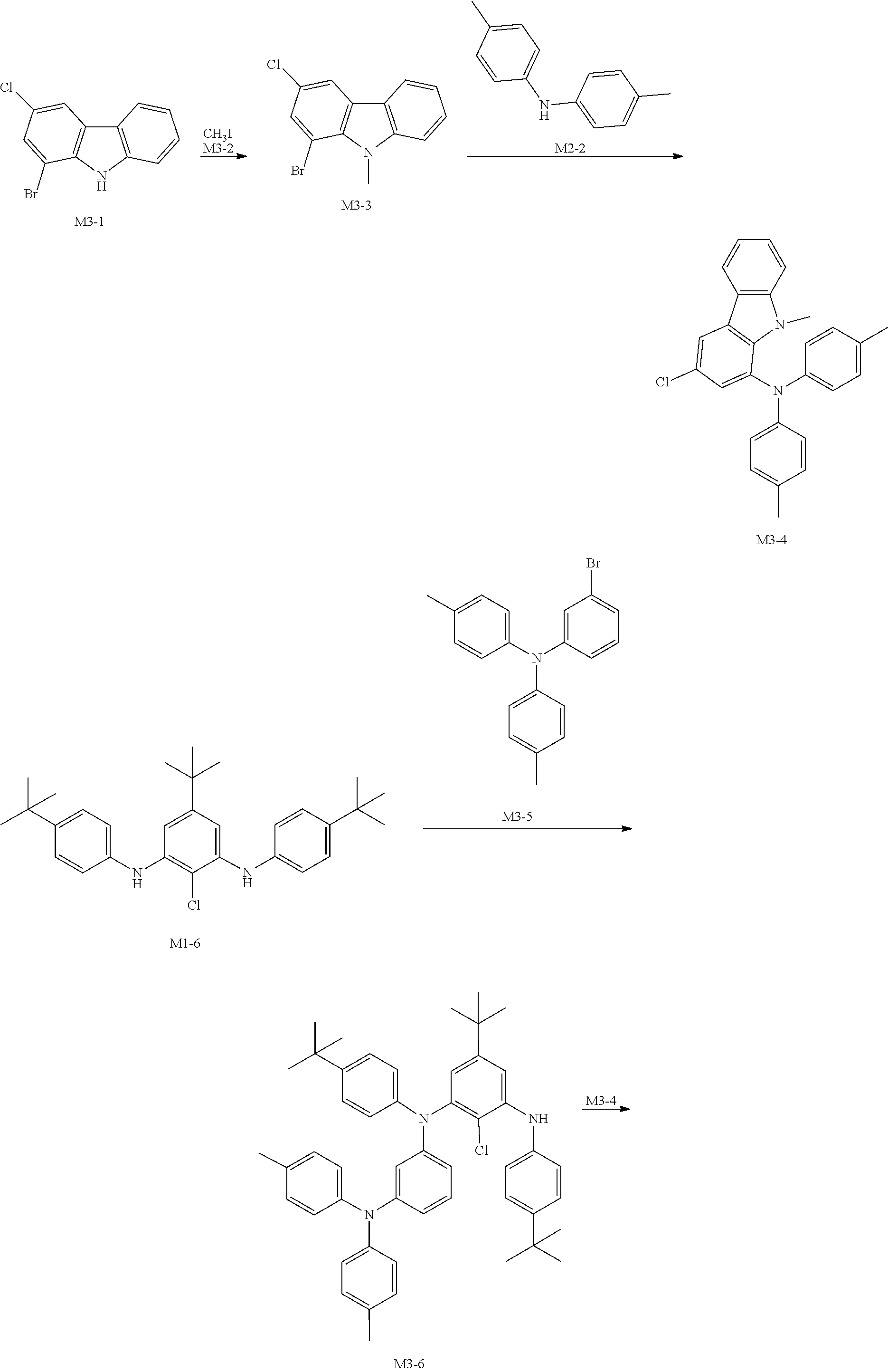

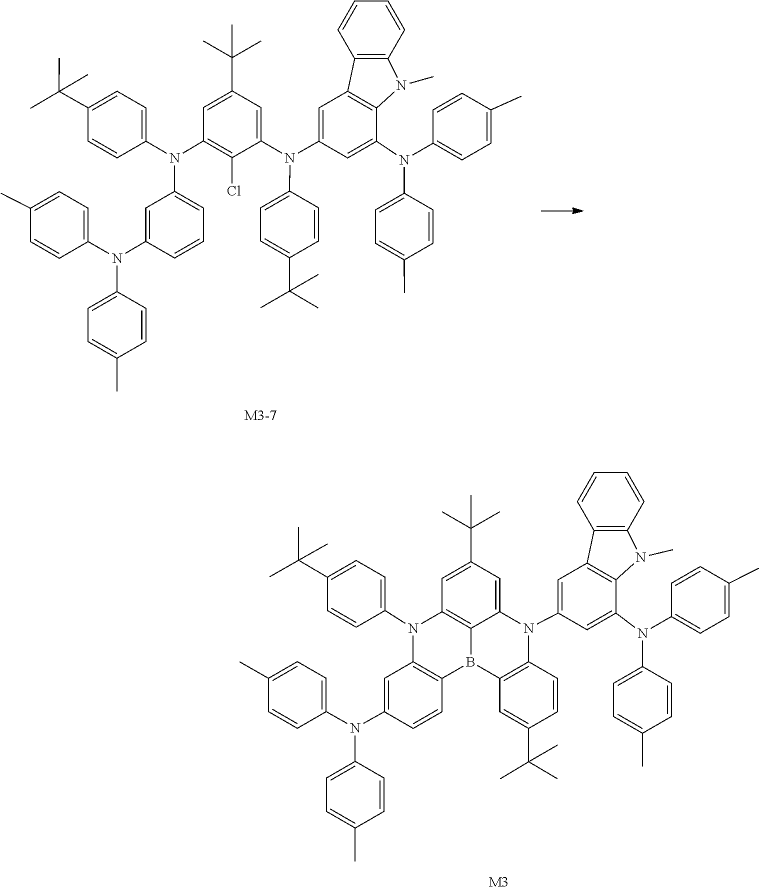

Specific synthesis steps of the organic compound M3 are as following:

1) Synthesis of intermediate M3-3: in a nitrogen atmosphere, 28.1 g (100 mmol) of compound M3-1, 6 g (150 mmol) of NaOH, and 150 mL dimethylformamide were added into a two neck-flask (500 mL). The reaction solution was stirred for 1 hour. Then, 15.6 g (110 mmol) of methyl iodide was added into the reaction solution at once, and was stirred for 4 hours. After the reaction was completed, the reaction solution was poured into 300 mL of pure water. Then, the reaction solution was stirred and filtered to obtain a solid. The product was recrystallized for purification with a mixed solution of ethanol and dichloromethane to obtain the intermediate M3-3 with yield of 82%.

2) Synthesis of intermediate M3-4: according to the synthesis method of the intermediate M1-3, the intermediate M3-3 and compound M2-2 were substituted for the compound M1-1 and the compound M1-2 respectively to obtain the intermediate M3-4 with yield of 72%.

3) Synthesis of intermediate M3-6: according to the synthesis method of the intermediate M1-8, compound M3-5 was substituted for the compound M1-7 to obtain the intermediate M3-6 with yield of 58%.

4) Synthesis of intermediate M3-7: according to the synthesis method of the

intermediate M1-9, the intermediate M3-4 and the intermediate M3-6 were substituted for the intermediate M1-3 and the intermediate 1-8 respectively to obtain the intermediate M3-7 with yield of 67%.

5) Synthesis of the organic compound M3: according to the synthesis method of the organic compound M1, the intermediate M3-7 was substituted for the intermediate M1-9 to obtain the organic compound M3 with yield of 27%. A result of ASAP-MS of the organic compound M3 was as following: MS (ASAP)=1083.

### EXAMPLE 4

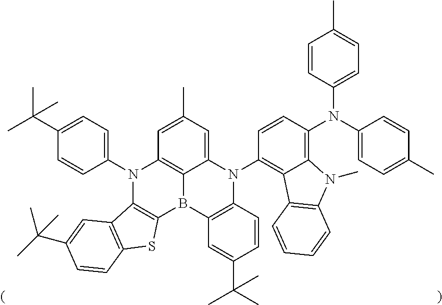 [SMILES: Cc1ccc(N(c2ccc(C)cc2)c2ccc(N3c4ccc(C(C)(C)C)cc4B4c5sc6ccc(C(C)(C)C)cc6c5N(c5ccc(C(C)(C)C)cc5)c5cc(C)cc3c54)c3c4ccccc4n(C)c23)cc1]

Synthesis of Organic Compound M4

Synthetic Route of the Organic Compound M4 is as following:

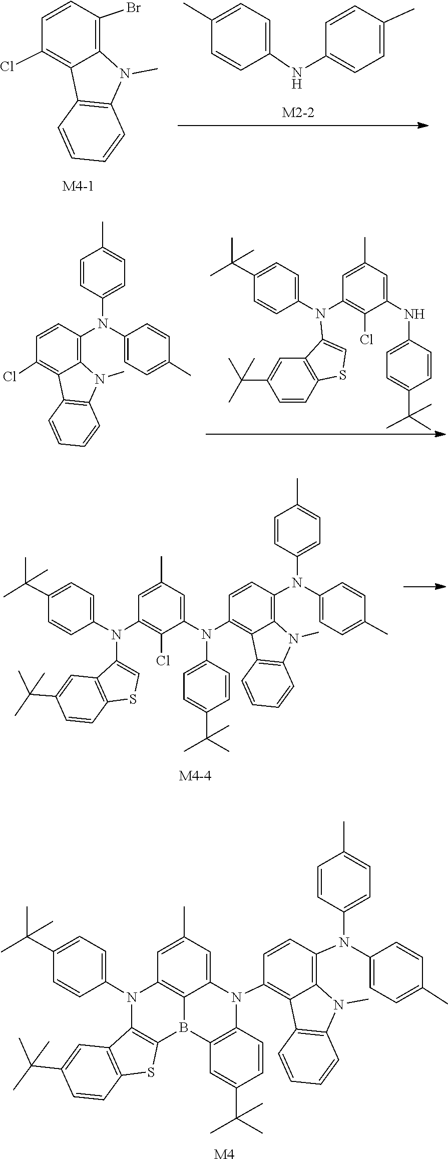

Specific synthesis steps of the organic compound M4 are as following:

1) Synthesis of intermediate M4-2: according to the synthesis method of the intermediate M1-3, compound M4-1 and the compound M2-2 were substituted for the compound M1-1 and the compound M1-2 respectively to obtain the intermediate M4-2 with yield of 73%.

2) Synthesis of intermediate M4-4: according to the synthesis method of the intermediate M1-9, the intermediate M4-2 and compound M4-3 were substituted for the intermediate M1-3 and the intermediate 1-8 respectively to obtain the intermediate M4-4 with yield of 66%.

3) Synthesis of the organic compound M4: according to the synthesis method of the organic compound M1, the intermediate M4-4 was substituted for the intermediate M1-9 to obtain the organic compound M4 with yield of 24%. A result of ASAP-MS of the organic compound M4 was as following: MS (ASAP)-957.

### EXAMPLE 5

Synthesis of Organic Compound M5

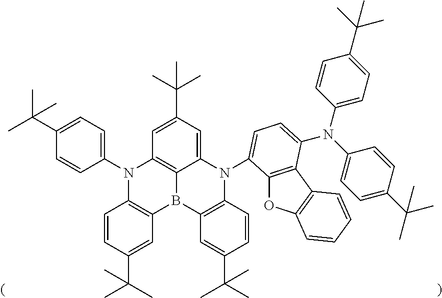 [SMILES: CC(C)(C)c1ccc(N2c3ccc(C(C)(C)C)cc3B3c4cc(C(C)(C)C)ccc4N(c4ccc(N(c5ccc(C(C)(C)C)cc5)c5ccc(C(C)(C)C)cc5)c5c4oc4ccccc45)c4cc(C(C)(C)C)cc2c43)cc1]

Synthetic Route of the Organic Compound M5 is as following:

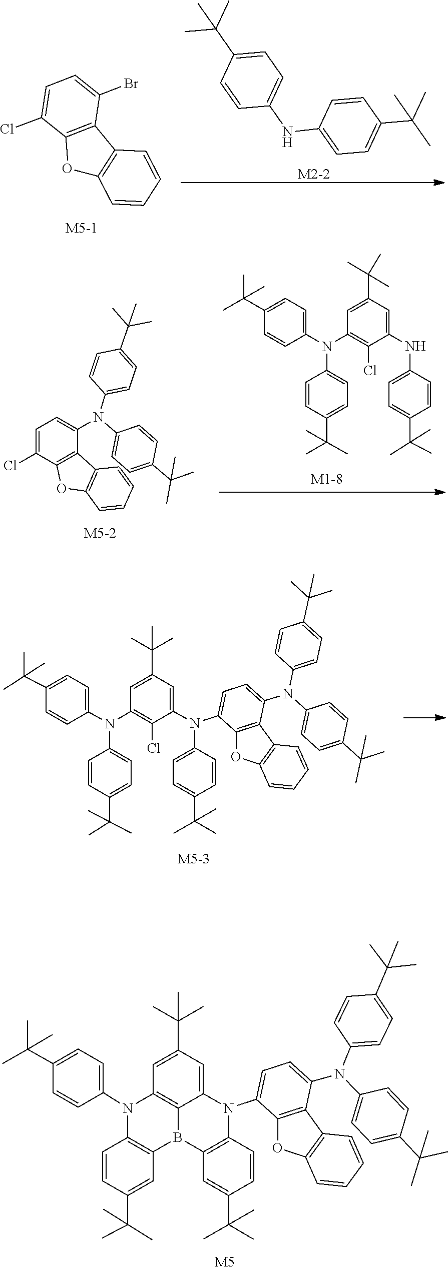

Specific synthesis steps of the organic compound M5 are as following:

1) Synthesis of intermediate M5-2: according to the synthesis method of the intermediate M1-3, compound M5-1 was substituted for the compound M1-1 to obtain the intermediate M5-2 with yield of 75%.

2) Synthesis of intermediate M5-3: according to the synthesis method of the intermediate M1-9, the intermediate M5-2 was substituted for the intermediate M1-3 to obtain the intermediate M5-3 with yield of 68%.

3) Synthesis of the organic compound M5: according to the synthesis method of the organic compound M1, the intermediate M5-3 was substituted for the intermediate M1-9 to obtain the organic compound M5 with yield of 29%. A result of ASAP-MS of the organic compound M5 was as following: MS (ASAP)=1015.

### EXAMPLE 6

Synthesis of Organic Compound M6

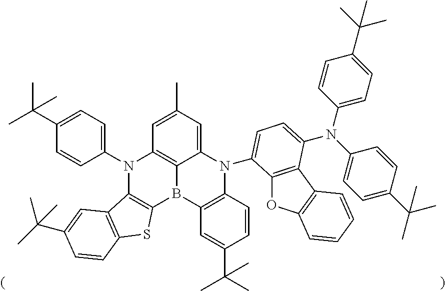 [SMILES: Cc1cc2c3c(c1)N(c1ccc(N(c4ccc(C(C)(C)C)cc4)c4ccc(C(C)(C)C)cc4)c4c1oc1ccccc14)c1ccc(C(C)(C)C)cc1B3c1sc3ccc(C(C)(C)C)cc3c1N2c1ccc(C(C)(C)C)cc1]

Synthetic Route of the Organic Compound M6 is as following:

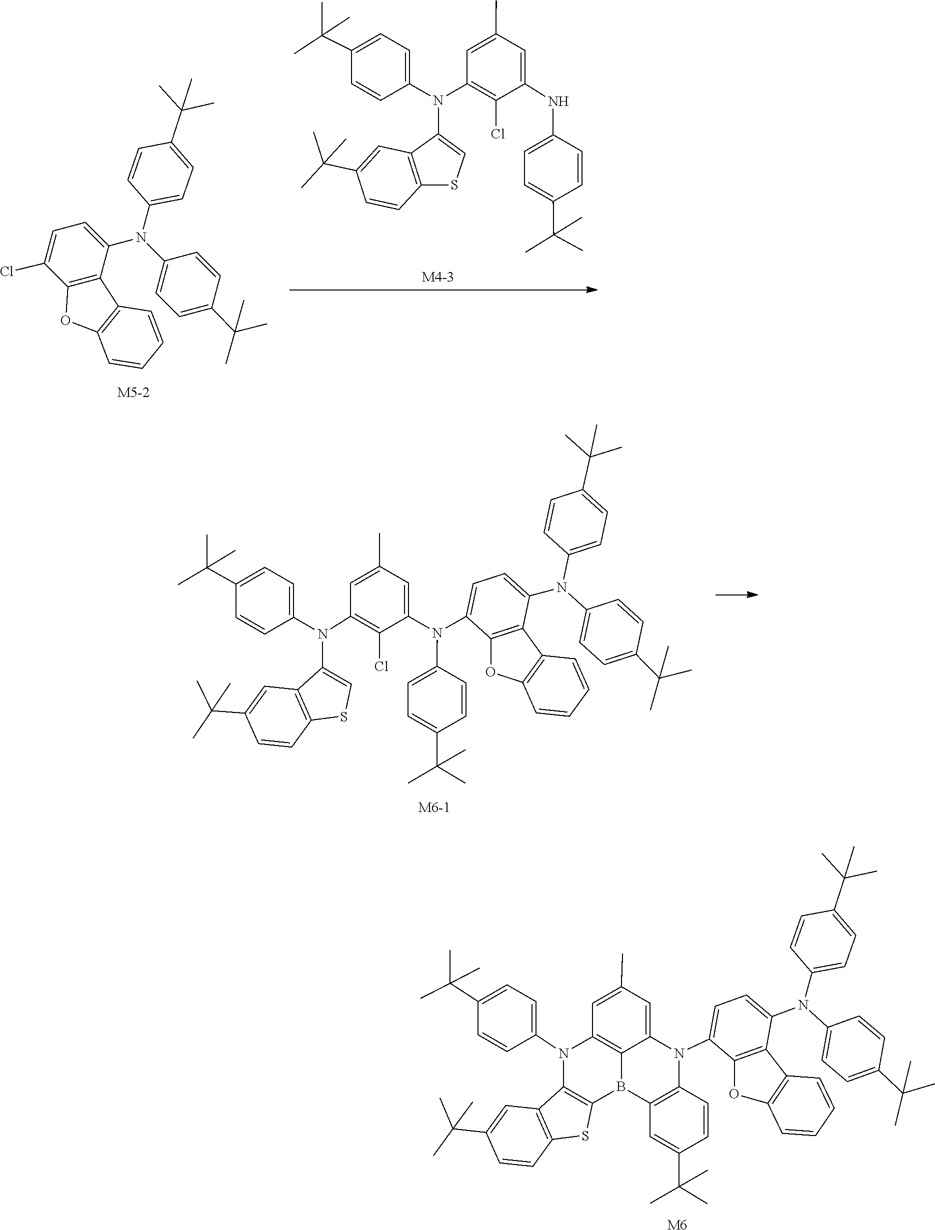

Specific synthesis steps of the organic compound M6 are as following:

1) Synthesis of intermediate M6-1: according to the synthesis method of the intermediate M1-9, compound M5-2 and the compound M4-3 were substituted for the intermediate M1-3 and the intermediate 1-8 respectively to obtain the intermediate M6-1 with yield of 64%.

2) Synthesis of the organic compound M6: according to the synthesis method of the organic compound M1, the intermediate M6-1 was substituted for the intermediate M1-9 to obtain the organic compound M6 with yield of 27%. A result of ASAP-MS of the organic compound M6 was as following: MS (ASAP)=1029.

### EXAMPLE 7

Synthesis of Organic Compound M7

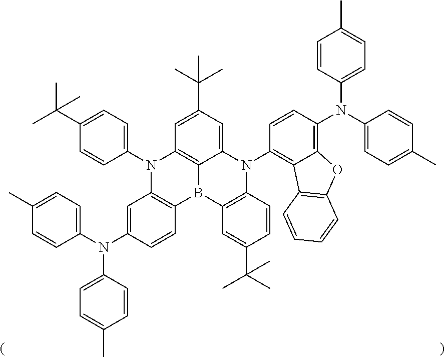

Synthetic Route of the Organic Compound M7 is as following:

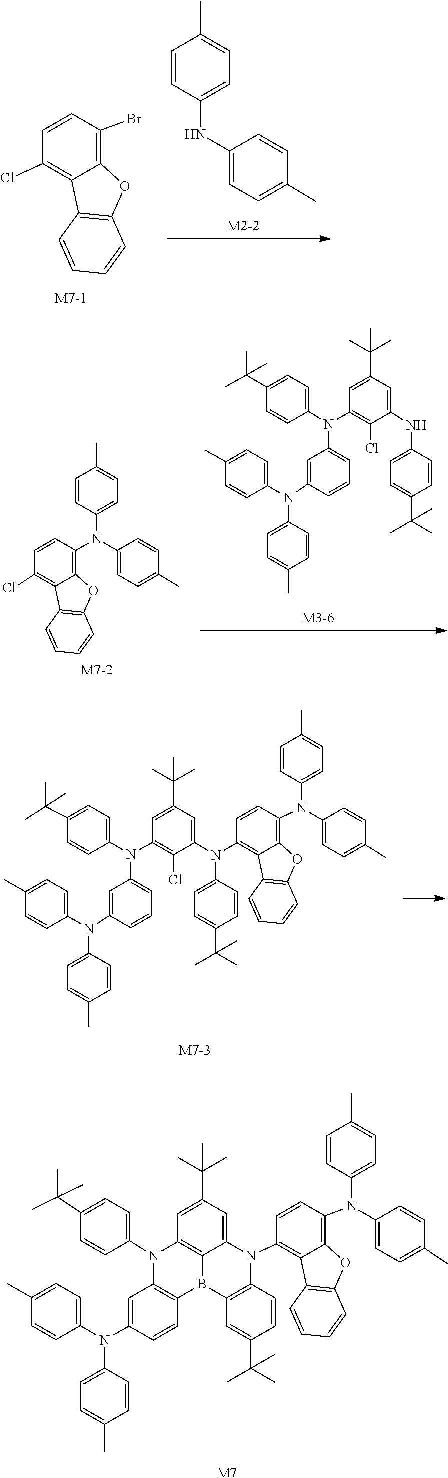

Specific synthesis steps of the organic compound M7 are as following:

1) Synthesis of intermediate M7-2: according to the synthesis method of the intermediate M1-3, compound M7-1 and the compound M2-2 were substituted for the compound M1-1 and the compound M1-2 respectively to obtain the intermediate M7-2 with yield of 74%.

2) Synthesis of intermediate M7-3: according to the synthesis method of the intermediate M1-9, the intermediate M7-2 and the intermediate M3-6 were substituted for the intermediate M1-3 and the intermediate 1-8 respectively to obtain the intermediate M7-3 with yield of 65%.

3) Synthesis of the organic compound M7: according to the synthesis method of the organic compound M1, the intermediate M7-3 was substituted for the intermediate M1-9 to obtain the organic compound M7 with yield of 30%. A result of ASAP-MS of the organic compound M7 was as following: MS (ASAP)=1070.

### EXAMPLE 8

Synthesis of Organic Compound M8

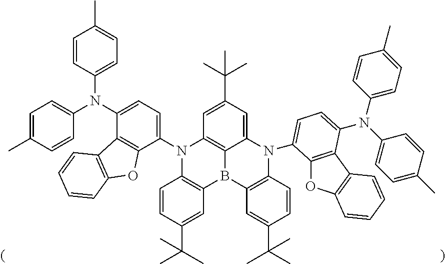

Synthetic Route of the Organic Compound M8 is as following:

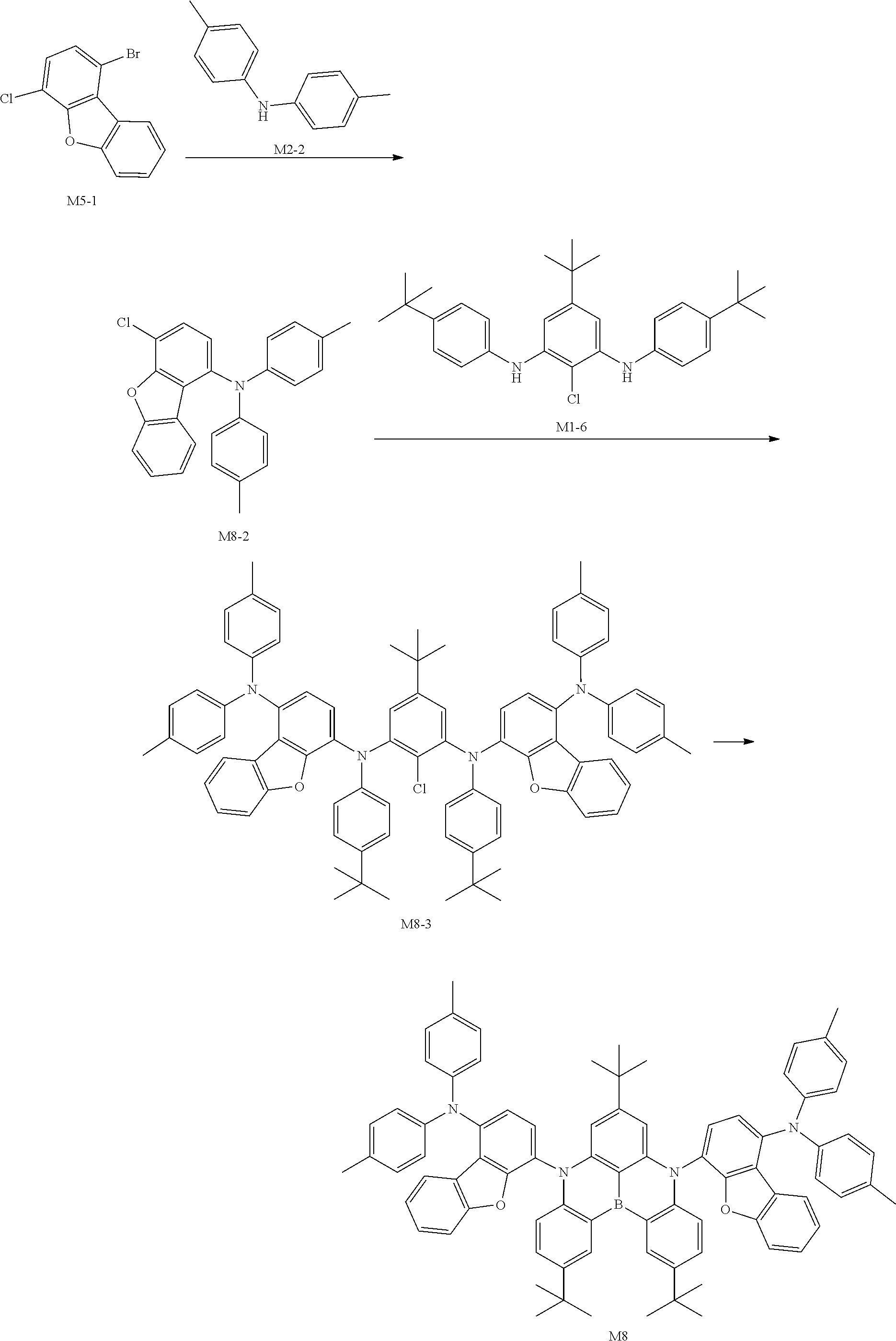

Specific synthesis steps of the organic compound M8 are as following:

1) Synthesis of intermediate M8-2: according to the synthesis method of the intermediate M1-3, the compound M5-1 and the compound M2-2 were substituted for the compound M1-1 and the compound M1-2 respectively to obtain the intermediate M8-2 with yield of 76%.

2) Synthesis of intermediate M8-3: according to the synthesis method of the intermediate M2-4, the intermediate M8-2 was substituted for the intermediate 2-3 respectively to obtain the intermediate M8-3 with yield of 70%.

3) Synthesis of the organic compound M8: according to the synthesis method of the organic compound M1, the intermediate M8-3 was substituted for the intermediate M1-9 to obtain the organic compound M8 with yield of 26%. A result of ASAP-MS of the organic compound M8 was as following: MS (ASAP)=1160.

### EXAMPLE 9

Synthesis of Organic Compound M9

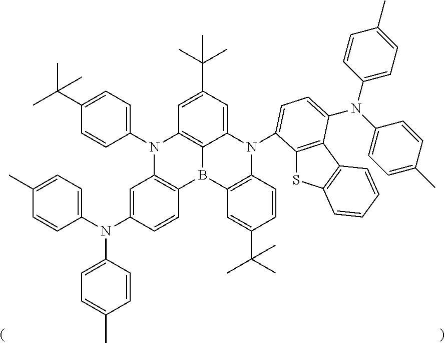

Synthetic Route of the Organic Compound M9 is as following:

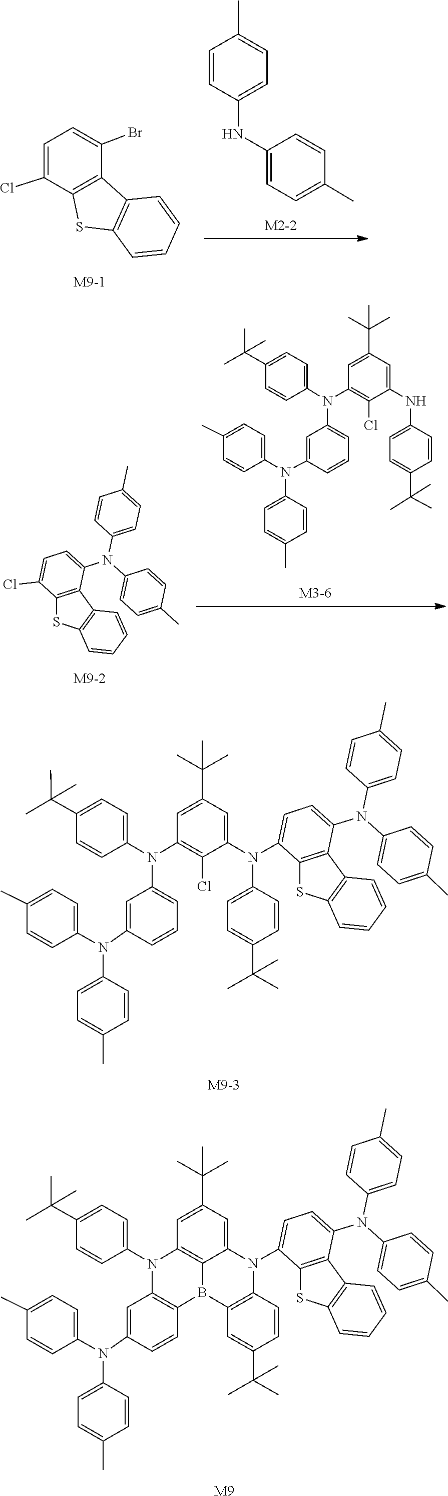

Specific synthesis steps of the organic compound M9 are as following:

1) Synthesis of intermediate M9-2: according to the synthesis method of the intermediate M1-3, compound M9-1 and the compound M2-2 were substituted for the compound M1-1 and the compound M1-2 respectively to obtain the intermediate M9-2 with yield of 75%.

2) Synthesis of intermediate M9-3: according to the synthesis method of the intermediate M1-9, the intermediate M9-2 and the intermediate M3-6 were substituted for the intermediate M1-3 and the intermediate 1-8 respectively to obtain the intermediate M9-3 with yield of 66%.

3) Synthesis of the organic compound M9: according to the synthesis method of the organic compound M1, the intermediate M9-3 was substituted for the intermediate M1-9 to obtain the organic compound M9 with yield of 27%. A result of ASAP-MS of the organic compound M9 was as following: MS (ASAP)=1086.

### EXAMPLE 10

Synthesis of Organic Compound M10

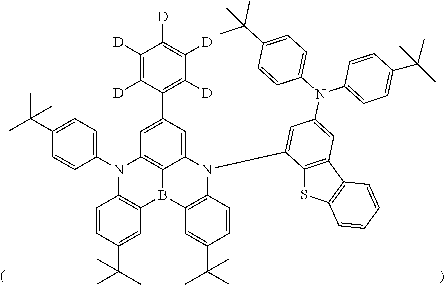 [SMILES: [2H]c1c([2H])c([2H])c(-c2cc3c4c(c2)N(c2cc(N(c5ccc(C(C)(C)C)cc5)c5ccc(C(C)(C)C)cc5)cc5c2sc2ccccc25)c2ccc(C(C)(C)C)cc2B4c2cc(C(C)(C)C)ccc2N3c2ccc(C(C)(C)C)cc2)c([2H])c1[2H]]

Synthetic Route of the Organic Compound M10 is as following:

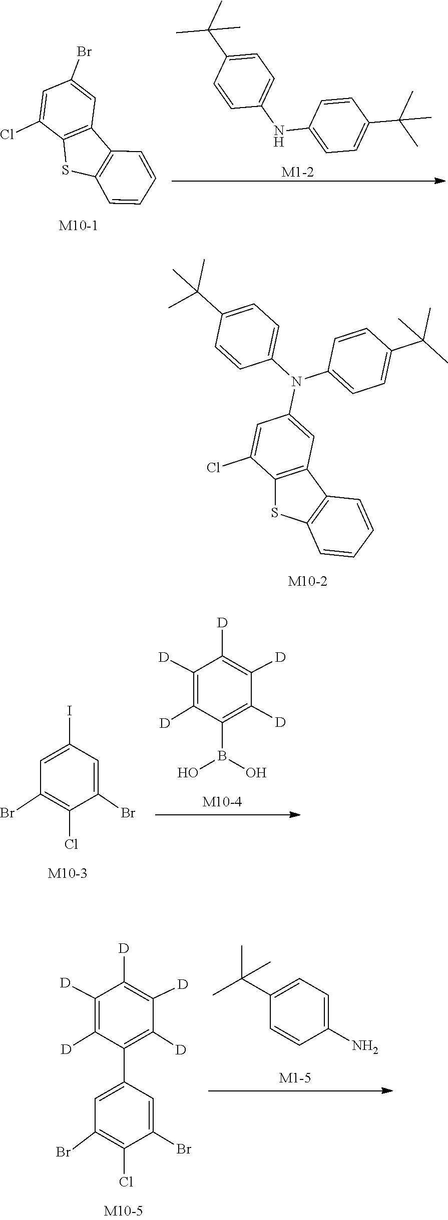

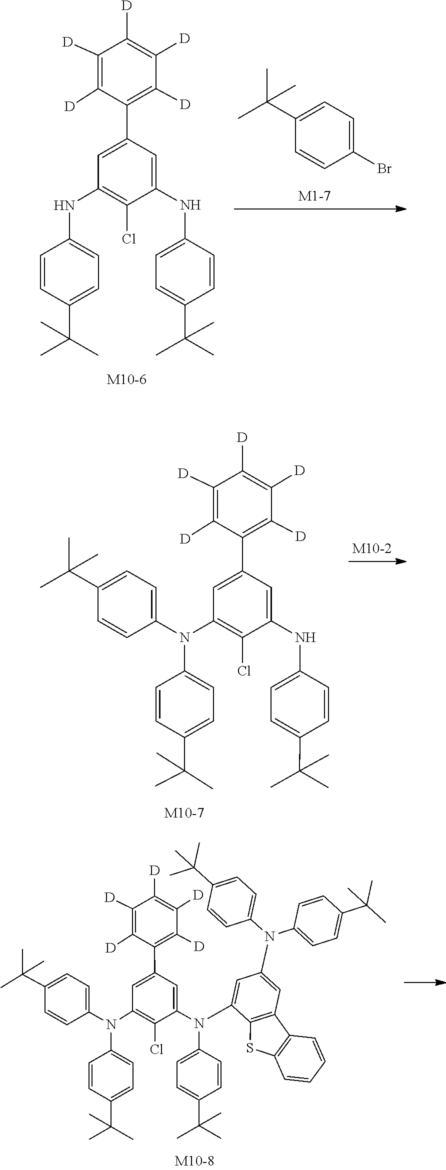

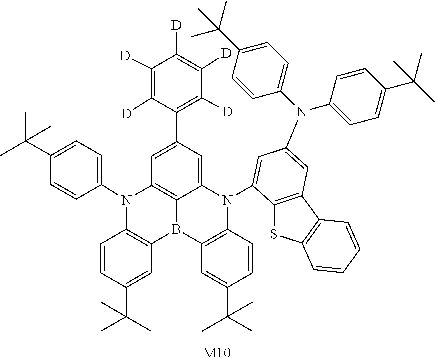

Specific synthesis steps of the organic compound M10 are as following:

1) Synthesis of intermediate M10-2: according to the synthesis method of the intermediate M1-3, compound M10-1 was substituted for the compound M1-1 to obtain the intermediate M10-2 with yield of 72%.

2) Synthesis of intermediate M10-5: in a nitrogen atmosphere, 39.6 g (100 mmol) of compound M10-3, 12.7 g (100 mmol) of compound M10-4, 3.3 g (3 mmol) of tetrakis (triphenylphosphine) palladium, 40 mL of aqueous solution of 20.6 g (150 mmol) of potassium carbonate, and 200 mL of toluene were added to a three neck-flask (500 mL). Then, the solution was heated and stirred to a temperature of 110° C.for 12 hours. After the reaction was completed, the solution was cooled to room temperature. Then, the filtrate was filtered by suction, and was collected. The reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M10-5 with yield of 70%.

3) Synthesis of intermediate M10-6: according to the synthesis method of the intermediate M1-6, the intermediate M10-5 was substituted for the compound M1-4 to obtain the intermediate M10-6 with yield of 61%.

4) Synthesis of intermediate M10-7: according to the synthesis method of the intermediate M1-8, the intermediate M10-6 was substituted for the intermediate M1-6 to obtain the intermediate M10-7 with yield of 54%.

5) Synthesis of intermediate M10-8: according to the synthesis method of the intermediate M1-9, the intermediate M10-2 and the intermediate M10-7 were substituted for the intermediate M1-3 and the intermediate 1-8 respectively to obtain the intermediate M10-8 with yield of 63%.

6) Synthesis of the organic compound M10: according to the synthesis method of the organic compound M1, the intermediate M10-8 was substituted for the intermediate M1-9 to obtain the organic compound M10 with yield of 26%. A result of ASAP-MS of the organic compound M10 was as following: MS (ASAP)=1055.

### EXAMPLE 11

Synthesis of Organic Compound M11

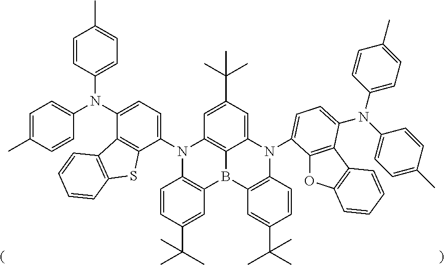

Synthetic Route of the Organic Compound M11 is as following:

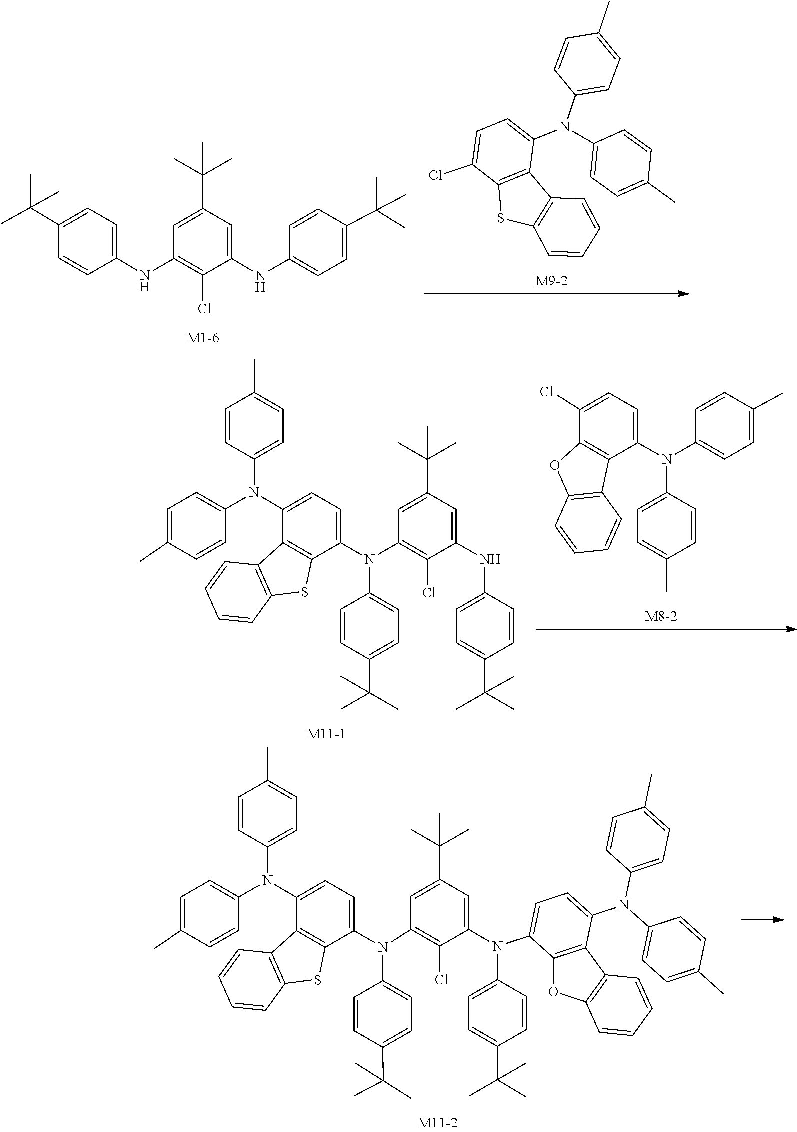

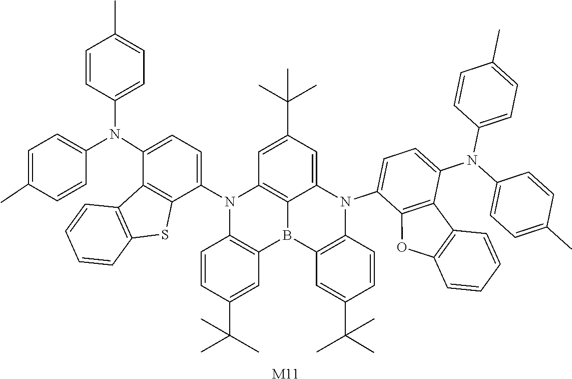

Specific synthesis steps of the organic compound M11 are as following:

1) Synthesis of intermediate M11-1: according to the synthesis method of the intermediate M1-8, the intermediate M9-2 was substituted for the compound M1-7 to obtain the intermediate M11-1 with yield of 52%.

2) Synthesis of intermediate M11-2: according to the synthesis method of the intermediate M1-9, the intermediate M8-2 and the intermediate M11-1 were substituted for the intermediate M1-3 and the intermediate 1-8 respectively to obtain the intermediate M11-2 with yield of 62%.

3) Synthesis of the organic compound M11: according to the synthesis method of the organic compound M1, the intermediate M11-2 was substituted for the intermediate M1-9 to obtain the organic compound M11 with yield of 25%. A result of ASAP-MS of the organic compound M11 was as following: MS (ASAP)=1176.

### EXAMPLE 12

Synthesis of Organic Compound M12

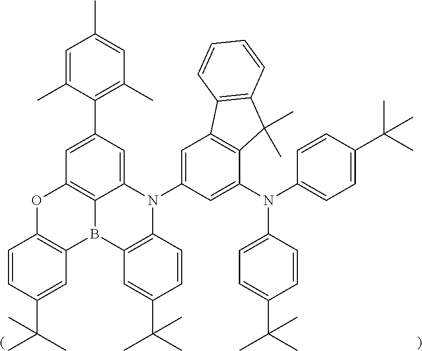 [SMILES: Cc1cc(C)c(-c2cc3c4c(c2)N(c2cc5c(c(N(c6ccc(C(C)(C)C)cc6)c6ccc(C(C)(C)C)cc6)c2)C(C)(C)c2ccccc2-5)c2ccc(C(C)(C)C)cc2B4c2cc(C(C)(C)C)ccc2O3)c(C)c1]

Synthetic Route of the Organic Compound M12 is as following:

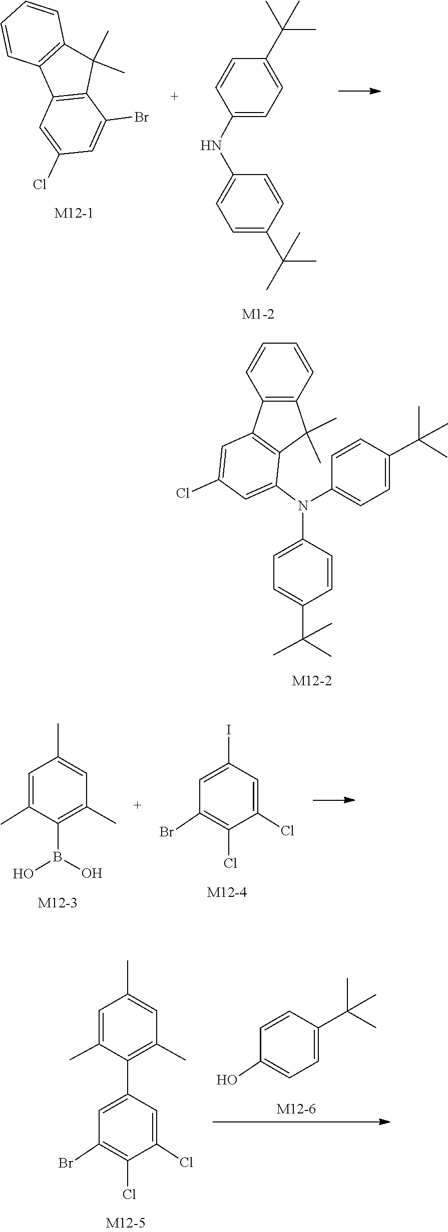

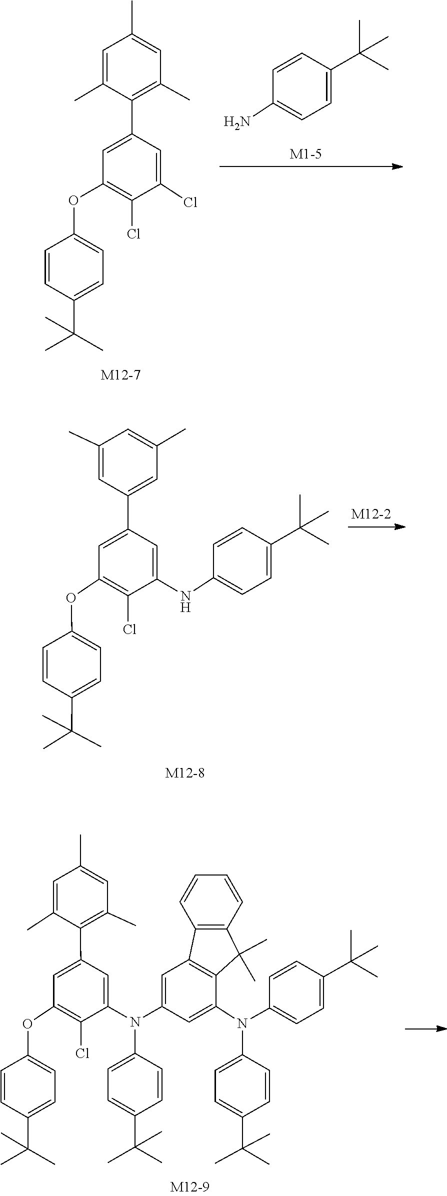 [SMILES: Cc1cc(C)c(-c2cc(Cl)c(Cl)c(Oc3ccc(C(C)(C)C)cc3)c2)c(C)c1 ; CC(C)(C)c1ccc(N)cc1 ; Cc1cc(C)cc(-c2cc(Nc3ccc(C(C)(C)C)cc3)c(Cl)c(Oc3ccc(C(C)(C)C)cc3)c2)c1 ; Cc1cc(C)c(-c2cc(Oc3ccc(C(C)(C)C)cc3)c(Cl)c(N(c3ccc(C(C)(C)C)cc3)c3cc4c(c(N(c5ccc(C(C)(C)C)cc5)c5ccc(C(C)(C)C)cc5)c3)C(C)(C)c3ccccc3-4)c2)c(C)c1]

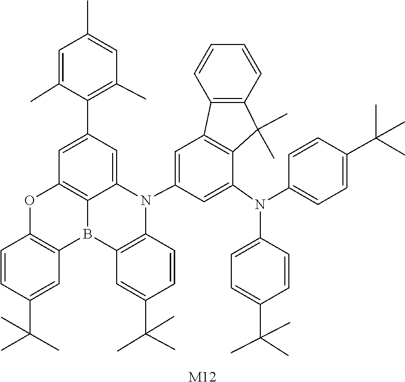

Specific synthesis steps of the organic compound M12 are as following:

1) Synthesis of intermediate M12-2: according to the synthesis method of the intermediate M1-3, compound M12-1 was substituted for the compound M1-1 to obtain the intermediate M12-2 with yield of 70%.

2) Synthesis of intermediate M12-5: according to the synthesis method of the intermediate M10-5, compound M12-3 and compound M12-4 were substituted for the compound M10-4 and the compound 10-3 respectively to obtain the intermediate M12-5 with yield of 66%.

3) Synthesis of intermediate M12-7: in a nitrogen atmosphere, 20.6 g (60 mmol) of the intermediate M12-5, 9 g (60 mmol) of compound M12-6, 0.57 g (3 mmol) of CuI, 13.8 g (100 mmol) of potassium carbonate, and 150 mL of dimethylformamide were added into a two neck-flask (500 mL). The solution was heated to a temperature of 110° C., and was stirred for 12 hours. Then, the solution was cooled to room temperature. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M12-7 with yield of 62%.

4) Synthesis of intermediate M12-8: in a nitrogen atmosphere, 12.4 g (30 mmol) of the intermediate M12-7, 4.5 g (30 mmol) of the compound M1-5, 1.66 g (1.8 mmol) of Pd₂(dba)₃, 0.72 g (3.6 mmol) of tri tertbutyl phosphine, 5.5 g (60 mmol) of sodium tertbutyl alcohol, and 100 mL of anhydrous toluene were added into a two neck-flask (350 mL). The solution was heated to a temperature of 90° C., and was stirred for 6 hours. Then, the solution was cooled to room temperature, and water was added to quench the reaction. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M12-8 with yield of 65%.

5) Synthesis of intermediate M12-9: according to the synthesis method of the intermediate M1-9, the intermediate M12-2 and the intermediate M12-8 were substituted for the intermediate M1-3 and the intermediate 1-8 respectively to obtain the intermediate M12-9 with yield of 64%.

6) Synthesis of the organic compound M12: according to the synthesis method of the organic compound M1, the intermediate M12-9 was substituted for the intermediate M1-9 to obtain the organic compound M12 with yield of 31%. A result of ASAP-MS of the organic compound M12 was as following: MS (ASAP)=971.

### EXAMPLE 13

Synthesis of Organic Compound M13

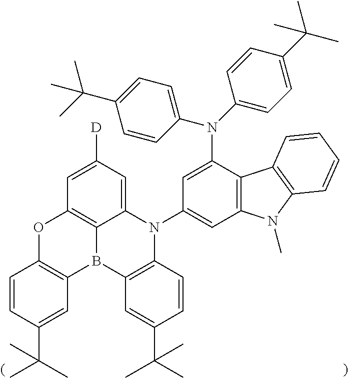 [SMILES: [2H]c1cc2c3c(c1)N(c1cc(N(c4ccc(C(C)(C)C)cc4)c4ccc(C(C)(C)C)cc4)c4c5ccccc5n(C)c4c1)c1ccc(C(C)(C)C)cc1B3c1cc(C(C)(C)C)ccc1O2]

Synthetic Route of the Organic Compound M13 is as following:

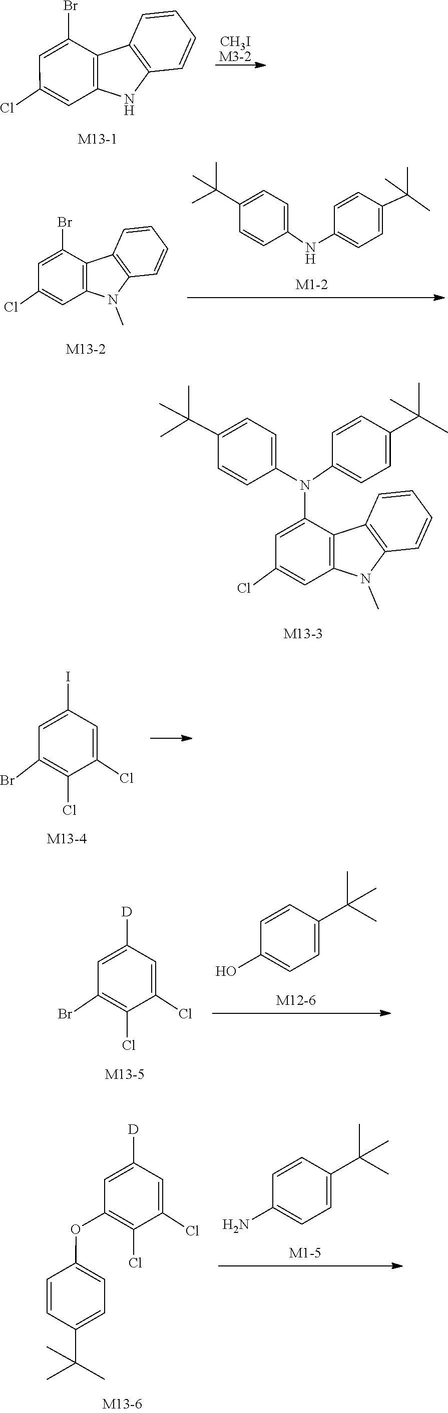

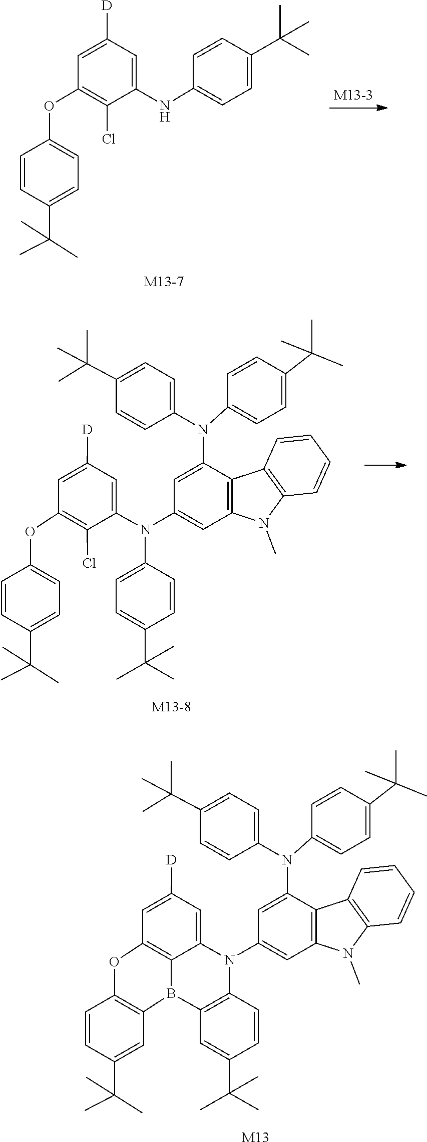

Specific synthesis steps of the organic compound M13 are as following:

1) Synthesis of intermediate M13-2: according to the synthesis method of the intermediate M3-3, compound M13-1 was substituted for the compound M3-1 to obtain the intermediate M13-2 with yield of 80%.

2) Synthesis of intermediate M13-3: according to the synthesis method of the intermediate M1-3, the intermediate M13-2 was substituted for the compound M1-1 to obtain the intermediate M13-3 with yield of 72%.

3) Synthesis of intermediate M13-5: in a nitrogen atmosphere, 35.2 g (100 mmol) of compound M13-4 and 100 mL of anhydrous tetrahydrofuran were added into a three neck-flask (500 mL), and the solution was stirred to dissolve it. Then, the solution was cooled to a temperature of −78° C., 100 mmol of n-butyl lithium was slowly add into the solution, and the reaction lasted for 2 hours. 150 mmol of deuterium instead of water was added into the solution at once. Then, a temperature of the reaction solution was slowly raised to room temperature, and the reaction solution was continuously stirred for 4 hours. After the reaction was completed, the reaction solution was rotationally evaporated to remove most of the solvent, and was dissolved with dichloromethane. Then, the mixture was washed with water for 3 times. The organic solution was collected, and then was stirred with silica gel. The product was purified by column chromatography to obtain the intermediate M13-5 with yield of 67%.

4) Synthesis of intermediate M13-6: according to the synthesis method of the intermediate M12-7, the intermediate M13-5 was substituted for the intermediate M12-5 to obtain the intermediate M13-6 with yield of 62%.

5) Synthesis of intermediate M13-7: according to the synthesis method of the intermediate M12-8, the intermediate M13-6 was substituted for the intermediate M12-7 to obtain the intermediate M13-7 with yield of 66%.

6) Synthesis of intermediate M13-8: according to the synthesis method of the intermediate M1-9, the intermediate M13-3 and the intermediate M13-7 were substituted for the compound M1-3 and the compound 1-8 respectively to obtain the intermediate M13-8 with yield of 63%.

7) Synthesis of the organic compound M13: according to the synthesis method of the organic compound M1, the intermediate M13-8 was substituted for the intermediate M1-9 to obtain the organic compound M13 with yield of 32%. A result of ASAP-MS of the organic compound M13 was as following: MS (ASAP)=841.

### EXAMPLE 14

Synthesis of Organic Compound M14

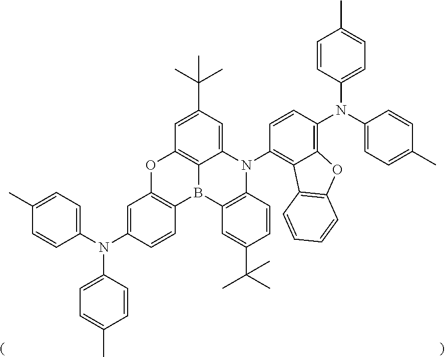

Synthetic Route of the Organic Compound M14 is as following:

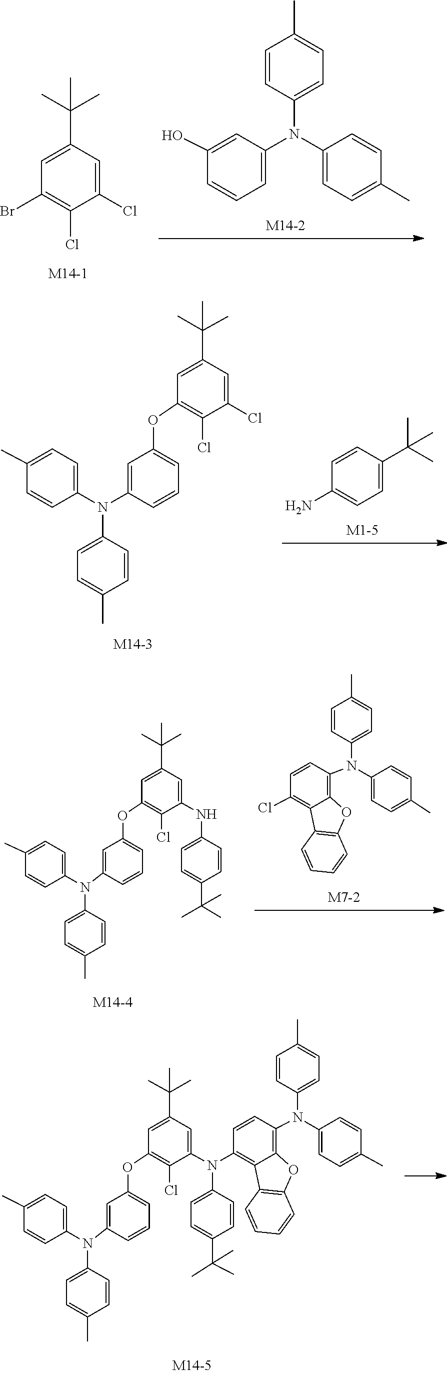

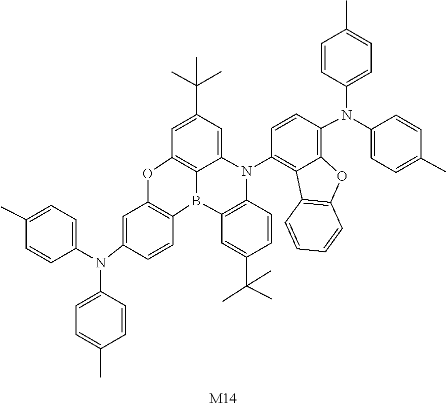

Specific synthesis steps of the organic compound M14 are as following:

1) Synthesis of intermediate M14-3: according to the synthesis method of the intermediate M12-7, compound M14-1 and compound M14-2 were substituted for the intermediate M12-5 and the compound M12-6 respectively to obtain the intermediate M14-3 with yield of 64%.

2) Synthesis of intermediate M14-4: according to the synthesis method of the intermediate M12-8, the intermediate M14-3 was substituted for the intermediate M12-7 to obtain the intermediate M14-4 with yield of 64%.

3) Synthesis of intermediate M14-5: according to the synthesis method of the intermediate M1-9, the intermediate M7-2 and the intermediate M14-4 were substituted for the intermediate M1-3 and the intermediate 1-8 respectively to obtain the intermediate M14-5 with yield of 65%.

4) Synthesis of the organic compound M14: according to the synthesis method of the organic compound M1, the intermediate M14-5 was substituted for the intermediate M1-9 to obtain the organic compound M14 with yield of 31%. A result of ASAP-MS of the organic compound M14 was as following: MS (ASAP)-938.

### EXAMPLE 15

Synthesis of Organic Compound M15

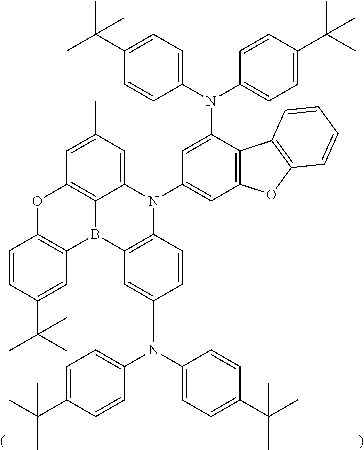 [SMILES: Cc1cc2c3c(c1)N(c1cc(N(c4ccc(C(C)(C)C)cc4)c4ccc(C(C)(C)C)cc4)c4c(c1)oc1ccccc14)c1ccc(N(c4ccc(C(C)(C)C)cc4)c4ccc(C(C)(C)C)cc4)cc1B3c1cc(C(C)(C)C)ccc1O2]

Synthetic Route of the Organic Compound M15 is as following:

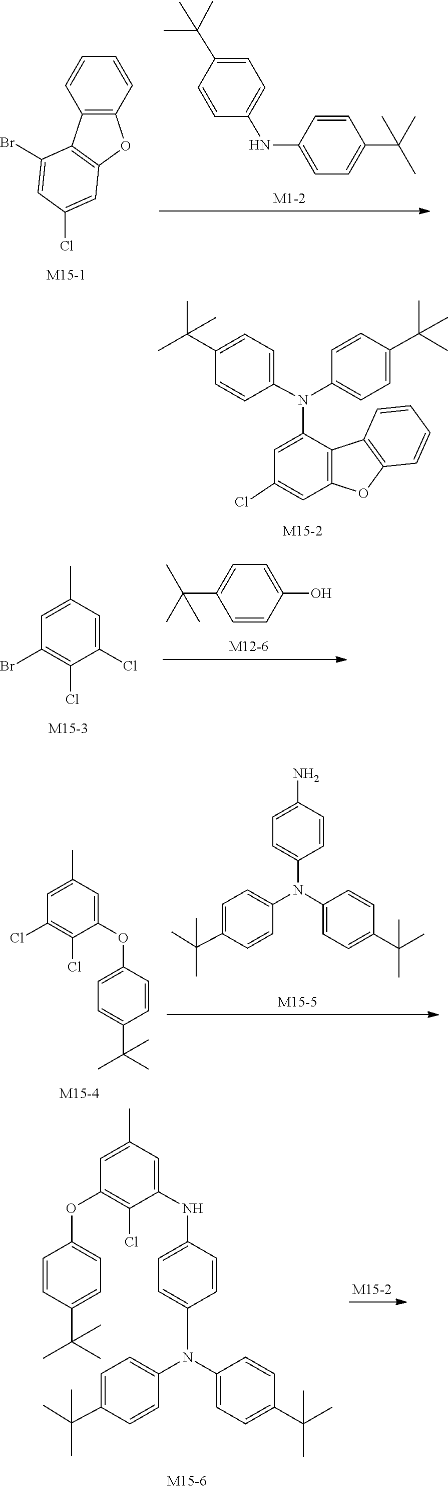

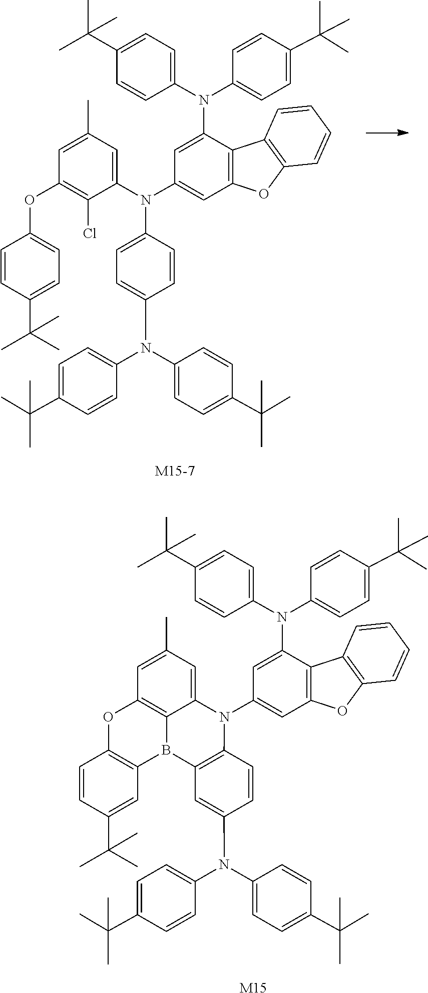

Specific synthesis steps of the organic compound M15 are as following:

1) Synthesis of intermediate M15-2: according to the synthesis method of the intermediate M1-3, compound M15-1 was substituted for the compound M1-1 to obtain the intermediate M15-2 with yield of 73%.

2) Synthesis of intermediate M15-4: according to the synthesis method of the intermediate M12-7, compound M15-3 was substituted for the intermediate M12-5 to obtain the intermediate M15-4 with yield of 65%.

3) Synthesis of intermediate M15-6: according to the synthesis method of the intermediate M12-8, the intermediate M15-4 and compound M15-5 were substituted for the intermediate M12-7 and the compound M1-5 respectively to obtain the intermediate M15-6 with yield of 67%.

4) Synthesis of intermediate M15-7: according to the synthesis method of the intermediate M1-9, the intermediate M15-2 and the intermediate M15-6 were substituted for the intermediate M1-3 and the intermediate M1-8 respectively to obtain the intermediate M15-7 with yield of 68%.

5) Synthesis of the organic compound M15: according to the synthesis method of the organic compound M1, the intermediate M15-7 was substituted for the intermediate M1-9 to obtain the organic compound M15 with yield of 33%. A result of ASAP-MS of the organic compound M15 was as following: MS (ASAP)=1064.

### EXAMPLE 16

Synthesis of Organic Compound M16

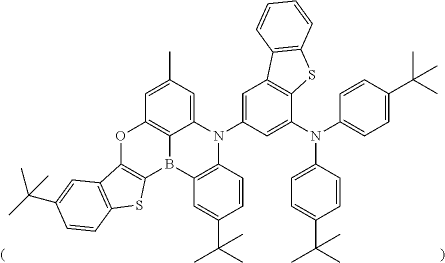 [SMILES: Cc1cc2c3c(c1)N(c1cc(N(c4ccc(C(C)(C)C)cc4)c4ccc(C(C)(C)C)cc4)c4sc5ccccc5c4c1)c1ccc(C(C)(C)C)cc1B3c1sc3ccc(C(C)(C)C)cc3c1O2]

Synthetic Route of the Organic Compound M16 is as following:

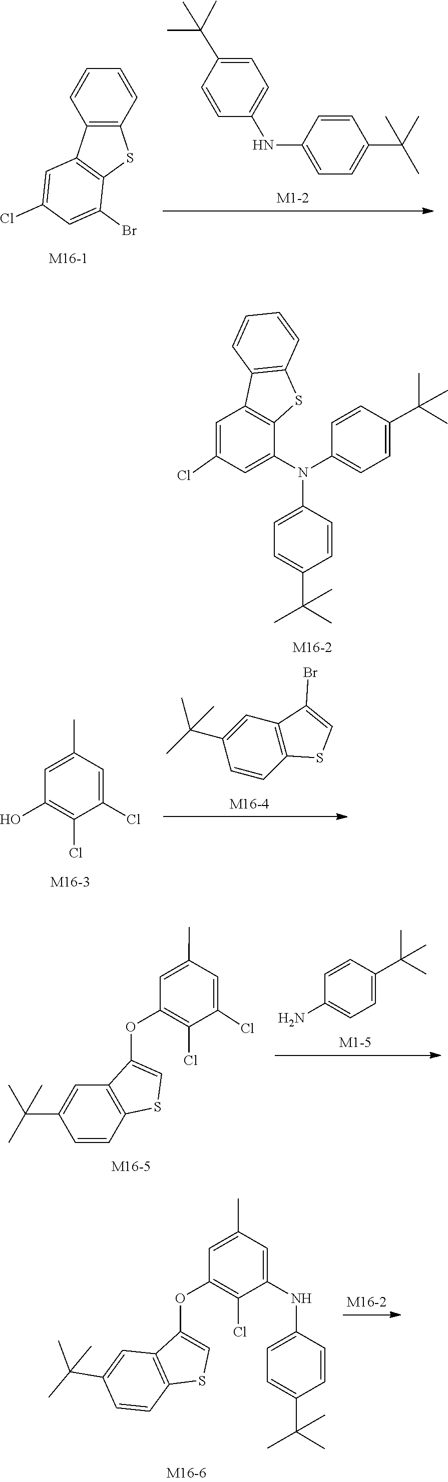

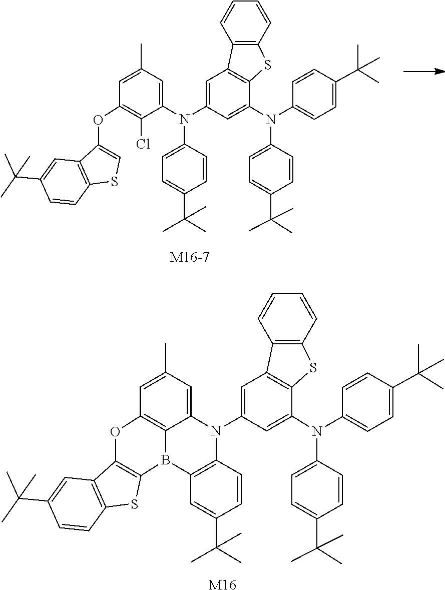

Specific synthesis steps of the organic compound M16 are as following:

1) Synthesis of intermediate M16-2: according to the synthesis method of the intermediate M1-3, compound M16-1was substituted for the compound M1-1 to obtain the intermediate M16-2 with yield of 72%.

2) Synthesis of intermediate M16-5: according to the synthesis method of the intermediate M12-7, compound M16-3 and compound M16-4 were substituted for the compound M12-6 and the intermediate M12-5 to obtain the intermediate M16-5 with yield of 67%.

3) Synthesis of intermediate M16-6: according to the synthesis method of the intermediate M12-8, the intermediate M16-5 was substituted for the intermediate M12-7 to obtain the intermediate M16-6 with yield of 62%.

4) Synthesis of intermediate M16-7: according to the synthesis method of the intermediate M1-9, the intermediate M16-2 and the intermediate M16-6 were substituted for the intermediate M1-3 and the intermediate M1-8 respectively to obtain the intermediate M16-7 with yield of 64%.

5) Synthesis of the organic compound M16: according to the synthesis method of the organic compound M1, the intermediate M16-7 was substituted for the intermediate M1-9 to obtain the organic compound M16 with yield of 33%. A result of ASAP-MS of the organic compound M16 was as following: MS (ASAP)=913.

Exemplary manufacturing steps of the light-emitting elements provided by the examples are shown in following exemplary example 17.

### EXAMPLE 17

In the example, the manufacturing steps of the light-emitting elements with the anode (with a material of ITO)/the hole injection layer (with a thickness of 40 nm)/the hole transport layer (with a thickness of 100 nm)/the light-emitting layer (a mass ratio of a host material to a guest material is 1:3, with a thickness of 50 nm)/the electron transport layer (with a thickness of 25 nm)/the cathode ((a LiQ layer) (with a thickness of 1 nm)/a A1 layer (with a thickness of 150 nm)) are as following:

a, a conductive glass substrate was cleaned: a variety of solvents may be used for cleaning, such as chloroform, ketone, and isopropyl alcohol, and then performing an ultraviolet ozone plasma treatment;

b, in a high vacuum atmosphere (1×10⁻⁶ mbar), the hole injection layer (with the thickness of 40 nm), the hole transport layer (with the thickness of 100 nm), the light-emitting layer (with the thickness of 50 nm), and the electron transport layer (with the thickness of 25 nm) were formed by hot evaporation in sequence;

c, the cathode with the LiQ layer (with the thickness of 1 nm)/the A1 layer (with the thickness of 150 nm) was formed by hot evaporation in a high vacuum atmosphere (1×10⁻⁶ mbar); and

d, the elements were encapsulated: the elements were encapsulated with UV curing resin in a nitrogen glove box.

In the example, the guest materials are the organic compounds M1 to M16 to form light-emitting elements 1 to 16, and a guest material is Ref-1 to form a comparative element 1.

A structural formula of the Ref-1 is

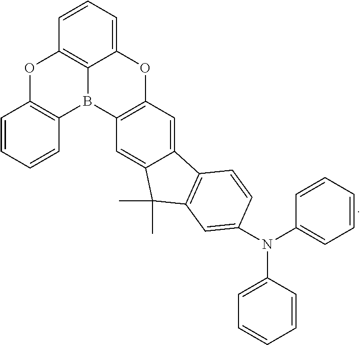 [SMILES: CC1(C)c2cc(N(c3ccccc3)c3ccccc3)ccc2-c2cc3c(cc21)B1c2ccccc2Oc2cccc(c21)O3]

In the light-emitting elements 1 to 16 and the comparative element 1,

a structural formula of a material of the hole injection layer is

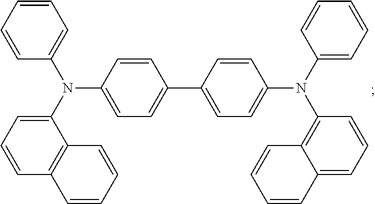 [SMILES: c1ccc(N(c2ccc(-c3ccc(N(c4ccccc4)c4cccc5ccccc45)cc3)cc2)c2cccc3ccccc23)cc1]

a structural formula of a material of the hole transport layer is

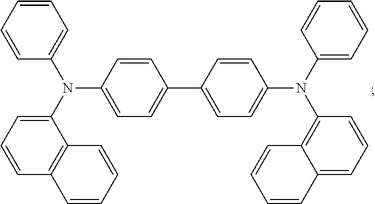 [SMILES: c1ccc(N(c2ccc(-c3ccc(N(c4ccccc4)c4cccc5ccccc45)cc3)cc2)c2cccc3ccccc23)cc1]

a structural formula of a host material in the light-emitting layer is

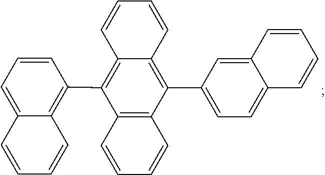 [SMILES: c1ccc2cc(-c3c4ccccc4c(-c4cccc5ccccc45)c4ccccc34)ccc2c1]

a structural formula of a material of the electronic transport layer is

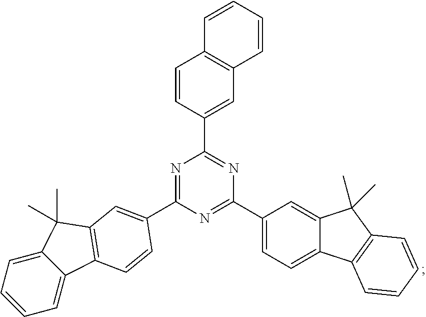 [SMILES: CC1(C)c2ccccc2-c2ccc(-c3nc(-c4ccc5c(c4)C(C)(C)c4ccccc4-5)nc(-c4ccc5ccccc5c4)n3)cc21]

and

a structural formula of the LiQ is

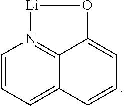

In the example, external quantum efficiency (EQE) and luminous life of the light-emitting elements 1 to 16 and the comparative element 1 are tested (T90@1000 nits, refers to a time when the element to be tested decays from 1000 nits to 900 nits), and the results are shown in table 1.

TABLE 1

| OLED element | Gust material | EQE | T90@1000nits |
|---|---|---|---|
| Example 1 | M1 | 1.63 | 1.71 |
| Example 2 | M2 | 1.66 | 1.77 |
| Example 3 | M3 | 1.65 | 1.75 |
| Example 4 | M4 | 1.64 | 1.73 |
| Example 5 | M5 | 1.73 | 1.85 |
| Example 6 | M6 | 1.72 | 1.83 |
| Example 7 | M7 | 1.75 | 1.86 |
| Example 8 | M8 | 1.76 | 1.88 |
| Example 9 | M9 | 1.68 | 1.78 |
| Example 10 | M10 | 1.69 | 1.80 |
| Example 11 | M11 | 1.70 | 1.81 |
| Example 12 | M12 | 1.57 | 1.64 |
| Example 13 | M13 | 1.58 | 1.66 |
| Example 14 | M14 | 1.61 | 1.70 |
| Example 15 | M15 | 1.60 | 1.68 |
| Example 16 | M16 | 1.55 | 1.63 |
| Comparative | Ref-1 | 1 | 1 |
| example 1 | | | |

It can be seen from table 1 that when the external quantum efficiency and luminous life of the comparative element 1 are taken as a reference value of 1, the external quantum efficiency of the light-emitting elements 1 to 16 is significantly improved, and the luminous life can further be effectively prolonged. It shows that an introduction of the amine group at a key site can enhance the resonance effect and space effect of the organic compound, improve performances of the guest material, and effectively improve the luminous efficiency and prolong luminous life of the light-emitting element.

In the light-emitting element disclosed in the embodiment of the present disclosure, by adopting the organic compound containing an amino group, the organic compound contains heterocyclic rings and the amino group at a same time. Therefore, a resonance effect of a material containing the organic compound used in the light-emitting element can be enhanced, thereby improving performances of the material, improving luminous efficiency of the light-emitting element, and prolonging luminous life of the light-emitting element.

An embodiment of the present disclosure further discloses a display panel. The display panel includes any of the above-mentioned light-emitting elements.

The display panel further includes an array substrate disposed on a side of the light-emitting element and an encapsulating layer disposed on a side of the light-emitting element away from the array substrate and covering the light-emitting element. The display panel further includes a polarizer layer located at a side of the encapsulating layer away from the light-emitting element and a cover plate layer located at a side of the polarizer layer away from the light-emitting element. The polarizer layer may be replaced by a color film layer. The color film layer may include a plurality of color resistors and black matrixes. The black matrix is located on both sides of the color resistor.

In the display panel disclosed in the embodiment of the present disclosure, by adopting the light-emitting element using the organic compound containing an amino group, the organic compound contains heterocyclic rings and the amino group at a same time. Therefore, a resonance effect of a material containing the organic compound used in the light-emitting element can be enhanced, thereby improving performances of the material, improving luminous efficiency of the light-emitting element, and prolonging luminous life of the light-emitting element.

Embodiments of the present disclosure discloses the organic compound, the light emitting element, and the display panel. The organic compound is represented by formula (1):

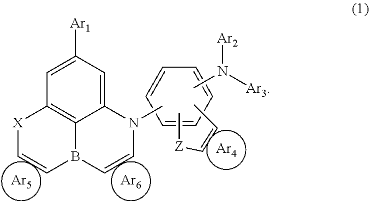

By adopting the organic compound containing an amino group, the organic compound contains heterocyclic rings and the amino group at a same time. Therefore, a resonance effect of a material containing the organic compound used in the light-emitting element can be enhanced, thereby improving performances of the material, improving luminous efficiency of the light-emitting element, and prolonging luminous life of the light-emitting element.

The organic compound, the light-emitting element, and the display panel provided by the embodiments of the present disclosure are described in detail. In this paper, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there will be changes in specific implementation modes and a scope of the present disclosure. In conclusion, contents of the specification should not be interpreted as a limitation of the present disclosure.

What is claimed is:

1. An organic compound represented by formula (1): 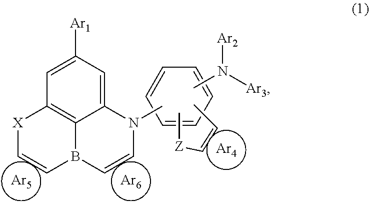
wherein Z is selected from CR₁R₂, NR₃, O, and S;
X is selected from O and NR₄;
R₁, R₂, R₃, and R₄ are each independently selected from a substituted or unsubstituted C₁-C₄ alkyl group, a substituted or unsubstituted C₆-C₂₉ aromatic group, and a substituted or unsubstituted C₂₆-C₃₆ heteroaromatic group;
a ring is formed or no ring is formed by an interconnection of R₁ and R₂;
Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group;
Ar₂ and Ar₃ are each independently selected from a methyl group, a substituted or unsubstituted C₇-C₁₈ aromatic group, and a substituted or unsubstituted C₁₂-C₁₆ heteroaromatic group; and
Ar₄, Ar₅, and Ar₆ are each independently selected from a substituted or unsubstituted C₆-C₃₁ aromatic group and a substituted or unsubstituted C₆-C₂₆ heteroaromatic group.

2. The organic compound of claim 1, wherein the organic compound is represented by any one of formula (2) to formula (11):

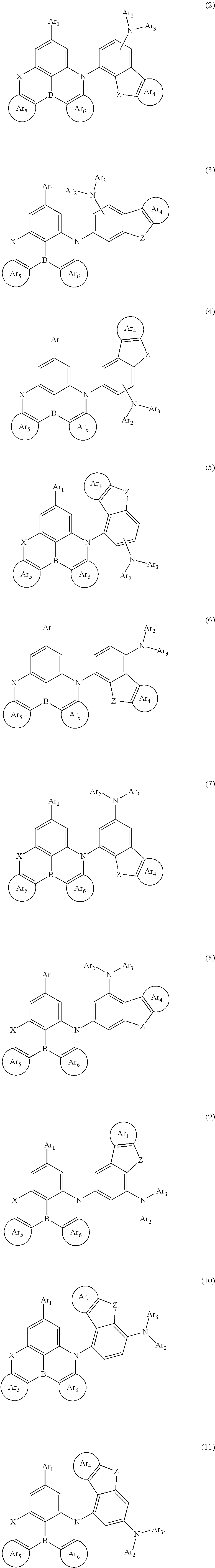

3. The organic compound of claim 1, wherein the organic compound is represented by formula (12): 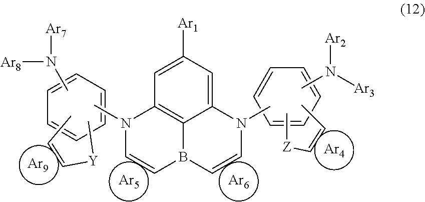
wherein Y is selected from CR₅R₆, NR₇, O, and S;
R₅, R₆, and R₇ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group;
a ring is formed or no ring is formed by an interconnection of R₅ and R₆;
Ar₇ and Ar₈, are each independently selected from a substituted or unsubstituted C₁-C₁₂ alkyl group, a substituted or unsubstituted C₆-C₂₀ aromatic group, and a substituted or unsubstituted C₅-C₂₀ heteroaromatic group; and
Ar₉ is selected from a substituted or unsubstituted C₆-C₂₀ aromatic group and a substituted or unsubstituted C₅-C₂₀ heteroaromatic group.

4. The organic compound of claim 1, wherein the organic compound is represented by formula (12): 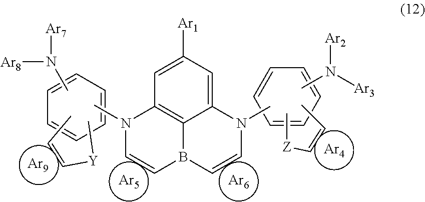
wherein Y is selected from CR₅R₆, NR₇, O, and S;
R₅, R₆, and R₇ are each independently selected from a substituted or unsubstituted methyl group and a substituted or unsubstituted C₆-C₁₀ aromatic group;
a ring is formed or no ring is formed by an interconnection of R₅ and R₆;
Ar₇ and Ar₈ are each independently selected from a substituted or unsubstituted C₆-C₁₀ aromatic group; and
Ar₉ is selected from a substituted or unsubstituted phenyl group.

5. The organic compound of claim 4, wherein R₅, R₆, and R₇ are each independently selected from a methyl group and a substituted or unsubstituted phenyl group;
Ar₇ and Ar₅, are each independently selected from a methyl group, a substituted or unsubstituted phenyl group, and a substituted or unsubstituted naphthyl group.

6. The organic compound of claim 1, wherein the organic compound is represented by formula (13): 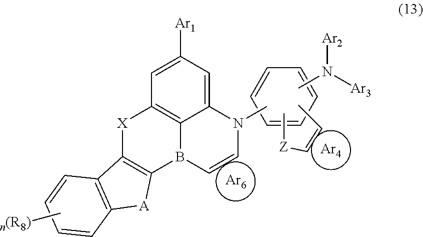
wherein A is represented by CR₉R₁₀, NR₁₁, O, or S;
n is an integer ranging from 0 to 4;
R₈, R₉, R₁₀, and R₁₁ are each independently selected from a substituted or unsubstituted C₁-C₂₀ alkyl group, a substituted or unsubstituted C₆-C₃₀ aromatic group, and a substituted or unsubstituted C₅-C₃₀ heteroaromatic group; and
when n is equal to 0, a ring is formed or no ring is formed by an interconnection of R₉ and R₁₀; when n is greater than or equal to 1, a ring is formed or no ring is formed by an interconnection of R₈ and R₉ and/or R₁₀.

7. The organic compound of claim 1, wherein the organic compound is represented by formula (13): 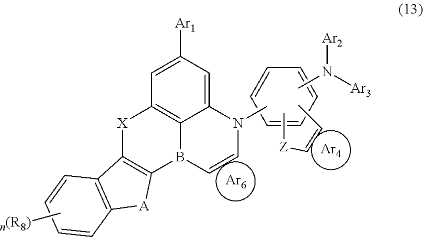
wherein A is represented by CR₉R₁₀, NR₁₁, O, or S;
n is an integer ranging from 0 to 4;
R₈, R₉, R₁₀, and R₁₁ are each independently selected from a substituted or unsubstituted C₁-C₄ alkyl group and a substituted or unsubstituted C₆-C₁₀ aromatic group; and
when n is equal to 0, a ring is formed or no ring is formed by an interconnection of R₉ and R₁₀; when n is greater than or equal to 1, a ring is formed or no ring is formed by an interconnection of R₈ and R₉ and/or R₁₀.

8. The organic compound of claim 1, wherein the organic compound is represented by formula (14): 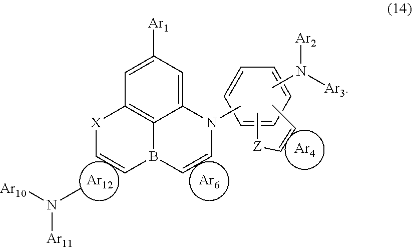
wherein Ar₁₀ and Ar₁₁ are each independently selected from a substituted or unsubstituted C₁-C₁₂ alkyl group, a substituted or unsubstituted C₆-C₂₄ aromatic group, and a substituted or unsubstituted C₅-C₂₄ heteroaromatic group; and
Ar₁₂ is selected from a substituted or unsubstituted phenyl group.

9. The organic compound of claim 1, wherein the organic compound is represented by formula (14): 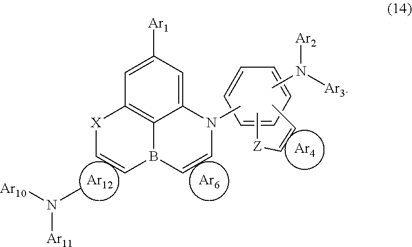
wherein Ar₁₀ and Ar₁₁ are each independently selected from a methyl group, a substituted or unsubstituted C₆-C₁₈ aromatic group, and a substituted or unsubstituted C₅-C₁₃ heteroaromatic group; and
Ar₁₂ is selected from a substituted or unsubstituted phenyl group.

10. The organic compound of claim 9, wherein Ar₁₀ and Ar₁₁ are each independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazole group.

11. The organic compound of claim 1, wherein Ar₁ is selected from —H, —D, a methyl group, an isopropyl group, a tertbutyl group, a tertamyl group, a substituted or unsubstituted phenyl group, a substituted or unsubstituted naphthyl group, a substituted or unsubstituted dibenzofuran, a substituted or unsubstituted dibenzothiophene, a substituted or unsubstituted fluorenyl group, a substituted or unsubstituted carbazolyl group, and a substituted or unsubstituted amino group;
Ar₂, Ar₃, Ar₄, Ar₅, and Ar₆ are each independently selected from a substituted or unsubstituted phenyl group, a substituted or unsubstituted naphthyl group, a substituted or unsubstituted triphenylene group, a substituted or unsubstituted dibenzofuran, a substituted or unsubstituted dibenzothiophene, a substituted or unsubstituted fluorenyl group, and a substituted or unsubstituted carbazolyl group; and
R₁, R₂, R₃, and R₄ are each independently selected from a methyl group and a substituted or unsubstituted phenyl group.

12. The organic compound of claim 1, wherein the organic compound is selected from following compounds:

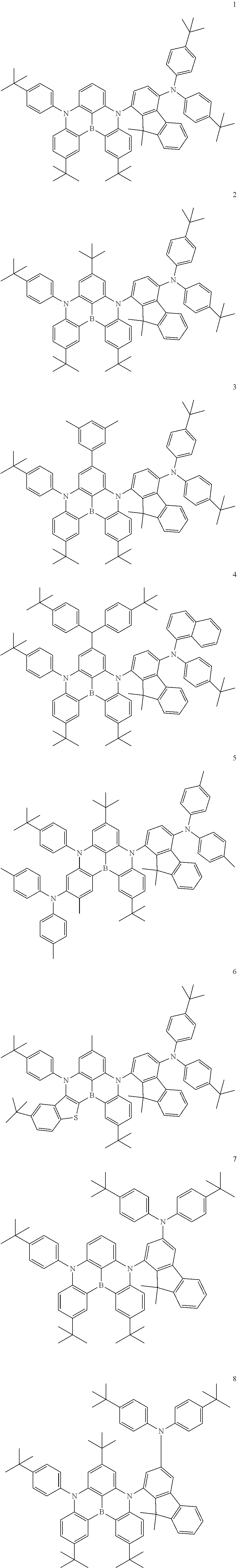

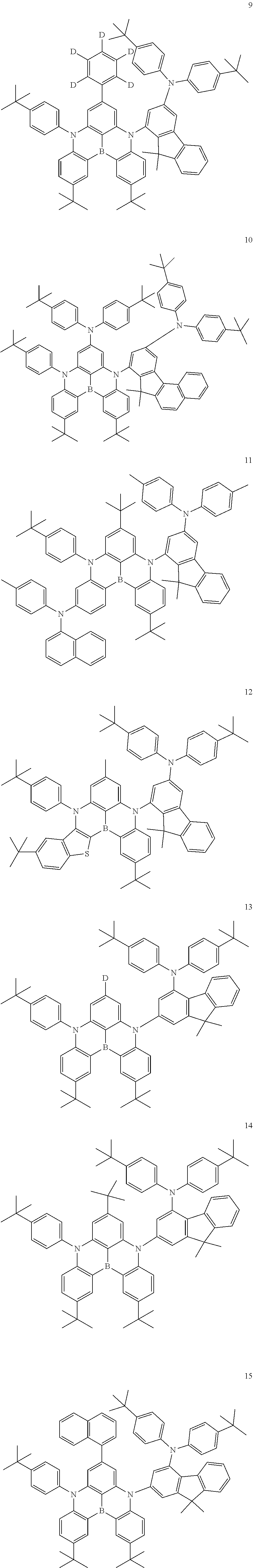

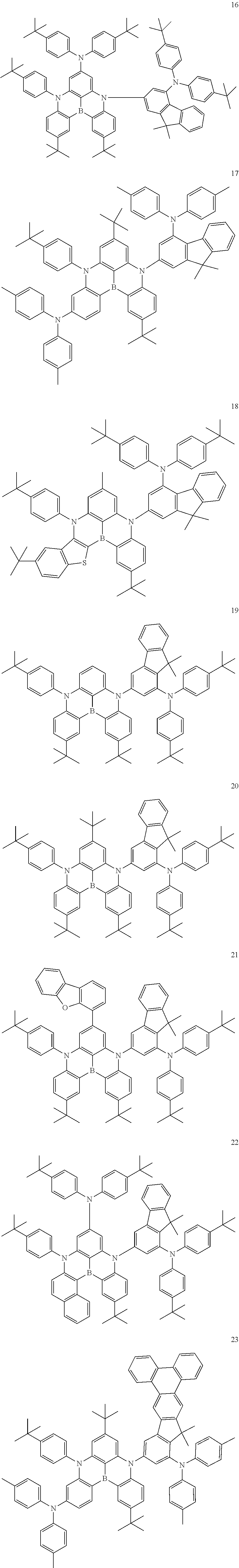

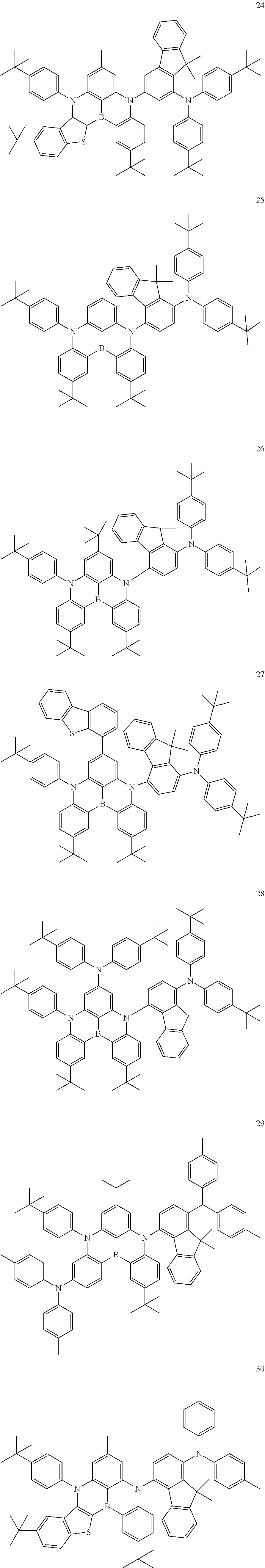

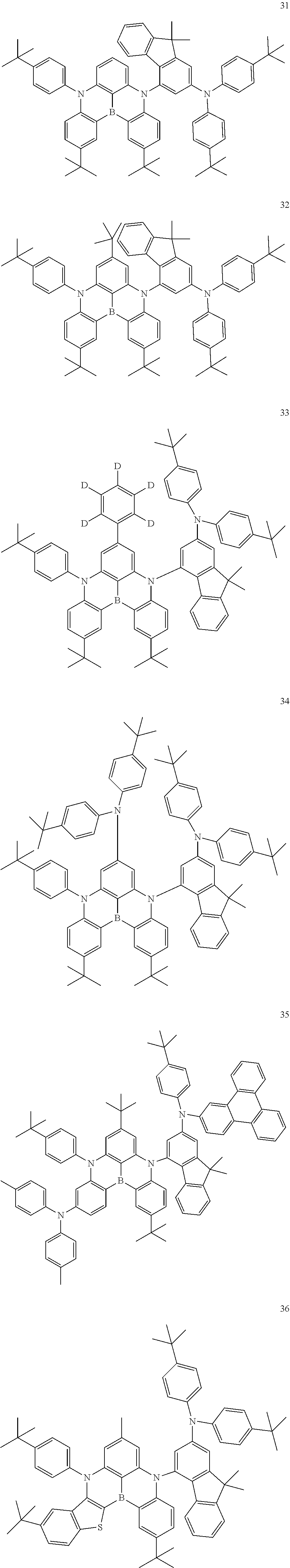

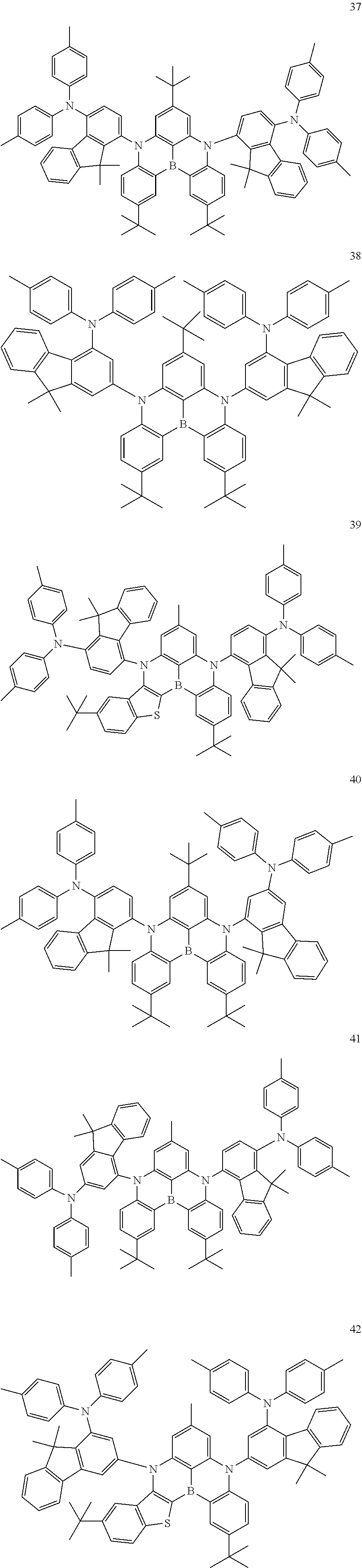

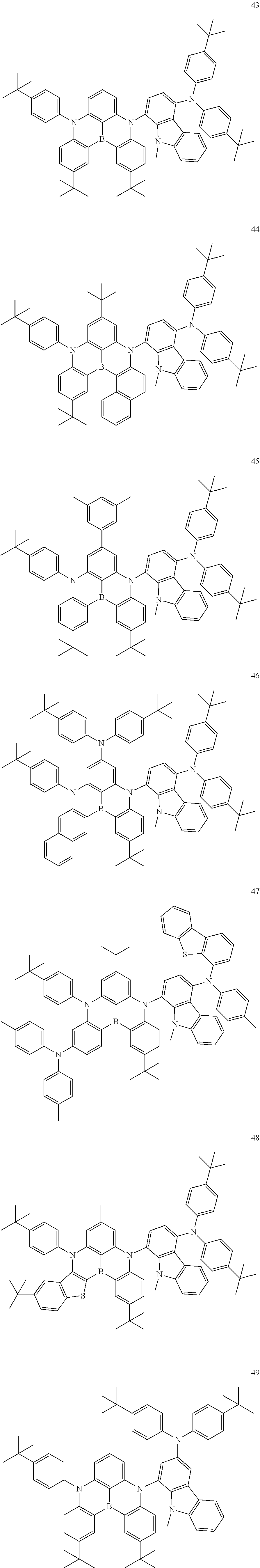

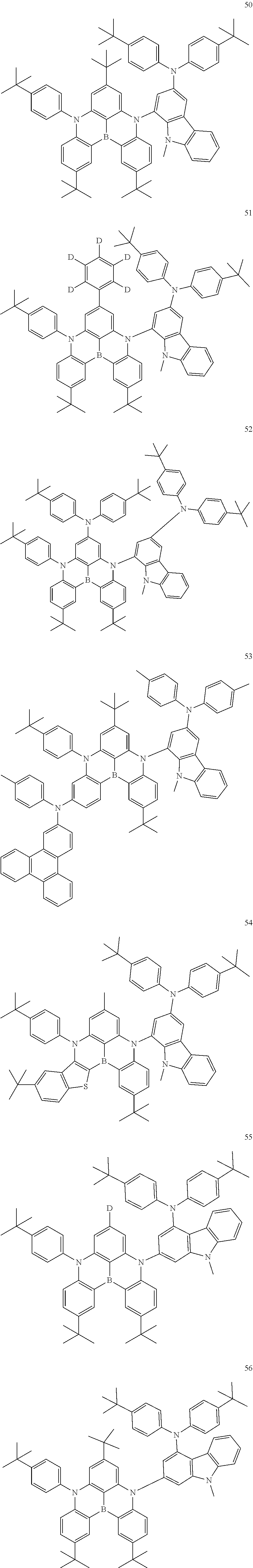

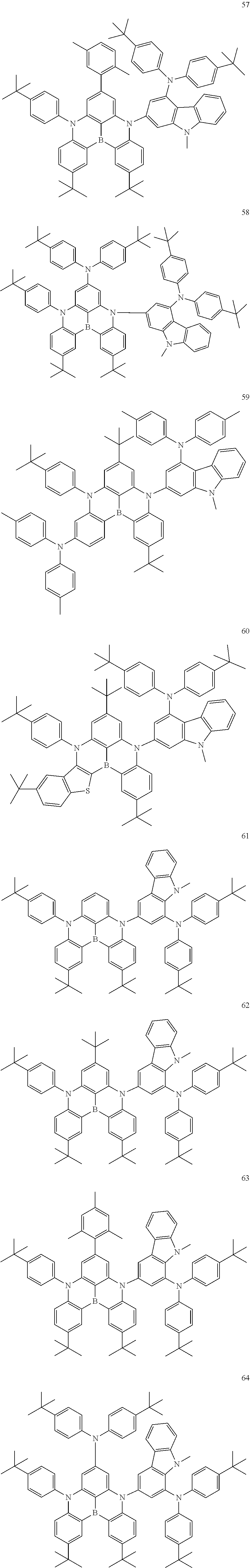

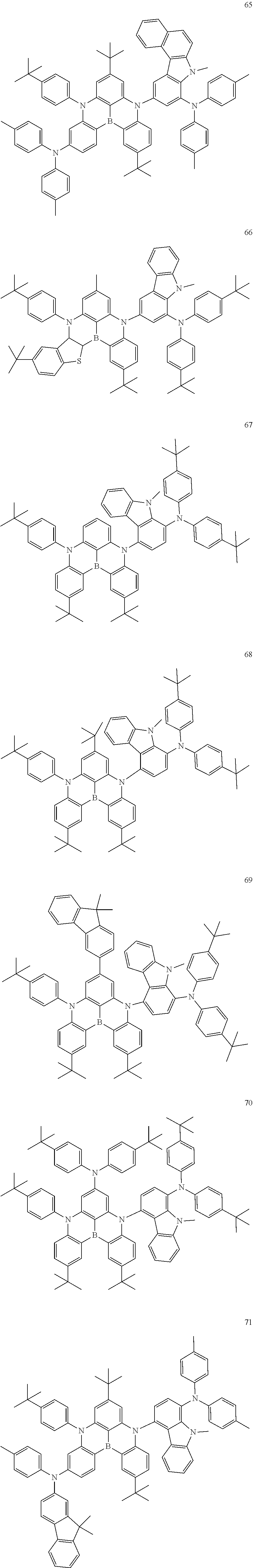

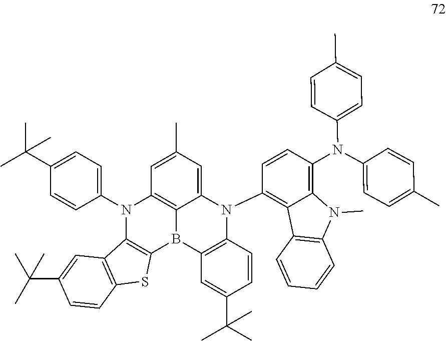 [SMILES: Cc1ccc(N(c2ccc(C)cc2)c2ccc(N3c4ccc(C(C)(C)C)cc4B4c5sc6ccc(C(C)(C)C)cc6c5N(c5ccc(C(C)(C)C)cc5)c5cc(C)cc3c54)c3c4ccccc4n(C)c23)cc1]

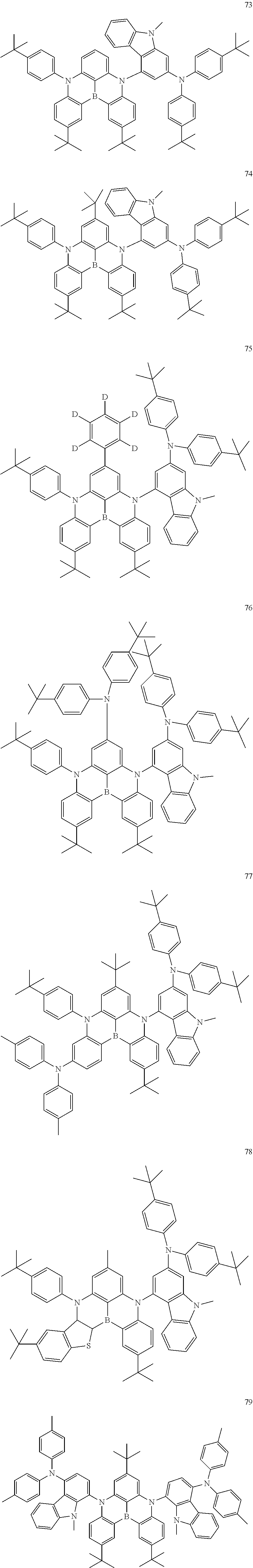

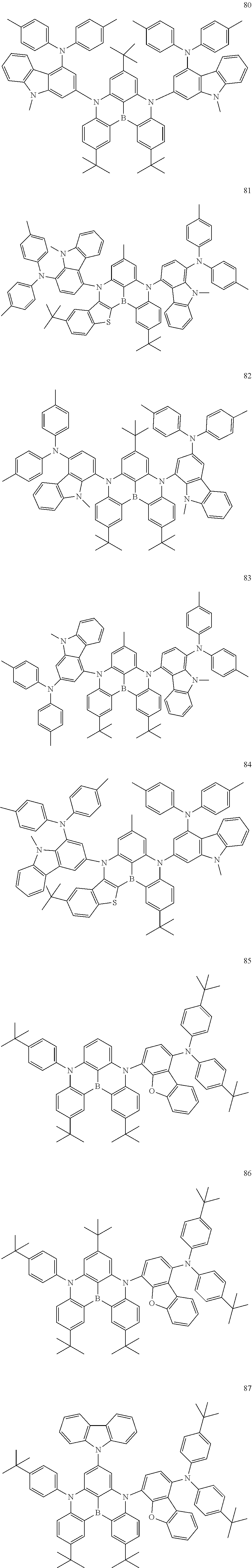

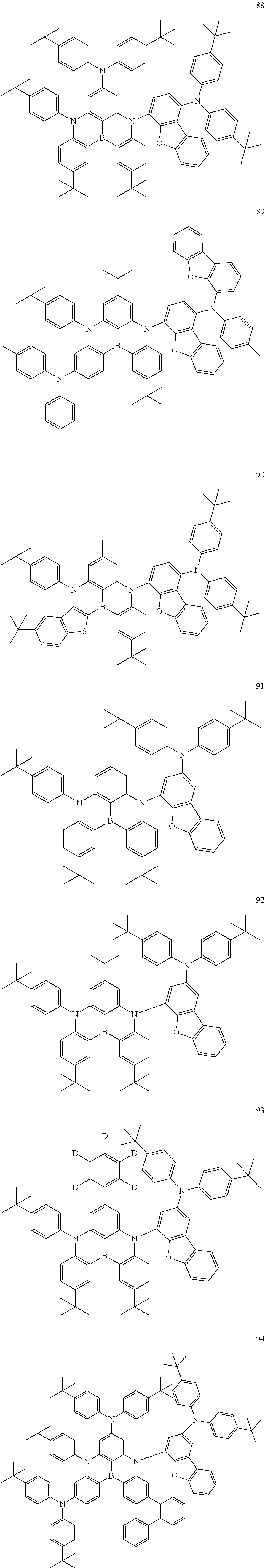

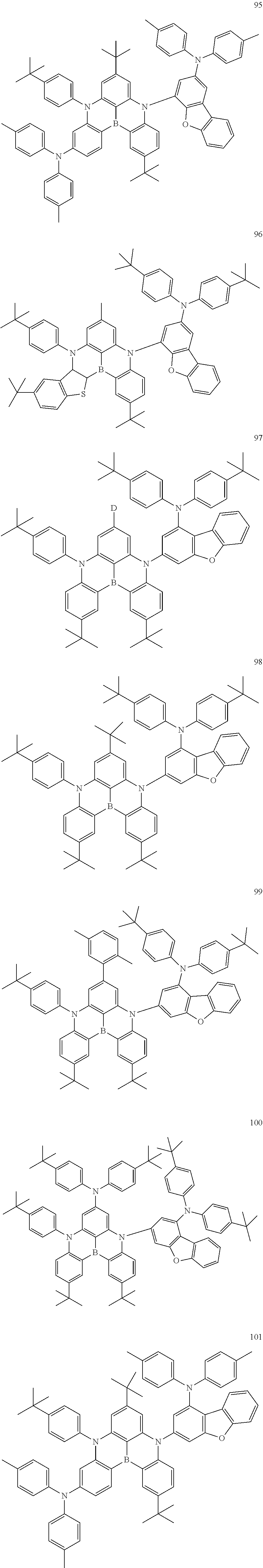

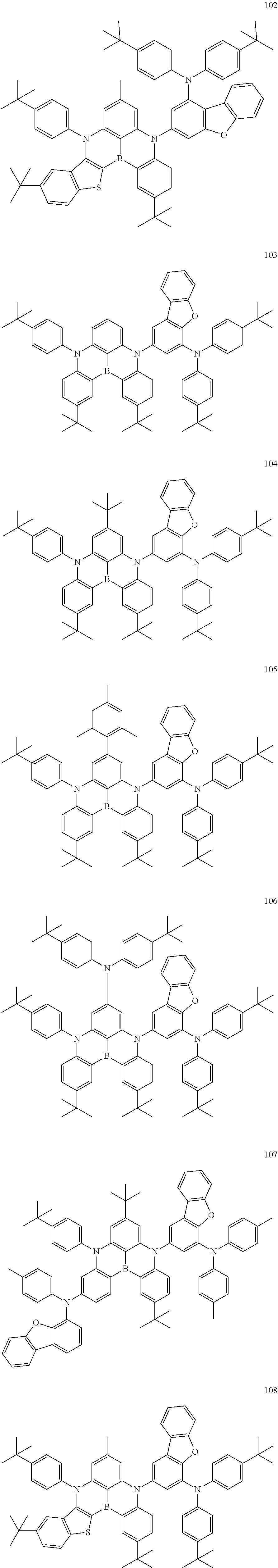

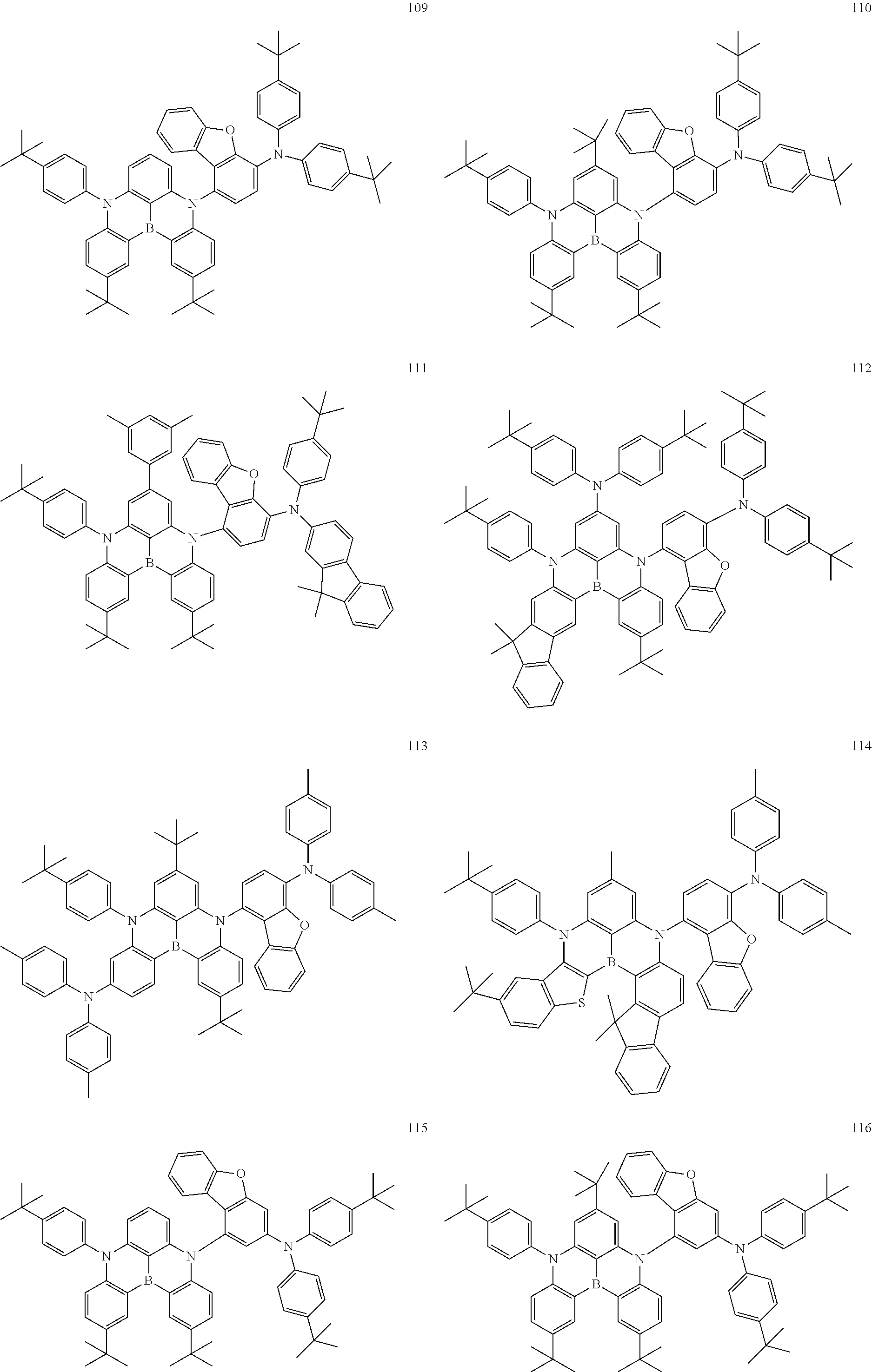

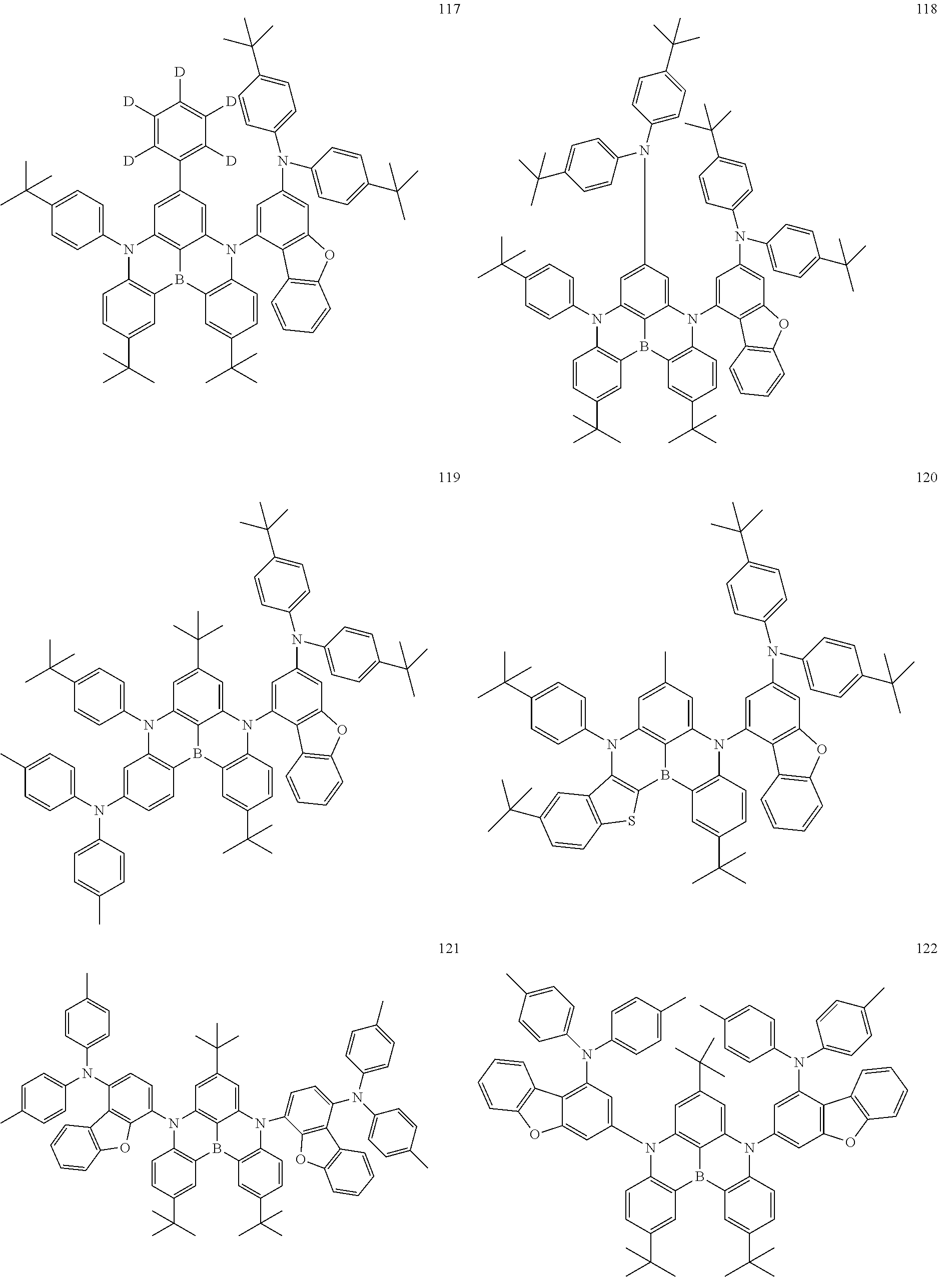

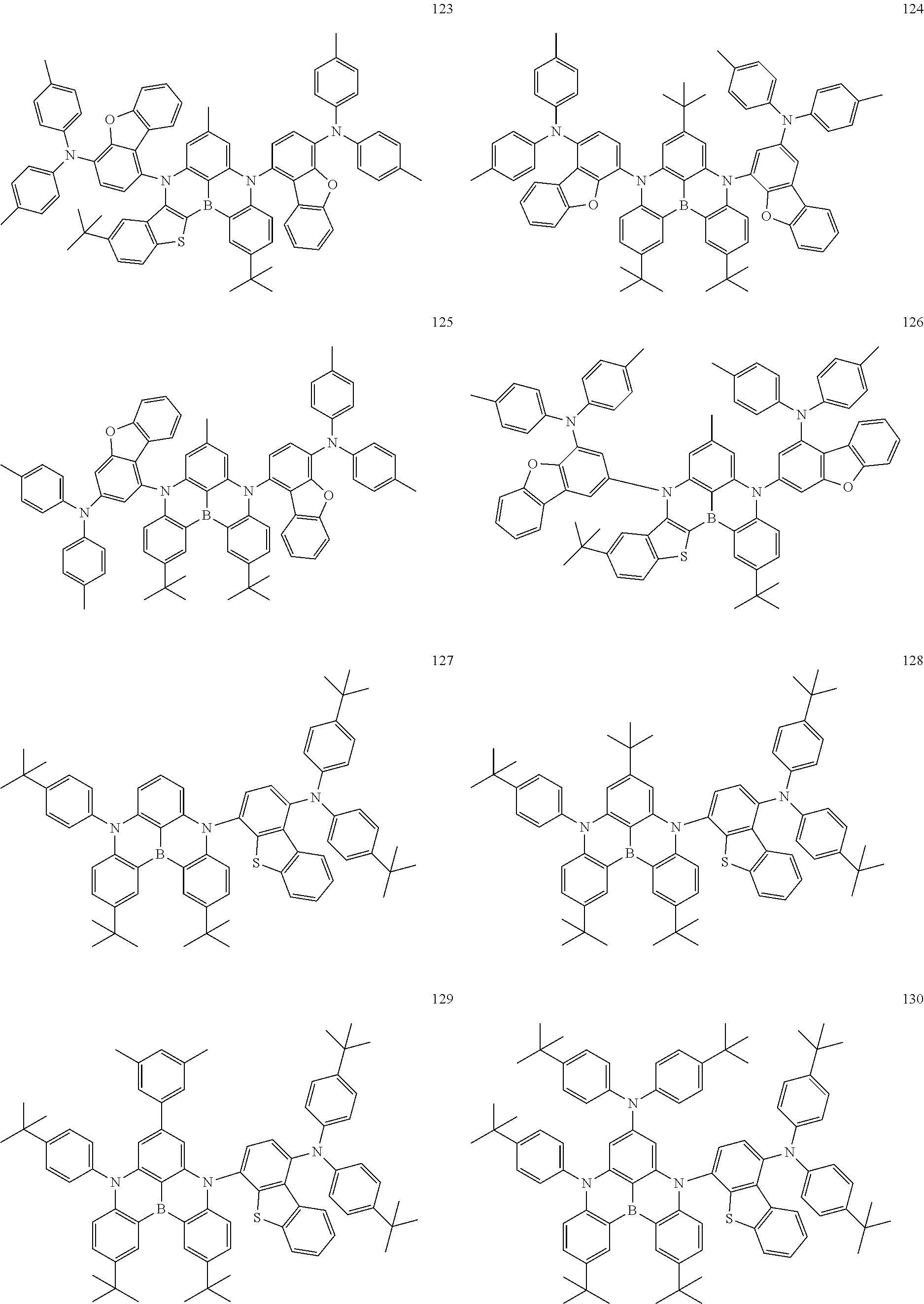

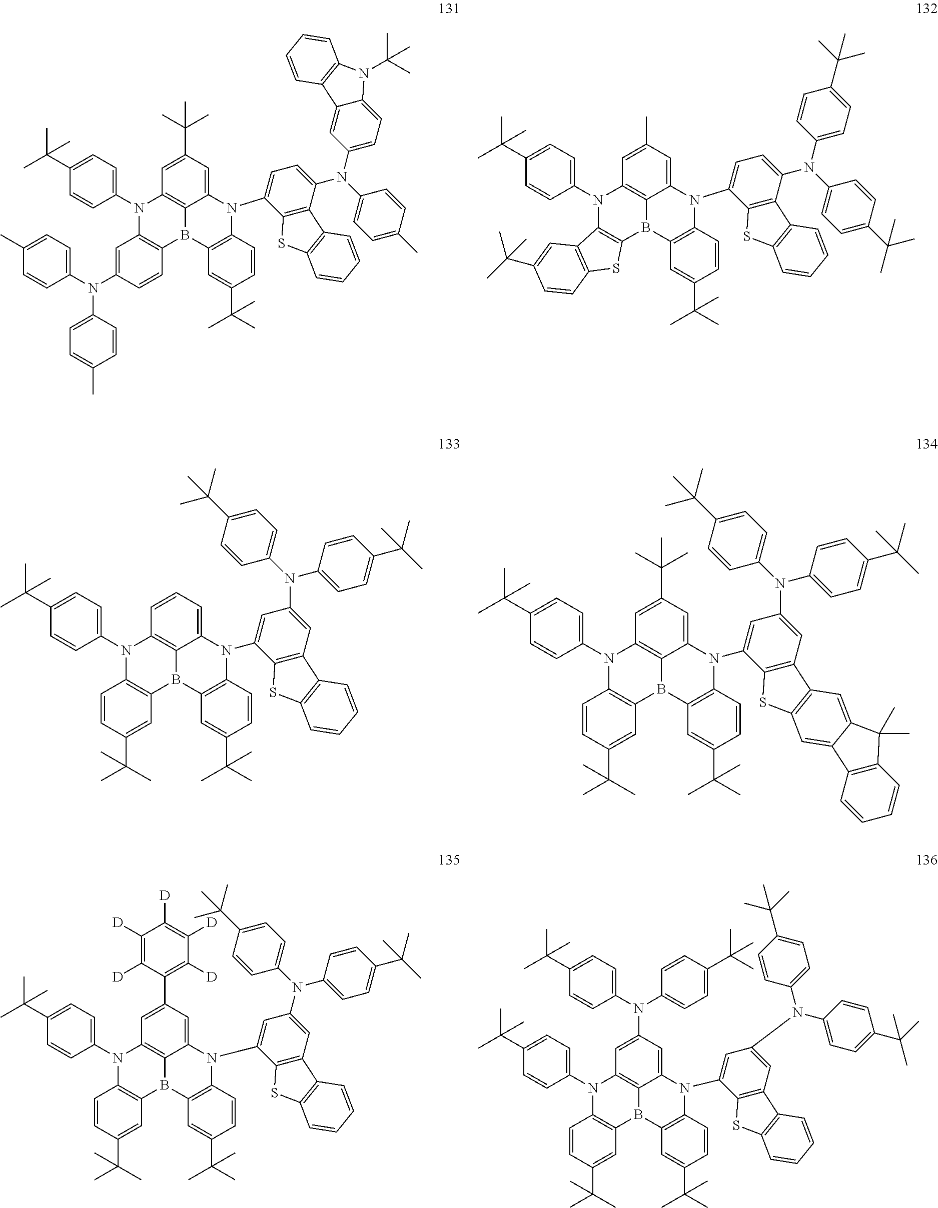

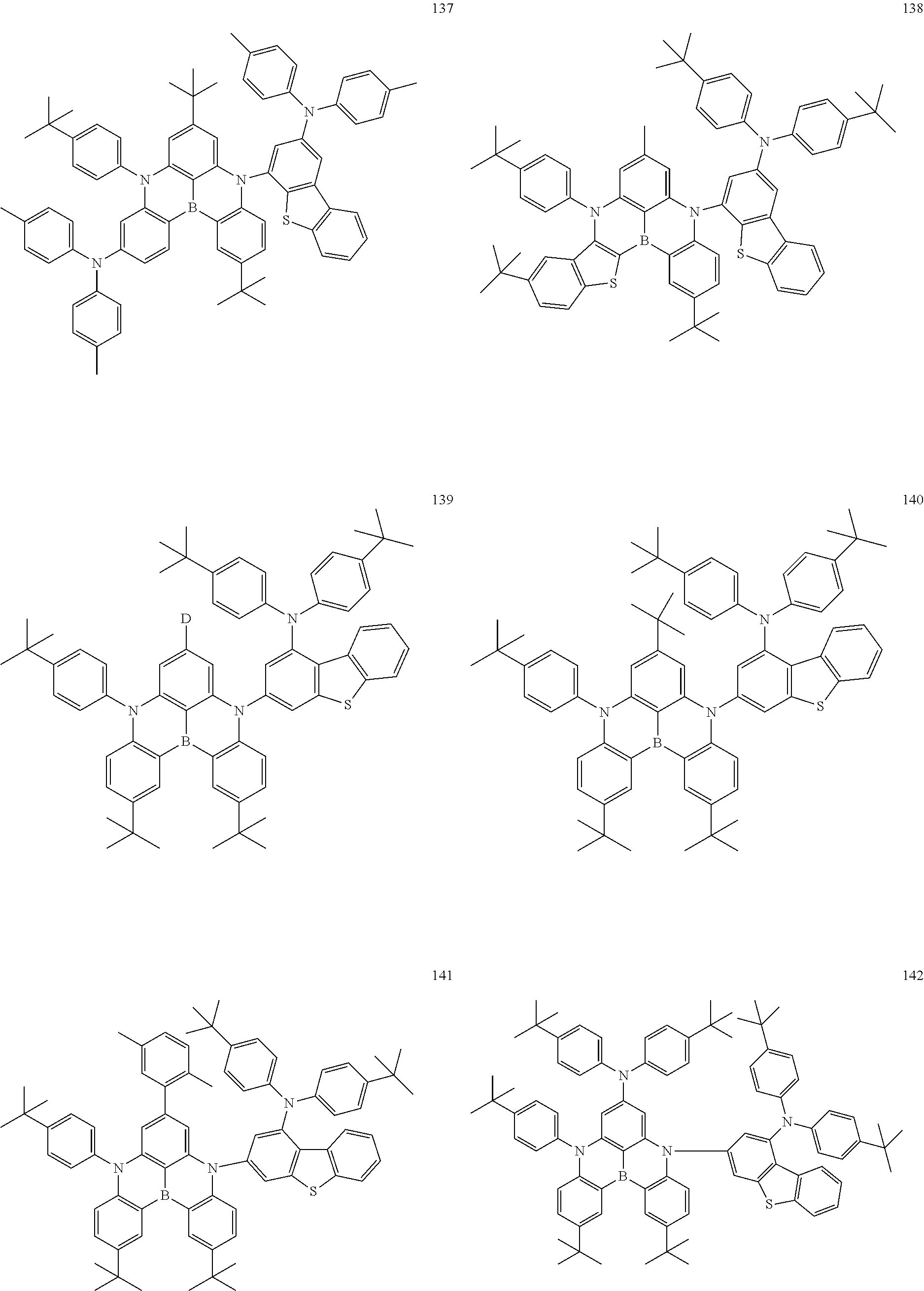

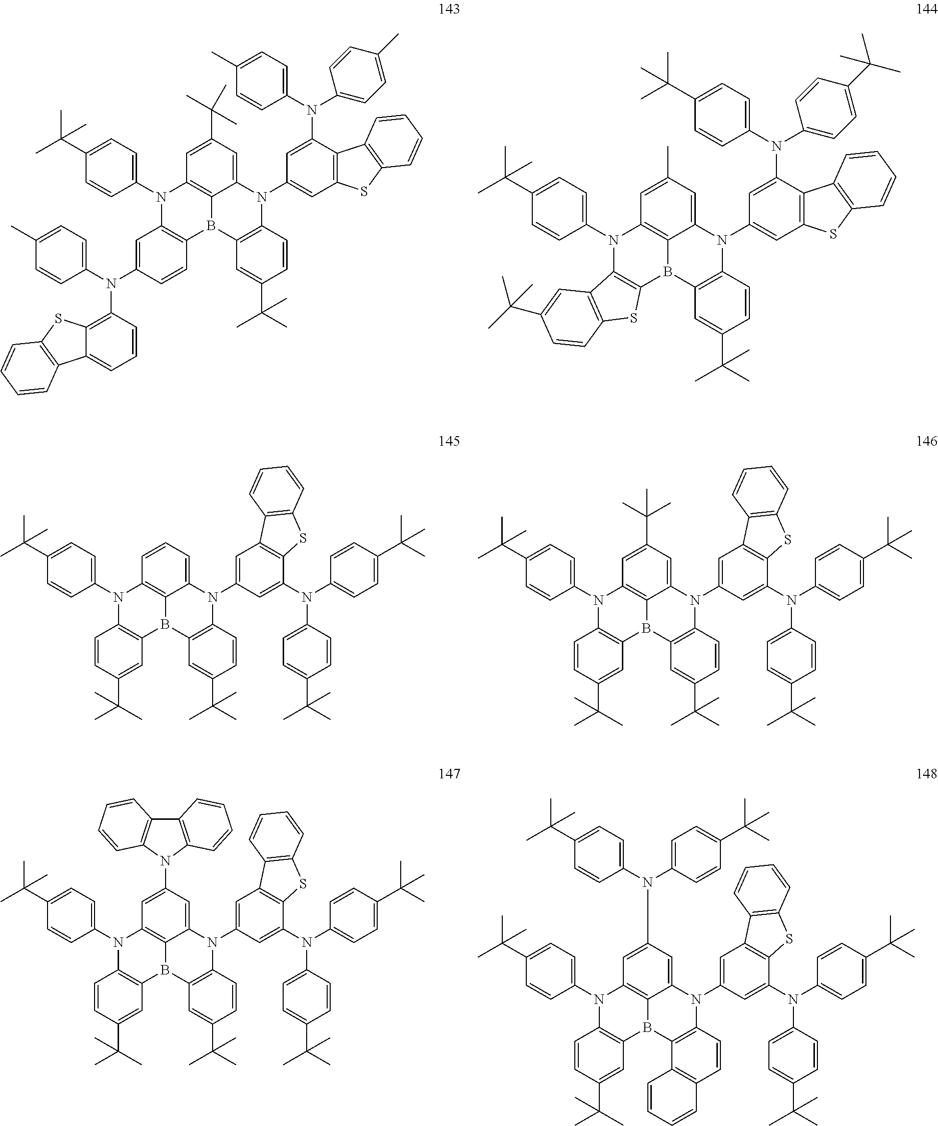

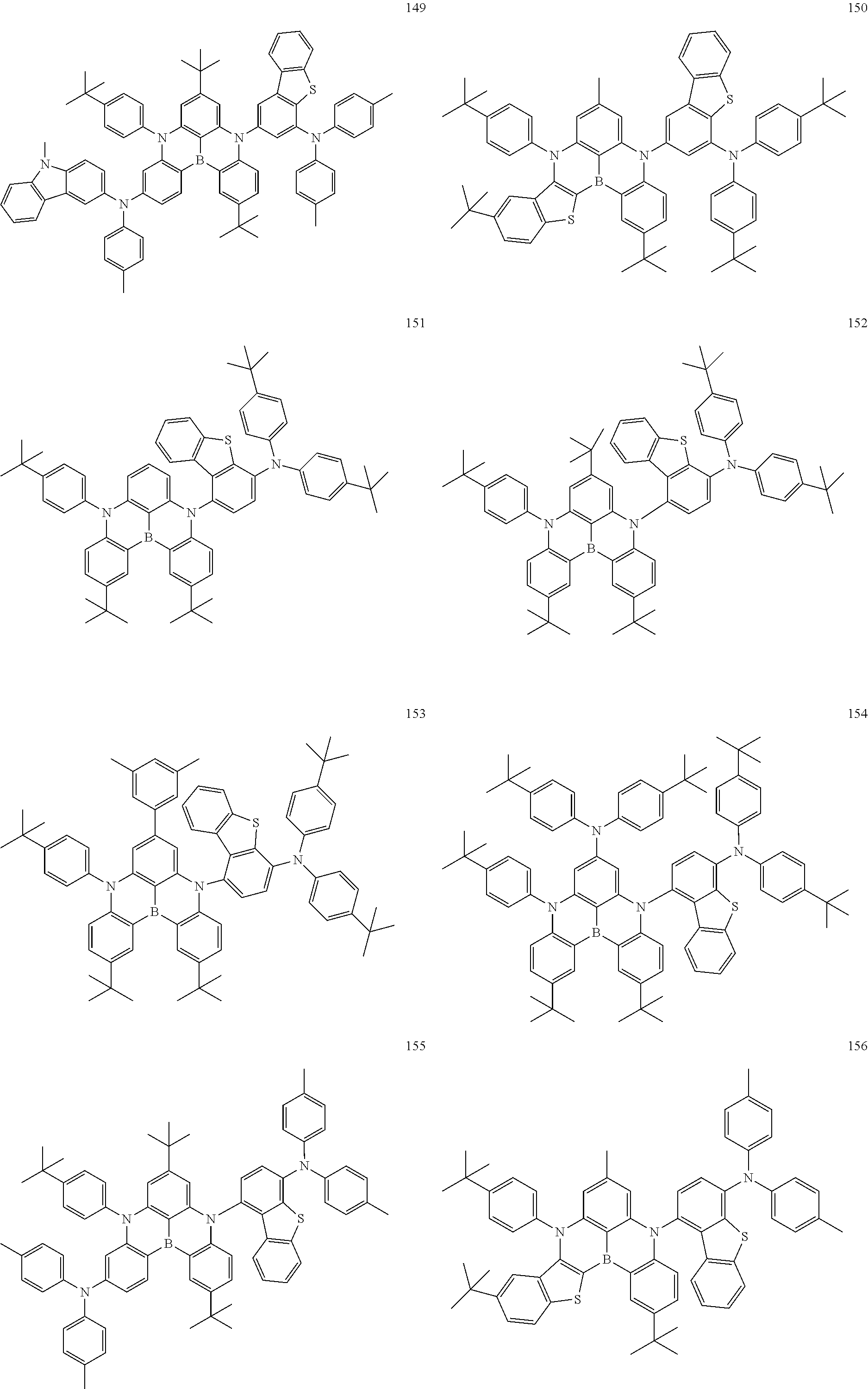

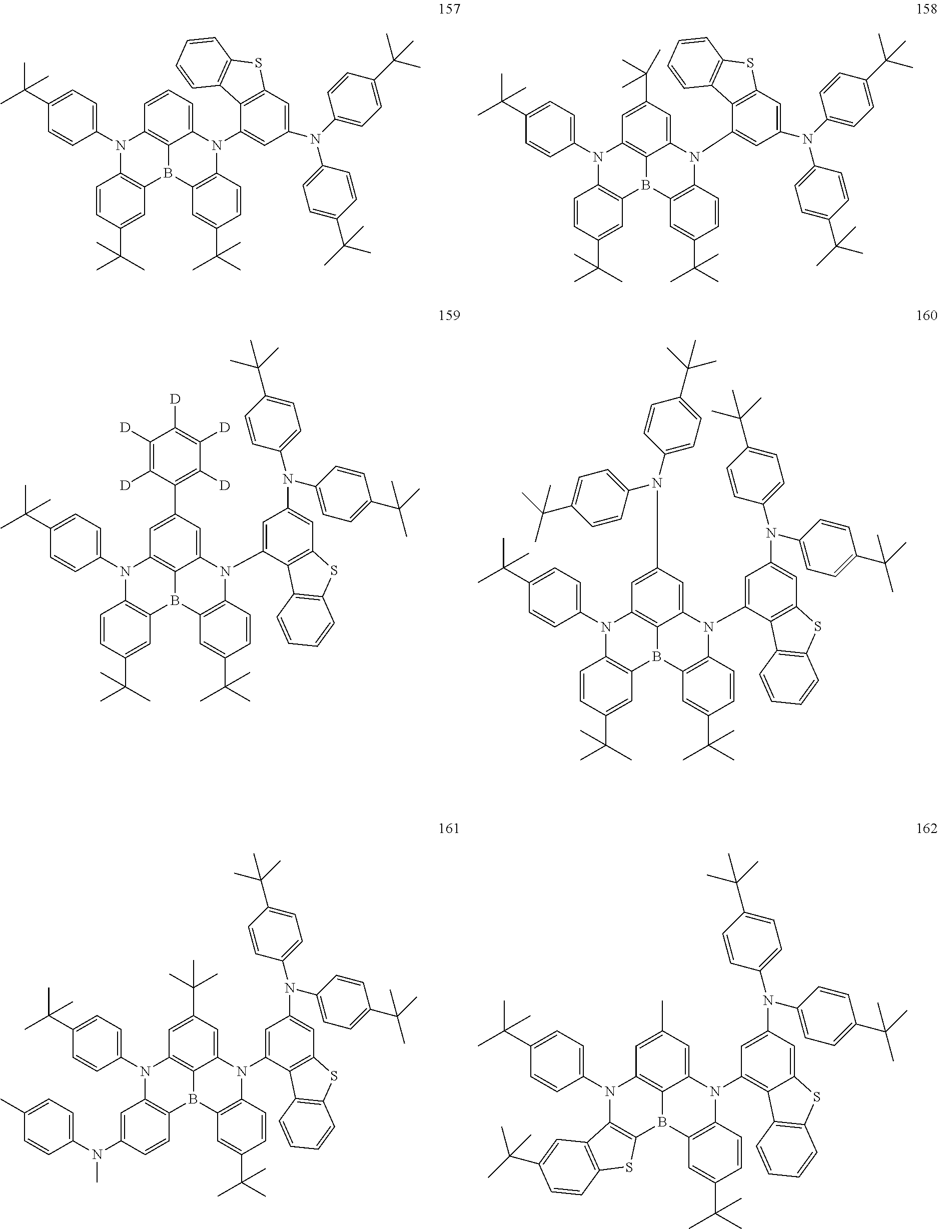

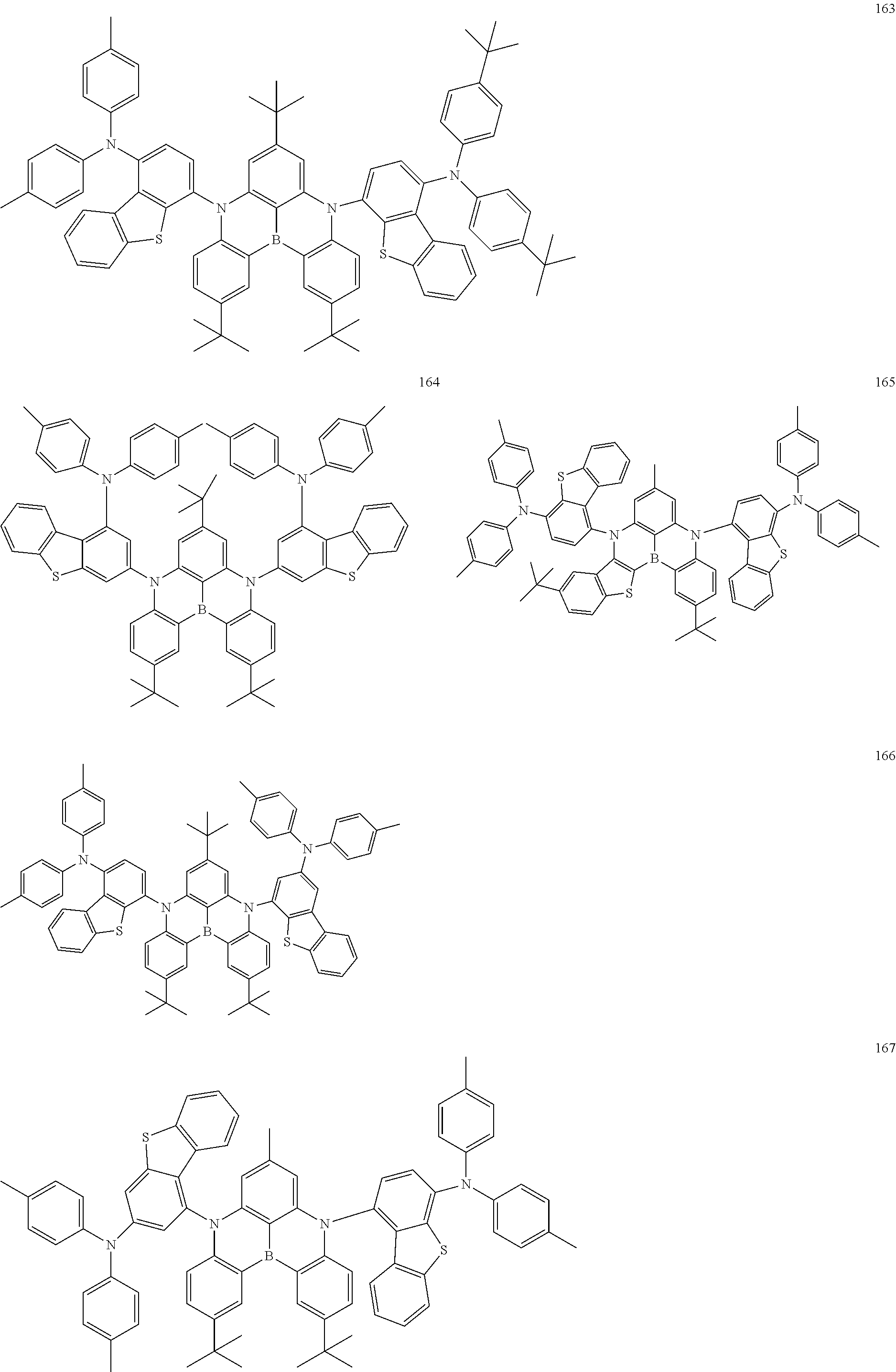

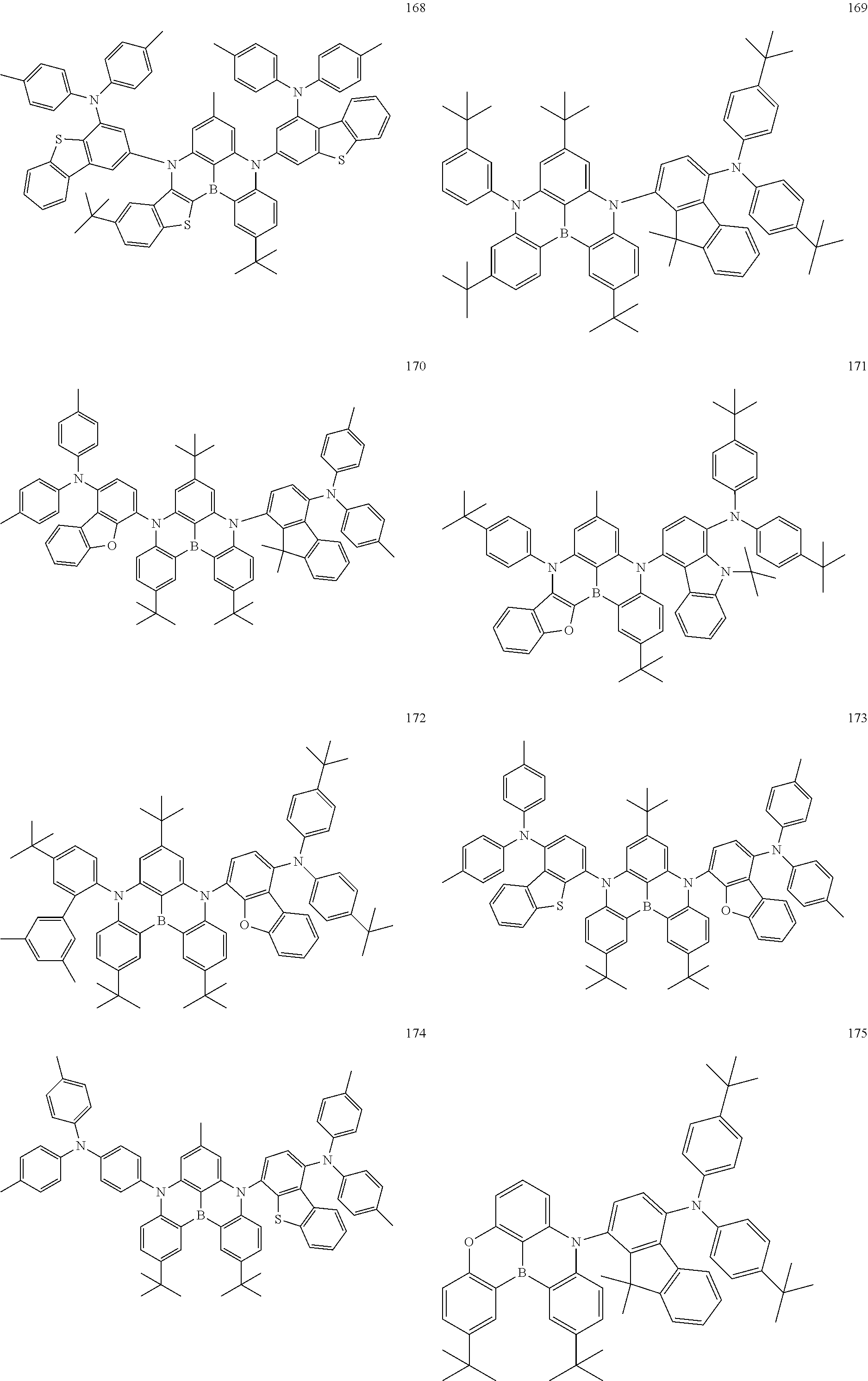

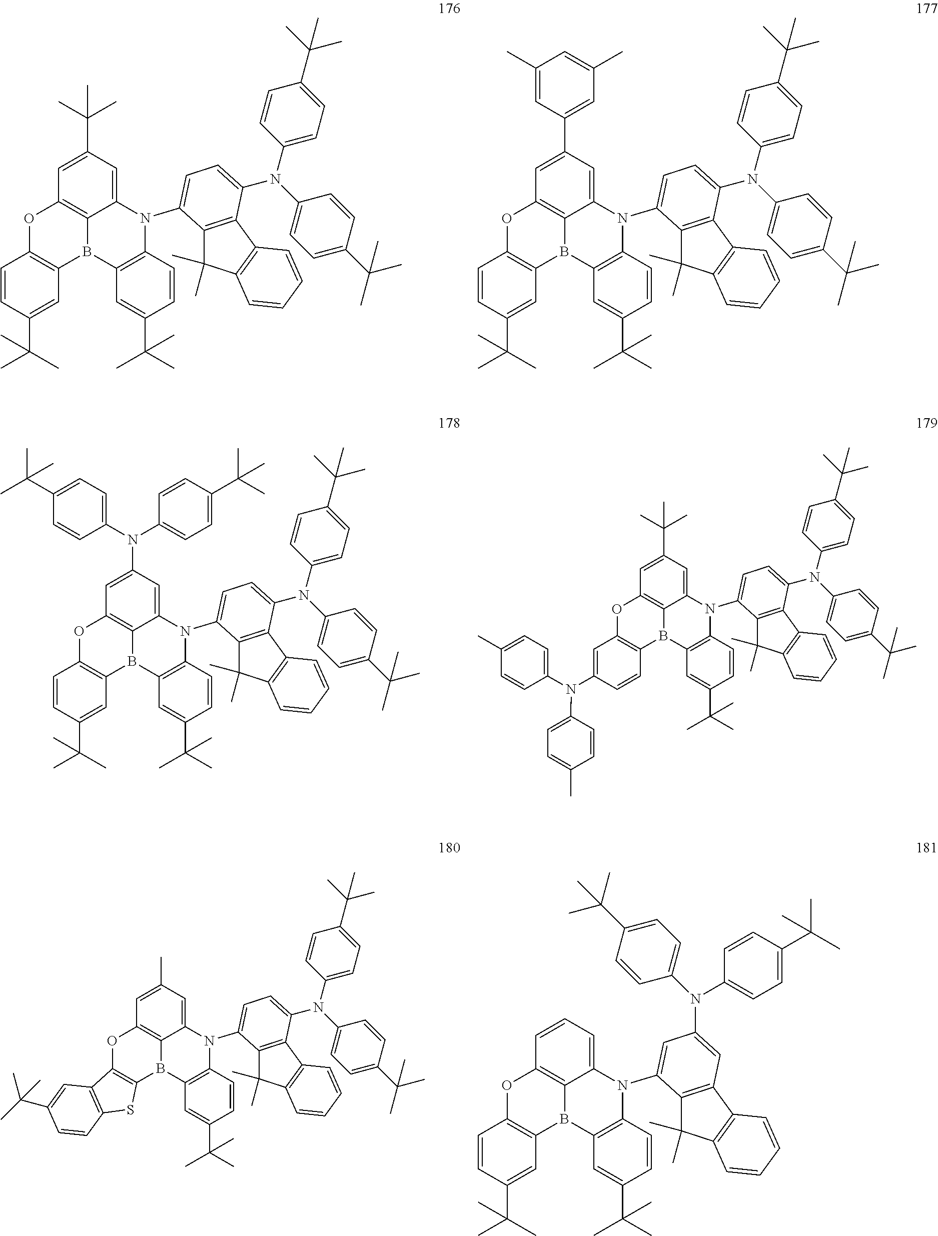

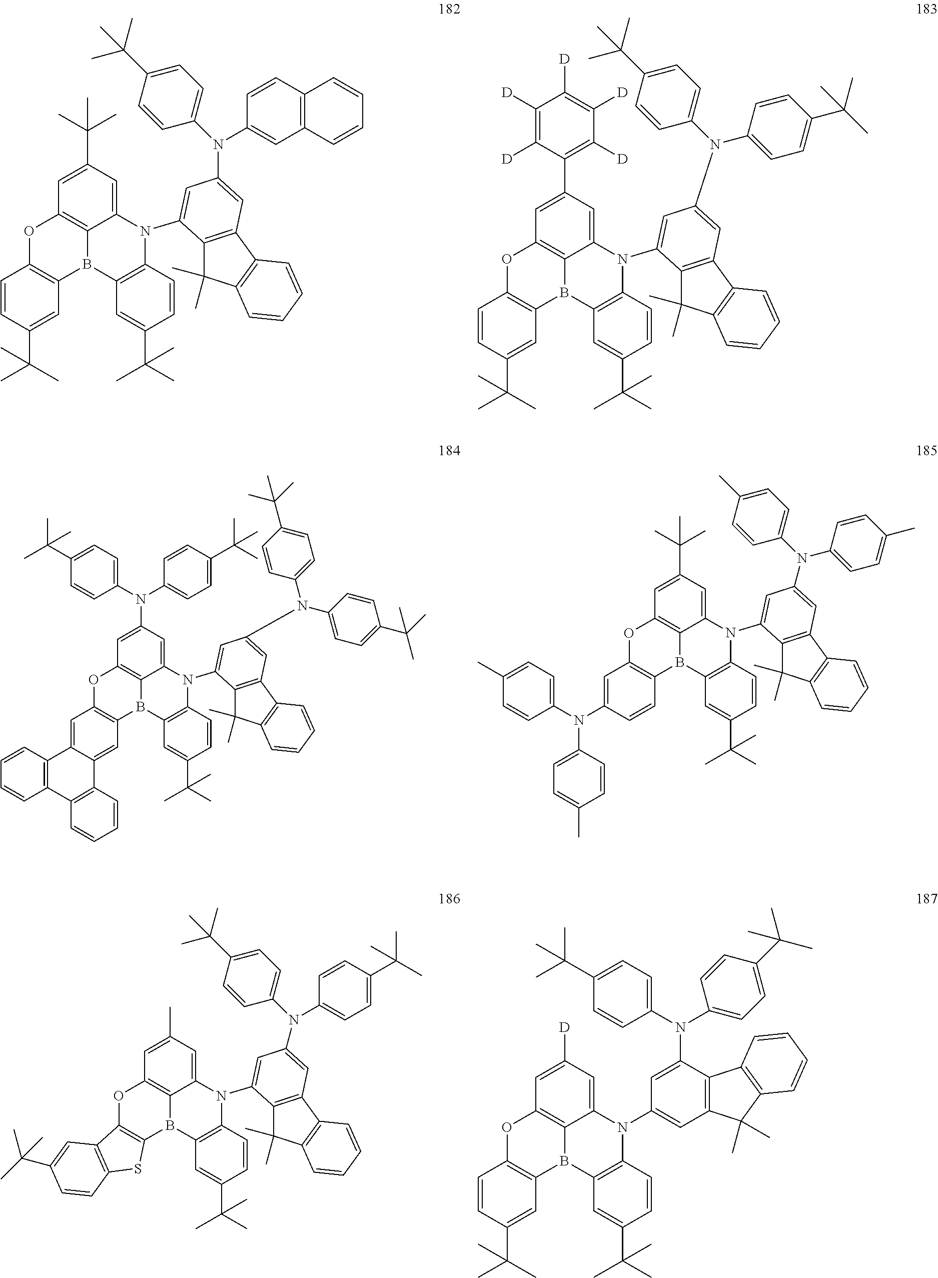

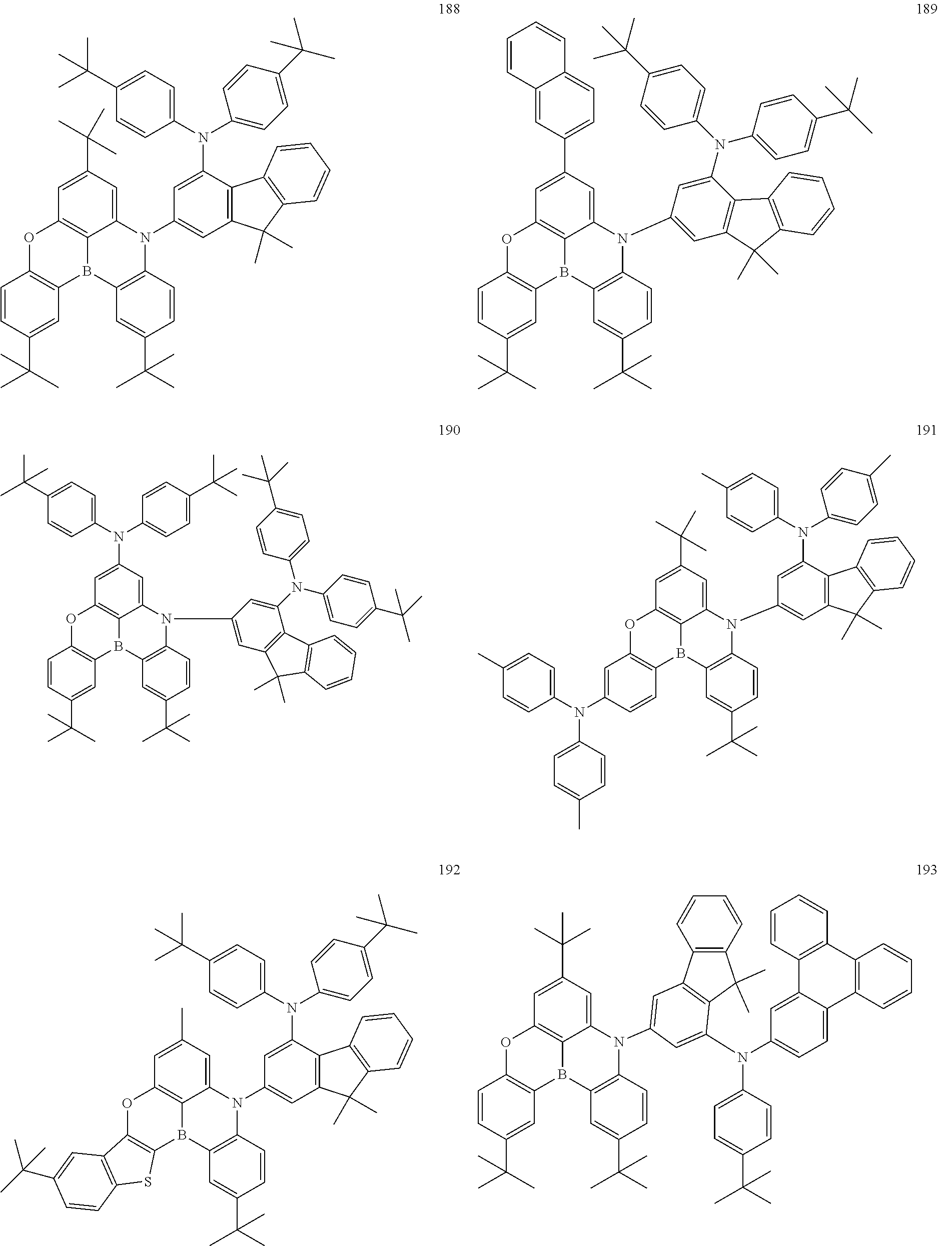

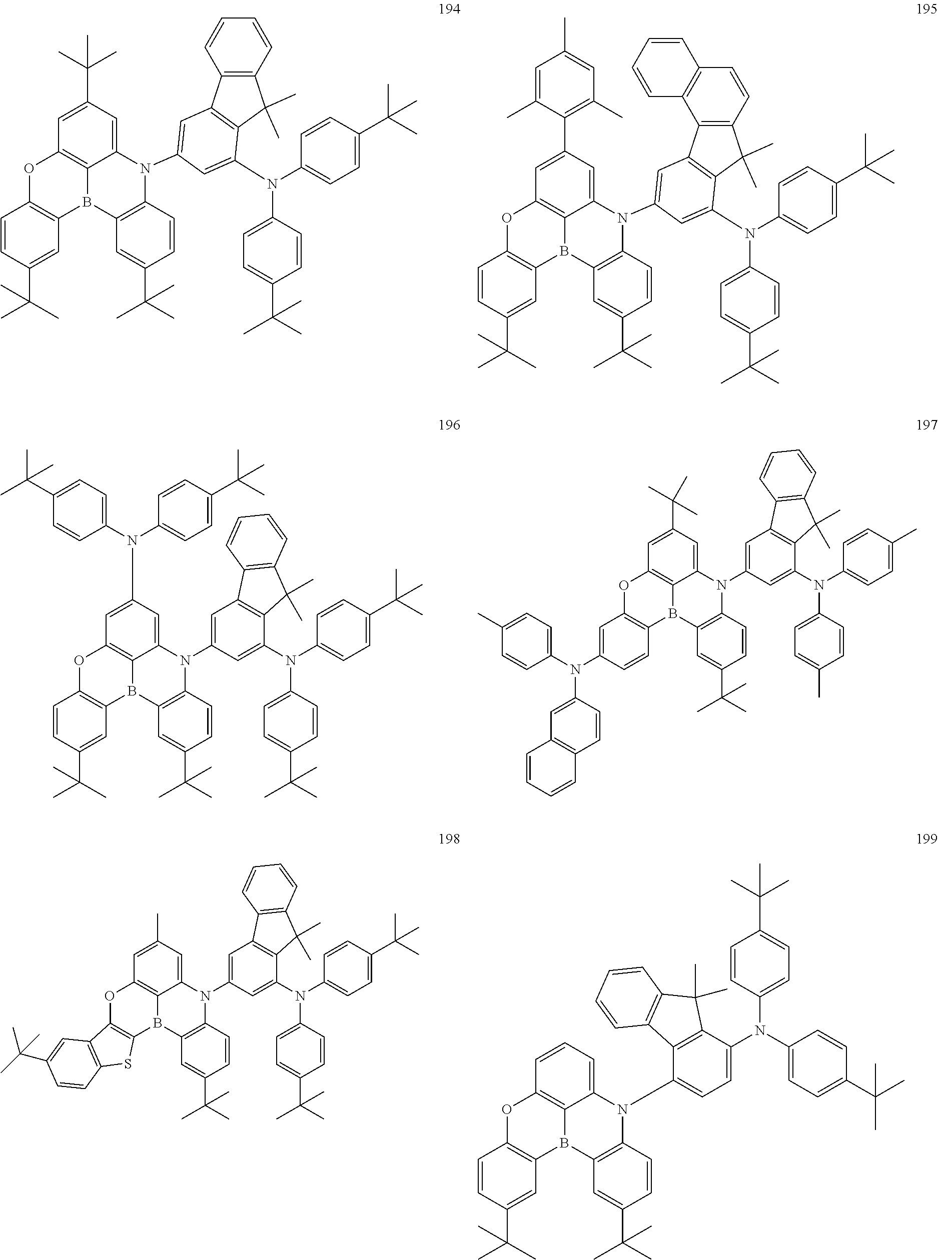

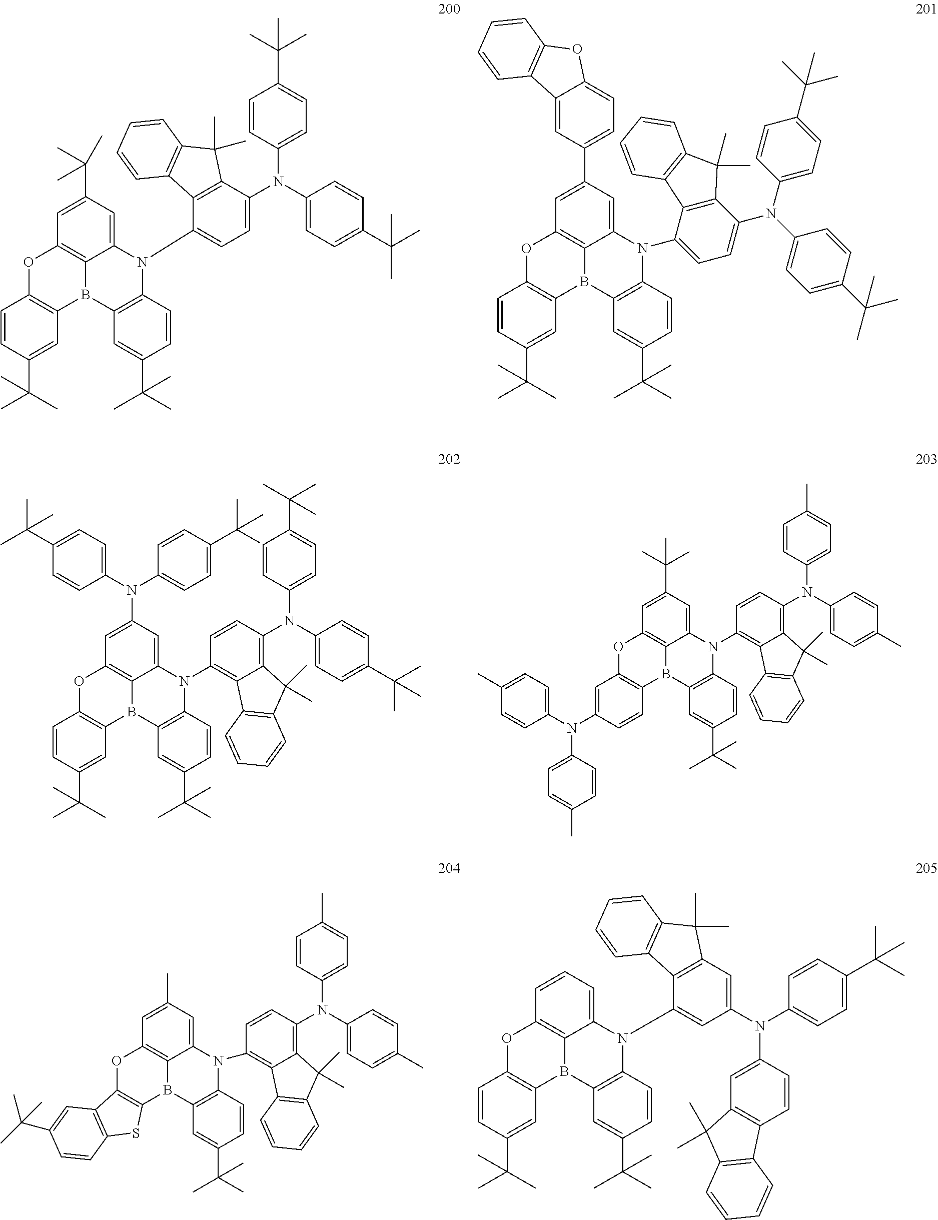

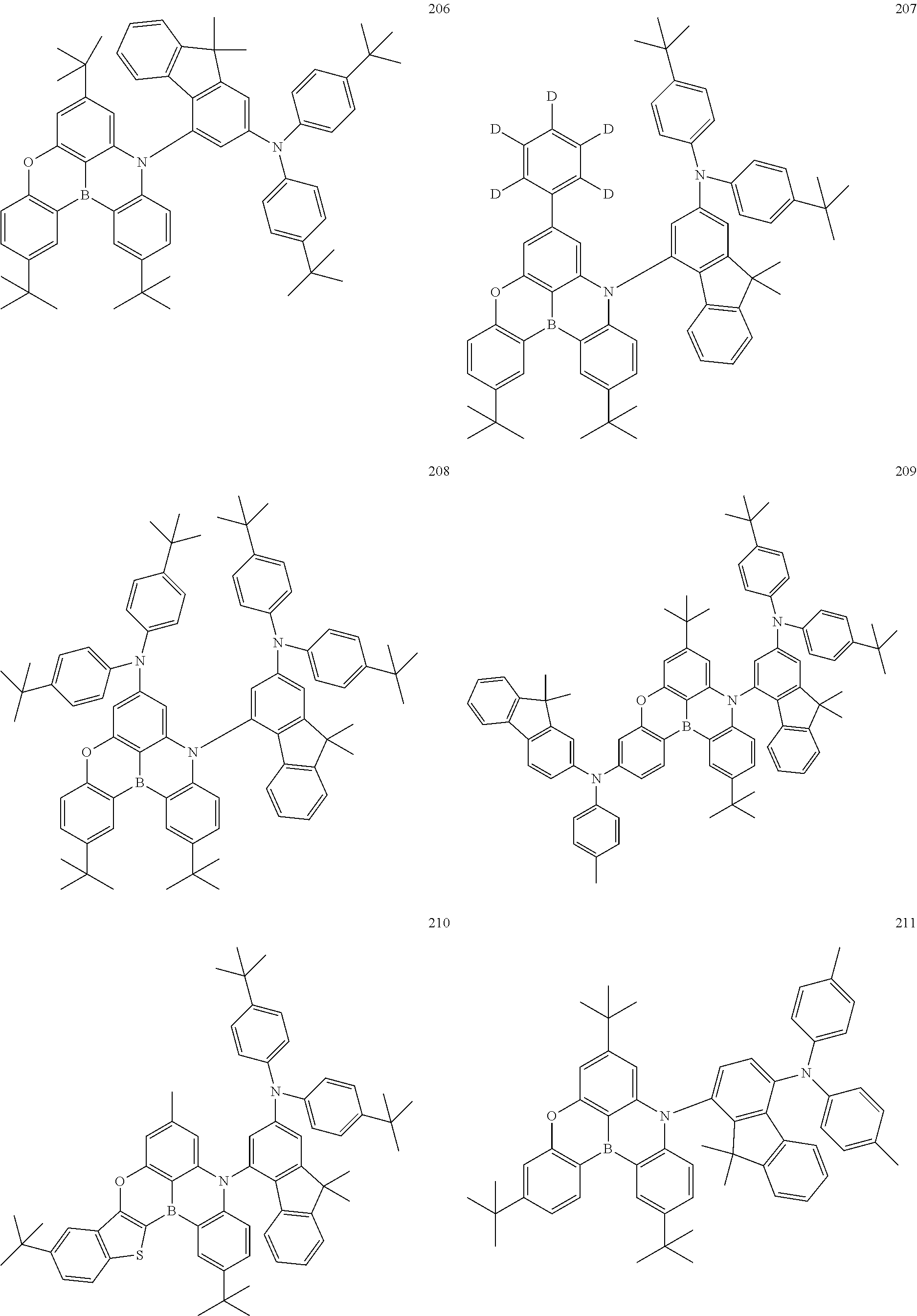

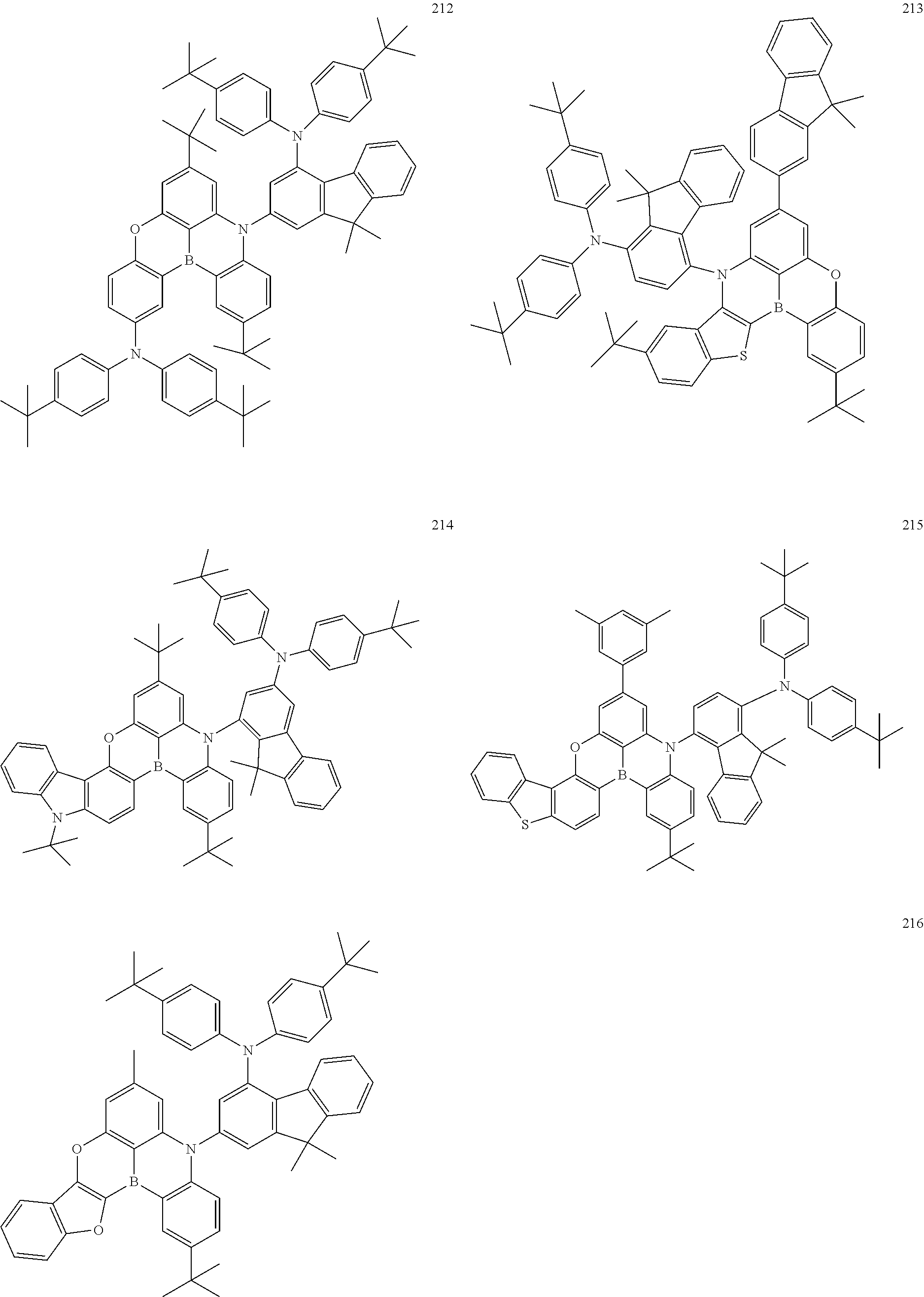

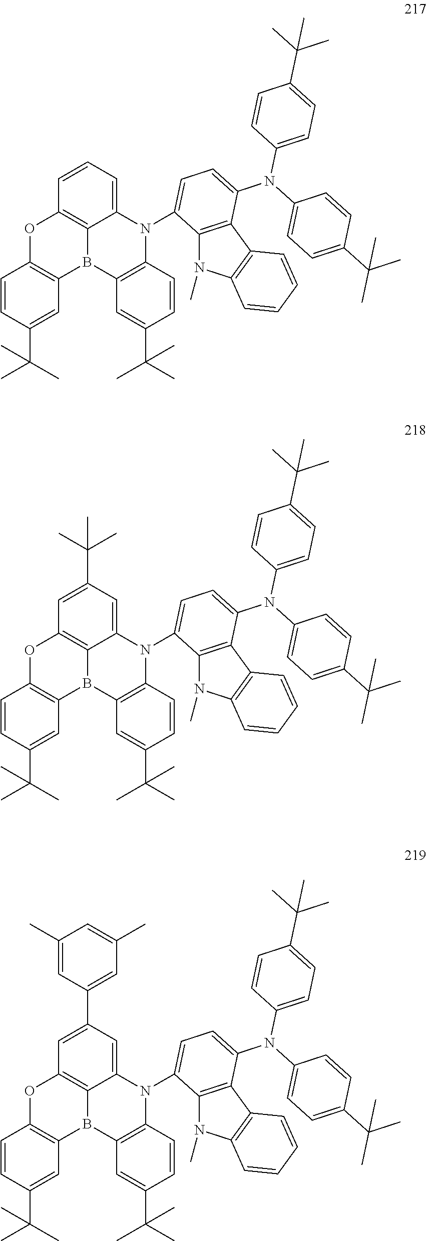 [SMILES: Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cccc3c54)c21 ; Cn1c2ccccc2c2c(N(c3ccc(C(C)(C)C)cc3)c3ccc(C(C)(C)C)cc3)ccc(N3c4ccc(C(C)(C)C)cc4B4c5cc(C(C)(C)C)ccc5Oc5cc(C(C)(C)C)cc3c54)c21 ; Cc1cc(C)cc(-c2cc3c4c(c2)N(c2ccc(N(c5ccc(C(C)(C)C)cc5)c5ccc(C(C)(C)C)cc5)c5c6ccccc6n(C)c25)c2ccc(C(C)(C)C)cc2B4c2cc(C(C)(C)C)ccc2O3)c1]

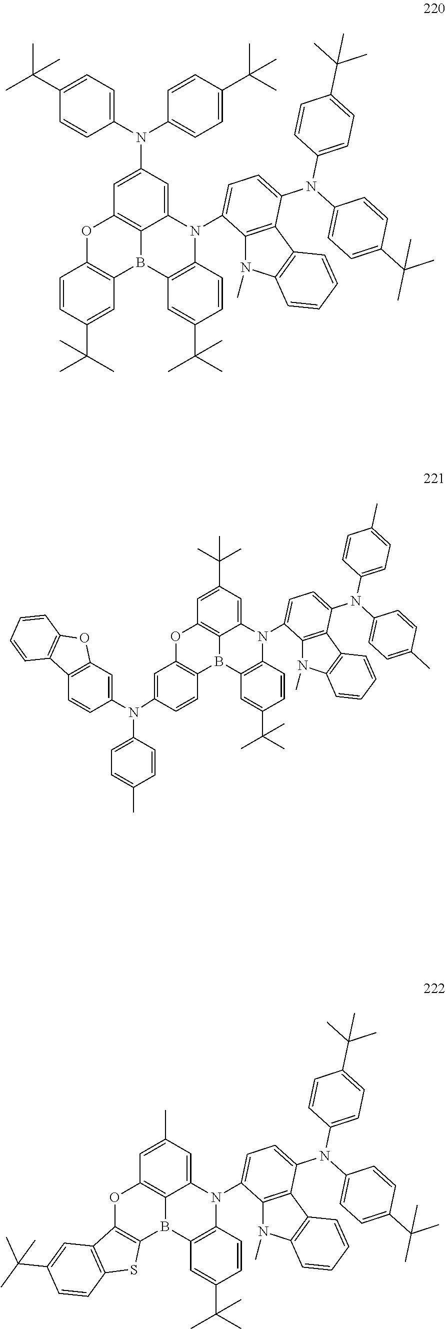

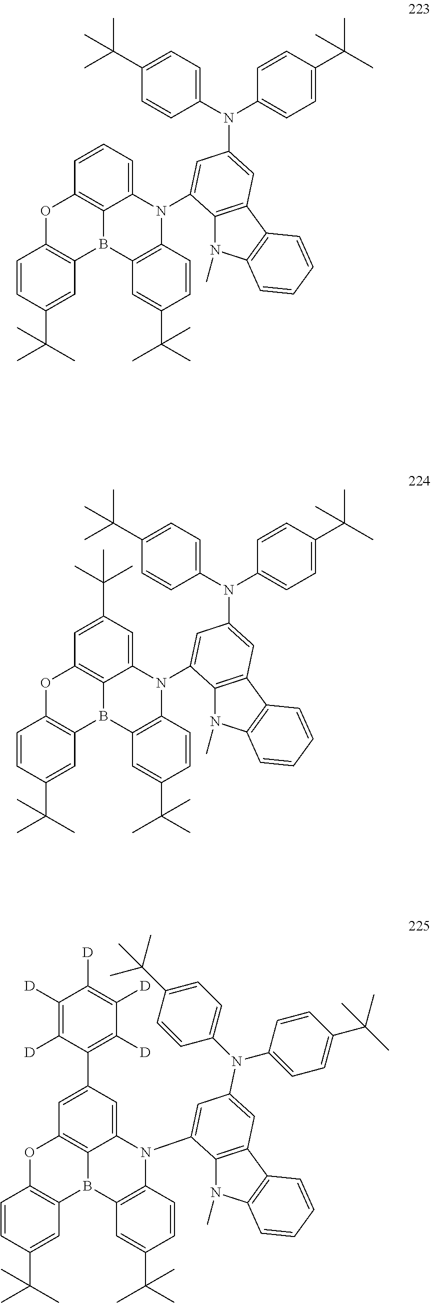 [SMILES: Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cccc3c54)c21 ; Cn1c2ccccc2c2cc(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)c21 ; [2H]c1c([2H])c([2H])c(-c2cc3c4c(c2)N(c2cc(N(c5ccc(C(C)(C)C)cc5)c5ccc(C(C)(C)C)cc5)cc5c6ccccc6n(C)c25)c2ccc(C(C)(C)C)cc2B4c2cc(C(C)(C)C)ccc2O3)c([2H])c1[2H]]

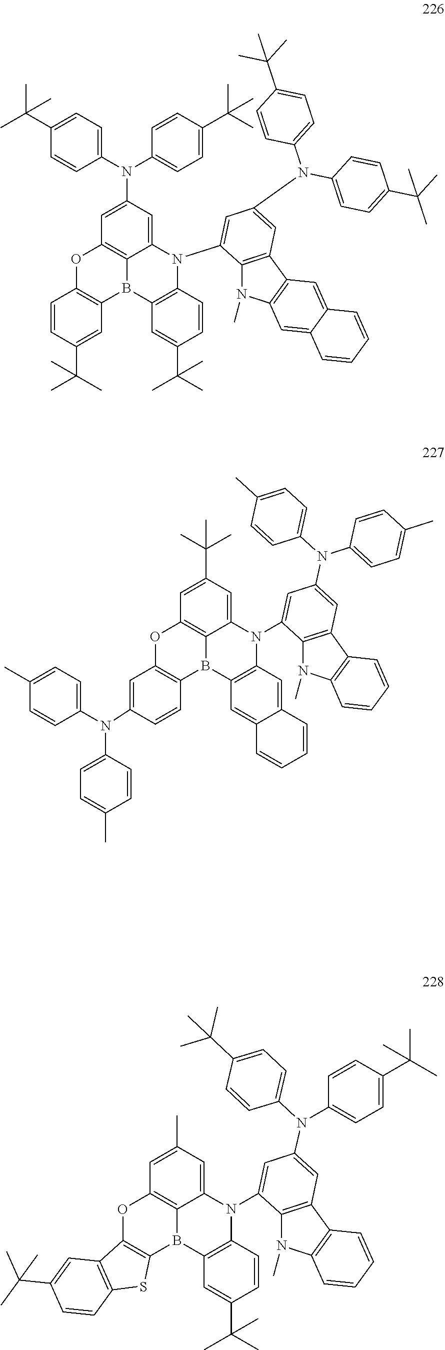

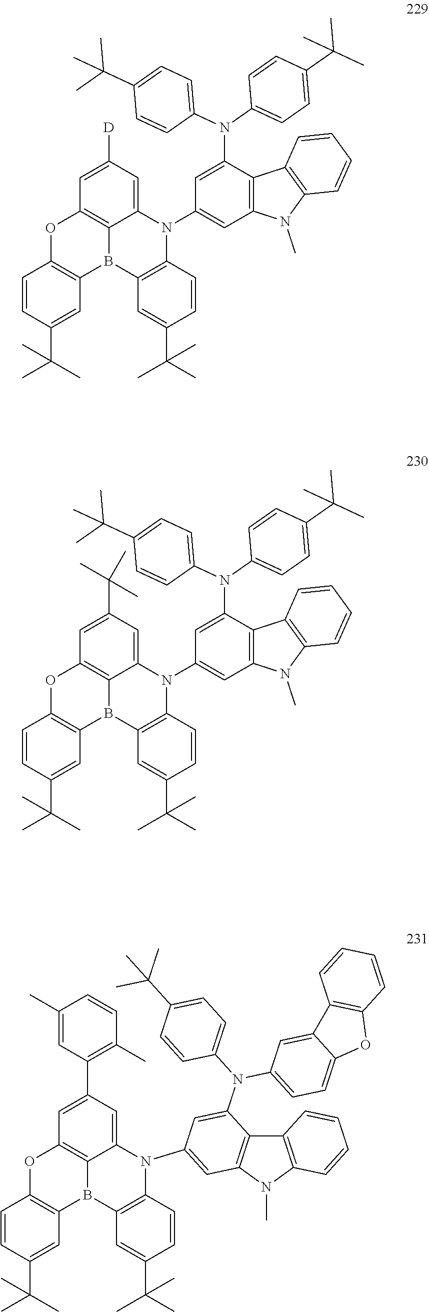 [SMILES: [2H]c1cc2c3c(c1)N(c1cc(N(c4ccc(C(C)(C)C)cc4)c4ccc(C(C)(C)C)cc4)c4c5ccccc5n(C)c4c1)c1ccc(C(C)(C)C)cc1B3c1cc(C(C)(C)C)ccc1O2 ; Cn1c2ccccc2c2c(N(c3ccc(C(C)(C)C)cc3)c3ccc(C(C)(C)C)cc3)cc(N3c4ccc(C(C)(C)C)cc4B4c5cc(C(C)(C)C)ccc5Oc5cc(C(C)(C)C)cc3c54)cc21 ; Cc1ccc(C)c(-c2cc3c4c(c2)N(c2cc(N(c5ccc(C(C)(C)C)cc5)c5ccc6oc7ccccc7c6c5)c5c6ccccc6n(C)c5c2)c2ccc(C(C)(C)C)cc2B4c2cc(C(C)(C)C)ccc2O3)c1]

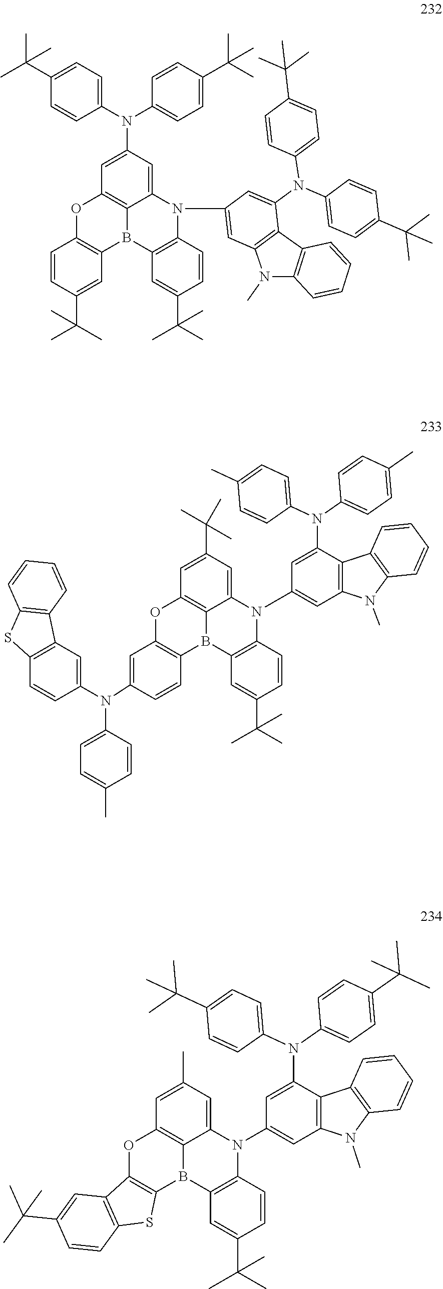

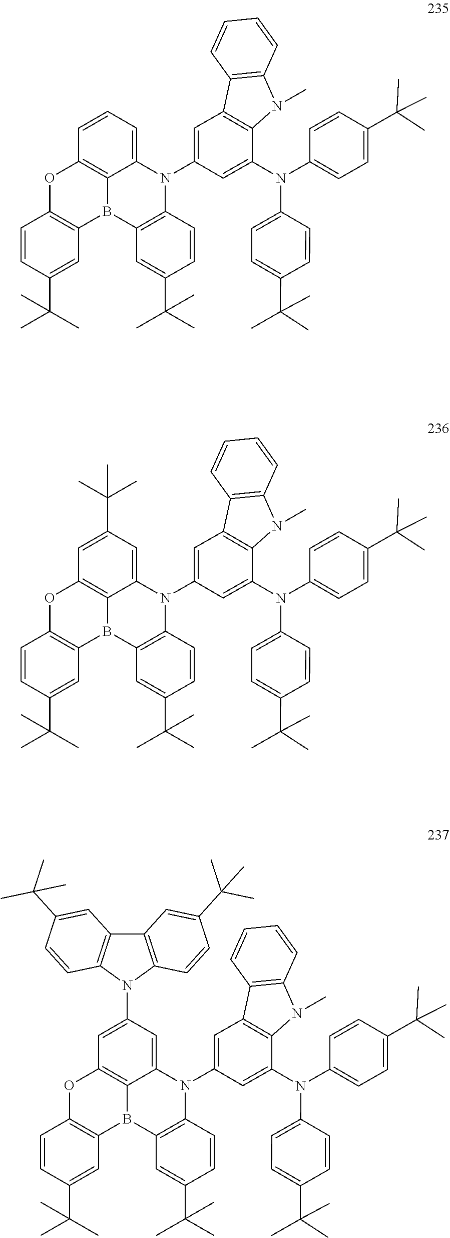

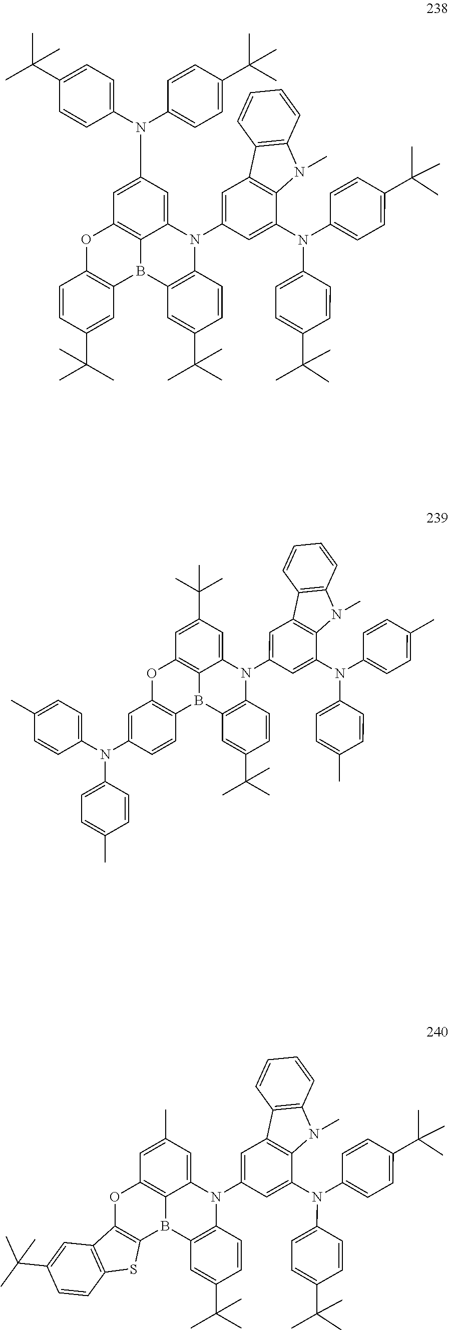

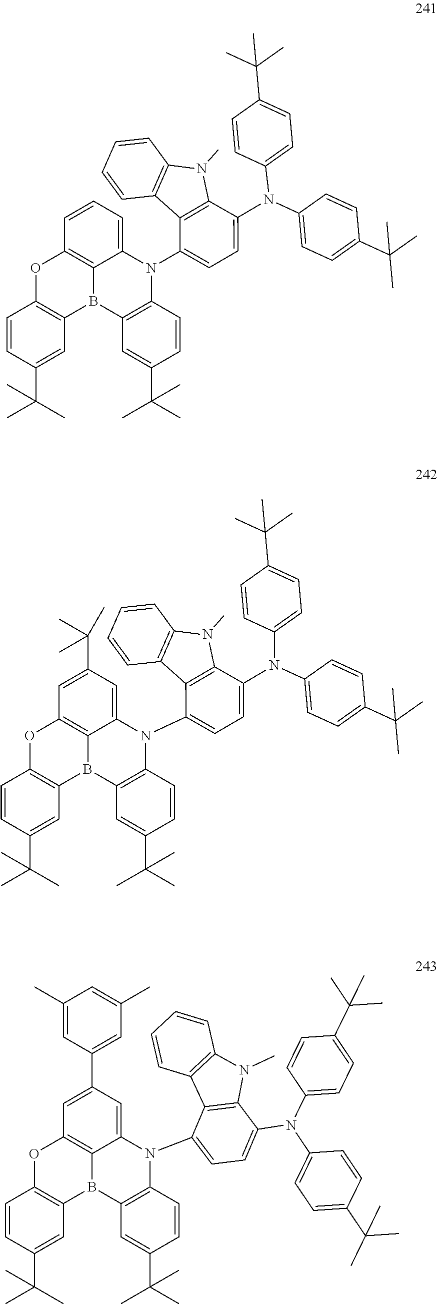 [SMILES: Cn1c2ccccc2c2c(N3c4ccc(C(C)(C)C)cc4B4c5cc(C(C)(C)C)ccc5Oc5cccc3c54)ccc(N(c3ccc(C(C)(C)C)cc3)c3ccc(C(C)(C)C)cc3)c21 ; Cn1c2ccccc2c2c(N3c4ccc(C(C)(C)C)cc4B4c5cc(C(C)(C)C)ccc5Oc5cc(C(C)(C)C)cc3c54)ccc(N(c3ccc(C(C)(C)C)cc3)c3ccc(C(C)(C)C)cc3)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2cc(C(C)(C)C)ccc2O3)c1]

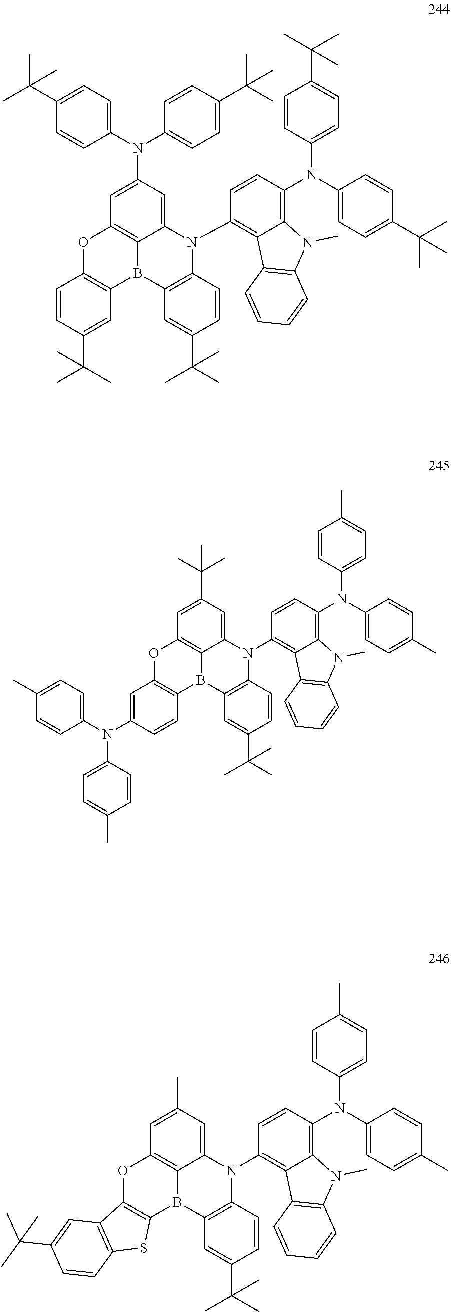

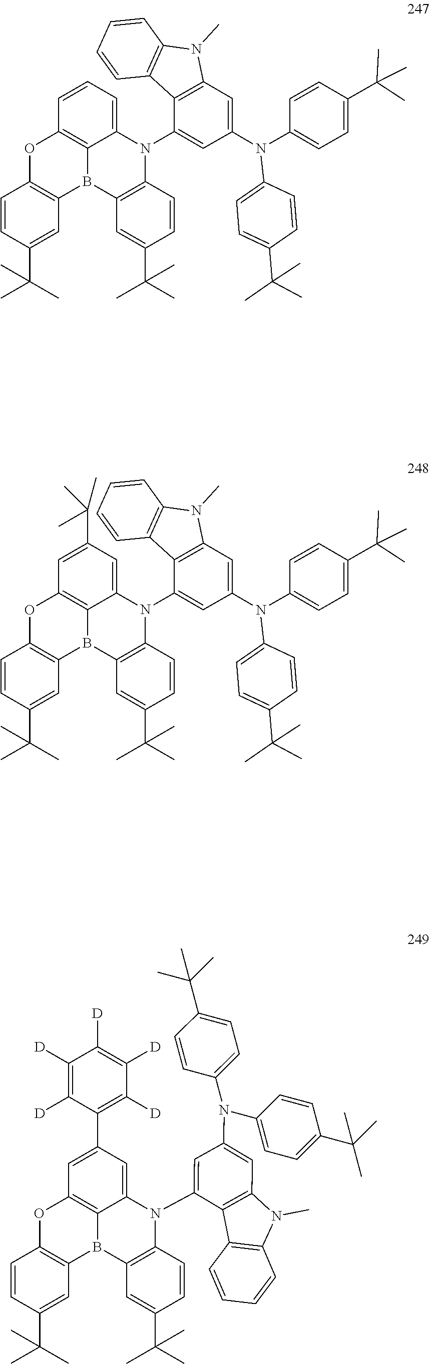 [SMILES: Cn1c2ccccc2c2c(N3c4ccc(C(C)(C)C)cc4B4c5cc(C(C)(C)C)ccc5Oc5cccc3c54)cc(N(c3ccc(C(C)(C)C)cc3)c3ccc(C(C)(C)C)cc3)cc21 ; Cn1c2ccccc2c2c(N3c4ccc(C(C)(C)C)cc4B4c5cc(C(C)(C)C)ccc5Oc5cc(C(C)(C)C)cc3c54)cc(N(c3ccc(C(C)(C)C)cc3)c3ccc(C(C)(C)C)cc3)cc21 ; [2H]c1c([2H])c([2H])c(-c2cc3c4c(c2)N(c2cc(N(c5ccc(C(C)(C)C)cc5)c5ccc(C(C)(C)C)cc5)cc5c2c2ccccc2n5C)c2ccc(C(C)(C)C)cc2B4c2cc(C(C)(C)C)ccc2O3)c([2H])c1[2H]]

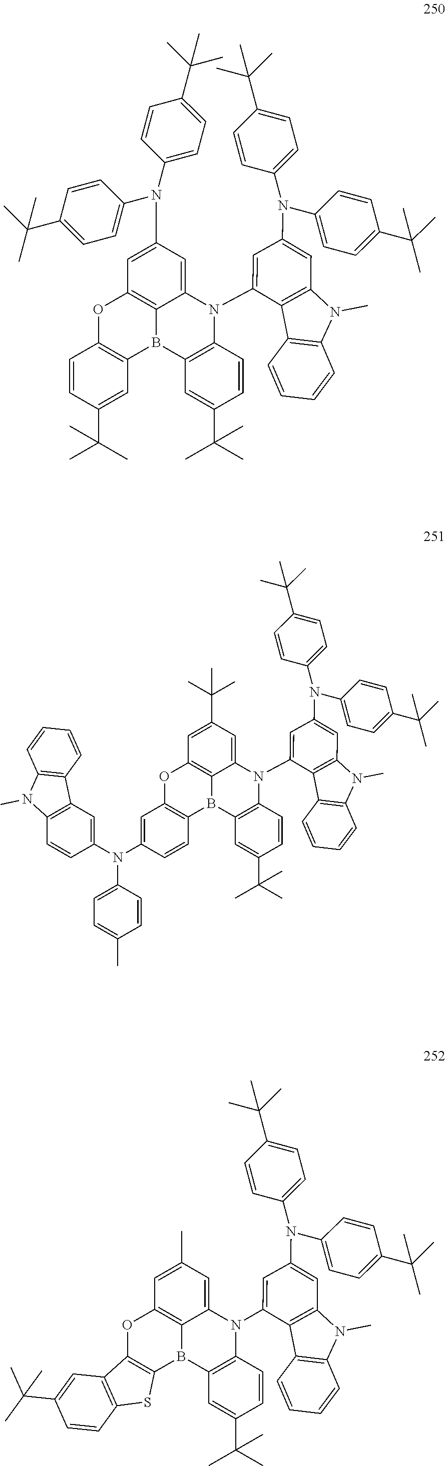

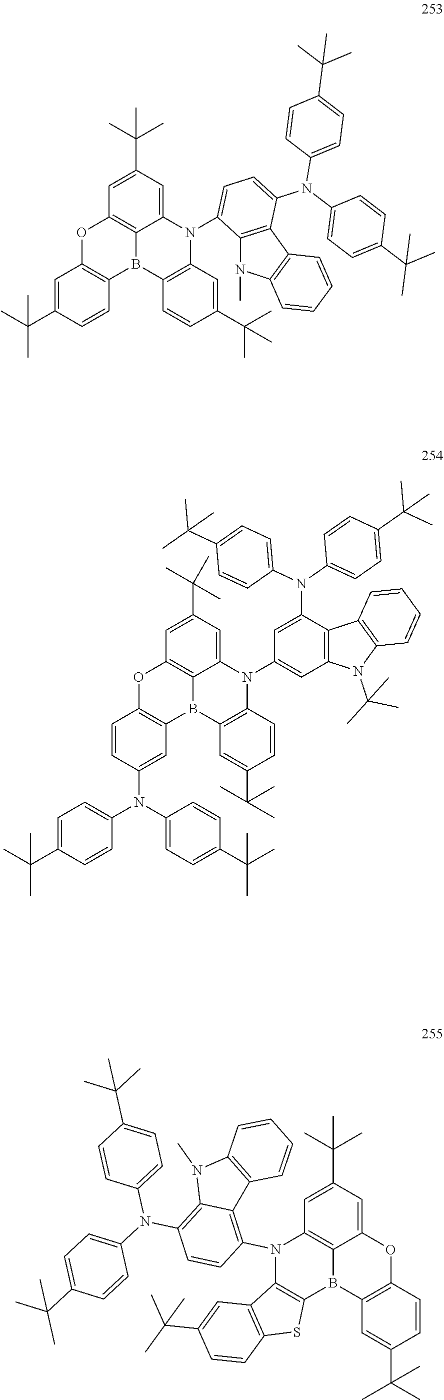

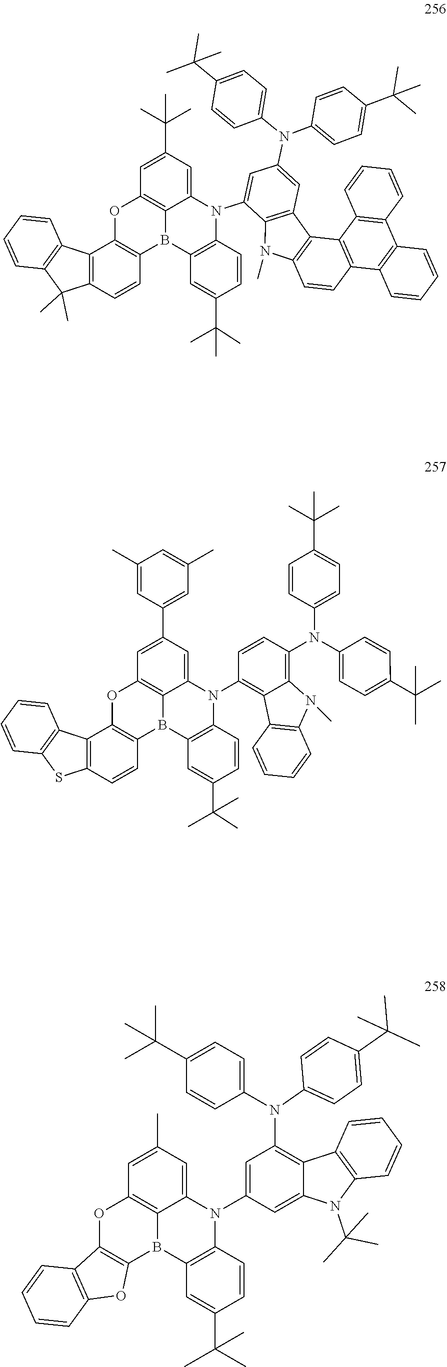 [SMILES: Cn1c2ccc3c4ccccc4c4ccccc4c3c2c2cc(N(c3ccc(C(C)(C)C)cc3)c3ccc(C(C)(C)C)cc3)cc(N3c4ccc(C(C)(C)C)cc4B4c5ccc6c(c5Oc5cc(C(C)(C)C)cc3c54)-c3ccccc3C6(C)C)c21 ; Cc1cc(C)cc(-c2cc3c4c(c2)N(c2ccc(N(c5ccc(C(C)(C)C)cc5)c5ccc(C(C)(C)C)cc5)c5c2c2ccccc2n5C)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c5ccccc5n(C(C)(C)C)c4c1)c1ccc(C(C)(C)C)cc1B3c1oc3ccccc3c1O2]

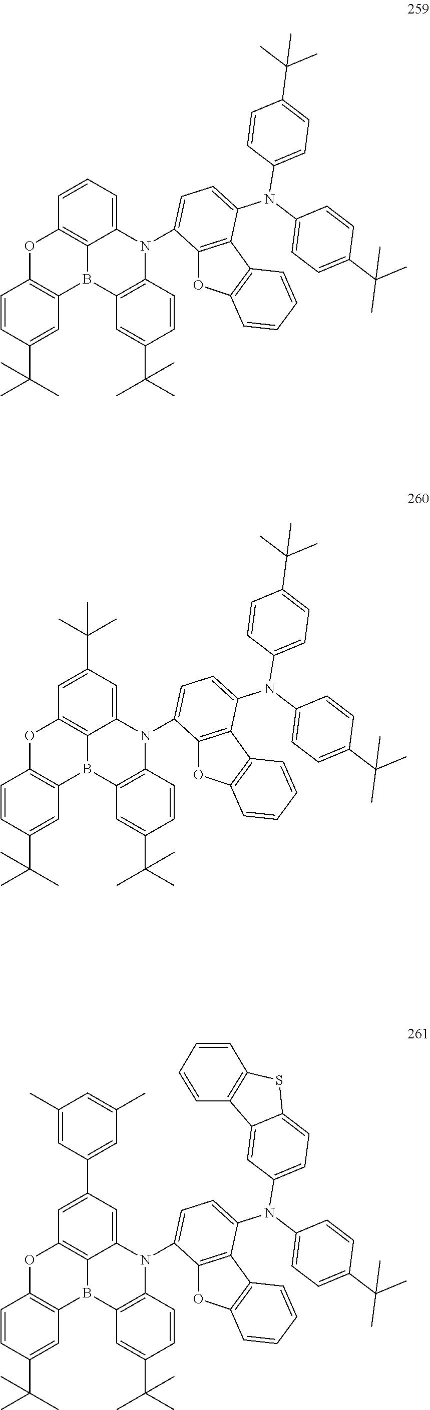 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3oc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3oc4ccccc4c23)cc1 ; Cc1cc(C)cc(-c2cc3c4c(c2)N(c2ccc(N(c5ccc(C(C)(C)C)cc5)c5ccc6sc7ccccc7c6c5)c5c2oc2ccccc25)c2ccc(C(C)(C)C)cc2B4c2cc(C(C)(C)C)ccc2O3)c1]

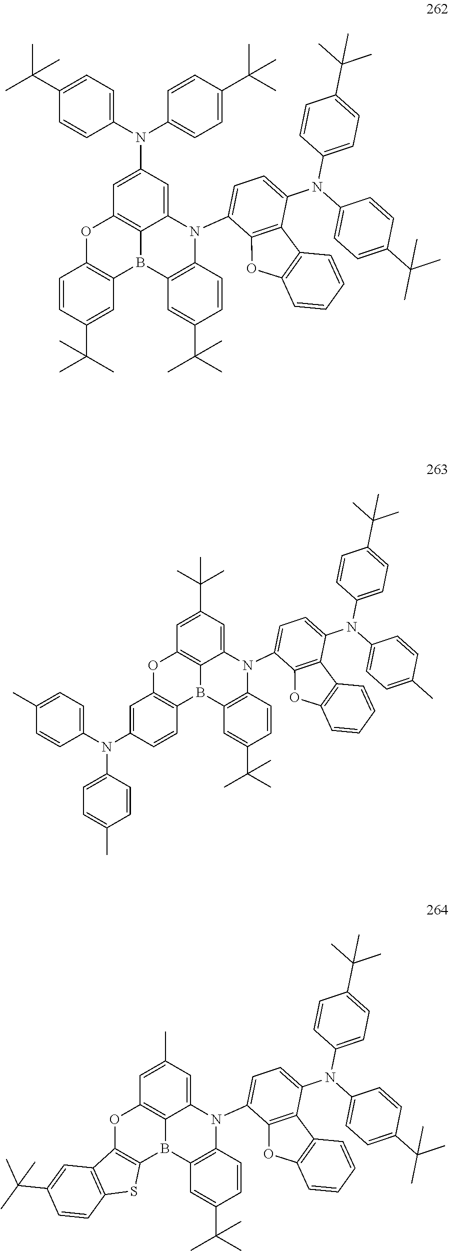

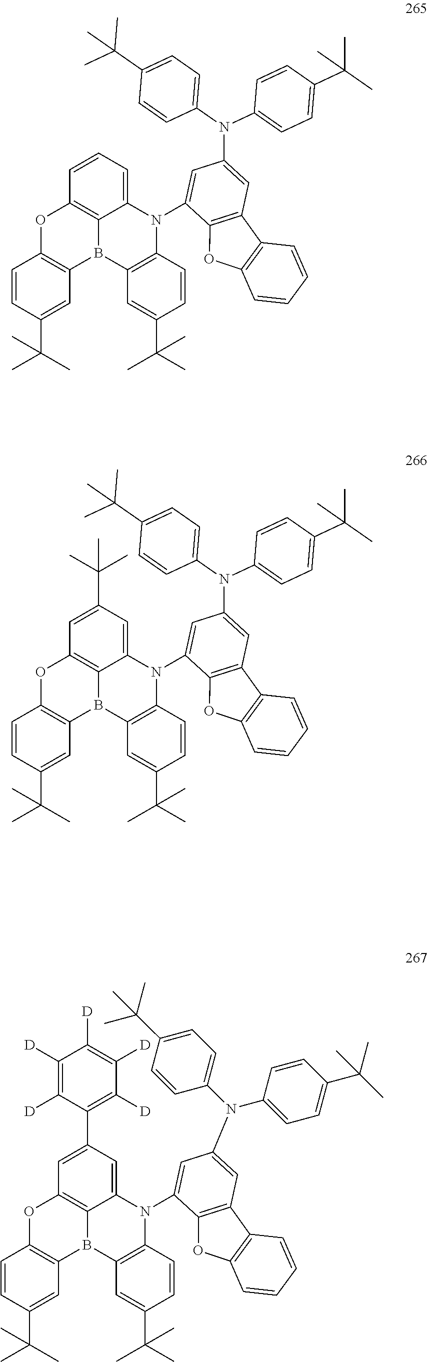 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3oc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3oc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2oc2ccccc25)c2ccc(C(C)(C)C)cc2B4c2cc(C(C)(C)C)ccc2O3)c([2H])c1[2H]]

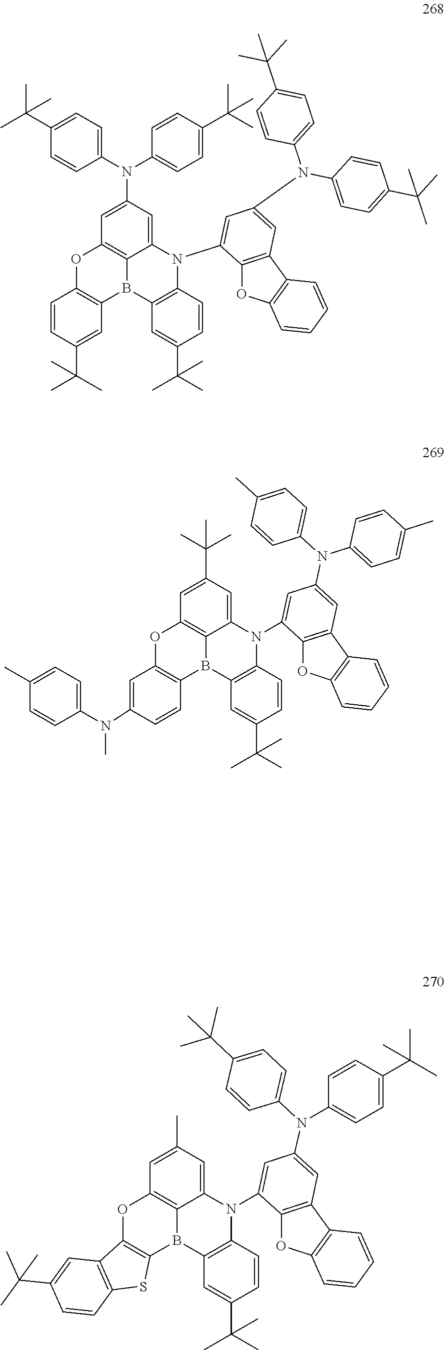

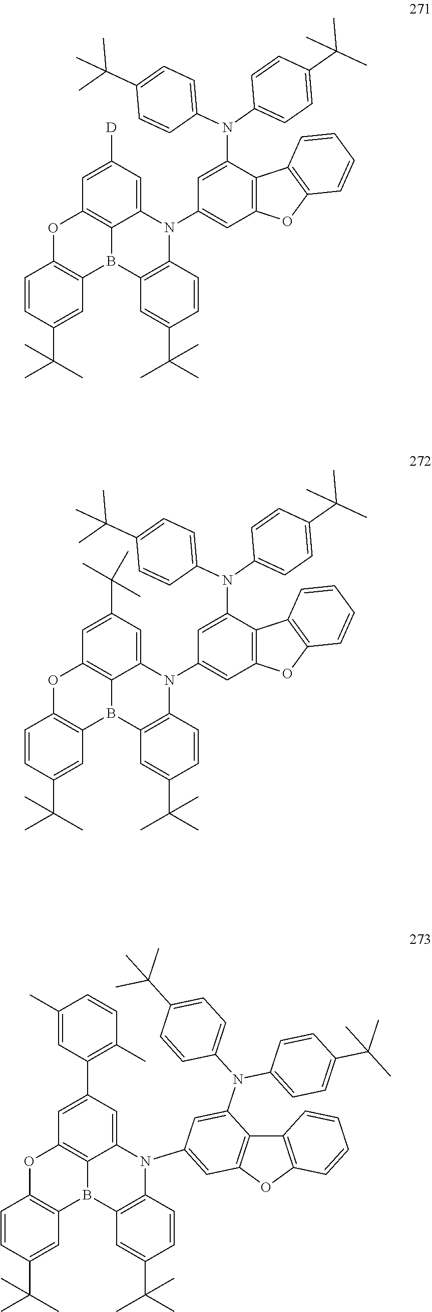 [SMILES: [2H]c1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3oc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)oc2ccccc25)c2ccc(C(C)(C)C)cc2B4c2cc(C(C)(C)C)ccc2O3)c1]

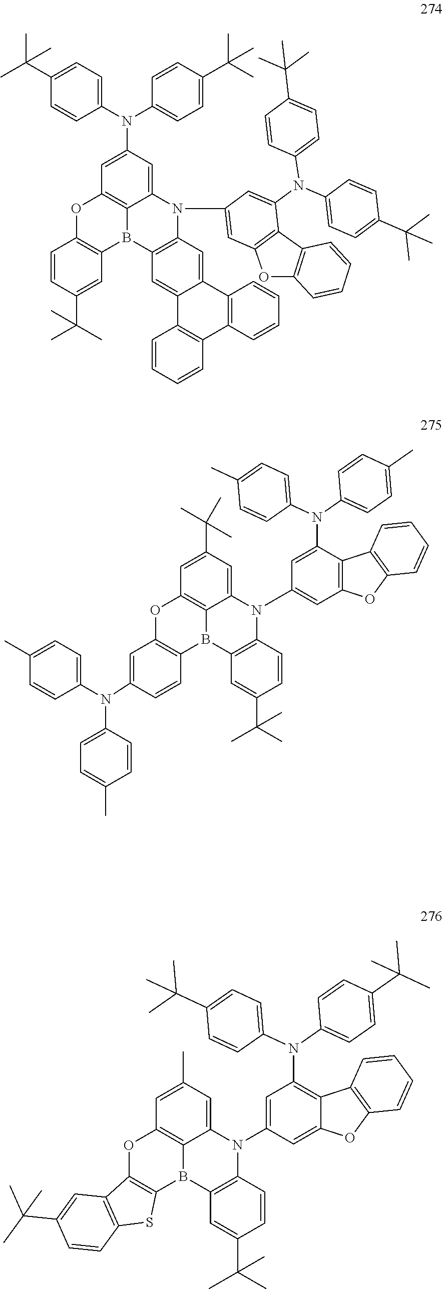

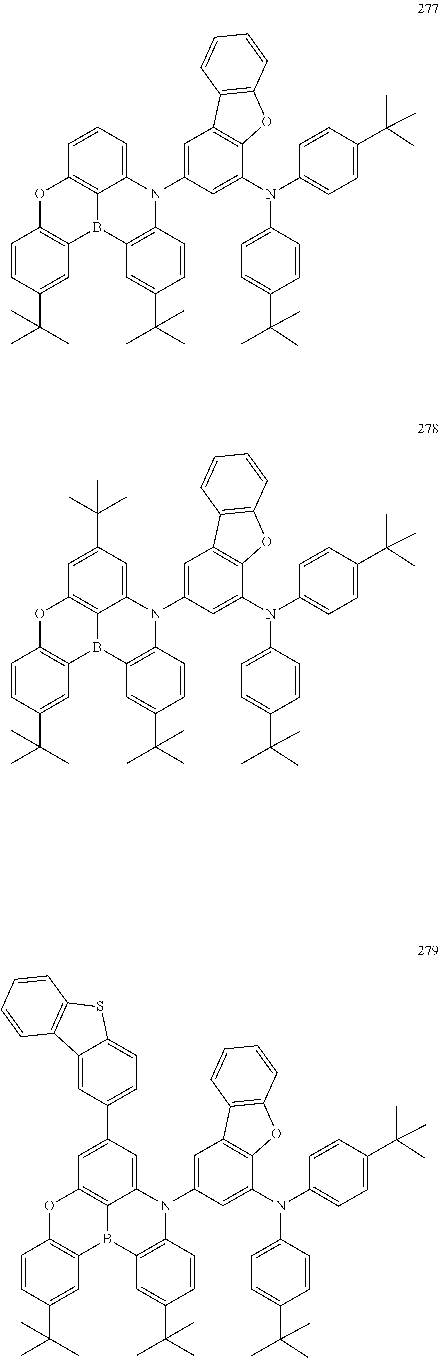 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(-c6ccc7sc8ccccc8c7c6)cc3c54)cc3c2oc2ccccc23)cc1]

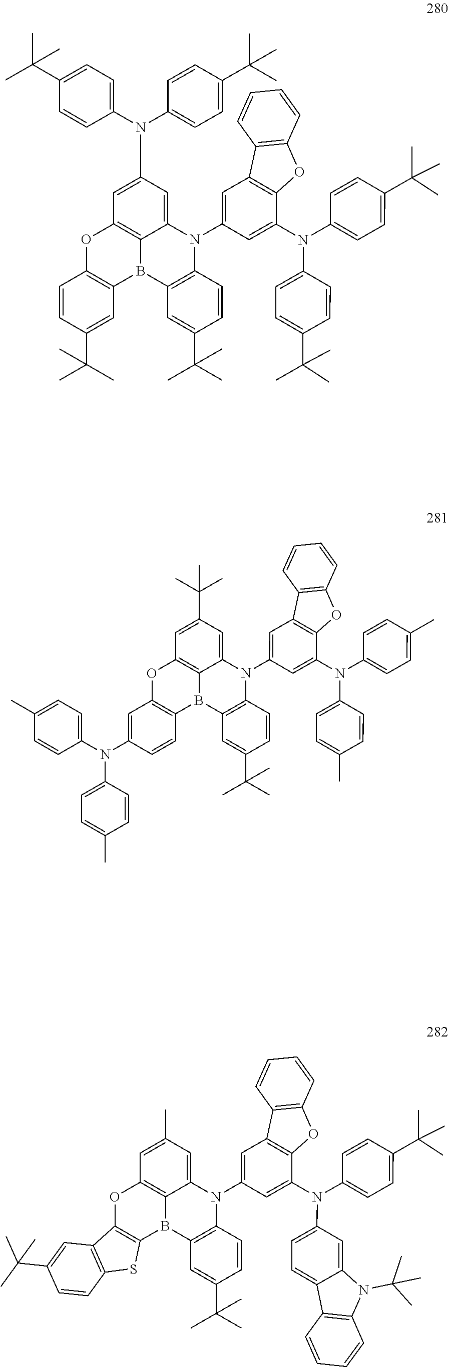

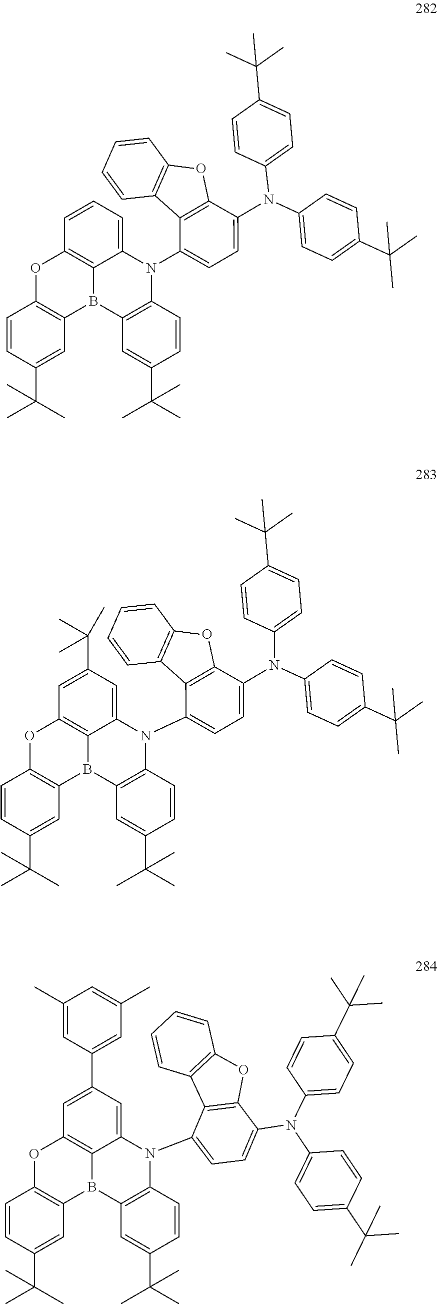 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2oc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2oc2ccccc23)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2cc(C(C)(C)C)ccc2O3)c1]

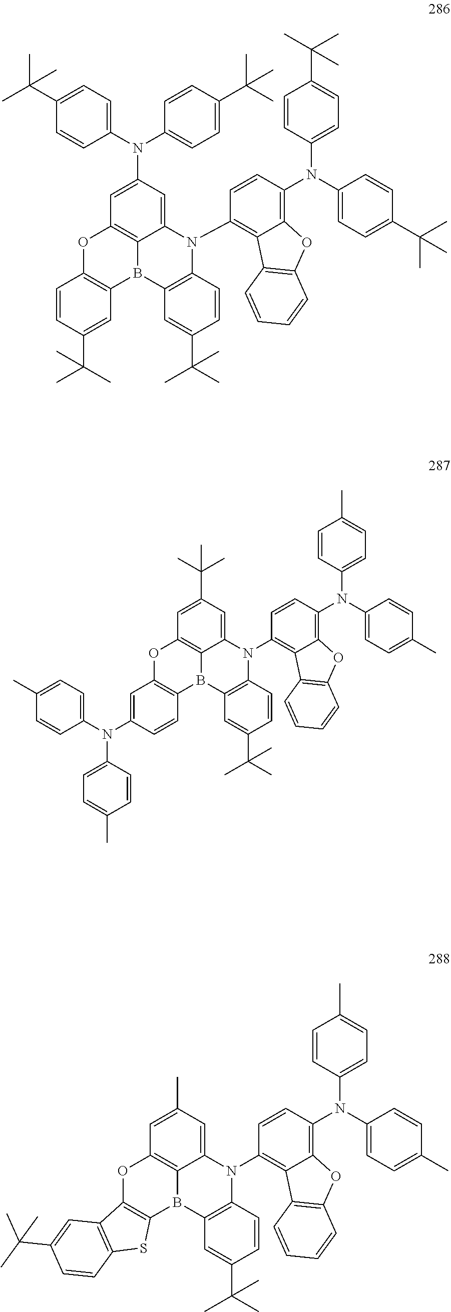

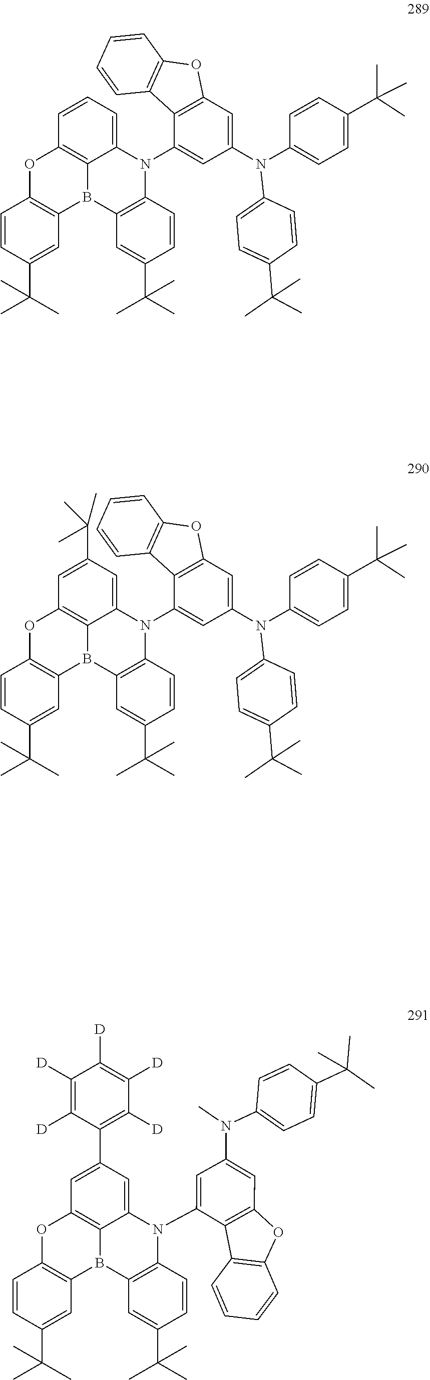 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)oc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)oc2ccccc23)cc1 ; [2H]c1c([2H])c([2H])c(-c2cc3c4c(c2)N(c2cc(N(C)c5ccc(C(C)(C)C)cc5)cc5oc6ccccc6c25)c2ccc(C(C)(C)C)cc2B4c2cc(C(C)(C)C)ccc2O3)c([2H])c1[2H]]

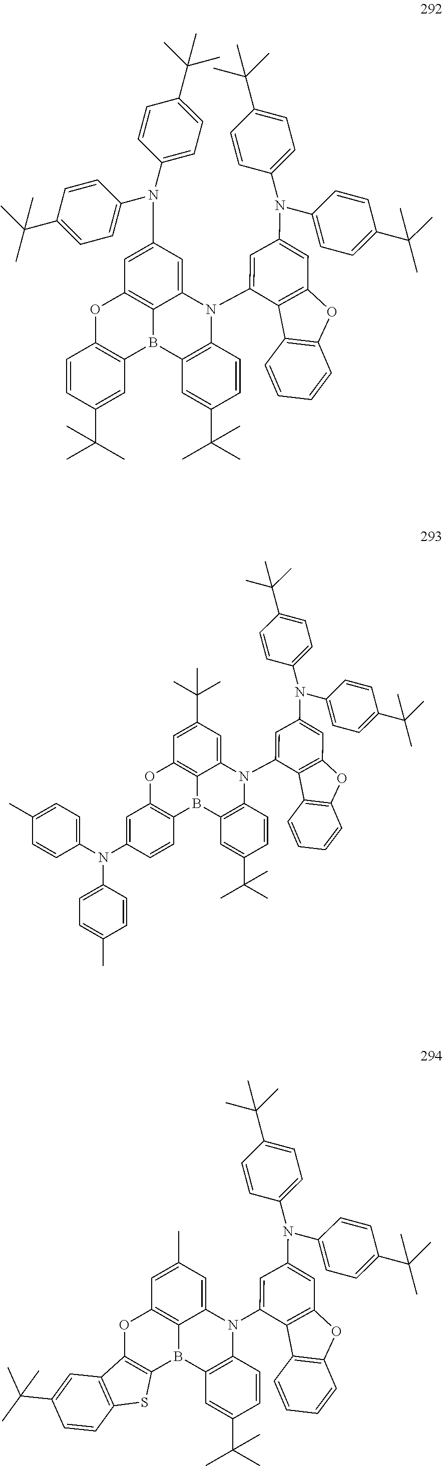

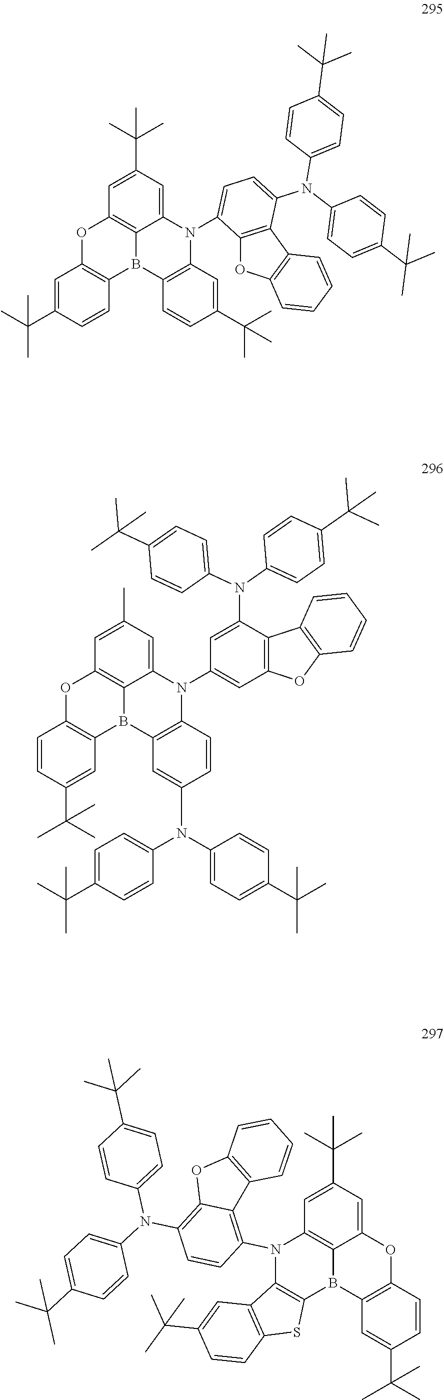

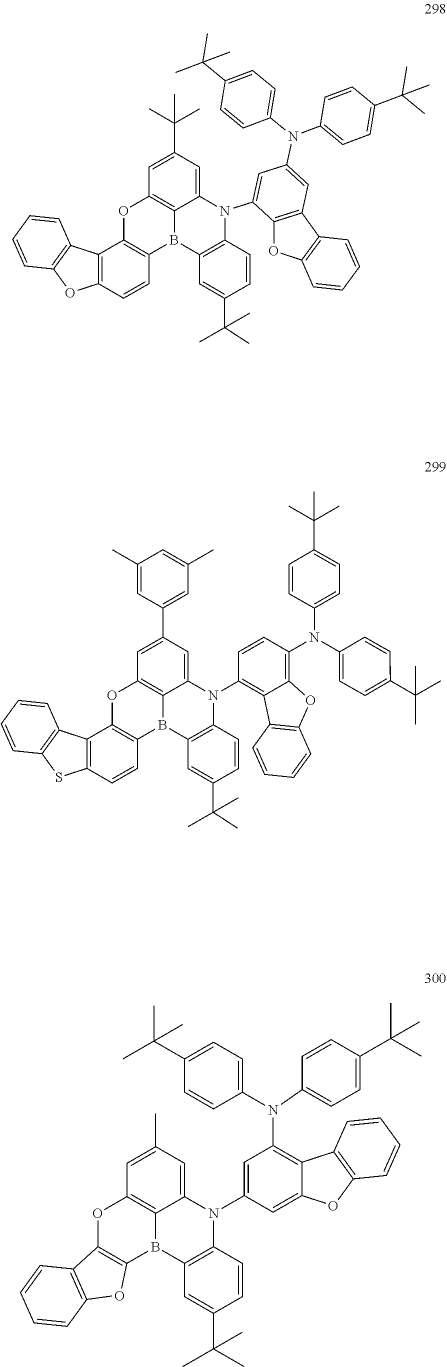 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3oc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5oc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)oc1ccccc14)c1ccc(C(C)(C)C)cc1B3c1oc3ccccc3c1O2]

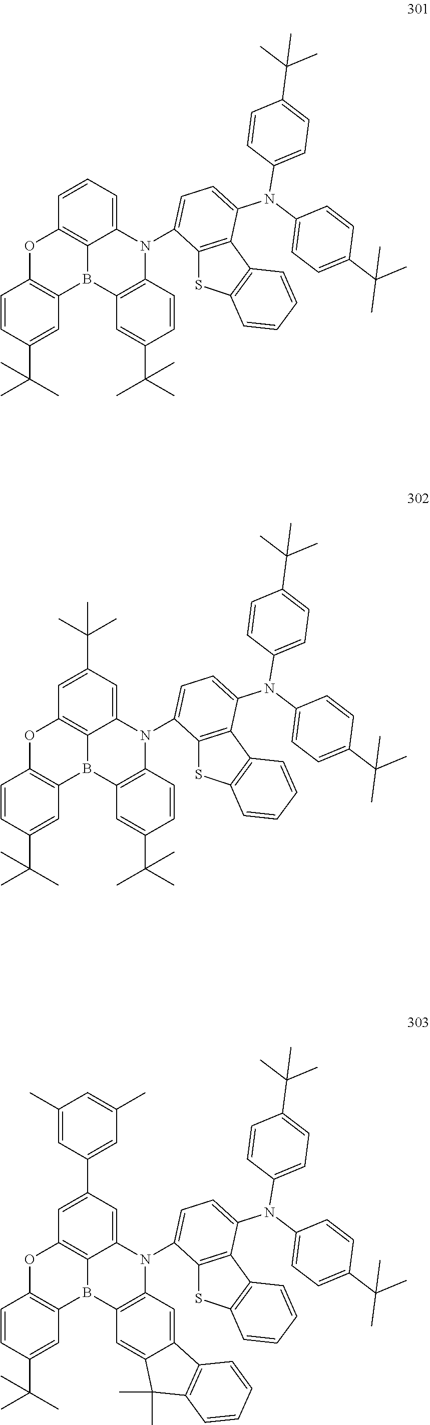 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3sc4ccccc4c23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3sc4ccccc4c23)cc1 ; Cc1cc(C)cc(-c2cc3c4c(c2)N(c2ccc(N(c5ccc(C(C)(C)C)cc5)c5ccc(C(C)(C)C)cc5)c5c2sc2ccccc25)c2cc5c(cc2B4c2cc(C(C)(C)C)ccc2O3)C(C)(C)c2ccccc2-5)c1]

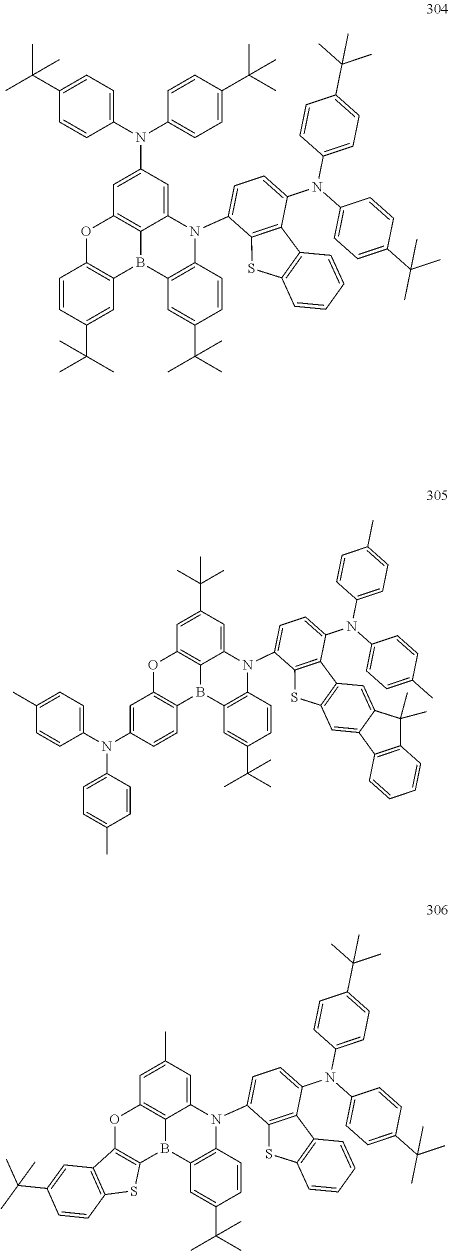

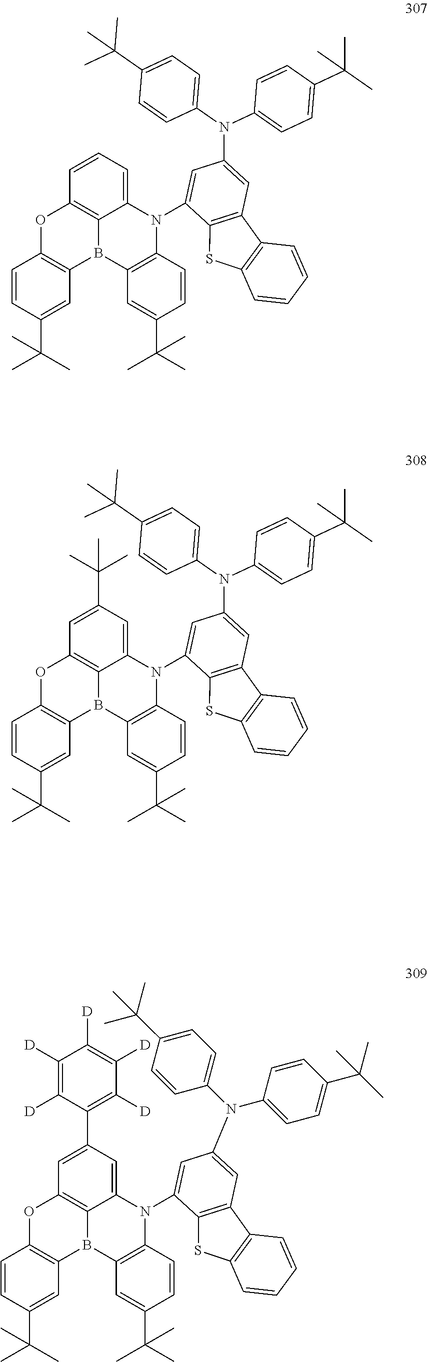 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3sc4ccccc4c3c2)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3sc4ccccc4c3c2)cc1 ; [2H]c1c([2H])c([2H])c(-c2cc3c4c(c2)N(c2cc(N(c5ccc(C(C)(C)C)cc5)c5ccc(C(C)(C)C)cc5)cc5c2sc2ccccc25)c2ccc(C(C)(C)C)cc2B4c2cc(C(C)(C)C)ccc2O3)c([2H])c1[2H]]

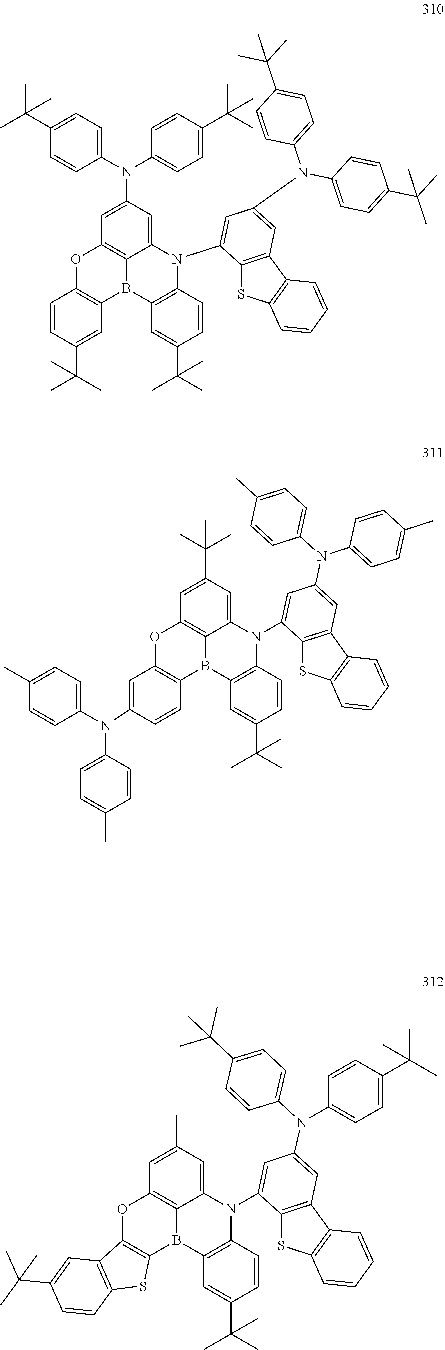

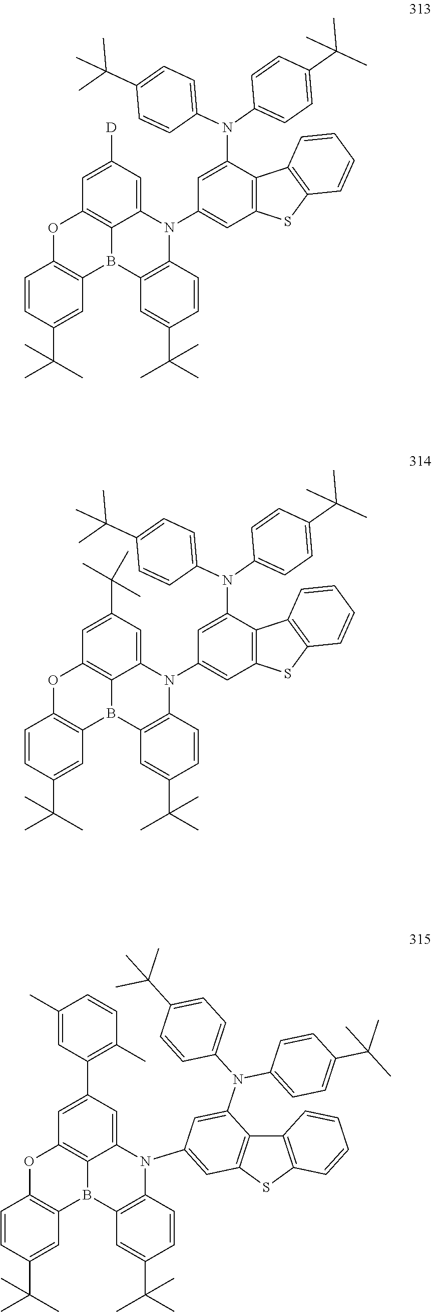 [SMILES: [2H]c1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1cc(C(C)(C)C)ccc1O2 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3sc4ccccc4c23)cc1 ; Cc1ccc(C)c(-c2cc3c4c(c2)N(c2cc(N(c5ccc(C(C)(C)C)cc5)c5ccc(C(C)(C)C)cc5)c5c(c2)sc2ccccc25)c2ccc(C(C)(C)C)cc2B4c2cc(C(C)(C)C)ccc2O3)c1]

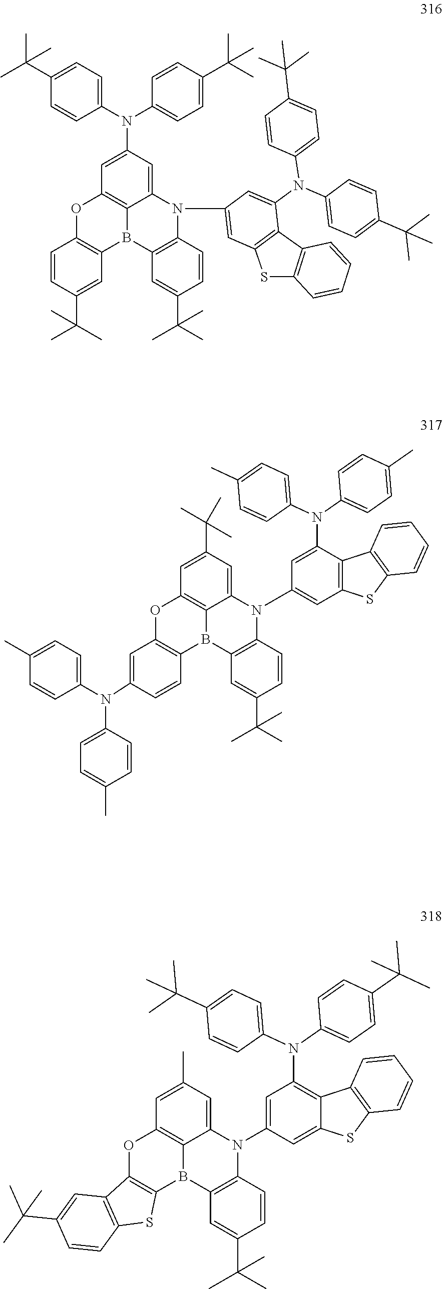

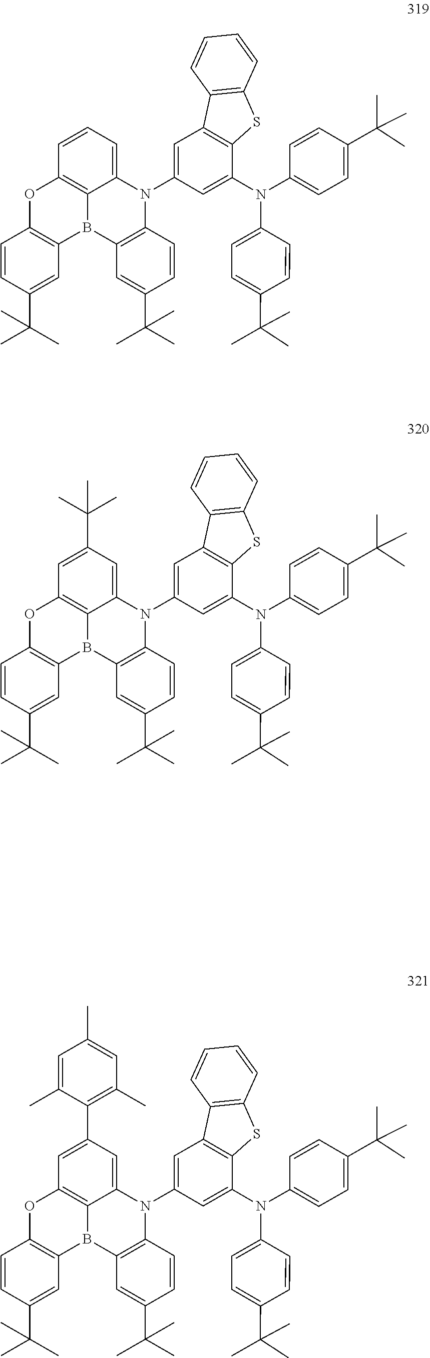 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)cc3c2sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)cc3c2sc2ccccc23)cc1 ; Cc1cc(C)c(-c2cc3c4c(c2)N(c2cc(N(c5ccc(C(C)(C)C)cc5)c5ccc(C(C)(C)C)cc5)c5sc6ccccc6c5c2)c2ccc(C(C)(C)C)cc2B4c2cc(C(C)(C)C)ccc2O3)c(C)c1]

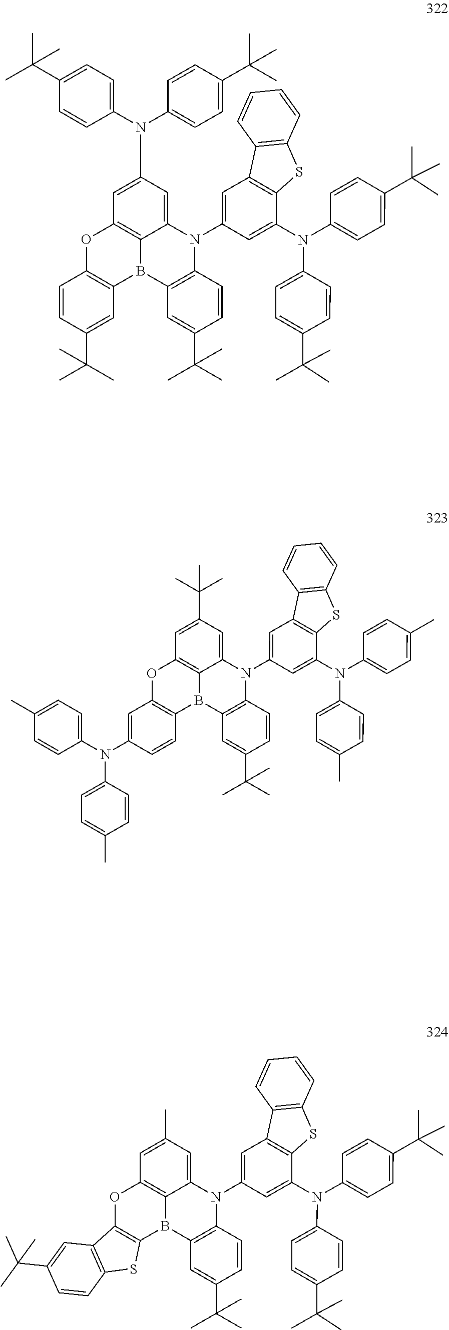

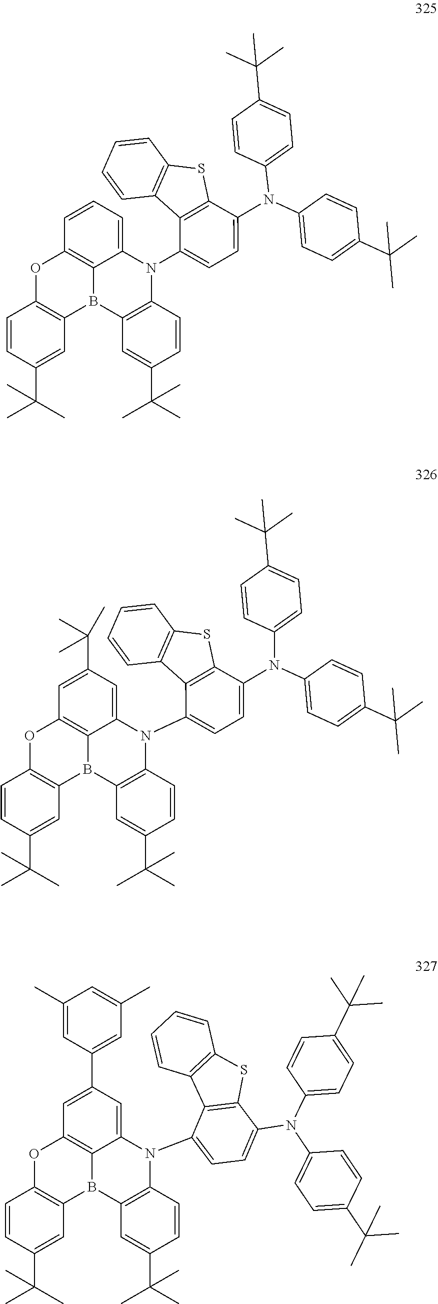 [SMILES: CC(C)(C)c1ccc(N(c2ccc(C(C)(C)C)cc2)c2ccc(N3c4ccc(C(C)(C)C)cc4B4c5cc(C(C)(C)C)ccc5Oc5cccc3c54)c3c2sc2ccccc23)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(C(C)(C)C)cc3c54)c3c2sc2ccccc23)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2cc(C(C)(C)C)ccc2O3)c1]

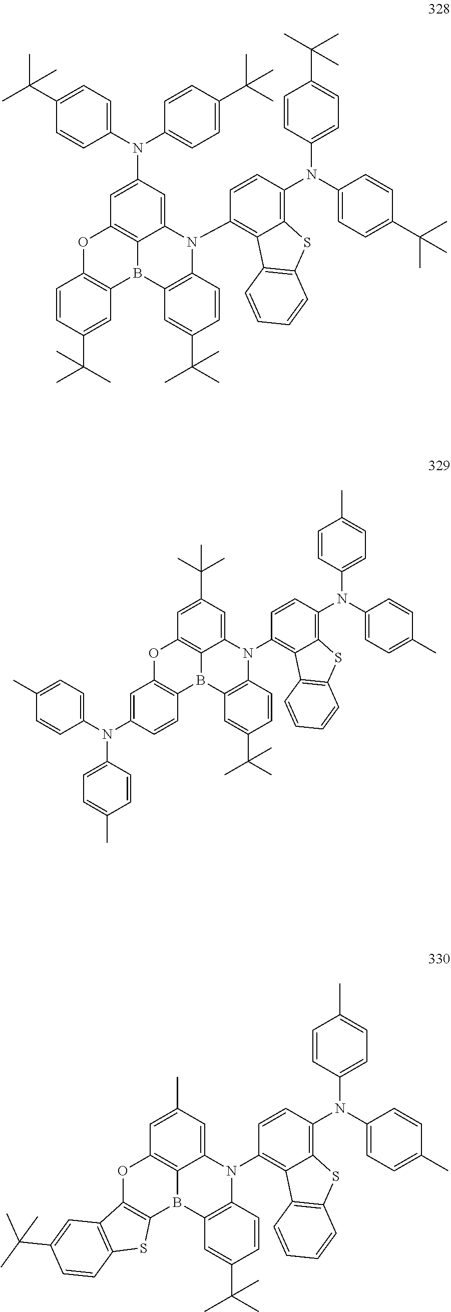

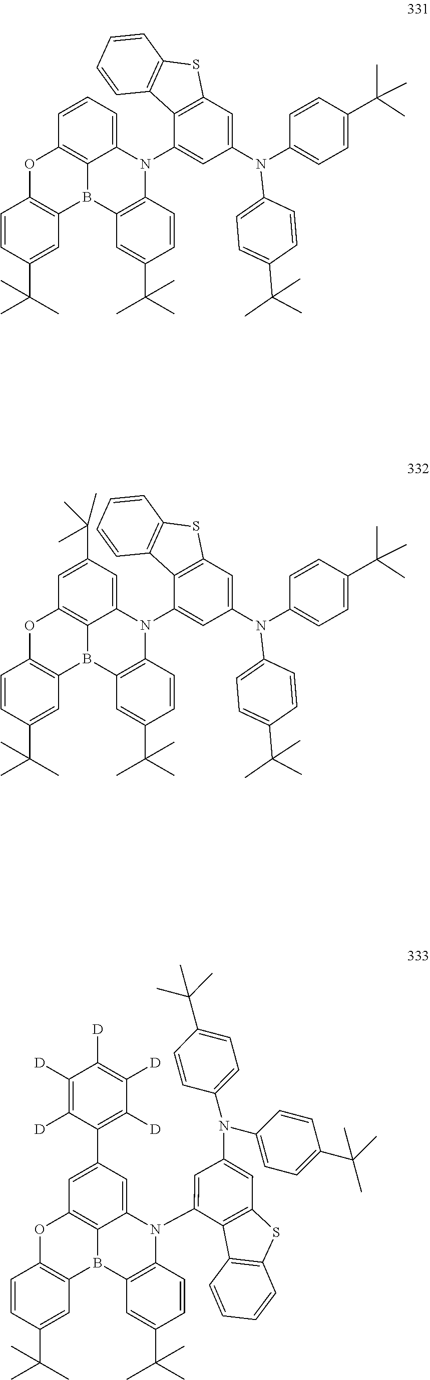 [SMILES: CC(C)(C)c1ccc(N(c2ccc(C(C)(C)C)cc2)c2cc(N3c4ccc(C(C)(C)C)cc4B4c5cc(C(C)(C)C)ccc5Oc5cccc3c54)c3c(c2)sc2ccccc23)cc1 ; CC(C)(C)c1ccc(N(c2ccc(C(C)(C)C)cc2)c2cc(N3c4ccc(C(C)(C)C)cc4B4c5cc(C(C)(C)C)ccc5Oc5cc(C(C)(C)C)cc3c54)c3c(c2)sc2ccccc23)cc1 ; [2H]c1c([2H])c([2H])c(-c2cc3c4c(c2)N(c2cc(N(c5ccc(C(C)(C)C)cc5)c5ccc(C(C)(C)C)cc5)cc5sc6ccccc6c25)c2ccc(C(C)(C)C)cc2B4c2cc(C(C)(C)C)ccc2O3)c([2H])c1[2H]]

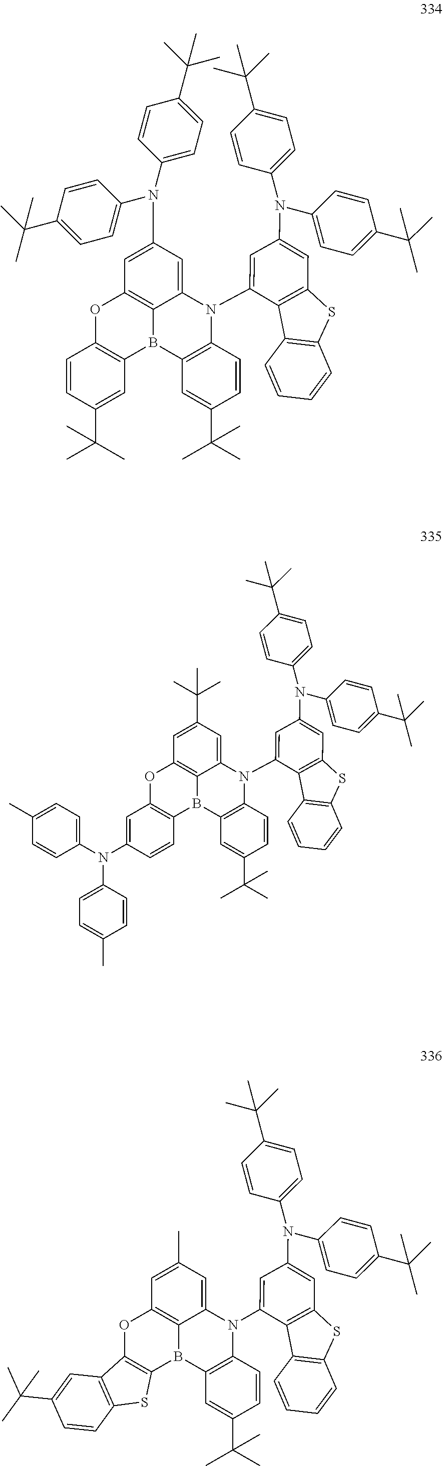

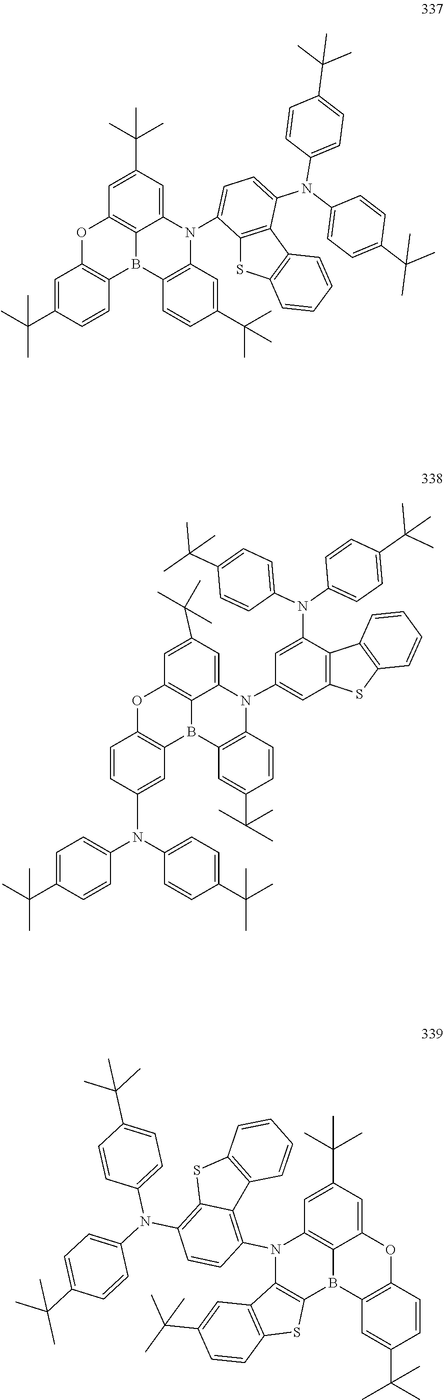

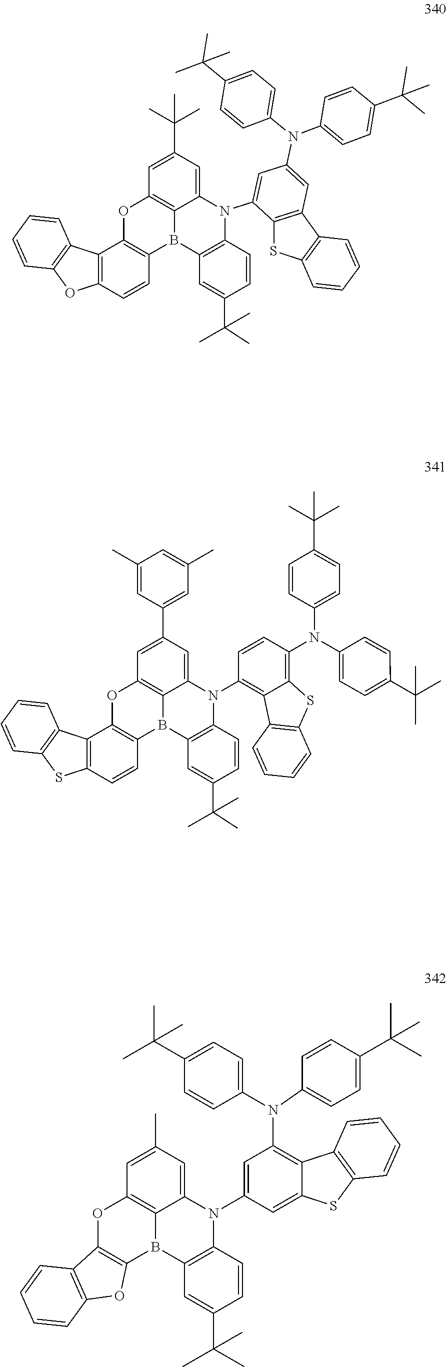 [SMILES: CC(C)(C)c1ccc(N(c2ccc(C(C)(C)C)cc2)c2cc(N3c4ccc(C(C)(C)C)cc4B4c5ccc6oc7ccccc7c6c5Oc5cc(C(C)(C)C)cc3c54)c3sc4ccccc4c3c2)cc1 ; Cc1cc(C)cc(-c2cc3c4c(c2)N(c2ccc(N(c5ccc(C(C)(C)C)cc5)c5ccc(C(C)(C)C)cc5)c5sc6ccccc6c25)c2ccc(C(C)(C)C)cc2B4c2ccc4sc5ccccc5c4c2O3)c1 ; Cc1cc2c3c(c1)N(c1cc(N(c4ccc(C(C)(C)C)cc4)c4ccc(C(C)(C)C)cc4)c4c(c1)sc1ccccc14)c1ccc(C(C)(C)C)cc1B3c1oc3ccccc3c1O2]

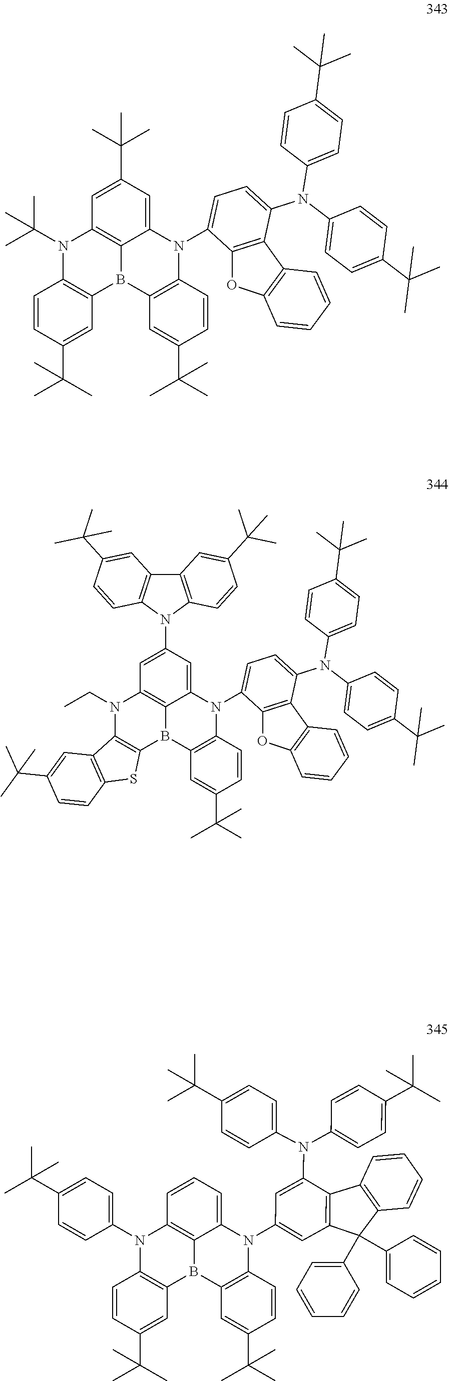

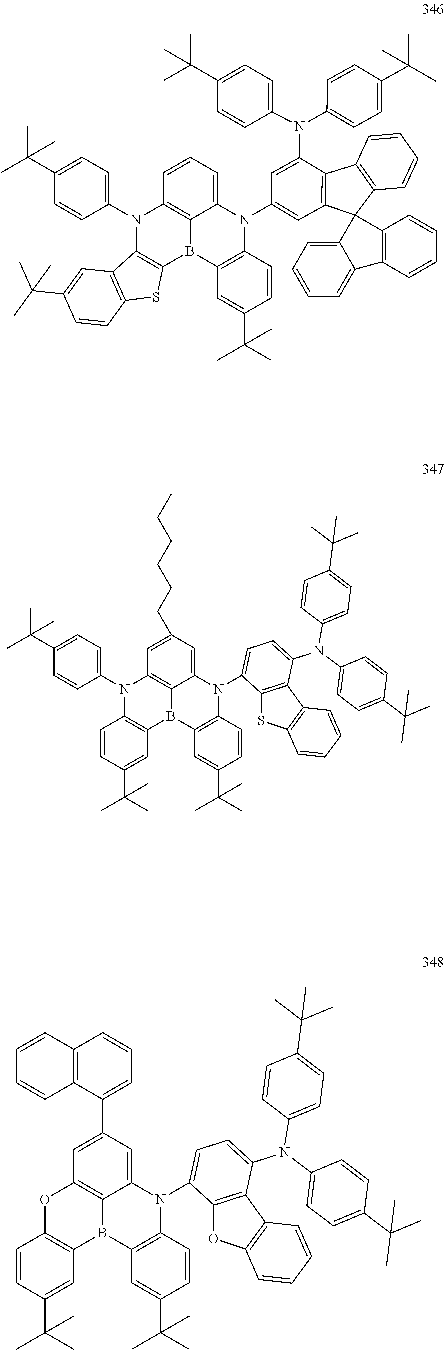 [SMILES: CC(C)(C)c1ccc(N(c2ccc(C(C)(C)C)cc2)c2cc(N3c4ccc(C(C)(C)C)cc4B4c5sc6ccc(C(C)(C)C)cc6c5N(c5ccc(C(C)(C)C)cc5)c5cccc3c54)cc3c2-c2ccccc2C32c3ccccc3-c3ccccc32)cc1 ; CCCCCCc1cc2c3c(c1)N(c1ccc(N(c4ccc(C(C)(C)C)cc4)c4ccc(C(C)(C)C)cc4)c4c1sc1ccccc14)c1ccc(C(C)(C)C)cc1B3c1cc(C(C)(C)C)ccc1N2c1ccc(C(C)(C)C)cc1 ; CC(C)(C)c1ccc(N(c2ccc(C(C)(C)C)cc2)c2ccc(N3c4ccc(C(C)(C)C)cc4B4c5cc(C(C)(C)C)ccc5Oc5cc(-c6cccc7ccccc67)cc3c54)c3oc4ccccc4c23)cc1]

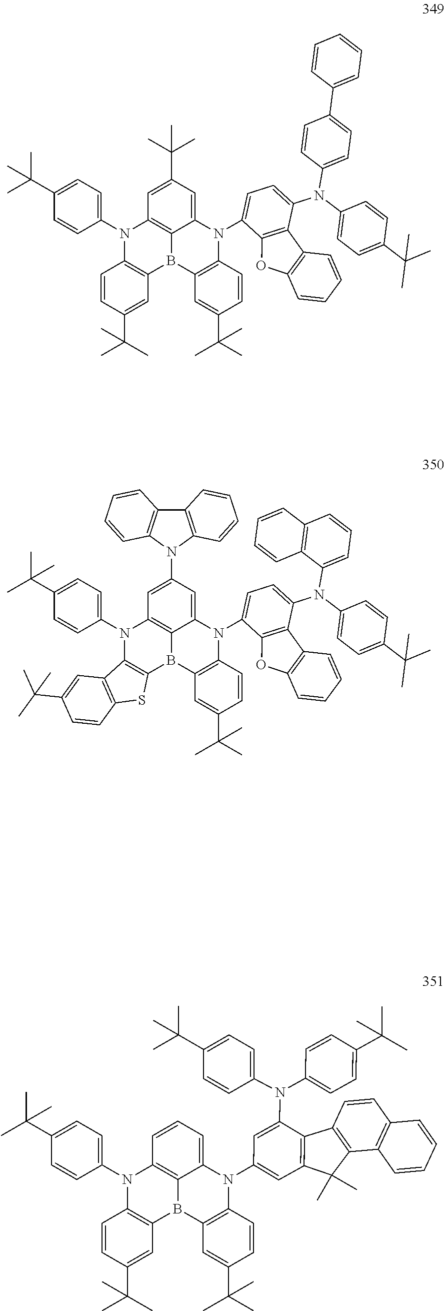

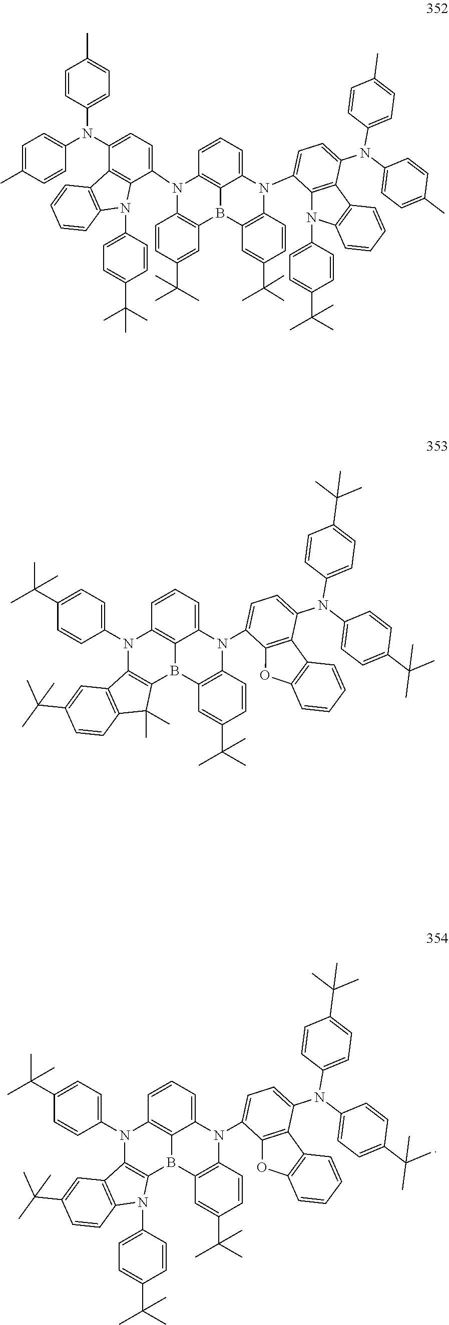

13. A light-emitting clement, comprising:
a pair of electrodes comprising a first electrode and a second electrode; and
an organic functional layer located between the first electrode and the second electrode;
wherein materials of the organic functional layer comprise at least one organic compound represented by formula (1): 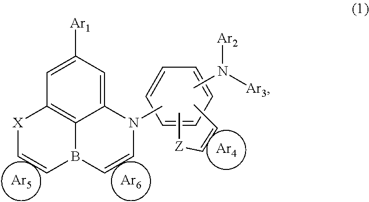
wherein Z is selected from CR₁R₂, NR₃, O, and S;
X is selected from O and NR₄;
R₁, R₂, R₃, and R₄ are each independently selected from a substituted or unsubstituted C₁-C₄ alkyl group, a substituted or unsubstituted C₆-C₂₉ aromatic group, and a substituted or unsubstituted C₂₆-C₃₆ heteroaromatic group;
a ring is formed or no ring is formed by an interconnection of R₁ and R₂;
Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group;
Ar₂ and Ar₃ are each independently selected from a methyl group, a substituted or unsubstituted C₇-C₁₈ aromatic group, and a substituted or unsubstituted C₁₂-C₁₆ heteroaromatic group; and
Ar₄, Ar₅, and Ar₆ are each independently selected from a substituted or unsubstituted C₆-C₃₁ aromatic group and a substituted or unsubstituted C₆-C₂₆ heteroaromatic group.

14. The light-emitting element of claim 13, wherein the organic functional layer comprises at least a light-emitting layer, the light-emitting layer comprises a host material and a guest material, and the guest material is the organic compound.

15. The light-emitting element of claim 13, wherein the organic compound is represented any one of formula (2) to formula (11):

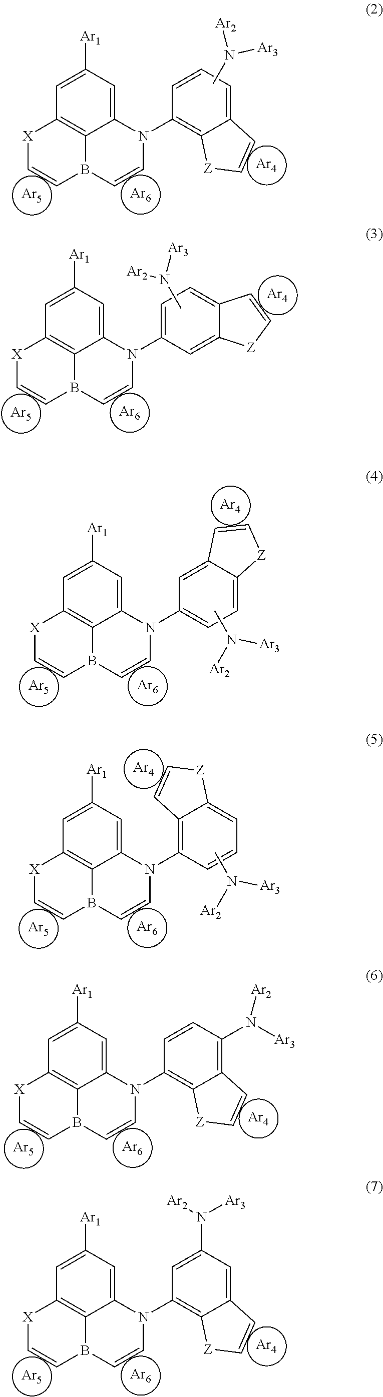

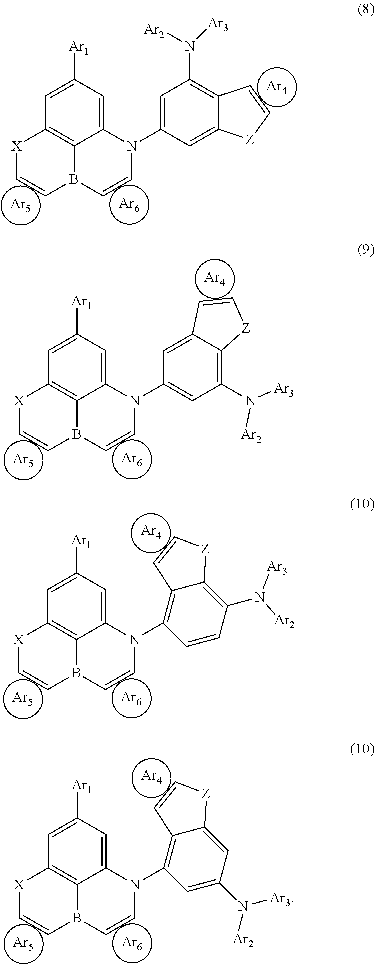

16. The light-emitting element of claim 13, wherein the organic compound is represented by formula (12): 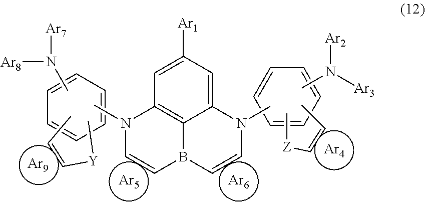
wherein Y is selected from CR₅R₆, NR₇, O, and S;
R₅, R₆, and R₇ are each independently selected from a substituted or unsubstituted methyl group and a substituted or unsubstituted C₆-C₁₀ aromatic group;
a ring is formed or no ring is formed by an interconnection of R₅ and R₆;
Ar₇ and Ar₈, are each independently selected from a substituted or unsubstituted C₆-C₁₀ aromatic group; and
Ar₉ is selected from a substituted or unsubstituted phenyl group.

17. The light-emitting element of claim 16, wherein R₅, R₆, and R₇ are each independently selected from a methyl group and a substituted or unsubstituted phenyl group;
Ar₇ and Ar₈, are each independently selected from a methyl group, a substituted or unsubstituted phenyl group, and a substituted or unsubstituted naphthyl group.

18. The light-emitting element of claim 13, wherein the organic compound is represented by formula (13): 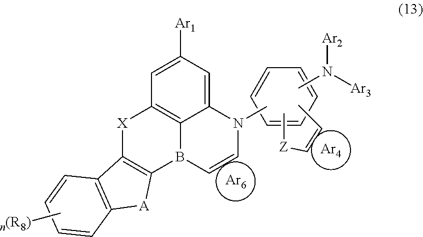
wherein A is represented by CR₉R₁₀, NR₁₁, O, or S;
n is an integer ranging from 0 to 4;
R₈, R₉, R₁₀, and R₁₁ are each independently selected from a substituted or unsubstituted C₁-C₄ alkyl group and a substituted or unsubstituted C₆-C₁₀ aromatic group; and
when n is equal to 0, a ring is formed or no ring is formed by an interconnection of R₉ and R₁₀; when n is greater than or equal to 1, a ring is formed or no ring is formed by an interconnection of R₈ and R₉ and/or R₁₀.

19. The light-emitting element of claim 13, wherein the organic compound is represented by formula (14): 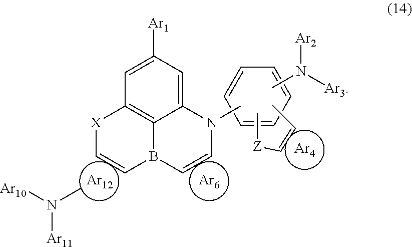
wherein Ar₁₀ and Ar₁₁ are each independently selected from a methyl group, a substituted or unsubstituted C₆-C₁₈ aromatic group, and a substituted or unsubstituted C₅-C₁₃ heteroaromatic group; and
Ar₁₂ is selected from a substituted or unsubstituted phenyl group.

20. A display panel, comprising a light-emitting element, wherein the light-emitting element comprises:
a pair of electrodes comprising a first electrode and a second electrode; and
an organic functional layer located between the first electrode and the second electrode;
wherein materials of the organic functional layer comprise at least one organic compound, the organic compound is represented by formula (1): 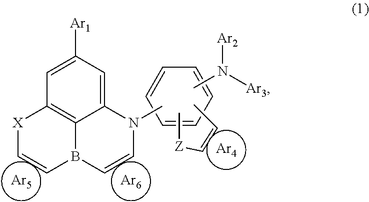
wherein Z is selected from CR₁R₂, NR₃, O, and S;
X is selected from O and NR₄;
R₁, R₂, R₃, and R₄ are each independently selected from a substituted or unsubstituted C₁-C₄ alkyl group, a substituted or unsubstituted C₆-C₂₉ aromatic group, and a substituted or unsubstituted C₂₆-C₃₆ heteroaromatic group;
a ring is formed or no ring is formed by an interconnection of R₁ and R₂;
Ar₁ is selected from —H, —D, a substituted or unsubstituted C₁-C₆ alkyl group, a substituted or unsubstituted C₆-C₂₀ aromatic group, and a substituted or unsubstituted C₁₂-C₂₀ heteroaromatic group;
Ar₂ and Ar₃ are each independently selected from a methyl group, a substituted or unsubstituted C₇-C₁₈ aromatic group, and a substituted or unsubstituted C₁₂-C₁₆ heteroaromatic group; and
Ar₄, Ar₅, and Ar₆ are each independently selected from a substituted or unsubstituted C₆-C₃₁ aromatic group and a substituted or unsubstituted C₆-C₂₆ heteroaromatic group.
